(19) United States
(12) Patent Application Publication
(10) Pub. No.: US 2018/0138326 A1
(43) Pub. Date: May 17, 2018

(54) ORGANIC THIN FILM SOLAR CELL MODULE, ELECTRONIC DEVICE AND METHOD FOR MANUFACTURING ORGANIC THIN FILM SOLAR CELL MODULE

(71) Applicant: ROHM CO., LTD., Kyoto-shi, Kyoto (JP)

(72) Inventor: Yoichi AOKI, Kyoto-shi, Kyoto (JP)

(73) Assignee: ROHM CO., LTD., Kyoto-shi, Kyoto (JP)

(21) Appl. No.: 15/575,248

(22) PCT Filed: May 19, 2016
(86) PCT No.: PCT/JP2016/064882

§ 371 Date: Nov. 17, 2017

(30) Foreign Application Priority Data
May 19, 2015 (JP) 2015-102193
May 19, 2015 (JP) 2015-102202
Jul. 31, 2015 (JP) 2015-152377
Feb. 23, 2016 (JP) 2016-031716
Mar. 4, 2016 (JP) 2016-041982
Mar. 11, 2016 (JP) 2016-047834
Mar. 14, 2016 (JP) 2016-049770
May 18, 2016 (JP) 2016-099721

(51) Int. Cl. H01L 31/0256; H01L 31/041; H01L 31/18; H01L 31/0224

(52) U.S. Cl. CPC H01L 31/0256; H01L 31/041; H01L 31/18; Y02E 10/549; H01L 31/1868; H01L 2031/0344; H01L 31/022475

(57) ABSTRACT

An organic thin film solar cell module A1 includes a transparent base substrate 41, a transparent first conductive layer 1 disposed on the base substrate 41, a second conductive layer 2, and a photoelectric conversion layer 3 formed of an organic thin film and interposed between the first conductive layer 1 and the second conductive layer 2. The second conductive layer 2 is thicker than the photoelectric conversion layer 3. The arrangements prevent occurrence of damage.

### TECHNICAL FIELD

The present invention relates to an organic thin film solar cell module, an electronic device, and a manufacturing method of the organic thin film solar cell module.

### BACKGROUND ART

Solar cells, which have a photoelectric conversion function to convert light, typically sunlight, into electric power, have been developed as a power generation means that utilizes what is known as renewable energy. The organic thin film solar cell is an example of the solar cell. Patent Literature (PTL) 1 discloses a configuration including a photoelectric conversion layer formed of an organic thin film, and a first conductive layer and a second conductive layer, between which the photoelectric conversion layer is interposed. The first conductive layer is a transparent conductive layer, for example formed of ITO.

In the organic thin film solar cell module, a projection may be formed on the photoelectric conversion layer, or particles may stick to the photoelectric conversion layer, during the formation process thereof. In such cases, the shape of the second conductive layer may be deformed, which may allow outside air to intrude.

As mentioned above, the solar cells, which have a photoelectric conversion function to convert light, typically sunlight, into electric power, have been developed as a power generation means that utilizes what is known as renewable energy. The organic thin film solar cell is an example of the solar cell. PTL 1 discloses a configuration including a photoelectric conversion layer formed of an organic thin film, and a first conductive layer and a second conductive layer, between which the photoelectric conversion layer is interposed. The first conductive layer is a transparent conductive layer, for example formed of ITO. FIG. 34 to FIG. 36 of PTL 1 illustrate an organic thin film solar cell including an opening. The opening is formed to expose a display unit such as an LCD on the outer appearance. Accordingly, the photoelectric conversion layer and the second electrode layer each include the opening of the same shape and size.

In the case of electronic devices, it is required to exhibit, in addition to the display unit, a design expressing the manufacturer's name, the product name, and characters or patterns that are desired to be displayed. For such a purpose, additional components or materials have to be prepared, for example for stacking a design plate expressing a design on the organic thin film solar cell module, or printing a design on the organic thin film solar cell module.

As mentioned above, the solar cells, which have a photoelectric conversion function to convert light, typically sunlight, into electric power, have been developed as a power generation means that utilizes what is known as renewable energy. The organic thin film solar cell is an example of the solar cell. PTL 1 discloses a configuration including a photoelectric conversion layer formed of an organic thin film, and a first conductive layer and a second conductive layer, between which the photoelectric conversion layer is interposed. The first conductive layer is a transparent conductive layer, for example formed of ITO. The configuration according to PTL 1 also includes a passivation film that protects the first conductive layer, the second conductive layer, and the photoelectric conversion layer. FIG. 34 to FIG. 36 of PTL 1 illustrate an organic thin film solar cell including an opening. The opening is formed to expose a display unit such as an LCD on the outer appearance. Accordingly, the photoelectric conversion layer and the second electrode layer each include the opening of the same shape and size.

The opening is, however, covered with the first conductive layer and the passivation film. Although the opening is translucent, it is tinted by the color of the first conductive layer and the passivation film when the first conductive layer and the passivation film are configured to have the expected functions.

As mentioned above, the solar cells, which have a photoelectric conversion function to convert light, such as sunlight, into electric power, have been developed as a power generation means that utilizes what is known as renewable energy. PTL 1 discloses a basic configuration of the organic thin film solar cell, including a photoelectric conversion layer formed of an organic thin film, and a first conductive layer and a second conductive layer, between which the photoelectric conversion layer is interposed.

The electronic devices are required to exhibit, on the surface of the casing, a design that is visually recognized from outside, such as the manufacturer's name, the product name, characters, or patterns. Such a design is normally exhibited on the surface of the casing by printing, carving, or sticking a label, and therefore it would be convenient, when the organic thin film solar cell occupies a major part of the casing surface, if the design can be put on a region of the casing surface where the organic thin film solar cell is located.

However, in the case where the design is printed on, or a label is stuck to the surface of the organic thin film solar cell, in other words the light receiving surface, additional materials for providing the design have to be prepared, and besides the quality of the design may be degraded, or the design itself may be lost, because of contacts or friction with other objects. Further, the photoelectric conversion efficiency is substantially degraded, since the photoelectric conversion layer is hidden by the design.

As mentioned above, the opening is covered with the first conductive layer and the passivation film. Although the opening is translucent, it is tinted by the color of the first conductive layer and the passivation film when the first conductive layer and the passivation film are configured to have the expected functions.

Further, in the organic thin film solar cell module, it is desirable to increase the ratio of the portion of the photoelectric conversion layer that actually contributes to generating power.

In addition, when the power obtained through the photoelectric conversion function is supplied, greater loss is suffered in the first conductive layer, than in the second conductive layer. Such a loss is naturally undesirable, since the power generation efficiency of the organic thin film solar cell module as a whole is degraded.

In the organic thin film solar cell module, further, it is required to prevent a decrease in ratio of the portion of the photoelectric conversion layer that actually contributes to generating power.

### CITATION LIST

### Patent Literature

PTL 1: JP-A-2014-192196

### SUMMARY OF INVENTION

### Technical Problem

The present invention has been accomplished in view of the foregoing situation, and provides an organic thin film solar cell module and an electronic device configured to prevent a damage, and a manufacturing method of the organic thin film solar cell module. The present invention also provides an organic thin film solar cell module and an electronic device that can exhibit a design on the outer appearance, without the need to employ additional components. The present invention also provides an organic thin film solar cell module and an electronic device having a more transparent surface, and a manufacturing method of such an organic thin film solar cell module. Further, the present invention provides an organic thin film solar cell that can exhibit a design on the outer appearance, without the need to employ additional components. Further, the present invention provides an organic thin film solar cell module and an electronic device having a more transparent surface, and a manufacturing method of such an organic thin film solar cell module. The present invention further provides an organic thin film solar cell and an electronic device capable of increasing the ratio of the portion of the photoelectric conversion layer that actually contributes to generating power. Still further, the present invention provides an organic thin film solar cell module and an electronic device capable of suppressing power loss while preventing deterioration of current paths. Still further, the present invention provides an organic thin film solar cell module and an electronic device photoelectric conversion layer capable of preventing a decrease in ratio of the portion of the photoelectric conversion layer that actually contributes to generating power.

### Solution to Problem

In a first aspect, the present invention provides an organic thin film solar cell module including a transparent base substrate, a transparent first conductive layer disposed on the base substrate, a second conductive layer, and a photoelectric conversion layer formed of an organic thin film and interposed between the first conductive layer and the second conductive layer. The second conductive layer is thicker than the photoelectric conversion layer.

In a preferred embodiment of the present invention, the first conductive layer may include two first blocks adjacent to each other via a substrate exposure region, where a part of the base substrate is exposed from the first conductive layer, the second conductive layer may include two second blocks adjacent to each other via a part of the substrate exposure region, and the photoelectric conversion layer may include a photoelectric conversion layer perforated portion, formed so as to penetrate through a photoelectric conversion layer connection portion in a thickness direction, the connection portion overlapping with both one of the two first blocks and the other of the two second blocks in plan view.

In a preferred embodiment of the present invention, the photoelectric conversion layer may include a projection surrounding the photoelectric conversion layer perforated portion in plan view, and the projection is covered with the second conductive layer.

In a preferred embodiment of the present invention, one of the two first blocks adjacent to each other may include a first electrode section spaced apart from the photoelectric conversion layer connection portion and overlapping with the second conductive layer in plan view, one of the two second blocks adjacent to each other may include a second electrode section coinciding with the first electrode section in plan view, and the photoelectric conversion layer may include a photoelectric conversion layer generation section coinciding with the first electrode section and the second electrode section in plan view.

In a preferred embodiment of the present invention, one of the two first blocks adjacent to each other may include a first connection portion coinciding with the photoelectric conversion layer connection portion in plan view, and the other of the two the second blocks adjacent to each other may include a second connection portion coinciding with the photoelectric conversion layer connection portion in plan view.

In a preferred embodiment of the present invention, the photoelectric conversion layer perforated portion may have a circular shape in plan view.

In a preferred embodiment of the present invention, the first connection portion of the one of the two first blocks adjacent to each other may include a first perforated portion, enclosed in the photoelectric conversion layer perforated portion in plan view, and formed so as to penetrate in the thickness direction.

In a preferred embodiment of the present invention, an inner edge of the first perforated portion may be spaced apart from an inner edge of the photoelectric conversion layer perforated portion, in plan view.

In a preferred embodiment of the present invention, the first connection portion of the one of the two first blocks adjacent to each other may cover the base substrate, in a region enclosed in the photoelectric conversion layer perforated portion in plan view.

In a preferred embodiment of the present invention, the first conductive layer may be formed of ITO.

In a preferred embodiment of the present invention, the second conductive layer may be formed of a metal.

In a preferred embodiment of the present invention, the second conductive layer may be formed of A1.

In a preferred embodiment of the present invention, the organic thin film solar cell module may further include a passivation layer covering the second conductive layer.

In a preferred embodiment of the present invention, the passivation layer may be formed of SiN or SiON.

In a second aspect, the present invention provides an electronic device including the organic thin film solar cell module according to the first aspect of the present invention, and a drive unit to operate by power supplied from the organic thin film solar cell module.

In a third aspect, the present invention provides a manufacturing method of an organic thin film solar cell module, the method including disposing a transparent first conductive layer on a transparent base substrate, disposing a photoelectric conversion layer formed of an organic thin film on the first conductive layer, and disposing a second conductive layer on the photoelectric conversion layer. The disposing of the second conductive layer includes forming the second conductive layer so as to be thicker than the photoelectric conversion layer.

In a preferred embodiment of the present invention, the disposing of the second conductive layer may include depositing a metal through a vapor deposition process.

In a preferred embodiment of the present invention, the disposing of the photoelectric conversion layer may include forming a photoelectric conversion layer perforated portion so as to penetrate through the photoelectric conversion layer, and the disposing of the second conductive layer may include covering the photoelectric conversion layer perforated portion with the second conductive layer.

In a preferred embodiment of the present invention, the disposing of the photoelectric conversion layer may include forming, in the first conductive layer, the photoelectric conversion layer perforated portion, and a first perforated portion enclosed in the photoelectric conversion layer perforated portion in plan view, so as to penetrate in the thickness direction.

In a preferred embodiment of the present invention, an IR laser may be employed to form the photoelectric conversion layer perforated portion.

In a preferred embodiment of the present invention, the first conductive layer may be formed of ITO.

In a preferred embodiment of the present invention, the second conductive layer may be formed of a metal.

In a preferred embodiment of the present invention, the second conductive layer may be formed of A1.

In a fourth aspect, the present invention provides an organic thin film solar cell module including a transparent first conductive layer, a second conductive layer, and a photoelectric conversion layer formed of an organic thin film and interposed between the first conductive layer and the second conductive layer. The photoelectric conversion layer includes one or more design display sections that constitute a design exhibited on outer appearance through the first conductive layer.

In a preferred embodiment of the present invention, the organic thin film solar cell module may further include a transparent base substrate on which the first conductive layer is disposed.

In a preferred embodiment of the present invention, the organic thin film solar cell module may further include a passivation layer covering the second conductive layer.

In a preferred embodiment of the present invention, the passivation film may cover the design display section.

In a preferred embodiment of the present invention, a portion of the passivation film covering the design display section, and a portion of the passivation film covering a portion of the photoelectric conversion layer adjacent to the design display section, may be formed in a flat shape.

In a preferred embodiment of the present invention, the passivation film may be thicker than the photoelectric conversion layer.

In a preferred embodiment of the present invention, the organic thin film solar cell module may further include a cover layer disposed on the passivation film.

In a preferred embodiment of the present invention, the organic thin film solar cell module may further include a bonding layer bonding the passivation film and the cover layer together.

In a preferred embodiment of the present invention, the first conductive layer may be formed of ITO.

In a preferred embodiment of the present invention, the second conductive layer may be formed of a metal.

In a preferred embodiment of the present invention, the second conductive layer may be formed of A1.

In a preferred embodiment of the present invention, the design display section may be constituted of a perforated portion formed so as to penetrate through the photoelectric conversion layer, in the thickness direction.

In a preferred embodiment of the present invention, the design display section may be constituted of a thin-wall portion thinner than a surrounding region.

In a preferred embodiment of the present invention, the first conductive layer may include a first electrode section, the second conductive layer may include a second electrode section coinciding with the first electrode section in plan view, the photoelectric conversion layer may include a generation region interposed between the first electrode section and the second electrode section, and configured to perform a photoelectric conversion function thereby contributing to power generation.

In a preferred embodiment of the present invention, the photoelectric conversion layer may include a non-generation region spaced apart from the first electrode section and the second electrode section in plan view, and not involved in the power generation.

In a preferred embodiment of the present invention, the first conductive layer may include a first block enclosing therein the design display section and surrounded by a slit formed so as to penetrate in the thickness direction, in plan view.

In a preferred embodiment of the present invention, the non-generation region of the photoelectric conversion layer may include a partitioned section overlapping with the first block of the first conductive layer.

In a preferred embodiment of the present invention, the first conductive layer and the second conductive layer may be in contact with each other, via the design display section included in the partitioned section of the photoelectric conversion layer.

In a preferred embodiment of the present invention, the first conductive layer may include two of the first electrode sections adjacent to each other via a slit, the second conductive layer may include two of the second electrode sections coinciding with the two first electrode sections in plan view, and the photoelectric conversion layer may include two of the generation regions interposed between the two first electrode sections and the two second electrode sections.

In a preferred embodiment of the present invention, the two generation regions may be connected in series to each other.

In a preferred embodiment of the present invention, the two generation regions may be connected in parallel to each other.

In a preferred embodiment of the present invention, the first conductive layer may include a first communication portion connected to one of the two first electrode sections and located adjacent to the other of the two first electrode sections via the slit, the second conductive layer may include a second communication portion connected to the second electrode section coinciding with the other of the two first electrode sections in plan view, and located adjacent to the other of the two second electrode sections via the slit and in contact with the first communication portion, and the non-generation region of the photoelectric conversion layer may include a communication region interposed between the first communication portion and the second communication portion.

In a preferred embodiment of the present invention, the communication region may include the design display section, and the first communication portion and the second communication portion may be in contact with each other via the design display section included in the communication region.

In a preferred embodiment of the present invention, the first conductive layer may include a plurality of the first electrode sections and the first communication portion concentrically arranged with respect to each other, the second conductive layer may include a plurality of the second electrode sections and the second communication portion concentrically arranged with respect to each other, and the photoelectric conversion layer may include a plurality of the generation regions and a plurality of the communication regions concentrically arranged with respect to each other.

In a preferred embodiment of the present invention, the first conductive layer may include a first extended portion extending outwardly of the photoelectric conversion layer in plan view, from one of the first electrode sections.

In a preferred embodiment of the present invention, the first conductive layer may include a first end portion located between, via a slit, the first electrode section extending from the first extended portion and the first electrode section adjacent to the first mentioned first electrode section, the photoelectric conversion layer may include a terminal region including the design display section enclosed in the first end portion in plan view, the terminal region overlapping with the first end portion, and the second conductive layer may include a second end portion coinciding with the first end portion in plan view and connected to the adjacent second electrode section, the second end portion being in contact with the first end portion via the design display section in the terminal region.

In a preferred embodiment of the present invention, the first conductive layer may include a second extended portion extending outwardly of the photoelectric conversion layer in plan view, from the first end portion.

In a preferred embodiment of the present invention, the design display section included in the communication region may display characters for identifying a time.

In a preferred embodiment of the present invention, the design display section included in the partitioned section may display characters for identifying a time.

In a preferred embodiment of the present invention, the first conductive layer may include an opening enclosing therein the design display section in plan view, and a portion of the photoelectric conversion layer coinciding with the opening of the first conductive layer may serve as the non-generation region.

In a preferred embodiment of the present invention, the design display section included in the opening may display a pattern for identifying a time.

In a fifth aspect, the present invention provides an electronic device including the organic thin film solar cell module according to the fourth aspect of the present invention, and a drive unit to operate by power supplied from the organic thin film solar cell module.

In a preferred embodiment of the present invention, the organic thin film solar cell module may further include a minute hand and an hour hand driven by the drive unit, thus to be utilized as a watch.

In a preferred embodiment of the present invention, the drive unit may have an arithmetic function, and the organic thin film solar cell module may include a display unit for displaying a calculation result provided by the drive unit, thus to be utilized as an electronic calculator.

In a sixth aspect, the present invention provides an organic thin film solar cell module including a transparent base substrate, a transparent first conductive layer disposed on the base substrate, a second conductive layer, a photoelectric conversion layer formed of an organic thin film and interposed between the first conductive layer and the second conductive layer, and a passivation film covering the second conductive layer. The passivation film includes a first edge, and the base substrate is exposed in a region adjacent to the first edge.

In a preferred embodiment of the present invention, the first conductive layer may include a third edge coinciding with the first edge in plan view.

In a preferred embodiment of the present invention, the first conductive layer may include a third inner recessed edge inwardly recessed with respect to the first edge, in plan view.

In a preferred embodiment of the present invention, the second conductive layer may include a fourth inner recessed edge, inwardly recessed with respect to the first edge in plan view.

In a preferred embodiment of the present invention, the photoelectric conversion layer may include a fifth inner recessed edge, inwardly recessed with respect to the first edge in plan view.

In a preferred embodiment of the present invention, the fourth inner recessed edge may be inwardly recessed with respect to the fifth inner recessed edge, in plan view.

In a preferred embodiment of the present invention, the first edge may have an annular shape in plan view.

In a preferred embodiment of the present invention, the third edge may have an annular shape in plan view.

In a preferred embodiment of the present invention, the third inner recessed edge may have an annular shape in plan view.

In a preferred embodiment of the present invention, the fourth inner recessed edge may have an annular shape in plan view.

In a preferred embodiment of the present invention, the fifth inner recessed edge may have an annular shape in plan view.

In a preferred embodiment of the present invention, the first conductive layer may be formed of ITO.

In a preferred embodiment of the present invention, the second conductive layer may be formed of a metal.

In a preferred embodiment of the present invention, the second conductive layer may be formed of A1.

In a preferred embodiment of the present invention, the passivation film may be formed of SiN.

In a preferred embodiment of the present invention, the organic thin film solar cell module may further include a resin cover layer covering the passivation film, the resin cover layer including a second edge coinciding with the first edge in plan view.

In a preferred embodiment of the present invention, the second edge and the first edge may form a continuous surface.

In a preferred embodiment of the present invention, the second edge may have an annular shape in plan view.

In a preferred embodiment of the present invention, the resin cover layer may be formed of a UV-curable resin.

In a preferred embodiment of the present invention, the resin cover layer may include a second outer edge located opposite to the second edge across at least a part of the photoelectric conversion layer in plan view, the passivation film may include a first outer edge coinciding with the second outer edge in plan view, the first conductive layer may include an extended portion extending outward from the second outer edge and the first outer edge, and the organic thin film solar cell module may further include a bypass conductive section covering at least a part of the extended portion, and formed of a material having lower resistance than a material of the first conductive layer.

In a preferred embodiment of the present invention, the second outer edge and the first outer edge may form a continuous surface.

In a preferred embodiment of the present invention, the bypass conductive section may cover the second outer edge and the first outer edge.

In a preferred embodiment of the present invention, the bypass conductive section may include Ag or carbon.

In a preferred embodiment of the present invention, the second conductive layer may include a fourth outer recessed edge, inwardly recessed with respect to the second outer edge and the first outer edge, in plan view.

In a preferred embodiment of the present invention, the photoelectric conversion layer may include a fifth outer recessed edge, inwardly recessed with respect to the second outer edge and the first outer edge, in plan view.

In a seventh aspect, the present invention provides an electronic device including the organic thin film solar cell module according to the sixth aspect of the present invention, and a drive unit to operate by power supplied from the organic thin film solar cell module.

In an eighth aspect, the present invention provides a manufacturing method of an organic thin film solar cell module, the method including disposing a transparent first conductive layer on a transparent base substrate, disposing a photoelectric conversion layer formed of an organic thin film on the first conductive layer, disposing a second conductive layer on the photoelectric conversion layer, forming a passivation film so as to cover the second conductive layer, disposing a resin cover layer having a second edge on the passivation film, partially removing the passivation film in a region delimited by the second edge, thereby forming, in the passivation film, a first edge coinciding with the second edge in plan view, and partially removing the first conductive layer, thereby exposing the base substrate in a region adjacent to the second edge and the first edge.

In a preferred embodiment of the present invention, the exposing of the base substrate may include forming, in the first conductive layer, a third edge coinciding with the second edge and the first edge in plan view.

In a preferred embodiment of the present invention, the second edge and the first edge may have an annular shape in plan view.

In a preferred embodiment of the present invention, the third edge may have an annular shape in plan view.

In a preferred embodiment of the present invention, the first conductive layer may be formed of ITO.

In a preferred embodiment of the present invention, the second conductive layer may be formed of a metal.

In a preferred embodiment of the present invention, the second conductive layer may be formed of A1.

In a preferred embodiment of the present invention, the passivation film may be formed of SiN.

In a preferred embodiment of the present invention, the resin cover layer may be formed of a UV-curable resin.

In a preferred embodiment of the present invention, the disposing of the resin cover layer may include forming a second outer edge at a position opposite to the second edge across at least a part of the photoelectric conversion layer in plan view. The method may further include partially removing the passivation film in a region delimited by the second edge, thereby forming, in the passivation film, a first outer edge coinciding with the second outer edge in plan view, and forming a bypass conductive section so as to cover at least a part of an extended portion extending outward from the second outer edge and the first outer edge of the first conductive layer, the bypass conductive section being formed of a material having lower resistance than a material of the first conductive layer.

In a preferred embodiment of the present invention, the forming of the bypass conductive section may include covering the second outer edge and the first outer edge with the bypass conductive section.

In a preferred embodiment of the present invention, the bypass conductive section may include Ag or carbon.

In a ninth aspect, the present invention provides an organic thin film solar cell including a transparent base substrate having a first surface, and a second surface opposite thereto, a transparent first electrode layer located on the side of the second surface of the base substrate, a photoelectric conversion layer formed of an organic thin film, and disposed on the first electrode layer on the opposite side to the base substrate, and a second electrode layer disposed on the photoelectric conversion layer on the opposite side to the base substrate. The first electrode layer includes an opening section formed on a surface thereof, the opening section being configured to display a design on the first surface of the base substrate.

In a preferred embodiment, an outer edge of the opening section in plan view may constitute a part of an outer edge of the design to be displayed.

In a preferred embodiment, the opening section may include a group of dots each having a predetermined plan-view shape.

In a preferred embodiment, the group of the dots may constitute a part of the design to be displayed.

In a preferred embodiment, the opening section may include a plurality of lines aligned at a predetermined interval, the lines each having a predetermined width and extending in a predetermined direction.

In a preferred embodiment, the plurality of lines may constitute a part of the design to be displayed.

In a preferred embodiment, the opening section may generate a hologram, when viewed from outside of the first surface of the base substrate.

In a preferred embodiment, the plurality of lines constituting the opening section may each have a width of 5 to 20 μm, and be aligned at intervals of 30 to 50 μm.

In a preferred embodiment, the first electrode layer may have a thickness of 100 to 200 nm, except for a portion corresponding to the opening section.

In a preferred embodiment, the opening section may be a recess having a predetermined depth, formed in a surface of the first electrode layer opposite to the base substrate.

In a preferred embodiment, the opening section may be a recess having a predetermined depth, formed in a surface of the first electrode layer on the side of the base substrate.

In a preferred embodiment, the opening section may be formed in such a depth that leaves a thin-wall portion having a thickness of 50 to 100 nm.

In a preferred embodiment, the opening section may be formed so as to penetrate through the first electrode layer in the thickness direction.

In a preferred embodiment, the organic thin film solar cell may further include a passivation layer, covering the second electrode layer on the opposite side to the photoelectric conversion layer.

In a preferred embodiment, the organic thin film solar cell may further include a cover layer, covering the passivation layer on the opposite side to the second electrode layer.

In a preferred embodiment, the organic thin film solar cell may further include a bonding layer bonding the passivation layer and the cover layer together.

In a preferred embodiment, the first electrode layer may be formed of ITO.

In a preferred embodiment, the photoelectric conversion layer may have a thickness of 100 to 200 nm.

In a preferred embodiment, the second electrode layer may have a thickness of 100 to 200 nm.

In a preferred embodiment, the second electrode layer may be formed of a metal.

In a preferred embodiment, the second electrode layer may be formed of A1.

In a preferred embodiment, a total thickness of the first electrode layer, the photoelectric conversion layer, the second electrode layer, and the passivation layer may be 1.0 to 2.0 μm.

In a tenth aspect, the present invention provides a manufacturing method of an organic thin film solar cell, the method including forming, on a second surface of a transparent base substrate having a first surface and the second surface opposite thereto, a transparent first electrode layer having a predetermined thickness and including an opening formed in a surface thereof, forming a photoelectric conversion layer on the first electrode layer, and forming a second electrode layer on the photoelectric conversion layer.

In a preferred embodiment, the forming of the first electrode layer may include removing with respect to the first electrode layer in the thickness direction, so as to form the opening section.

In a preferred embodiment, the forming of the opening section may include removing with respect to the first electrode layer in the thickness direction to a predetermined depth.

In a preferred embodiment, the forming of the opening section may include removing with respect to the first electrode layer having a thickness of 100 to 200 nm, so as to leave a thin-wall portion having a thickness of 50 to 100 nm.

In a preferred embodiment, the forming of the opening section may include removing with respect to the first electrode layer from the side opposite to the base substrate.

In a preferred embodiment, the forming of the opening section may be performed after the forming of the first electrode layer, in which the opening section is yet to be formed.

In a preferred embodiment, the forming of the opening section may include removing with respect to the first electrode layer from the side of the first surface of the base substrate.

In a preferred embodiment, the forming of the opening section may be performed on the first electrode layer in which the opening section is yet to be formed, after the forming of the second electrode layer.

In a preferred embodiment, the forming of the opening section may include forming a perforated portion so as to penetrate through the first electrode layer, in the thickness direction.

In a preferred embodiment, the forming of the opening section may include aligning a plurality of lines each having a width of 5 to 20 μm and extending in a predetermined direction, at intervals of 30 to 50 μm.

In a preferred embodiment, the forming of the opening section may be performed by laser irradiation.

In an eleventh aspect, the present invention provides an electronic device including a casing, and the organic thin film solar cell according to the ninth aspect, arranged such that the first surface of the base substrate is exposed in a surface of the casing.

In a twelfth aspect, the present invention provides an organic thin film solar cell module including a transparent base substrate, a transparent first conductive layer disposed on the base substrate, a second conductive layer, a photoelectric conversion layer formed of an organic thin film and interposed between the first conductive layer and the second conductive layer, and a passivation layer covering the second conductive layer. The passivation layer includes a first edge, and the base substrate is exposed in a region adjacent to the first edge.

In a preferred embodiment of the present invention, the first conductive layer may include a third edge coinciding with the first edge in plan view.

In a preferred embodiment of the present invention, the first conductive layer may include a third inner recessed edge inwardly recessed with respect to the first edge, in plan view.

In a preferred embodiment of the present invention, the second conductive layer may include a fourth inner recessed edge, inwardly recessed with respect to the first edge in plan view.

In a preferred embodiment of the present invention, the photoelectric conversion layer may include a fifth inner recessed edge, inwardly recessed with respect to the first edge in plan view.

In a preferred embodiment of the present invention, the fourth inner recessed edge may be inwardly recessed with respect to the fifth inner recessed edge, in plan view.

In a preferred embodiment of the present invention, the first edge may have an annular shape in plan view.

In a preferred embodiment of the present invention, the third edge may have an annular shape in plan view.

In a preferred embodiment of the present invention, the third inner recessed edge may have an annular shape in plan view.

In a preferred embodiment of the present invention, the fourth inner recessed edge may have an annular shape in plan view.

In a preferred embodiment of the present invention, the fifth inner recessed edge may have an annular shape in plan view.

In a preferred embodiment of the present invention, the first conductive layer may be formed of ITO.

In a preferred embodiment of the present invention, the second conductive layer may be formed of a metal.

In a preferred embodiment of the present invention, the second conductive layer may be formed of A1.

In a preferred embodiment of the present invention, the passivation layer may be formed of SiN.

In a preferred embodiment of the present invention, the organic thin film solar cell module may further include a resin cover layer covering the passivation film, the resin cover layer including a second edge coinciding with the first edge in plan view.

In a preferred embodiment of the present invention, the second edge and the first edge may form a continuous surface.

In a preferred embodiment of the present invention, the second edge may have an annular shape in plan view.

In a preferred embodiment of the present invention, the resin cover layer may be formed of a UV-curable resin.

In a preferred embodiment of the present invention, the resin cover layer may include a second outer edge located opposite to the second edge across at least a part of the photoelectric conversion layer in plan view, the passivation layer may include a first outer edge coinciding with the second outer edge in plan view, the first conductive layer may include an extended portion extending outward from the second outer edge and the first outer edge, and the organic thin film solar cell module may further include a bypass conductive section covering at least a part of the extended portion, and formed of a material having lower resistance than a material of the first conductive layer.

In a preferred embodiment of the present invention, the second outer edge and the first outer edge may form a continuous surface.

In a preferred embodiment of the present invention, the bypass conductive section may cover the second outer edge and the first outer edge.

In a preferred embodiment of the present invention, the bypass conductive section may include Ag or carbon.

In a preferred embodiment of the present invention, the passivation layer may include a first outer edge located opposite to the first edge across at least a part of the photoelectric conversion layer in plan view, the first conductive layer may include an extended portion extending outward from the first outer edge, and the organic thin film solar cell module may further include a bypass conductive section covering at least a part of the extended portion, and formed of a material having lower resistance than a material of the first conductive layer, and a resin cover layer covering the bypass conductive section.

In a preferred embodiment of the present invention, the bypass conductive section may cover the first outer edge.

In a preferred embodiment of the present invention, the bypass conductive section may include Ag or carbon.

In a preferred embodiment of the present invention, the resin cover layer may include a non-translucent portion overlapping with the bypass conductive section in plan view, and formed in a region on the side of the first outer edge, with respect to the first edge.

In a preferred embodiment of the present invention, the non-translucent portion may be white.

In a preferred embodiment of the present invention, the second conductive layer may include a fourth outer recessed edge, inwardly recessed with respect to the second outer edge and the first outer edge in plan view.

In a preferred embodiment of the present invention, the photoelectric conversion layer may include a fifth outer recessed edge, inwardly recessed with respect to the second outer edge and the first outer edge in plan view.

In a thirteenth aspect, the present invention provides an electronic device including the organic thin film solar cell module according to the twelfth aspect of the present invention, and a drive unit to operate by power supplied from the organic thin film solar cell module.

In a fourteenth aspect, the present invention provides a manufacturing method of an organic thin film solar cell module, the method including disposing a transparent first conductive layer on a transparent base substrate, disposing a photoelectric conversion layer formed of an organic thin film on the first conductive layer, disposing a second conductive layer on the photoelectric conversion layer, disposing a passivation film so as to cover the second conductive layer, forming an insulation film covering the second conductive layer, and exposing the base substrate in a region adjacent to a first edge of a passivation layer, including partially removing the insulation film thereby forming the passivation layer having the first edge, and partially removing the first conductive film thereby forming a first conductive layer.

In a preferred embodiment of the present invention, the method may further include, after the forming of the insulation film and before the exposing of the base substrate, disposing a resin cover layer having a second edge on the insulation film. The exposing of the base substrate may include partially removing the insulation film in a region delimited by the second edge thereby forming the passivation layer having the first edge coinciding with the second edge in plan view, and removing a portion of the first conductive film exposed from the first edge and the second edge, thereby forming the first conductive layer.

In a preferred embodiment of the present invention, the exposing of the base substrate may include forming the first conductive layer, having a third edge coinciding with the second edge and the first edge in plan view.

In a preferred embodiment of the present invention, the second edge and the first edge may have an annular shape in plan view.

In a preferred embodiment of the present invention, the third edge may have an annular shape in plan view.

In a preferred embodiment of the present invention, the first conductive layer may be formed of ITO.

In a preferred embodiment of the present invention, the second conductive layer may be formed of a metal.

In a preferred embodiment of the present invention, the second conductive layer may be formed of A1.

In a preferred embodiment of the present invention, the passivation layer may be formed of SiN.

In a preferred embodiment of the present invention, the resin cover layer may be formed of a UV-curable resin.

In a preferred embodiment of the present invention, the disposing of the resin cover layer may include forming a second outer edge at a position opposite to the second edge across at least a part of the photoelectric conversion layer in plan view. The method may further include partially removing the insulation film in a region delimited by the second edge, thereby forming, in the passivation layer, a first outer edge coinciding with the second outer edge in plan view, and forming a bypass conductive section so as to cover at least a part of an extended portion extending outward from the second outer edge and the first outer edge of the first conductive layer, the bypass conductive section being formed of a material having lower resistance than a material of the first conductive layer.

In a preferred embodiment of the present invention, the forming of the bypass conductive section may include covering the second outer edge and the first outer edge with the bypass conductive section.

In a preferred embodiment of the present invention, the bypass conductive section may include Ag or carbon.

In a preferred embodiment of the present invention, the exposing of the base substrate may include irradiating the first conductive film with a laser beam through the insulation film, so as to partially remove the first conductive film and the insulation film.

In a preferred embodiment of the present invention, the exposing of the base substrate may include removing a region of the insulation film adjacent in plan view to the region thereof irradiated with the laser beam in the partially removing process, thereby forming an extended portion by exposing a portion of the first conductive film unirradiated with the laser beam from the passivation layer. The method may further include forming a bypass conductive section so as to cover at least a part of the extended portion, from a material having lower resistance than a material of the first conductive layer, and forming a resin cover layer covering the bypass conductive section.

In a preferred embodiment of the present invention, the bypass conductive section may include Ag or carbon.

In a preferred embodiment of the present invention, the forming of the resin cover layer may include forming a non-translucent portion in a region overlapping with the bypass conductive section in plan view, and on the side of the first outer edge, with respect to the first edge.

In a fifteenth aspect, the present invention provides an organic thin film solar cell module including a transparent base substrate, a transparent first conductive layer disposed on the base substrate, a second conductive layer, a photoelectric conversion layer formed of an organic thin film and interposed between the first conductive layer and the second conductive layer, and a passivation layer covering the second conductive layer. The first conductive layer includes an extended portion extending from the passivation layer in plan view, a slit formed such that both ends reach an edge of the extended portion, and a connection portion defined by the slit and having a connection portion edge connected to the both ends of the slit. The photoelectric conversion layer includes a conductive perforated portion enclosed in the connection portion of the first conductive layer in plan view and formed so as to penetrate in the thickness direction. The second conductive layer and the connection portion of the first conductive layer are electrically connected via the conductive perforated portion of the photoelectric conversion layer. The organic thin film solar cell module also includes a first bus-bar section covering at least a part of an extended connection portion in the connection portion, extending from the passivation layer, and a bypass conductive section including a first collector electrode electrically connected to the first bus-bar section.

In a preferred embodiment of the present invention, the conductive perforated portion may have a circular shape in plan view.

In a preferred embodiment of the present invention, the conductive perforated portion may have an elongate shape having a longitudinal side extending parallel to the edge of the connection portion, in plan view.

In a preferred embodiment of the present invention, the first collector electrode may overlap with the second conductive layer and the photoelectric conversion layer in plan view, and the passivation layer may be interposed between the first collector electrode and the second conductive layer, in the thickness direction of the base substrate.

In a preferred embodiment of the present invention, the bypass conductive section may include a second bus-bar section covering at least a part of the extended portion of the first conductive layer, and a second collector electrode electrically connected to the second bus-bar section.

In a preferred embodiment of the present invention, the second collector electrode may overlap with the second conductive layer and the photoelectric conversion layer in plan view, and the passivation layer may be interposed between the second collector electrode and the second conductive layer, in the thickness direction of the base substrate.

In a preferred embodiment of the present invention, the second bus-bar section may include a circumvent portion having both ends connected to a portion of the extended portion of the first conductive layer located on both sides of the connection portion, and arranged so as to circumvent the first collector electrode in plan view.

In a preferred embodiment of the present invention, the photoelectric conversion layer may include a design display perforated portion formed so as to penetrate in the thickness direction, and constituting a design display section exposed in the outer appearance, and the design display perforated portion may be located opposite to the connection portion edge, across the conductive perforated portion.

In a preferred embodiment of the present invention, the first conductive layer may include a display opening for forming the display region, a third edge that defines the display opening, and a first extended portion extending from the passivation layer toward the display opening, and the connection portion may be defined by the slit formed such that both ends reach the third edge.

In a preferred embodiment of the present invention, the first conductive layer may include a display opening for forming the display region, a third edge that defines the display opening, a third outer edge located opposite to the third edge, a first extended portion extending from the passivation layer toward the display opening, and a second extended portion extending from the passivation layer in a direction opposite to the display opening, and the connection portion may be defined by the slit formed such that both ends reach the third outer edge.

In a preferred embodiment of the present invention, the organic thin film solar cell module may further include a resin cover layer covering the bypass conductive section.

In a preferred embodiment of the present invention, the passivation layer may include a first edge opposing the display opening in plan view, the resin cover layer may include a first resin cover layer covering the passivation layer, and a second resin cover layer disposed on the first resin cover layer and covering the bypass conductive section, and the first resin cover layer may include a second edge coinciding with the first edge in plan view.

In a preferred embodiment of the present invention, the first edge and the second edge may form a continuous surface.

In a preferred embodiment of the present invention, the bypass conductive section may include a seventh edge coinciding with the third edge in plan view.

In a preferred embodiment of the present invention, the second resin cover layer may include a sixth edge located opposite to the first edge across the third edge and the seventh edge in plan view, and may be in contact with the base substrate.

In a preferred embodiment of the present invention, the second conductive layer may include a fourth inner recessed edge, inwardly recessed with respect to the first edge in plan view.

In a preferred embodiment of the present invention, the photoelectric conversion layer may include a fifth inner recessed edge, inwardly recessed with respect to the first edge in plan view.

In a preferred embodiment of the present invention, the fourth inner recessed edge may be inwardly recessed with respect to the fifth inner recessed edge, in plan view.

In a preferred embodiment of the present invention, the passivation layer may include a first edge opposing the display opening in plan view, and the bypass conductive section may include a seventh edge located opposite to the first edge across the third edge, in plan view.

In a preferred embodiment of the present invention, the resin cover layer may include a second edge located opposite to the first edge across the seventh edge in plan view, and may be in contact with the base substrate.

In a preferred embodiment of the present invention, the second conductive layer may include a fourth inner recessed edge, inwardly recessed with respect to the first edge in plan view.

In a preferred embodiment of the present invention, the photoelectric conversion layer may include a fifth inner recessed edge, inwardly recessed with respect to the first edge in plan view.

In a preferred embodiment of the present invention, the fourth inner recessed edge may be inwardly recessed with respect to the fifth inner recessed edge, in plan view.

In a preferred embodiment of the present invention, the first edge may have an annular shape in plan view.

In a preferred embodiment of the present invention, the third edge may have an annular shape in plan view.

In a preferred embodiment of the present invention, the fourth inner recessed edge may have an annular shape in plan view.

In a preferred embodiment of the present invention, the fifth inner recessed edge may have an annular shape in plan view.

In a preferred embodiment of the present invention, the seventh edge may have an annular shape in plan view.

In a preferred embodiment of the present invention, the second edge may have an annular shape in plan view.

In a preferred embodiment of the present invention, the sixth edge may have an annular shape in plan view.

In a preferred embodiment of the present invention, the first conductive layer may be formed of ITO.

In a preferred embodiment of the present invention, the second conductive layer may be formed of a metal.

In a preferred embodiment of the present invention, the second conductive layer may be formed of A1.

In a preferred embodiment of the present invention, the passivation layer may be formed of SiN.

In a preferred embodiment of the present invention, the resin cover layer may be formed of a UV-curable resin.

In a sixteenth aspect, the present invention provides an electronic device including the organic thin film solar cell module according to the fifteenth aspect of the present invention, and a drive unit to operate by power supplied from the organic thin film solar cell module.

In a seventeenth aspect, the present invention provides an organic thin film solar cell module including a transparent base substrate, a transparent first conductive layer disposed on the base substrate, a second conductive layer, a photoelectric conversion layer formed of an organic thin film and interposed between the first conductive layer and the second conductive layer, and a passivation layer covering the second conductive layer. The first conductive layer includes an extended portion extending from the passivation layer in plan view. The organic thin film solar cell module also includes a bypass conductive section covering at least a part of the extended portion, and formed of a material having lower resistance than a material of the first conductive layer, and a resin cover layer covering the bypass conductive section.

In a preferred embodiment of the present invention, the passivation layer may include a first edge, and the base substrate may be exposed in a region adjacent to the first edge.

In a preferred embodiment of the present invention, the extended portion of the first conductive layer may include a first extended portion exposed from the first edge, and the first extended portion may include a third edge spaced apart from the first edge in plan view.

In a preferred embodiment of the present invention, the resin cover layer may include a first resin cover layer covering the passivation layer, and a second resin cover layer disposed on the first resin cover layer and covering the bypass conductive section, and the first resin cover layer may include a second edge coinciding with the first edge in plan view.

In a preferred embodiment of the present invention, the first edge and the second edge may form a continuous surface.

In a preferred embodiment of the present invention, the bypass conductive section may include a seventh edge coinciding with the third edge in plan view.

In a preferred embodiment of the present invention, the second resin cover layer may include a sixth edge located opposite to the first edge across the third edge and the seventh edge in plan view, and may be in contact with the base substrate.

In a preferred embodiment of the present invention, the second conductive layer may include a fourth inner recessed edge, inwardly recessed with respect to the first edge in plan view.

In a preferred embodiment of the present invention, the photoelectric conversion layer may include a fifth inner recessed edge, inwardly recessed with respect to the first edge in plan view.

In a preferred embodiment of the present invention, the fourth inner recessed edge may be inwardly recessed with respect to the fifth inner recessed edge, in plan view.

In a preferred embodiment of the present invention, the passivation layer may include a first outer edge located opposite to the first edge across at least a part of the photoelectric conversion layer in plan view, the extended portion may include a second extended portion extending from the first outer edge, and the second extended portion may include a third outer edge spaced apart from the first outer edge in plan view.

In a preferred embodiment of the present invention, the first resin cover layer may include a second outer edge coinciding with the first outer edge in plan view.

In a preferred embodiment of the present invention, the first outer edge and the second outer edge may form a continuous surface.

In a preferred embodiment of the present invention, the bypass conductive section may include a seventh outer edge coinciding with the third outer edge in plan view.

In a preferred embodiment of the present invention, the second resin cover layer may include a sixth outer edge located opposite to the first outer edge across the third outer edge and the seventh outer edge in plan view, and may be in contact with the base substrate.

In a preferred embodiment of the present invention, the second resin cover layer may include a non-translucent portion overlapping with the bypass conductive section in plan view, and located in a region on the side of the first outer edge, with respect to the first edge.

In a preferred embodiment of the present invention, the non-translucent portion may be white.

In a preferred embodiment of the present invention, the bypass conductive section may include a seventh edge located opposite to the first edge across the third edge in plan view.

In a preferred embodiment of the present invention, the resin cover layer may include a second edge located opposite to the first edge across the seventh edge in plan view, and may be in contact with the base substrate.

In a preferred embodiment of the present invention, the second conductive layer may include a fourth inner recessed edge, inwardly recessed with respect to the first edge in plan view.

In a preferred embodiment of the present invention, the photoelectric conversion layer may include a fifth inner recessed edge, inwardly recessed with respect to the first edge in plan view.

In a preferred embodiment of the present invention, the fourth inner recessed edge may be inwardly recessed with respect to the fifth inner recessed edge, in plan view.

In a preferred embodiment of the present invention, the passivation layer may include a first outer edge located opposite to the first edge across at least a part of the photoelectric conversion layer in plan view, the extended portion may include a second extended portion extending from the first outer edge, and the second extended portion may include a third outer edge spaced apart from the first outer edge in plan view.

In a preferred embodiment of the present invention, the bypass conductive section may include a seventh outer edge located opposite to the first outer edge across the third outer edge in plan view.

In a preferred embodiment of the present invention, the resin cover layer may include a second outer edge located opposite to the first outer edge across the seventh outer edge in plan view, and may be in contact with the base substrate.

In a preferred embodiment of the present invention, the resin cover layer may include a non-translucent portion overlapping with the bypass conductive section in plan view, and formed in a region on the side of the first outer edge, with respect to the first edge.

In a preferred embodiment of the present invention, the non-translucent portion may be white.

In a preferred embodiment of the present invention, the first edge may have an annular shape in plan view.

In a preferred embodiment of the present invention, the third edge may have an annular shape in plan view.

In a preferred embodiment of the present invention, the fourth inner recessed edge may have an annular shape in plan view.

In a preferred embodiment of the present invention, the fifth inner recessed edge may have an annular shape in plan view.

In a preferred embodiment of the present invention, the sixth edge may have an annular shape in plan view.

In a preferred embodiment of the present invention, the seventh edge may have an annular shape in plan view.

In a preferred embodiment of the present invention, the second edge may have an annular shape in plan view.

In a preferred embodiment of the present invention, the first conductive layer may be formed of ITO.

In a preferred embodiment of the present invention, the second conductive layer may be formed of a metal.

In a preferred embodiment of the present invention, the second conductive layer may be formed of A1.

In a preferred embodiment of the present invention, the passivation layer may be formed of SiN.

In a preferred embodiment of the present invention, the resin cover layer may be formed of a UV-curable resin.

In an eighteenth aspect, the present invention provides an electronic device including the organic thin film solar cell module according to the seventeenth aspect of the present invention, and a drive unit to operate by power supplied from the organic thin film solar cell module.

In a nineteenth aspect, the present invention provides an organic thin film solar cell module including a transparent base substrate, a transparent first conductive layer disposed on the base substrate, a second conductive layer, and a photoelectric conversion layer formed of an organic thin film and interposed between the first conductive layer and the second conductive layer. The first conductive layer includes two first blocks adjacent to each other via a substrate exposure region where a part of the base substrate is exposed from the first conductive layer. The second conductive layer includes two second blocks adjacent to each other via a part of the substrate exposure region. One of the two first blocks adjacent to each other includes a first block first edge that defines the substrate exposure region, and the other of the two first blocks adjacent to each other includes a first block second edge that defines the substrate exposure region. One of the two second blocks adjacent to each other includes a second block first edge overlapping with the one of the two first blocks in plan view, and located opposite to the first block second edge of the other of the two first blocks adjacent to each other, across the first block first edge of the one of the two first blocks adjacent to each other. The other of the two second blocks adjacent to each other includes a second block second edge opposing the first edge of the one of the two second blocks adjacent to each other, in plan view. The photoelectric conversion layer includes a photoelectric conversion layer perforated portion formed so as to penetrate through a photoelectric conversion layer connection portion in the thickness direction, the photoelectric conversion layer connection portion being formed in a region overlapping with both of the one of the two first blocks adjacent to each other and the other of the two second blocks adjacent to each other in plan view, and defined by (i) a first shielded portion corresponding to a portion of the first block first edge of the one of the two first blocks adjacent to each other overlapping with the other of the two second blocks adjacent to each other, and (ii) the second block second edge of the other of the two second blocks adjacent to each other. The substrate exposure region includes one or more intersections intersecting the second block second edge of the other of the two second blocks adjacent to each other.

In a preferred embodiment of the present invention, the one of the two first blocks adjacent to each other may include a first electrode section spaced apart from the photoelectric conversion layer connection portion and overlapping with the second conductive layer in plan view, the one of the two second blocks adjacent to each other may include a second electrode section coinciding with the first electrode section in plan view, and the photoelectric conversion layer may include a photoelectric conversion layer generation section coinciding with the first electrode section and the second electrode section in plan view.

In a preferred embodiment of the present invention, the one of the two first blocks adjacent to each other may include a first connection portion coinciding with the photoelectric conversion layer connection portion in plan view, and the other of the two second blocks adjacent to each other may include a second connection portion coinciding with the photoelectric conversion layer connection portion in plan view.

In a preferred embodiment of the present invention, the photoelectric conversion layer connection portion and a part of the photoelectric conversion layer generation section may be located adjacent to each other, in a direction intersecting the direction in which the two first blocks are aligned, in plan view.

In a preferred embodiment of the present invention, the photoelectric conversion layer generation section may be located on both sides of the photoelectric conversion layer connection portion, in a direction intersecting the direction in which the two first blocks are aligned, in plan view.

In a preferred embodiment of the present invention, the photoelectric conversion layer perforated portion may have a circular shape in plan view.

In a preferred embodiment of the present invention, the first connection portion of the one of the two first blocks adjacent to each other may include a first perforated portion enclosed in the photoelectric conversion layer perforated portion in plan view, and formed so as to penetrate in the thickness direction.

In a preferred embodiment of the present invention, an inner edge of the first perforated portion may be spaced apart from an inner edge of the photoelectric conversion layer perforated portion in plan view.

In a preferred embodiment of the present invention, the first connection portion of the one of the two first blocks adjacent to each other may cover the base substrate, in a region enclosed in the photoelectric conversion layer perforated portion, in plan view.

In a preferred embodiment of the present invention, the other of the two second blocks adjacent to each other may include second block third edge connected to the second block second edge and extending in a direction away from the one of the two second blocks adjacent to each other, and the substrate exposure region may include two of the intersections, one formed on the second block second edge, and the other formed on the second block third edge, of the other of the two second blocks adjacent to each other.

In a preferred embodiment of the present invention, the substrate exposure region may include two of the intersections, each formed on the second block second edge of the other of the two second blocks adjacent to each other.

In a preferred embodiment of the present invention, the first block first edge of the one of the two first blocks adjacent to each other may have a first side in a region spaced apart from the two second block in plan view, and the first block second edge of the other of the two first blocks adjacent to each other may have a second edge parallel to the first side.

In a preferred embodiment of the present invention, the first side and the second side may be linear.

In a preferred embodiment of the present invention, the second block first edge of the one of the two second blocks adjacent to each other, and the second block second edge of the other of the two second blocks adjacent to each other may be parallel to each other.

In a preferred embodiment of the present invention, the second block first edge of the one of the two second blocks adjacent to each other, and the second block second edge of the other of the two second blocks adjacent to each other may be linear.

In a preferred embodiment of the present invention, the first side of the one of the two first blocks adjacent to each other, the second side of the other of the two first blocks adjacent to each other, the second block first edge of the one of the two second blocks adjacent to each other, and the second block second edge of the other of the two second blocks adjacent to each other may be parallel to each other.

In a preferred embodiment of the present invention, the first side, the second side, the second block first edge, and the second block second edge may be linear.

In a preferred embodiment of the present invention, three or more of the first blocks adjacent to each other, and three or more of the second blocks adjacent to each other may be aligned.

In a preferred embodiment of the present invention, three or more of the first blocks adjacent to each other, and three or more of the second blocks adjacent to each other may be aligned along a straight line.

In a preferred embodiment of the present invention, three or more of the first blocks adjacent to each other, and three or more of the second blocks adjacent to each other may be aligned in an annular shape.

In a preferred embodiment of the present invention, the second block located between two of the second blocks, out of the three or more second blocks adjacent to each other, may include a second block first edge and a second block second edge, and two second block third edges each connecting both ends of the second block first edge and both ends of the second block second edge.

In a preferred embodiment of the present invention, the second block first edge and the second block second edge of the second block located between two of the second blocks, out of the three or more second blocks adjacent to each other, may be parallel to each other.

In a preferred embodiment of the present invention, the two second block third edges of the second block located between two of the second blocks, out of the three or more second blocks adjacent to each other, may be parallel to each other.

In a preferred embodiment of the present invention, the second block first edge and the second block second edge may be perpendicular to the two second block third edges, in the second block located between two of the second blocks, out of the three or more second blocks adjacent to each other.

In a preferred embodiment of the present invention, the first conductive layer may include a third block having an external connection portion coinciding with the photoelectric conversion layer connection portion in plan view, and an external electrode section connected to the external connection portion and exposed from the second conductive layer and the photoelectric conversion layer.

In a preferred embodiment of the present invention, the first conductive layer may be formed of ITO.

In a preferred embodiment of the present invention, the second conductive layer may be formed of a metal.

In a preferred embodiment of the present invention, the second conductive layer may be formed of A1.

In a preferred embodiment of the present invention, the organic thin film solar cell module may further include a passivation layer covering the second conductive layer.

In a preferred embodiment of the present invention, the passivation layer may be formed of SiN or SiON.

In a twentieth aspect, the present invention provides an electronic device including the organic thin film solar cell module according to the nineteenth aspect of the present invention, and a drive unit to operate by power supplied from the organic thin film solar cell module.

Other features and advantages of the present invention will become more apparent through the detailed description, given hereunder with reference to the accompanying drawings.

### BRIEF DESCRIPTION OF DRAWINGS

FIG. 1 is a partial plan view of an organic thin film solar cell module according to a first embodiment of the present invention.

FIG. 2 is a cross-sectional view taken along a line II-II in FIG. 1.

FIG. 3 is an enlarged partial plan view of the organic thin film solar cell module according to the first embodiment of the present invention.

FIG. 4 is an enlarged partial cross-sectional view taken along a line IV-IV in FIG. 3.

FIG. 5 is an enlarged partial cross-sectional view taken along a line V-V in FIG. 3.

FIG. 6 is an enlarged partial plan view of the organic thin film solar cell module according to the first embodiment of the present invention.

FIG. 7 is an enlarged partial cross-sectional view taken along a line VII-VII in FIG. 6.

FIG. 8 is a system diagram of the organic thin film solar cell module and an electronic device according to the first embodiment of the present invention.

FIG. 9 is an enlarged partial plan view showing an exemplary manufacturing method of the organic thin film solar cell module according to the first embodiment of the present invention.

FIG. 10 is an enlarged partial cross-sectional view showing an exemplary manufacturing method of the organic thin film solar cell module according to the first embodiment of the present invention.

FIG. 11 is an enlarged partial plan view showing an exemplary manufacturing method of the organic thin film solar cell module according to the first embodiment of the present invention.

FIG. 12 is an enlarged partial cross-sectional view showing an exemplary manufacturing method of the organic thin film solar cell module according to the first embodiment of the present invention.

FIG. 13 is an enlarged partial plan view showing an exemplary manufacturing method of the organic thin film solar cell module according to the first embodiment of the present invention.

FIG. 14 is an enlarged partial cross-sectional view showing an exemplary manufacturing method of the organic thin film solar cell module according to the first embodiment of the present invention.

FIG. 15 is an enlarged partial plan view showing an exemplary manufacturing method of the organic thin film solar cell module according to the first embodiment of the present invention.

FIG. 16 is an enlarged partial cross-sectional view taken along a line XVI-XVI in FIG. 15.

FIG. 17 is an enlarged partial cross-sectional view showing a variation of the organic thin film solar cell module according to the first embodiment of the present invention.

FIG. 18 is a plan view showing an electronic device according to a second embodiment of the present invention.

FIG. 19 is a system diagram of the electronic device shown in FIG. 18.

FIG. 20 is a plan view showing an organic thin film solar cell module according to the second embodiment of the present invention.

FIG. 21 is an exploded perspective view showing the organic thin film solar cell module shown in FIG. 20.

FIG. 22 is an enlarged partial cross-sectional view taken along a line XXII-XXII in FIG. 20.

FIG. 23 is an enlarged partial cross-sectional view taken along a line XXIII-XXIII in FIG. 20.

FIG. 24 is an enlarged partial cross-sectional view taken along a line XXIV-XXIV in FIG. 20.

FIG. 25 is an enlarged partial cross-sectional view taken along a line XXV-XXV in FIG. 20.

FIG. 26 is a plan view showing a first conductive layer of the organic thin film solar cell module shown in FIG. 20.

FIG. 27 is a plan view showing a second conductive layer of the organic thin film solar cell module shown in FIG. 20.

FIG. 28 is a plan view showing a photoelectric conversion layer of the organic thin film solar cell module shown in FIG. 20.

FIG. 29 is an enlarged partial cross-sectional view showing an exemplary manufacturing method of the organic thin film solar cell module shown in FIG. 20.

FIG. 30 is an enlarged partial cross-sectional view showing an exemplary manufacturing method of the organic thin film solar cell module shown in FIG. 20.

FIG. 31 is an enlarged partial cross-sectional view showing an exemplary manufacturing method of the organic thin film solar cell module shown in FIG. 20.

FIG. 32 is an enlarged partial cross-sectional view showing an exemplary manufacturing method of the organic thin film solar cell module shown in FIG. 20.

FIG. 33 is a plan view showing a variation of the organic thin film solar cell module according to the second embodiment of the present invention.

FIG. 34 is a plan view showing a first conductive layer of the organic thin film solar cell module shown in FIG. 33.

FIG. 35 is a plan view showing a second conductive layer of the organic thin film solar cell module shown in FIG. 33.

FIG. 36 is a plan view showing a photoelectric conversion layer of the organic thin film solar cell module shown in FIG. 33.

FIG. 37 is a plan view showing an electronic device according to a third embodiment of the present invention.

FIG. 38 is a system diagram of the electronic device shown in FIG. 37.

FIG. 39 is a plan view showing an organic thin film solar cell module according to the third embodiment of the present invention.

FIG. 40 is a plan view showing a first conductive layer of the organic thin film solar cell module shown in FIG. 39.

FIG. 41 is a plan view showing a second conductive layer of the organic thin film solar cell module shown in FIG. 39.

FIG. 42 is a plan view showing a photoelectric conversion layer of the organic thin film solar cell module shown in FIG. 39.

FIG. 43 is an enlarged partial cross-sectional view showing an organic thin film solar cell module according to a fourth embodiment of the present invention.

FIG. 44 is a plan view showing organic thin film solar cell modules according to a fifth and a sixth embodiment of the present invention, and an electronic device incorporated with the organic thin film solar cell modules.

FIG. 45 is a bottom view showing the organic thin film solar cell module and the electronic device shown in FIG. 44.

FIG. 46 is a schematic cross-sectional view taken along a line XLVI-XLVI in FIG. 44.

FIG. 47 is an enlarged partial cross-sectional view taken along a line XLVII-XLVII in FIG. 44.

FIG. 48 is a system diagram of the electronic device shown in FIG. 44.

FIG. 49 is a partial exploded perspective view showing the organic thin film solar cell module according to the fifth embodiment of the present invention.

FIG. 50 is a plan view showing a first conductive layer of the organic thin film solar cell module according to the fifth embodiment of the present invention.

FIG. 51 is a plan view showing a photoelectric conversion layer of the organic thin film solar cell module according to the fifth embodiment of the present invention.

FIG. 52 is a plan view showing a second conductive layer of the organic thin film solar cell module according to the fifth embodiment of the present invention.

FIG. 53 is a plan view showing a resin cover layer and a bypass conductive section of the organic thin film solar cell module according to the fifth embodiment of the present invention.

FIG. 54 is a plan view showing a first conductive layer of the organic thin film solar cell module according to the sixth embodiment of the present invention.

FIG. 55 is a plan view showing a photoelectric conversion layer of the organic thin film solar cell module according to the sixth embodiment of the present invention.

FIG. 56 is a plan view showing a second conductive layer of the organic thin film solar cell module according to the sixth embodiment of the present invention.

FIG. 57 is a plan view showing a resin cover layer and a bypass conductive section of the organic thin film solar cell module according to the sixth embodiment of the present invention.

FIG. 58 is an enlarged partial cross-sectional view showing an exemplary manufacturing method of the organic thin film solar cell module according to the fifth embodiment of the present invention.

FIG. 59 is an enlarged partial cross-sectional view showing an exemplary manufacturing method of the organic thin film solar cell module according to the fifth embodiment of the present invention.

FIG. 60 is an enlarged partial cross-sectional view showing an exemplary manufacturing method of the organic thin film solar cell module according to the fifth embodiment of the present invention.

FIG. 61 is an enlarged partial cross-sectional view showing an exemplary manufacturing method of the organic thin film solar cell module according to the fifth embodiment of the present invention.

FIG. 62 is an enlarged partial cross-sectional view showing an exemplary manufacturing method of the organic thin film solar cell module according to the fifth embodiment of the present invention.

FIG. 63 is an enlarged partial cross-sectional view showing an exemplary manufacturing method of the organic thin film solar cell module according to the fifth embodiment of the present invention.

FIG. 64 is an enlarged partial cross-sectional view showing an exemplary manufacturing method of the organic thin film solar cell module according to the fifth embodiment of the present invention.

FIG. 65 is an enlarged partial cross-sectional view showing an exemplary manufacturing method of the organic thin film solar cell module according to the fifth embodiment of the present invention.

FIG. 66 is an enlarged partial cross-sectional view showing a variation of the organic thin film solar cell module according to the fifth embodiment of the present invention.

FIG. 67 is an enlarged partial cross-sectional view showing another variation of the organic thin film solar cell module according to the fifth embodiment of the present invention.

FIG. 68 is a plan view showing an electronic device incorporated with the organic thin film solar cell according to the present invention.

FIG. 69 is a plan view showing organic thin film solar cells according to a seventh to a ninth embodiments of the present invention.

FIG. 70 is an enlarged cross-sectional view taken along a line LXX-LXX in FIG. 69, showing a configuration of an organic thin film solar cell according to the seventh embodiment of the present invention.

FIG. 71 is a schematic cross-sectional view for explaining an exemplary manufacturing process of the organic thin film solar cell shown in FIG. 70.

FIG. 72 is a schematic cross-sectional view for explaining an exemplary manufacturing process of the organic thin film solar cell shown in FIG. 70.

FIG. 73 is a schematic cross-sectional view for explaining an exemplary manufacturing process of the organic thin film solar cell shown in FIG. 70.

FIG. 74 is a schematic cross-sectional view for explaining an exemplary manufacturing process of the organic thin film solar cell shown in FIG. 70.

FIG. 75 is a schematic cross-sectional view for explaining an exemplary manufacturing process of the organic thin film solar cell shown in FIG. 70.

FIG. 76 is a schematic cross-sectional view for explaining an exemplary manufacturing process of the organic thin film solar cell shown in FIG. 70.

FIG. 77 is a schematic cross-sectional view for explaining an exemplary manufacturing process of the organic thin film solar cell shown in FIG. 70.

FIG. 78 is a rear view of the organic thin film solar cell according to the seventh embodiment of the present invention.

FIG. 79 is an enlarged cross-sectional view, corresponding to the view taken along the line LXX-LXX in FIG. 69, showing a configuration of the organic thin film solar cell according to the eighth embodiment of the present invention.

FIG. 80 is a schematic cross-sectional view for explaining an exemplary manufacturing process of the organic thin film solar cell shown in FIG. 79.

FIG. 81 is a schematic cross-sectional view for explaining an exemplary manufacturing process of the organic thin film solar cell shown in FIG. 79.

FIG. 82 is a schematic cross-sectional view for explaining an exemplary manufacturing process of the organic thin film solar cell shown in FIG. 79.

FIG. 83 is a schematic cross-sectional view for explaining an exemplary manufacturing process of the organic thin film solar cell shown in FIG. 79.

FIG. 84 is a schematic cross-sectional view for explaining an exemplary manufacturing process of the organic thin film solar cell shown in FIG. 79.

FIG. 85 is a schematic cross-sectional view for explaining an exemplary manufacturing process of the organic thin film solar cell shown in FIG. 79.

FIG. 86 is a schematic cross-sectional view for explaining an exemplary manufacturing process of the organic thin film solar cell shown in FIG. 79.

FIG. 87 is an enlarged cross-sectional view, corresponding to the view taken along the line LXX-LXX in FIG. 69, showing a configuration of the organic thin film solar cell according to the ninth embodiment of the present invention.

FIG. 88 is a schematic cross-sectional view for explaining an exemplary manufacturing process of the organic thin film solar cell shown in FIG. 86.

FIG. 89 is a schematic cross-sectional view for explaining an exemplary manufacturing process of the organic thin film solar cell shown in FIG. 86.

FIG. 90 is a schematic cross-sectional view for explaining an exemplary manufacturing process of the organic thin film solar cell shown in FIG. 86.

FIG. 91 is a schematic cross-sectional view for explaining an exemplary manufacturing process of the organic thin film solar cell shown in FIG. 86.

FIG. 92 is a schematic cross-sectional view for explaining an exemplary manufacturing process of the organic thin film solar cell shown in FIG. 86.

FIG. 93 is a schematic cross-sectional view for explaining an exemplary manufacturing process of the organic thin film solar cell shown in FIG. 86.

FIG. 94 is a schematic cross-sectional view for explaining an exemplary manufacturing process of the organic thin film solar cell shown in FIG. 86.

FIG. 95 is a plan view showing an organic thin film solar cell according to a tenth embodiment of the present invention.

FIG. 96 is an enlarged cross-sectional view taken along a line XCVI-XCVI in FIG. 95, showing a configuration of the organic thin film solar cell according to the tenth embodiment of the present invention.

FIG. 97 is a schematic cross-sectional view for explaining an exemplary manufacturing process of the organic thin film solar cell shown in FIG. 96.

FIG. 98 is a schematic cross-sectional view for explaining an exemplary manufacturing process of the organic thin film solar cell shown in FIG. 96.

FIG. 99 is a schematic cross-sectional view for explaining an exemplary manufacturing process of the organic thin film solar cell shown in FIG. 96.

FIG. 100 is a schematic cross-sectional view for explaining an exemplary manufacturing process of the organic thin film solar cell shown in FIG. 96.

FIG. 101 is a schematic cross-sectional view for explaining an exemplary manufacturing process of the organic thin film solar cell shown in FIG. 96.

FIG. 102 is a schematic cross-sectional view for explaining an exemplary manufacturing process of the organic thin film solar cell shown in FIG. 96.

FIG. 103 is a schematic cross-sectional view for explaining an exemplary manufacturing process of the organic thin film solar cell shown in FIG. 96.

FIG. 104 is a plan view showing organic thin film solar cells according to an eleventh and a twelfth embodiment of the present invention.

FIG. 105 is an enlarged cross-sectional view taken along a line CV-CV in FIG. 104, showing a configuration of an organic thin film solar cell according to the seventh embodiment of the present invention.

FIG. 106 is an enlarged cross-sectional view, corresponding to the view taken along the line CV-CV in FIG. 104, showing a configuration of the organic thin film solar cell according to the twelfth embodiment of the present invention.

FIG. 107 is a plan view showing another electronic device incorporated with the organic thin film solar cell according to the present invention.

FIG. 108 is an enlarged cross-sectional view taken along a line CVIII-CVIII in FIG. 107.

FIG. 109 is an enlarged cross-sectional view taken along a line CIX-CIX in FIG. 107.

FIG. 110 is a plan view showing still another electronic device incorporated with the organic thin film solar cell according to the present invention.

FIG. 111 is an enlarged partial plan view of FIG. 110.

FIG. 112 is an enlarged cross-sectional view taken along a line CXII-CXII in FIG. 111.

FIG. 113 is a plan view showing organic thin film solar cell modules according to a thirteenth and a fourteenth embodiment of the present invention, and an electronic device incorporated with the organic thin film solar cell modules.

FIG. 114 is a bottom view showing the organic thin film solar cell module and the electronic device shown in FIG. 113.

FIG. 115 is a schematic cross-sectional view taken along a line CXV-CXV in FIG. 113.

FIG. 116 is an enlarged partial cross-sectional view taken along a line CXVI-CXVI in FIG. 113.

FIG. 117 is a system diagram of the electronic device shown in FIG. 113.

FIG. 118 is a partial exploded perspective view showing the organic thin film solar cell module according to the thirteenth embodiment of the present invention.

FIG. 119 is a plan view showing a first conductive layer of the organic thin film solar cell module according to the thirteenth embodiment of the present invention.

FIG. 120 is a plan view showing a photoelectric conversion layer of the organic thin film solar cell module according to the thirteenth embodiment of the present invention.

FIG. 121 is a plan view showing a second conductive layer of the organic thin film solar cell module according to the thirteenth embodiment of the present invention.

FIG. 122 is a plan view showing a resin cover layer and a bypass conductive section of the organic thin film solar cell module according to the thirteenth embodiment of the present invention.

FIG. 123 is a plan view showing a first conductive layer of the organic thin film solar cell module according to the fourteenth embodiment of the present invention.

FIG. 124 is a plan view showing a photoelectric conversion layer of the organic thin film solar cell module according to the fourteenth embodiment of the present invention.

FIG. 125 is a plan view showing a second conductive layer of the organic thin film solar cell module according to the fourteenth embodiment of the present invention.

FIG. 126 is a plan view showing a resin cover layer and a bypass conductive section of the organic thin film solar cell module according to the fourteenth embodiment of the present invention.

FIG. 127 is an enlarged partial cross-sectional view showing an exemplary manufacturing method of the organic thin film solar cell module according to the thirteenth embodiment of the present invention.

FIG. 128 is an enlarged partial cross-sectional view showing an exemplary manufacturing method of the organic thin film solar cell module according to the thirteenth embodiment of the present invention.

FIG. 129 is an enlarged partial cross-sectional view showing an exemplary manufacturing method of the organic thin film solar cell module according to the thirteenth embodiment of the present invention.

FIG. 130 is an enlarged partial cross-sectional view showing an exemplary manufacturing method of the organic thin film solar cell module according to the thirteenth embodiment of the present invention.

FIG. 131 is an enlarged partial cross-sectional view showing an exemplary manufacturing method of the organic thin film solar cell module according to the thirteenth embodiment of the present invention.

FIG. 132 is an enlarged partial cross-sectional view showing an exemplary manufacturing method of the organic thin film solar cell module according to the thirteenth embodiment of the present invention.

FIG. 133 is an enlarged partial cross-sectional view showing an exemplary manufacturing method of the organic thin film solar cell module according to the thirteenth embodiment of the present invention.

FIG. 134 is an enlarged partial cross-sectional view showing an exemplary manufacturing method of the organic thin film solar cell module according to the thirteenth embodiment of the present invention.

FIG. 135 is an enlarged partial cross-sectional view showing a variation of the organic thin film solar cell module according to the thirteenth embodiment of the present invention.

FIG. 136 is an enlarged partial cross-sectional view showing another variation of the organic thin film solar cell module according to the thirteenth embodiment of the present invention.

FIG. 137 is an enlarged cross-sectional view showing an organic thin film solar cell module according to a fifteenth embodiment of the present invention.

FIG. 138 is a partial plan view showing the organic thin film solar cell module according to the fifteenth embodiment of the present invention.

FIG. 139 is an enlarged cross-sectional view showing the organic thin film solar cell module according to the fifteenth embodiment of the present invention.

FIG. 140 is an enlarged partial cross-sectional view showing an exemplary manufacturing method of the organic thin film solar cell module according to the fifteenth embodiment of the present invention.

FIG. 141 is an enlarged partial cross-sectional view showing an exemplary manufacturing method of the organic thin film solar cell module according to the fifteenth embodiment of the present invention.

FIG. 142 is an enlarged partial cross-sectional view showing an exemplary manufacturing method of the organic thin film solar cell module according to the fifteenth embodiment of the present invention.

FIG. 143 is an enlarged partial cross-sectional view showing an exemplary manufacturing method of the organic thin film solar cell module according to the fifteenth embodiment of the present invention.

FIG. 144 is an enlarged partial cross-sectional view showing an exemplary manufacturing method of the organic thin film solar cell module according to the fifteenth embodiment of the present invention.

FIG. 145 is an enlarged partial cross-sectional view showing a variation of the organic thin film solar cell module according to the fifteenth embodiment of the present invention.

FIG. 146 is a plan view showing an organic thin film solar cell module according to a sixteenth embodiment of the present invention, and an electronic device incorporated with the organic thin film solar cell module.

FIG. 147 is a schematic cross-sectional view taken along a line CXLVII-CXLVII in FIG. 146.

FIG. 148 is an enlarged partial bottom view showing the organic thin film solar cell module according to the sixteenth embodiment of the present invention.

FIG. 149 is an enlarged partial cross-sectional view taken along a line CXLIX-CXLIX in FIG. 148.

FIG. 150 is an enlarged partial cross-sectional view taken along a line CL-CL in FIG. 148.

FIG. 151 is a system diagram of the electronic device shown in FIG. 146.

FIG. 152 is a partial exploded perspective view showing the organic thin film solar cell module according to the sixteenth embodiment of the present invention.

FIG. 153 is a plan view showing a first conductive layer of the organic thin film solar cell module according to the sixteenth embodiment of the present invention.

FIG. 154 is a plan view showing a photoelectric conversion layer of the organic thin film solar cell module according to the sixteenth embodiment of the present invention.

FIG. 155 is a plan view showing a second conductive layer of the organic thin film solar cell module according to the sixteenth embodiment of the present invention.

FIG. 156 is a plan view showing a resin cover layer and a bypass conductive section of the organic thin film solar cell module according to the sixteenth embodiment of the present invention.

FIG. 157 is a plan view showing a resin cover layer and a bypass conductive section of the organic thin film solar cell module according to the sixteenth embodiment of the present invention.

FIG. 158 is an enlarged partial cross-sectional view showing an exemplary manufacturing method of the organic thin film solar cell module according to the sixteenth embodiment of the present invention.

FIG. 159 is an enlarged partial cross-sectional view showing an exemplary manufacturing method of the organic thin film solar cell module according to the sixteenth embodiment of the present invention.

FIG. 160 is an enlarged partial cross-sectional view showing an exemplary manufacturing method of the organic thin film solar cell module according to the sixteenth embodiment of the present invention.

FIG. 161 is an enlarged partial cross-sectional view showing an exemplary manufacturing method of the organic thin film solar cell module according to the sixteenth embodiment of the present invention.

FIG. 162 is an enlarged partial cross-sectional view showing an exemplary manufacturing method of the organic thin film solar cell module according to the sixteenth embodiment of the present invention.

FIG. 163 is an enlarged partial cross-sectional view showing an exemplary manufacturing method of the organic thin film solar cell module according to the sixteenth embodiment of the present invention.

FIG. 164 is an enlarged partial cross-sectional view showing an exemplary manufacturing method of the organic thin film solar cell module according to the sixteenth embodiment of the present invention.

FIG. 165 is an enlarged partial cross-sectional view showing an exemplary manufacturing method of the organic thin film solar cell module according to the sixteenth embodiment of the present invention.

FIG. 166 is an enlarged partial cross-sectional view showing an exemplary manufacturing method of the organic thin film solar cell module according to the sixteenth embodiment of the present invention.

FIG. 167 is an enlarged partial cross-sectional view showing an exemplary manufacturing method of the organic thin film solar cell module according to the sixteenth embodiment of the present invention.

FIG. 168 is an enlarged partial cross-sectional view showing an exemplary manufacturing method of the organic thin film solar cell module according to the sixteenth embodiment of the present invention.

FIG. 169 is an enlarged partial cross-sectional view showing an exemplary manufacturing method of the organic thin film solar cell module according to the sixteenth embodiment of the present invention.

FIG. 170 is an enlarged partial cross-sectional view showing an exemplary manufacturing method of the organic thin film solar cell module according to the sixteenth embodiment of the present invention.

FIG. 171 is an enlarged partial plan view showing a variation of the organic thin film solar cell module according to the sixteenth embodiment of the present invention.

FIG. 172 is an enlarged partial plan view (rear view) showing an organic thin film solar cell module according to a seventeenth embodiment of the present invention.

FIG. 173 is an enlarged partial cross-sectional view taken along a line CLXXIII-CLXXIII in FIG. 172.

FIG. 174 is an enlarged partial cross-sectional view taken along a line CLXXIV-CLXXIV in FIG. 172.

FIG. 175 is an enlarged partial plan view showing the organic thin film solar cell module according to the seventeenth embodiment of the present invention.

FIG. 176 is an enlarged partial bottom view showing an exemplary manufacturing method of the organic thin film solar cell module according to the seventeenth embodiment of the present invention.

FIG. 177 is an enlarged partial bottom view showing an exemplary manufacturing method of the organic thin film solar cell module according to the seventeenth embodiment of the present invention.

FIG. 178 is an enlarged partial cross-sectional view showing an exemplary manufacturing method of the organic thin film solar cell module according to the seventeenth embodiment of the present invention.

FIG. 179 is an enlarged partial cross-sectional view showing an exemplary manufacturing method of the organic thin film solar cell module according to the seventeenth embodiment of the present invention.

FIG. 180 is an enlarged partial cross-sectional view showing an exemplary manufacturing method of the organic thin film solar cell module according to the seventeenth embodiment of the present invention.

FIG. 181 is an enlarged partial cross-sectional view showing an exemplary manufacturing method of the organic thin film solar cell module according to the seventeenth embodiment of the present invention.

FIG. 182 is an enlarged partial cross-sectional view showing an exemplary manufacturing method of the organic thin film solar cell module according to the seventeenth embodiment of the present invention.

FIG. 183 is an enlarged partial bottom view showing an organic thin film solar cell module according to an eighteenth embodiment of the present invention.

FIG. 184 is a plan view showing organic thin film solar cell modules according to a nineteenth and a twentieth embodiment of the present invention, and an electronic device incorporated with the organic thin film solar cell modules.

FIG. 185 is a bottom view showing the organic thin film solar cell module and the electronic device shown in FIG. 184.

FIG. 186 is a schematic cross-sectional view taken along a line CLXXXVI-CLXXXVI in FIG. 184.

FIG. 187 is an enlarged partial cross-sectional view taken along a line CLXXXVII-CLXXXVII in FIG. 184.

FIG. 188 is a system diagram of the electronic device shown in FIG. 184.

FIG. 189 is a partial exploded perspective view showing the organic thin film solar cell module according to the nineteenth embodiment of the present invention.

FIG. 190 is a plan view showing a first conductive layer of the organic thin film solar cell module according to the nineteenth embodiment of the present invention.

FIG. 191 is a plan view showing a photoelectric conversion layer of the organic thin film solar cell module according to the nineteenth embodiment of the present invention.

FIG. 192 is a plan view showing a second conductive layer of the organic thin film solar cell module according to the nineteenth embodiment of the present invention.

FIG. 193 is a plan view showing a resin cover layer and a bypass conductive section of the organic thin film solar cell module according to the nineteenth embodiment of the present invention.

FIG. 194 is a plan view showing a resin cover layer and a bypass conductive section of the organic thin film solar cell module according to the nineteenth embodiment of the present invention.

FIG. 195 is a plan view showing a first conductive layer of the organic thin film solar cell module according to the twentieth embodiment of the present invention.

FIG. 196 is a plan view showing a photoelectric conversion layer of the organic thin film solar cell module according to the twentieth embodiment of the present invention.

FIG. 197 is a plan view showing a second conductive layer of the organic thin film solar cell module according to the twentieth embodiment of the present invention.

FIG. 198 is a plan view showing a resin cover layer and a bypass conductive section of the organic thin film solar cell module according to the twentieth embodiment of the present invention.

FIG. 199 is a plan view showing a resin cover layer and a bypass conductive section of the organic thin film solar cell module according to the twentieth embodiment of the present invention.

FIG. 200 is an enlarged partial cross-sectional view showing an exemplary manufacturing method of the organic thin film solar cell module according to the nineteenth embodiment of the present invention.

FIG. 201 is an enlarged partial cross-sectional view showing an exemplary manufacturing method of the organic thin film solar cell module according to the nineteenth embodiment of the present invention.

FIG. 202 is an enlarged partial cross-sectional view showing an exemplary manufacturing method of the organic thin film solar cell module according to the nineteenth embodiment of the present invention.

FIG. 203 is an enlarged partial cross-sectional view showing an exemplary manufacturing method of the organic thin film solar cell module according to the nineteenth embodiment of the present invention.

FIG. 204 is an enlarged partial cross-sectional view showing an exemplary manufacturing method of the organic thin film solar cell module according to the nineteenth embodiment of the present invention.

FIG. 205 is an enlarged partial cross-sectional view showing an exemplary manufacturing method of the organic thin film solar cell module according to the nineteenth embodiment of the present invention.

FIG. 206 is an enlarged partial cross-sectional view showing an exemplary manufacturing method of the organic thin film solar cell module according to the nineteenth embodiment of the present invention.

FIG. 207 is an enlarged partial cross-sectional view showing an exemplary manufacturing method of the organic thin film solar cell module according to the nineteenth embodiment of the present invention.

FIG. 208 is an enlarged partial cross-sectional view showing a variation of the organic thin film solar cell module according to the nineteenth embodiment of the present invention.

FIG. 209 is an enlarged partial cross-sectional view showing another variation of the organic thin film solar cell module according to the nineteenth embodiment of the present invention.

FIG. 210 is an enlarged partial cross-sectional view showing still another variation of the organic thin film solar cell module according to the nineteenth embodiment of the present invention.

FIG. 211 is a plan view showing a first conductive layer of the variation shown in FIG. 210.

FIG. 212 is an enlarged partial cross-sectional view showing an organic thin film solar cell module according to a twenty-first embodiment of the present invention.

FIG. 213 is an enlarged partial plan view showing an organic thin film solar cell module according to the twenty-first embodiment of the present invention.

FIG. 214 is an enlarged partial cross-sectional view showing an exemplary manufacturing method of the organic thin film solar cell module according to the twenty-first embodiment of the present invention.

FIG. 215 is an enlarged partial cross-sectional view showing an exemplary manufacturing method of the organic thin film solar cell module according to the twenty-first embodiment of the present invention.

FIG. 216 is an enlarged partial cross-sectional view showing an exemplary manufacturing method of the organic thin film solar cell module according to the twenty-first embodiment of the present invention.

FIG. 217 is an enlarged partial cross-sectional view showing an exemplary manufacturing method of the organic thin film solar cell module according to the twenty-first embodiment of the present invention.

FIG. 218 is an enlarged partial cross-sectional view showing an exemplary manufacturing method of the organic thin film solar cell module according to the twenty-first embodiment of the present invention.

FIG. 219 is an enlarged partial cross-sectional view showing a variation of the organic thin film solar cell module according to the twenty-first embodiment of the present invention.

FIG. 220 is a partial plan view showing an organic thin film solar cell module according to a twenty-second embodiment of the present invention.

FIG. 221 is a cross-sectional view taken along a line CCXXI-CCXXI in FIG. 220.

FIG. 222 is an enlarged partial plan view showing the organic thin film solar cell module according to the twenty-second embodiment of the present invention.

FIG. 223 is an enlarged partial cross-sectional view taken along a line CCXXIII-CCXXIII in FIG. 222.

FIG. 224 is an enlarged partial cross-sectional view taken along a line CCXXIV-CCXXIV in FIG. 222.

FIG. 225 is an enlarged partial plan view showing the organic thin film solar cell module according to the twenty-second embodiment of the present invention.

FIG. 226 is an enlarged partial cross-sectional view taken along a line CCXXVI-CCXXVI in FIG. 225.

FIG. 227 is a system diagram of the organic thin film solar cell module and an electronic device according to the twenty-second embodiment of the present invention.

FIG. 228 is an enlarged partial plan view showing an exemplary manufacturing method of the organic thin film solar cell module according to the twenty-second embodiment of the present invention.

FIG. 229 is an enlarged partial cross-sectional view showing an exemplary manufacturing method of the organic thin film solar cell module according to the twenty-second embodiment of the present invention.

FIG. 230 is an enlarged partial plan view showing an exemplary manufacturing method of the organic thin film solar cell module according to the twenty-second embodiment of the present invention.

FIG. 231 is an enlarged partial cross-sectional view showing an exemplary manufacturing method of the organic thin film solar cell module according to the twenty-second embodiment of the present invention.

FIG. 232 is an enlarged partial plan view showing an exemplary manufacturing method of the organic thin film solar cell module according to the twenty-second embodiment of the present invention.

FIG. 233 is an enlarged partial cross-sectional view showing an exemplary manufacturing method of the organic thin film solar cell module according to the twenty-second embodiment of the present invention.

FIG. 234 is an enlarged partial plan view showing a variation of the organic thin film solar cell module according to the twenty-second embodiment of the present invention.

FIG. 235 is an enlarged partial cross-sectional view taken along a line CCXXXV-CCXXXV in FIG. 234.

FIG. 236 is an enlarged partial cross-sectional view showing a variation of the organic thin film solar cell module according to the twenty-second embodiment of the present invention.

FIG. 237 is a partial plan view showing an organic thin film solar cell module according to a twenty-third embodiment of the present invention.

FIG. 238 is an enlarged partial plan view showing the organic thin film solar cell module according to the twenty-third embodiment of the present invention.

FIG. 239 is an enlarged partial cross-sectional view taken along a line CCXXXIX-CCXXXIX in FIG. 238.

FIG. 240 is an enlarged partial cross-sectional view taken along a line CCXL-CCXL in FIG. 238.

FIG. 241 is an enlarged partial plan view showing an organic thin film solar cell module according to a twenty-fourth embodiment of the present invention.

FIG. 242 is an enlarged partial plan view showing an organic thin film solar cell module according to a twenty-fifth embodiment of the present invention.

FIG. 243 is a partial plan view showing an organic thin film solar cell module and an electronic device according to a twenty-sixth embodiment of the present invention.

FIG. 244 is a partial plan view showing an organic thin film solar cell module and an electronic device according to a twenty-seventh embodiment of the present invention.

### MODE FOR CARRYING OUT INVENTION

Hereafter, exemplary embodiments of the present invention will be described in detail, with reference to the drawings.

### First Embodiment

The reference numerals used for a first embodiment and FIG. to FIG. 17 are given for these particular embodiment and drawings, and independent of numerals used for other embodiments and drawings. It should be noted, however, that the arrangements of the first embodiment and those of any other embodiment may be combined or exchanged in an appropriate manner.

The term “transparent” used herein may be defined as having a transmittance of approximately 50% or higher. The term “transparent” may also be used for visible light when it is colorless and clear. The visible light corresponds to a wavelength range of approximately 360 nm to 830 nm and an energy range of approximately 3.45 eV to 1.49 eV. When a transmittance of a substance is 50% or higher in these ranges, that substance may be regarded as transparent.

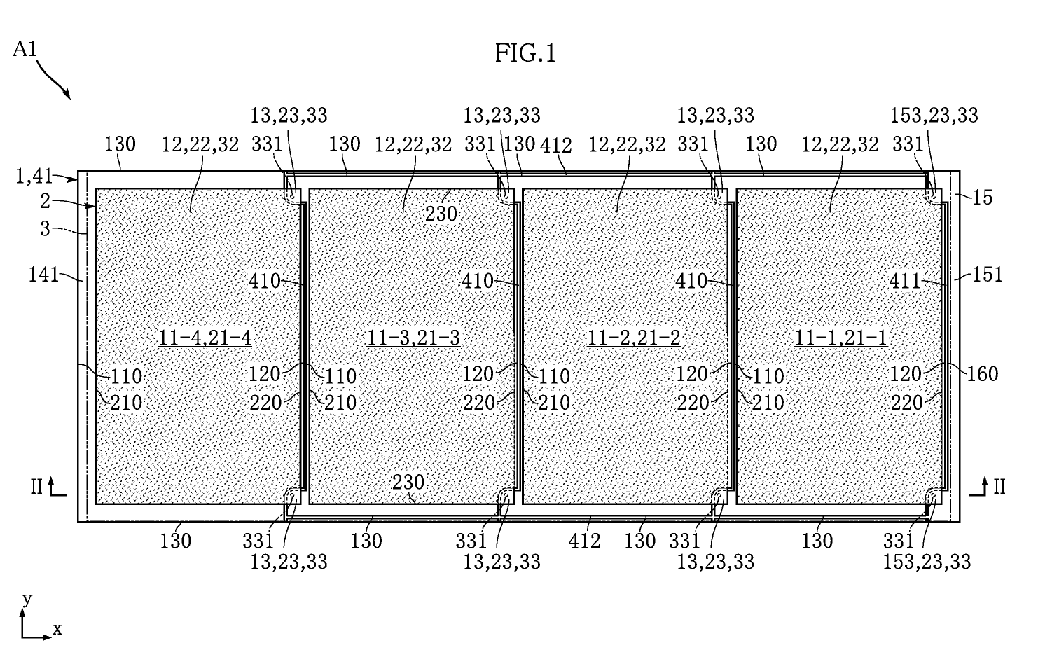

FIG. 1 to FIG. 7 illustrate an organic thin film solar cell module according to the first embodiment of the present invention. FIG. 8 illustrates an electronic device according to the first embodiment of the present invention.

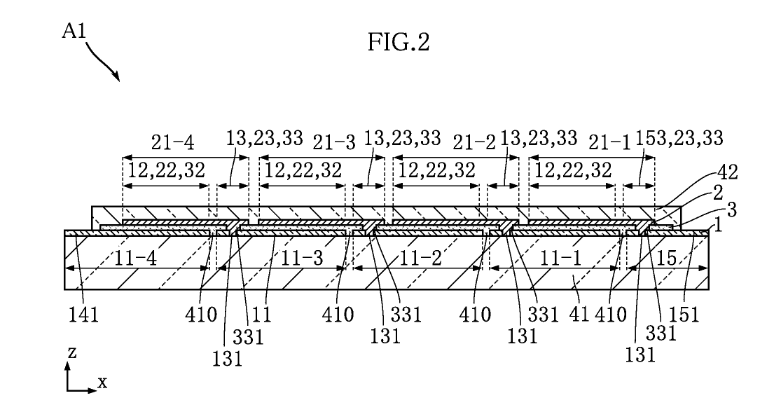

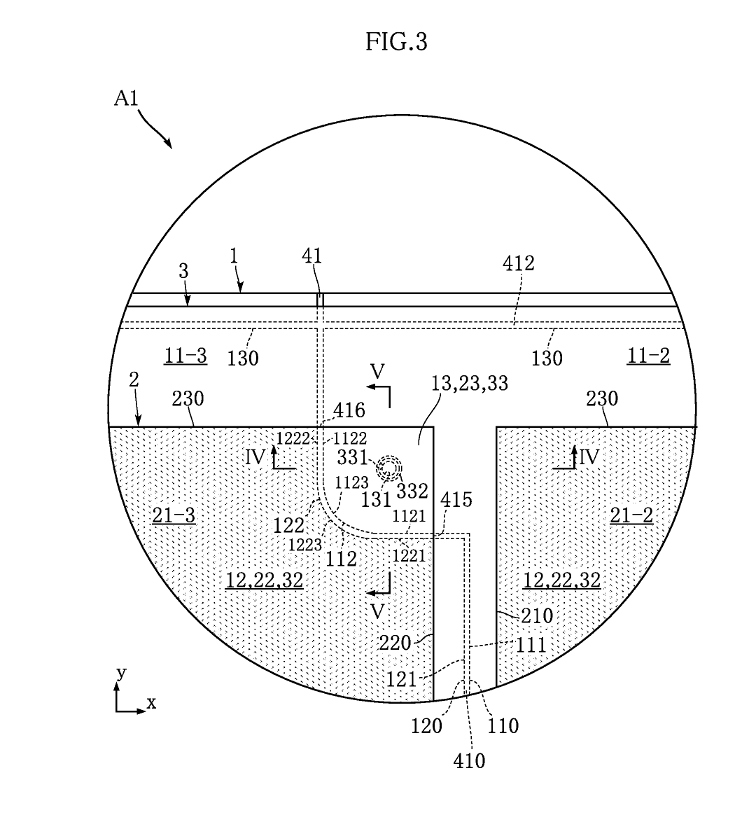

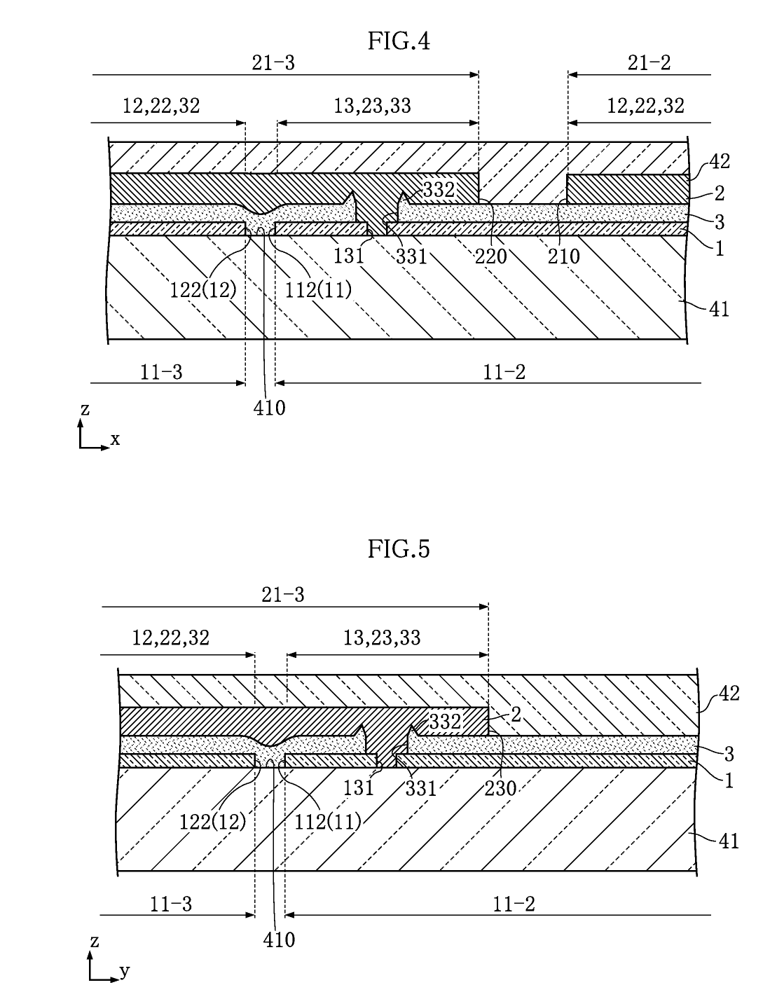

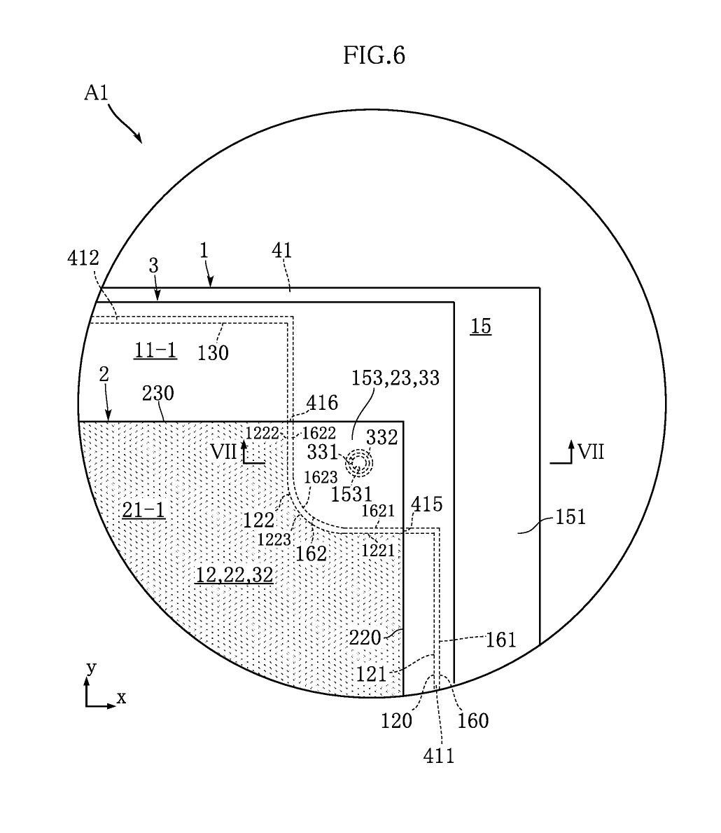

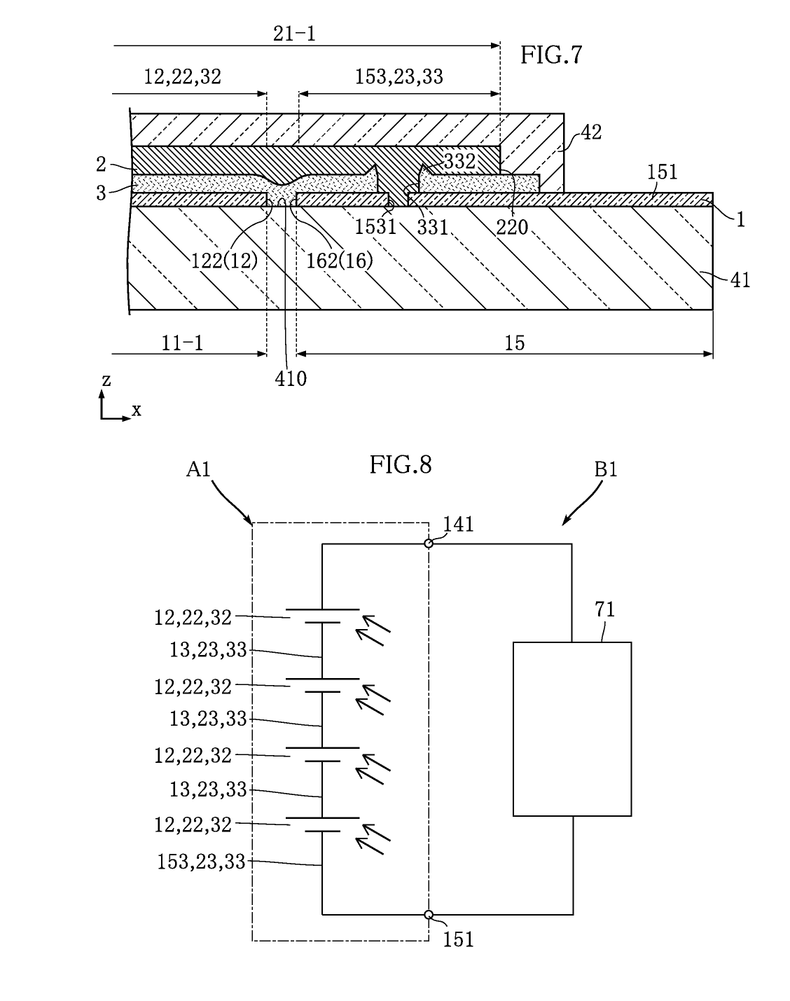

FIG. 1 is a partial plan view of the organic thin film solar cell module A1. FIG. 2 is a cross-sectional view taken along a line II-II in FIG. 1. FIG. 3 is an enlarged partial plan view of the organic thin film solar cell module A1. FIG. 4 is an enlarged partial cross-sectional view taken along a line IV-IV in FIG. 3. FIG. 5 is an enlarged partial cross-sectional view taken along a line V-V in FIG. 3. FIG. 6 is an enlarged partial plan view of the organic thin film solar cell module A1. FIG. 7 is an enlarged partial cross-sectional view taken along a line VII-VII in FIG. 6. FIG. 8 is a system diagram of an organic thin film solar cell module A1 and an electronic device B1. In the description below, “z-direction view” refers to plan view, and “z-direction” refers to a thickness direction of, for example, a base substrate 41.

As shown in FIG. 8, the electronic device B1 includes the organic thin film solar cell module A1 and a drive unit 71. The organic thin film solar cell module A1 serves as the power source module for the electronic device B1, and is configured to convert light, such as sunlight, into electric power.

The drive unit 71 operates by power supplied from the organic thin film solar cell module A1. The configuration and function of the drive unit 71 are not specifically limited, and various configurations may be adopted, provided that the function of the electronic device B1 can be realized. The drive unit 71 may be set up as, for example, an electronic arithmetic processing unit for realizing the electronic device B1 acting as electronic calculator, a wireless communication unit for realizing the electronic device B1 acting as wireless communication module, a timing processor for realizing the electronic device B1 acting as wrist watch, and an input/output operation processor for realizing the electronic device B1 acting as mobile electronic terminal device.

The organic thin film solar cell module A1 includes a base substrate 41, a first conductive layer 1, a second conductive layer 2, a photoelectric conversion layer 3, and a passivation layer 42. The organic thin film solar cell module A1 has a rectangular shape in z-direction view in this embodiment, though this is merely an example and the organic thin film solar cell module A1 may be formed in various shapes. In FIG. 1, FIG. 3, and FIG. 6, the passivation layer 42 is omitted for sake of simplicity.

The base substrate 41 serves as the base of the organic thin film solar cell module A1. The base substrate 41 may have a single-layer or multilayer structure, formed of a material selected from, for example, a transparent glass or a transparent resin. The base substrate 41 has a thickness of, for example, 0.05 mm to 2.0 mm. The shape and size of the base substrate 41 are not specifically limited, and in this embodiment the base substrate 41 has a rectangular shape in z-direction view.

As shown in FIG. 1 and FIG. 3, the organic thin film solar cell module A1 has a plurality of substrate exposure regions 410 and 412, while also having a substrate exposure region 411 as shown in FIG. 1. The substrate exposure regions 410, 411 and 412 are regions of the base substrate 41 exposed from the first conductive layer 1.

The first conductive layer 1 is formed on the base substrate 41. The first conductive layer 1 is transparent, and formed of Indium Tin Oxide, ITO, in this embodiment. The first conductive layer 1 includes first blocks 11 and a third block 15. The first conductive layer 1 may be formed in various shapes. The first conductive layer 1 has a thickness of, for example, 100 nm to 300 nm.

The first blocks 11 are located adjacent to each other via the substrate exposure regions 410. In this embodiment, four first blocks 11 are located side by side, with three substrate exposure regions 410 interposed. The four first blocks 11 are aligned along a straight line in the x-direction. In the description below, the four first blocks 11 may be distinguished as first blocks 11-1, 11-2, 11-3 and 11-4 when necessary to facilitate understanding.

Each first block 11 includes a first block first edge 110, a first block second edge 120, and two first block third edges 130.

The first block first edge 110 defines a part of a substrate exposure region 410. The first block second edge 120 defines a part of a substrate exposure region 410. Thus, a substrate exposure region 410 is defined by a combination of the first block first edge 110 of one of the first blocks 11 (e.g. first block 11-2, right in the x-direction in FIG. 3) and the first block second edge 120 of the opposite first block 11 (e.g. first block 11-3, left in the x-direction in FIG. 3).

In this embodiment, the first block first edge 110 of the first blocks 11-1 to 3 includes a first side 111, and the first block second edge 120 of the first blocks 11-2 to 4 includes a second side 121. Two sides defining the same substrate exposure region 410, e.g. the first side 111 (first side 111 of the first block 11-2 in FIG. 3) and the second side 121 (second side 121 of the first block 11-3 in FIG. 3), are parallel to each other. In this embodiment, the first side 111 and the second side 121 both linearly extend in the y-direction. Accordingly, the elongated portion of the substrate exposure region 410 defined by the first side 111 and second side 121 also linearly extends in the y-direction.

The two first block third edges 130 each connect an end of the first block first edge 110 and a corresponding end of the first block second edge 120. In this embodiment, the first block third edges 130 linearly extend in the x-direction. The first block third edges 130 define a part of the substrate exposure region 412. The first block 11 according to this embodiment has a generally rectangular shape defined by the first side 111 of the first block first edge 110, the second side 121 of the first block second edge 120, and the two first block third edges 130.

As shown in FIG. 1 and FIG. 6, the first block 11-1 on the right extremity in the x-direction and the third block 15 are located adjacent to each other via the substrate exposure region 411. The third block 15 includes a third block edge 160. The third block edge 160 of the third block 15 and the first block second edge 120 of the first block 11-1 adjacent to the third block 15 define the substrate exposure region 411. The third block edge 160 includes a third block parallel portion 161. The third block parallel portion 161 is parallel to the second side 121 of the first block 11-1. In this embodiment, the third block parallel portion 161 linearly extends in the y-direction.

The photoelectric conversion layer 3 is disposed on the base substrate 41 and the first conductive layer 1, and interposed between the first conductive layer 1 and the second conductive layer 2. The photoelectric conversion layer 3 is formed of an organic thin film, and configured to perform a photoelectric conversion function, to convert received light into electric power. Although the configuration of the photoelectric conversion layer 3 is not specifically limited, the photoelectric conversion layer 3 may include, for example, a bulk heterojunction organic active layer and a hole transport layer disposed on the bulk heterojunction organic active layer on the side of the first conductive layer 1. In this embodiment, the photoelectric conversion layer 3 is formed in a circular shape in plan view, however this is merely an example and the photoelectric conversion layer 3 may be formed in various shapes. The photoelectric conversion layer 3 has a thickness of, for example, 50 nm to 300 nm.

In the bulk heterojunction organic active layer, p-type organic active layer regions and n-type organic active layer regions are intermixed, forming a complicated bulk hetero pn junction. The p-type organic active layer region is, for example, formed of poly(3-hexylthiophene-2,5diyl) (P3HT), and the n-type organic active layer region is formed of 6,6-phenyl-C61-butyric acid methyl ester (PCBM), for example. The hole transport layer is formed of, for example, PEDOT:PSS.

Examples of materials that may be utilized to form the photoelectric conversion layer 3 include phthalocyanine (Pc), zinc-phthalocyanine (ZnPc), N,N′-dimethyl perylene-3,4,9,10-dicarboximide (Me-Ptcdi), and Buckminster fullerene (C60). These materials are, for example, utilized for vacuum vapor deposition.

In addition, poly[2-methoxy-5-(3,7-dimethyl octyloxy)]-1,4-phenylene vinylene (MDMO-PPV), poly[N-9′-hepta-decanyl-2,7-carbazole-alt-5,5-(4′,7′-di-thienyl-2′1′,3′-b3nzothiadizaole)] (PCDTBT), 6,6-phenyl-C61-butyric acid methyl ester (PC60BM), or 6,6-phenyl-C71-butyric acid methyl ester (PC70BM) may be utilized to form the photoelectric conversion layer 3. These materials are, for example, utilized for a solution process.

A major part of the second conductive layer 2 is disposed on the first conductive layer 1 via the photoelectric conversion layer 3. A part of the second conductive layer 2 is in direct contact with the first conductive layer 1. The material of the second conductive layer 2 is not specifically limited, and may be transparent or non-transparent. In this embodiment, the second conductive layer 2 is formed of a metal, typically A1, W, Mo, Mn, or Mg. In the following example, the second conductive layer 2 is formed of A1. Accordingly, the second conductive layer 2 is non-transparent. In this case, a non-illustrated passive film formed of Al₂O₃ may be formed on the surface of the second conductive layer 2 opposite to the base substrate 41. The second conductive layer 2, which is thicker than the photoelectric conversion layer 3, has a thickness of, for example, 1 μm to 5 μm.

As shown in FIG. 1, the second conductive layer 2 includes a plurality of second blocks 21. The second blocks 21 are located adjacent to each other, via a part of the substrate exposure region 410. In this embodiment, specifically, the second blocks 21 adjacent to each other are aligned, with the first side 111 of the first block first edge 110 and the second side 121 of the first block second edge 120 therebetween. In this embodiment, the four second blocks 21 are aligned, with a part of each of the three substrate exposure regions 410 therebetween. Further, the four second blocks 21 are aligned along a straight line in the x-direction. In the description below, the four second blocks 21 may be distinguished as second block 21-1, second block 21-2, second block 21-3, and second block 21-4 when necessary to facilitate understanding.

As shown in FIG. 1 and FIG. 3, the second block 21 overlaps with the first block 11 in z-direction view. The second block 21 includes a second block first edge 210, a second block second edge 220, and two second block third edges 230.

The second block first edge 210 of the second blocks 21-1 to 3 (second block 21-2 in FIG. 3) is located opposite to the first block second edge 120 of the first block 11-2 to 4 (first block 11-3 in FIG. 3) defining the substrate exposure region 410, across the first block first edge 110 of the first blocks 11-1 to 3 (first block 11-2 in FIG. 3), also defining the substrate exposure region 410. The second block second edge 220 is opposed to the second block first edge 210 of the second block 21 adjacent thereto, across a part of the substrate exposure region 410, in z-direction view.

In this embodiment, the second block first edge 210 (of the second block 21-2 in FIG. 3) and the second block second edge 220 (of the second block 21-3 in FIG. 3) are parallel to each other. The second block first edge 210 and the second block second edge 220 linearly extend in the y-direction. Thus, in this embodiment the first side 111, the second side 121, the second block first edge 210, and the second block second edge 220 are parallel to each other and linearly extend in the y-direction.

The two second block third edges 230 each connect an end of the second block first edge 210 and a corresponding end of the second block second edge 220. The two second block third edges 230 are parallel to each other and linearly extend in the x-direction. The second block 21, having the second block first edge 210, the second block second edge 22, and the two second block third edges 230, has a rectangular shape in z-direction view.

As shown in FIG. 2, FIG. 4, FIG. 5, and FIG. 7, the passivation layer 42 is disposed on the second conductive layer 2, so as to cover the second conductive layer 2 and the photoelectric conversion layer 3. The passivation layer 42 is, for example, formed of SiN or SiON. The passivation layer 42 has a thickness of, for example, 0.5 μm to 2.0 μm and, in this embodiment, approximately 1.5 μm. Since the passivation layer 42 covers the photoelectric conversion layer 3, intrusion of moisture or particles from outside into the photoelectric conversion layer 3 can be prevented. In addition, the passivation layer 42 is thicker than the photoelectric conversion layer 3, and hence the strength of the organic thin film solar cell module A1 can be improved. A flat passivation layer 42 such as noted above can be formed, without limitation, by setting its thickness to be greater than that of the photoelectric conversion layer 3 and using a CVD process to be described below. Another layer may be additionally formed on the passivation layer 42. For example, a bonding layer may be used to bond an element of the electronic device B1 to the organic thin film solar cell module A1. A cover layer may be used to protect the passivation layer 42.

As shown in FIG. 3 to FIG. 5, the first block first edge 110 of a first block 11-1 to 11-3 (see first block 11-2 in FIG. 3) includes two first shielded portions 112 in addition to the first side 111. The first shielded portions 112 each correspond to a portion of the first block first edge 110 that overlaps with the second block 21 in z-direction view, and that is shielded with the second block 21 in z-direction view. In this embodiment, the two first shielded portions 112 are connected to the respective end portions of the first side 111, which are spaced apart from each other in the y-direction. The shape of the first shielded portion 112 is not specifically limited, and in this embodiment the first shielded portion 112 is formed so as to protrude from the first side 111 in the x-direction, and includes a first side 1121, a second side 1122, and a third side 1123. The first side 1121 extends in the x-direction, parallel to the first block third edge 130. The second side 1122 extends in the y-direction, so as to intersect the first side 1121. The third side 1123, connecting the first side 1121 and the second side 1122, is formed in a curved shape in the example shown in FIG. 3. An end of the first shielded portion 112 shown in FIG. 3 reaches the second block second edge 220, and the other end intersects the second block third edge 230 in z-direction view.

As shown in FIG. 3 to FIG. 5, the first block second edge 120 of the first blocks 11-2 to 4 (first block 11-3 in FIG. 3) includes two second shielded portions 122 in addition to the second side 121. The second shielded portion 122 each correspond to a portion of the first block second edge 120 overlapping with the second block 21 in z-direction view. In this embodiment, the two second shielded portions 122 are connected to the respective end portions of the second side 121 in the y-direction. The shape of the second shielded portion 122 is not specifically limited, and in this embodiment the second shielded portion 122 is retracted from the second side 121 in the x-direction, and includes a first side 1221, a second side 1222, and a third side 1223. The first side 1221 extends in the x-direction, parallel to the first block third edge 130. The second side 1222 extends in the y-direction, so as to intersect the first side 1221. The third side 1223, connecting the first side 1221 and the second side 1222, is formed in a curved shape in the example shown in FIG. 3. An end of the second shielded portion 122 shown in FIG. 3 reaches the second block second edge 220, and the other end reaches the second block third edge 230 in z-direction view.

Because of the first shielded portion 112 and the second shielded portion 122 configured as above, the substrate exposure region 410 according to this embodiment overlaps with the second block 21 in z-direction view, and includes an intersection 415 and an intersection 416. The intersection 415 is the intersection between the substrate exposure region 410 and the second block second edge 220. The intersection 416 is the intersection between the substrate exposure region 410 and the second block third edge 230.

As shown in FIG. 1 to FIG. 5, the photoelectric conversion layer 3 includes a plurality of photoelectric conversion layer connection portions 33. As shown in FIG. 3 to FIG. 5, the photoelectric conversion layer connection portion 33 overlaps with both of the first block 11 (in FIG. 3, first block 11-2) of the first conductive layer 1 and the second block 21 (in FIG. 3, second block 21-3) of the second conductive layer 2 in z-direction view, which are adjacent to each other via a part of the substrate exposure region 410 (in FIG. 3, region defined by the first side 111 of the first block 11-2 and the second side 121 of the first block 11-3), and is defined by the first shielded portion 112 of the first block 11 and the second block second edge 220 of the second block 21. In this embodiment, further, the photoelectric conversion layer connection portion 33 is defined by the second block third edge 230 (in FIG. 3, second block third edge 230 of the second block 21-3). Thus, the photoelectric conversion layer connection portion 33 according to this embodiment is located at a position overlapping with a corner portion of the second block 21 (in FIG. 3, second block 21-3) of a rectangular shape, in z-direction view. In addition, in this embodiment the two photoelectric conversion layer connection portions 33 are respectively located at two corner portions spaced apart from each other in the y-direction, in each of the second blocks 21, as shown in FIG. 1.

The photoelectric conversion layer connection portion 33 includes a photoelectric conversion layer perforated portion 331. The photoelectric conversion layer perforated portion 331 is a through-hole formed so as to penetrate through the photoelectric conversion layer 3 in the z-direction. The shape and size of the photoelectric conversion layer perforated portion 331 are not specifically limited, and in this embodiment the photoelectric conversion layer perforated portion 331 has a circular shape in z-direction view. The photoelectric conversion layer perforated portion 331 has a diameter of, for example, approximately 40 μm. The photoelectric conversion layer connection portion 33 also includes a projection 332. The projection 332 is, as shown in FIG. 4, formed so as to protrude in the z-direction from a surrounding region of the photoelectric conversion layer 3. As shown in FIG. 3, the projection 332 surrounds the photoelectric conversion layer perforated portion 331, in z-direction view.

The first blocks 11-1 to 3 each include a first connection portion 13. The first connection portion 13 is located at a position coinciding with the photoelectric conversion layer connection portion 33 in z-direction view. The second block 21 includes a second connection portion 23. The second connection portion 23 is located at a position coinciding with the photoelectric conversion layer connection portion 33 in z-direction view. The first connection portion 13 of the first blocks 11-1 to 3 and the second connection portion 23 of the second blocks 21-2 to 4 are in contact with each other via the photoelectric conversion layer perforated portion 331, the electrically connected to each other. Accordingly, the first connection portion 13, the second connection portion 23, and the photoelectric conversion layer connection portion 33 are regions not involved in power generation.

In this embodiment, the first connection portion 13 of the first block 11 includes a first perforated portion 131. In this embodiment, the first perforated portion 131 refers to a through-hole penetrating through the first conductive layer 1 in the z-direction. The first perforated portion 131 is enclosed in the photoelectric conversion layer perforated portion 331, in z-direction view. In addition, the inner edge of the first perforated portion 131 is spaced apart from the inner edge of the photoelectric conversion layer perforated portion 331, in z-direction view. Accordingly, a part of the first connection portion 13 of the first block 11 is exposed from the photoelectric conversion layer perforated portion 331, in z-direction view. The second connection portion 23 of the second blocks 21-2 to 4 of the second conductive layer 2 is in contact with the exposed portion. In addition, the second connection portion 23 of the second blocks 21-2 to 4 is in contact with the base substrate 41 via the first perforated portion 131.

The photoelectric conversion layer 3 includes a plurality of photoelectric conversion layer generation sections 32. The first block 11 of the first conductive layer 1 includes a first electrode section 12, and the second block 21 of the second conductive layer 2 includes a second electrode section 22. In FIG. 1, FIG. 3, and FIG. 6, the first electrode section 12, the second electrode section 22, and the photoelectric conversion layer generation section 32 are shaded with scattered dots. The first electrode section 12 is spaced apart from the photoelectric conversion layer connection portion 33 and overlapping with the second block 21 of the second conductive layer 2, in z-direction view. In other words, the second block 21 coincides with the first electrode section 12, in z-direction view. The photoelectric conversion layer generation section 32 coincides with the first electrode section 12 and the second electrode section 22, in z-direction view. In this embodiment, the first electrode section 12, the second electrode section 22, and the photoelectric conversion layer generation section 32 are defined by the second block first edge 210, the second block second edge 220, the two second block third edges 230, and the two second shielded portions 122, in z-direction view. The first electrode section 12 and the second electrode section 22 are stacked, with the photoelectric conversion layer generation section 32 therebetween, and are hence not in contact with each other. Accordingly, the first electrode section 12, the second electrode section 22, and the photoelectric conversion layer generation section 32 are regions involved in power generation.

In this embodiment, the photoelectric conversion layer connection portion 33 and a part of the photoelectric conversion layer generation section 32 are located adjacent to each other in the y-direction with a gap therebetween, in z-direction view. More specifically, the photoelectric conversion layer connection portion 33 is located at the same position as a part of the photoelectric conversion layer generation section 32, in the x-direction. The first connection portion 13 is adjacent, in the y-direction, to a part of the first electrode section 12 of the first block 11 adjacent via the substrate exposure region 410. Thus, the position of the first connection portion 13 in the x-direction overlaps with the position of the part of the first electrode section 12 in the x-direction.

As shown in FIG. 1, FIG. 2, FIG. 6, and FIG. 7, the third block 15 includes an external electrode section 151 and an external connection portion 153. The external connection portion 153 is located at a position coinciding with the second connection portion 23 of the second block 21-1 and the photoelectric conversion layer connection portion 33, in z-direction view. The external connection portion 153 is in contact with the second connection portion 23 of the second block 21-1, via the photoelectric conversion layer perforated portion 331. In this embodiment, the external connection portion 153 includes an external connection portion perforated portion 1531. In this embodiment, the external connection portion perforated portion 1531 refers to a through-hole penetrating through the external connection portion 153 of the first conductive layer 1, in the z-direction. The external connection portion perforated portion 1531 is enclosed in the photoelectric conversion layer perforated portion 331, in z-direction view. Further, the inner edge of the external connection portion perforated portion 1531 is spaced apart from the inner edge of the photoelectric conversion layer perforated portion 331, in z-direction view. Accordingly, a part of the external connection portion 153 of the third block 15 is exposed from the photoelectric conversion layer perforated portion 331, in z-direction view. The second connection portion 23 of the second block 21-1 of the second conductive layer 2 is in contact with the exposed portion. In addition, the second connection portion 23 is in contact with the base substrate 41, via the external connection portion perforated portion 1531. The external electrode section 151 is exposed from the second conductive layer 2, the photoelectric conversion layer 3, and the passivation layer 42. The external electrode section 151 is a portion from which the power generated in the organic thin film solar cell module A1 is outputted, and is electrically connected, for example, to a terminal of the electronic device B1.

In this embodiment, as shown in FIG. 1 and FIG. 2, the first block 11-4, located on the side opposite to the third block 15 in the x-direction, includes an external electrode section 141. The external electrode section 141 is a portion of the first block 11-4 exposed from the second conductive layer 2, the photoelectric conversion layer 3, and the passivation layer 42. The external electrode section 141 is a portion from which the power generated in the organic thin film solar cell module A1 is outputted, and is electrically connected, for example, to a terminal of the electronic device B1.

As seen from FIG. 1, FIG. 2, and FIG. 8, in the organic thin film solar cell module A1, four sets of the first electrode section 12, the second electrode section 22, and the photoelectric conversion layer generation section 32, are connected to each other directly, i.e. merely via six sets of the first connection portion 13, the second connection portion 23, and the photoelectric conversion layer connection portion 33, in this embodiment. The power generated in the four sets of the first electrode section 12, the second electrode section 22 and the photoelectric conversion layer generation section 32 connected in series to each other, is outputted from the external electrode section 141 and the external electrode section 151. Such power is utilized to activate the drive unit 71 of the electronic device B1.

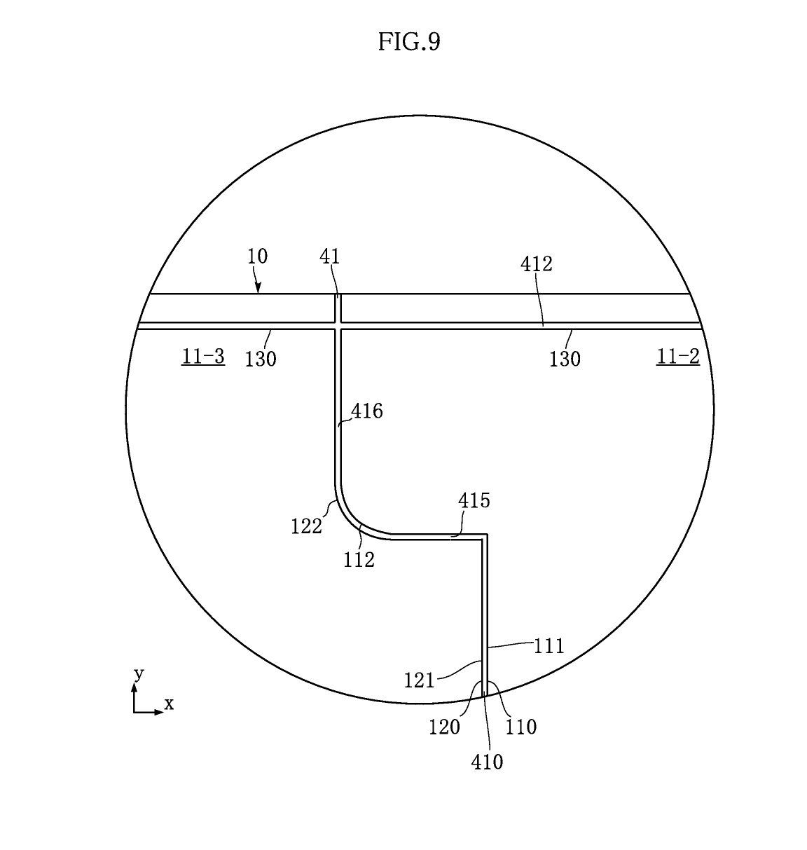

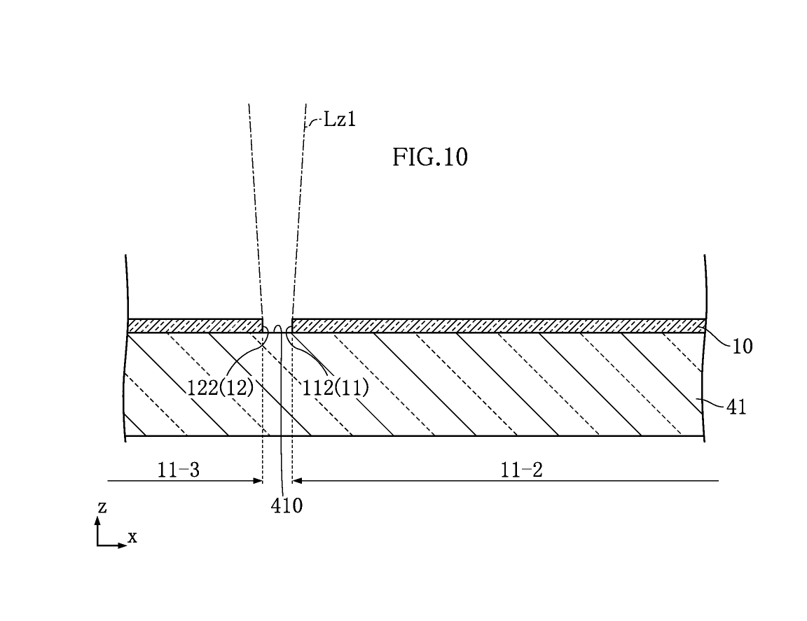

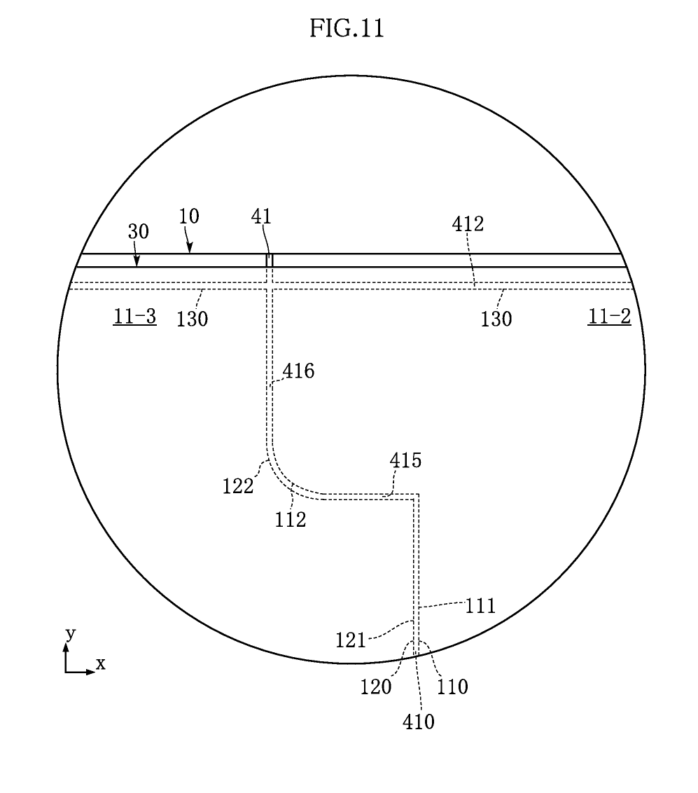

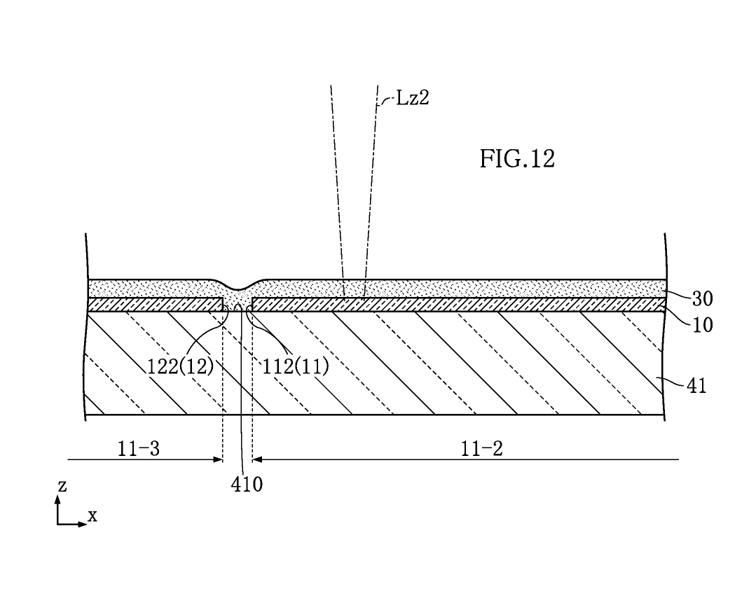

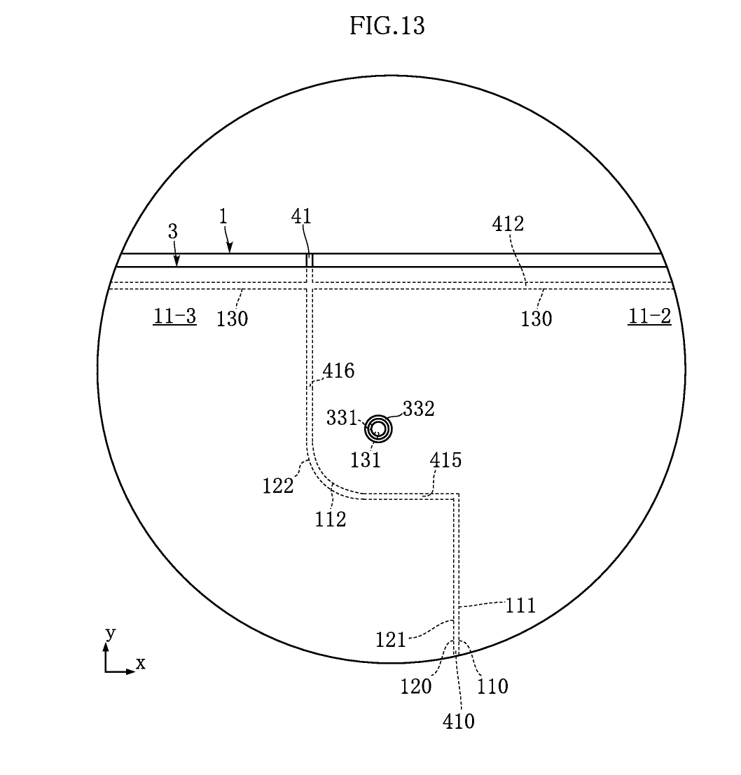

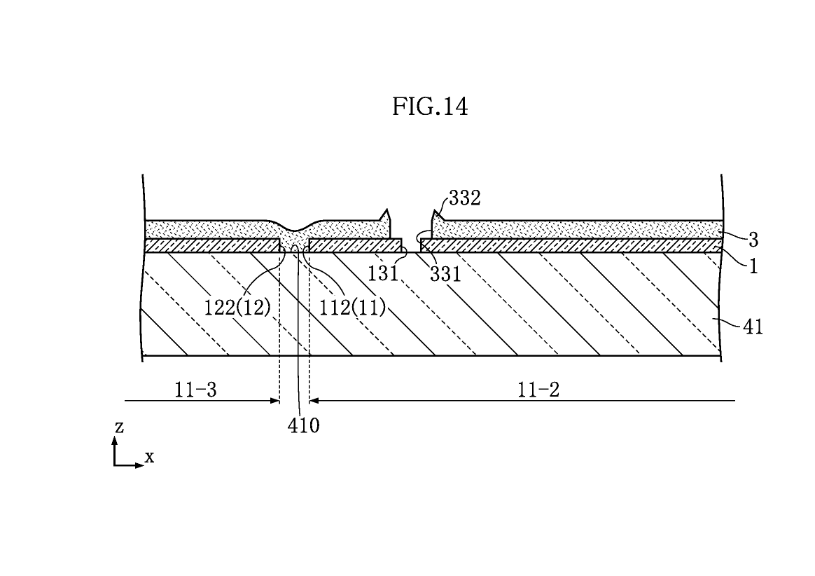

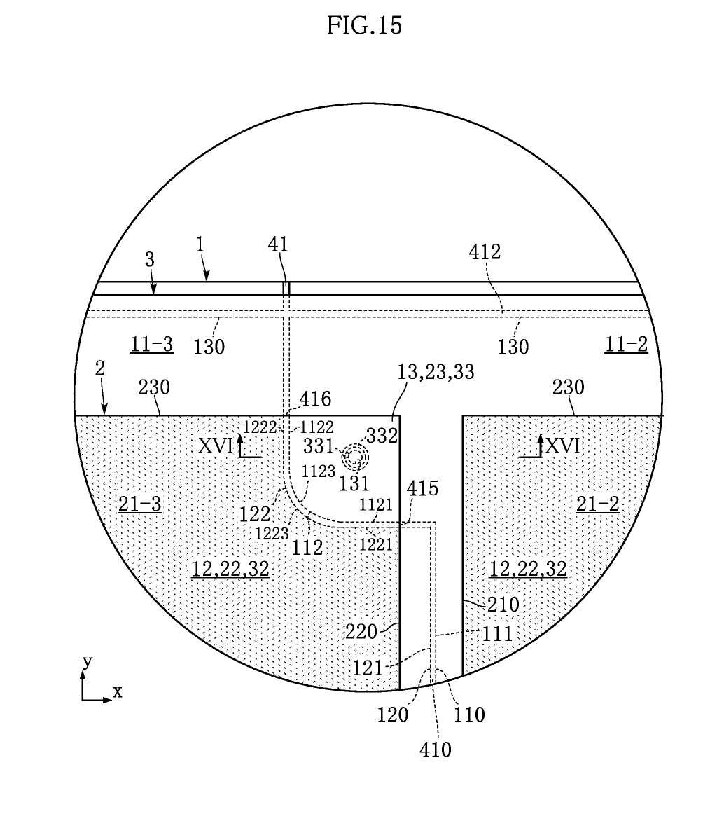

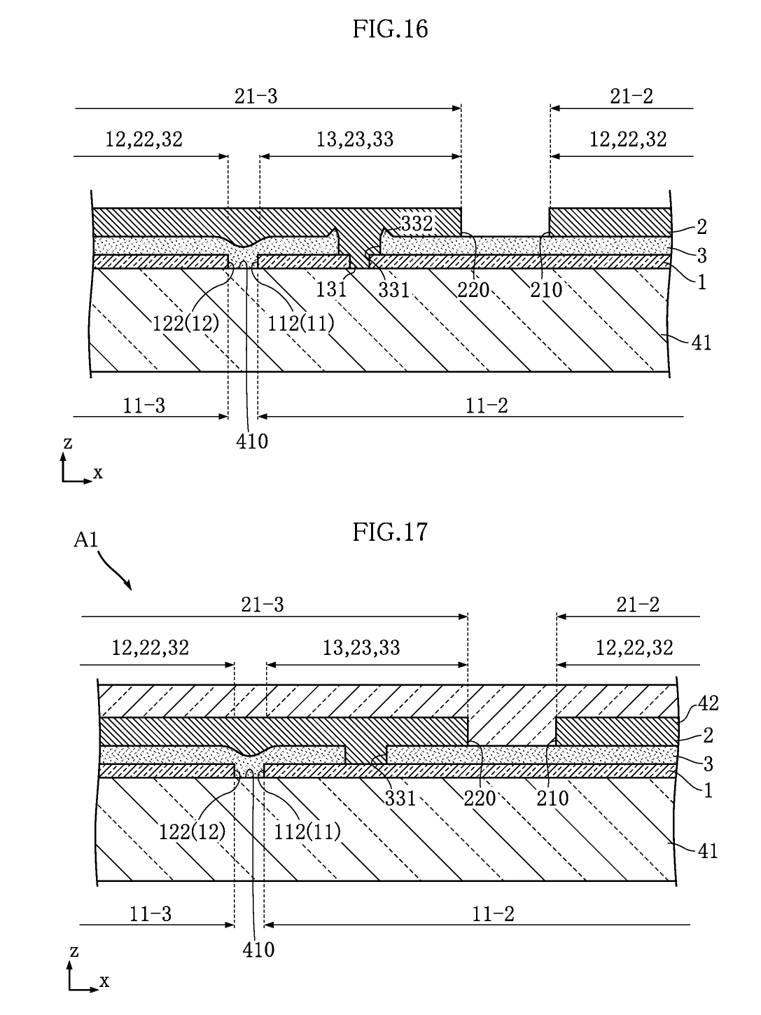

Hereunder, a manufacturing method of the organic thin film solar cell module A1 will be described with reference to FIG. 9 to FIG. 16. FIG. 9, FIG. 11, FIG. 13, and FIG. 15 are enlarged partial plan views showing the same portion as that of FIG. 3, and FIG. 10, FIG. 12, FIG. 14, and FIG. 16 are enlarged partial cross-sectional view showing the same portion as that of FIG. 4.

Referring first to FIG. 9 and FIG. 10, the first conductive film 10 is formed on one of the surfaces of the base substrate 41, by depositing ITO by a known method such as sputtering. Then the first conductive film 10 is patterned to form the substrate exposure region 410, the substrate exposure region 411, and the substrate exposure region 412. Thus, a plurality of first blocks 11 and the third block 15 are obtained. For the patterning of the first conductive film 10, for example, a wet etching process, or a laser patterning that utilizes green laser beam or IR laser beam, may be employed. In this embodiment, the IR laser beam is employed as a laser beam Lz1. In FIG. 9, the portions to be subsequently formed into the first shielded portion 112 and the second shielded portion 122 are indicated by the numerals.

Proceeding to FIG. 11 and FIG. 12, an organic film 30 is formed. The organic film 30 may be formed by applying an organic film onto the base substrate 41 and the first conductive film 10, for example by spin coating. Then the photoelectric conversion layer perforated portion 331 is formed in the organic film 30. The photoelectric conversion layer perforated portion 33 may be formed, for example, by laser patterning. For the laser patterning, a laser beam Lz2 is selected from laser beams that are capable of partially removing the photoelectric conversion layer perforated portion 331. In this embodiment, the IR laser beam is employed as the laser beam Lz2, to perform the laser patterning. In this case, the laser beam Lz2 removes a part of each of the organic film 30 and the first conductive film 10. Accordingly, the photoelectric conversion layer perforated portion 331 is formed in the organic film 30, and the first perforated portion 131 is formed in the first conductive film 10. Through such laser patterning, the first conductive layer 1 and the photoelectric conversion layer 3 can be obtained, as shown in FIG. 13 and FIG. 14. By the formation of the photoelectric conversion layer perforated portion 331 and the first perforated portion 131 with the laser beam Lz2, the projection 332 is formed on the photoelectric conversion layer 3.

Proceeding to FIG. 15 and FIG. 16, the second conductive layer 2 is formed. To form the second conductive layer 2, for example, one of the aforementioned metals is deposited by electron beam deposition on the base substrate 41, the first conductive layer 1, and the photoelectric conversion layer 3, to deposit a metal film thereon. The metal film is formed so as to be thicker than the photoelectric conversion layer 3, for example in a thickness of 1 μm to 5 μm. Then the metal film is patterned, for example by etching with a mask layer. Through such patterning, the second conductive layer 2 including a plurality of second blocks 21 is formed on the first conductive layer 1 and the photoelectric conversion layer 3. Thereafter, SiN or SiON is deposited on the base substrate 41, the first conductive layer 1, the photoelectric conversion layer 3, and the second conductive layer 2, for example by plasma CVD, to form the passivation layer 42. Through the mentioned process, the organic thin film solar cell module A1 can be obtained.

The organic thin film solar cell module A1 and the electronic device B1 provide the following advantageous effects.

In this embodiment, the second conductive layer 2 is thicker than the photoelectric conversion layer 3, as shown in FIG. 4 and FIG. 5. Accordingly, even when the projection 332 is formed through the formation process of the photoelectric conversion layer perforated portion 331 in the photoelectric conversion layer 3, the projection 332 can be securely covered with the second conductive layer 2. Thus, it is possible to prevent minute cracks from forming in the passivation layer 42, for example, due to the presence of the projection 332. Accordingly, intrusion of outside air into the photoelectric conversion layer 3 can be suppressed. Consequently, an accidental damage to the organic thin film solar cell module A1 and the electronic device B1 can be prevented.

While the photoelectric conversion layer 3 has a thickness of 50 nm to 300 nm, the second conductive layer 2 has a thickness of 1 μm to 5 μm. With such a thickness design, for example an uneven portion in the photoelectric conversion layer perforated portion 331, which may be formed in the photoelectric conversion layer 3 in the manufacturing process, can be properly covered. In addition, for example, silica particles that may stick to the surface of the photoelectric conversion layer 3, in the manufacturing process of the organic thin film solar cell module A1, can be covered with the second conductive layer 2.

Referring to FIG. 3, the substrate exposure region 410, a part of which is defined by the first shielded portion 112 of the first block 11-2 defining the photoelectric conversion layer connection portion 33, includes the intersection 415 intersecting the second block second edge 220 of the second block 21-3. Accordingly, the photoelectric conversion layer connection portion 33 is formed along only a part of the second block second edge 220 of the second block 21-3, instead of along the entire length thereof. Such a configuration allows reduction of the area ratio of the photoelectric conversion layer connection portion 33, which is the non-generating portion, to the photoelectric conversion layer 3, thereby preventing reduction of the area of the photoelectric conversion layer generation section 32, which is the section actually contributing to the power generation.

In the example shown in FIG. 3, the substrate exposure region 410 includes one intersection 415 and one intersection 416. In other words, the substrate exposure region 410 defining the photoelectric conversion layer connection portion 33 extends from the second block second edge 220 of the second block 21-3 and intersects the second block third edge 230 of the second block 21-3. In a case where, for example, the substrate exposure region 410 intersects the second block second edge 220 of the second block 21-3 at two points unlike in this embodiment, the portion of the substrate exposure region 410 overlapping with the second block 21-3 in z-direction view is longer, compared with the configuration of this embodiment. Since the substrate exposure region 410 is a region not involved in the power generation, the mentioned configuration of this embodiment contributes to reducing the area ratio of the non-generating region.

The photoelectric conversion layer perforated portion 331 is a through-hole having a diameter of, for example, approximately 40 μm. Accordingly, the area of the photoelectric conversion layer connection portion 33 including the photoelectric conversion layer perforated portion 331 can be further reduced.

The first perforated portion 131 is collectively formed with the photoelectric conversion layer perforated portion 331, by employing the IR laser beam as the laser beam Lz2 shown in FIG. 12. The IR laser beam is capable of partially removing the first conductive layer 1 which is formed of ITO, and can therefore be utilized as the laser beam Lz1 shown in FIG. 10, used for the laser patterning of the first conductive film 10. Therefore, it suffices to employ one type of laser beam, namely the IR laser beam, as the laser beam Lz1 and the laser beam Lz2 employed in the manufacturing method of the organic thin film solar cell module A1, shown in FIG. 9 to FIG. 16. This is advantageous for simplifying the manufacturing method and equipment, and contributes to reducing the manufacturing time.

Two sets of the first connection portion 13, the second connection portion 23, and the photoelectric conversion layer connection portion 33 are respectively provided so as to overlap with the two corner portions of the second block 21, and therefore the resistance between two sets of the first electrode section 12, the second electrode section 22, and the photoelectric conversion layer generation section 32, located adjacent to each other, can be reduced. Further, even when the electric conduction fails in one of the sets of the first connection portion 13, the second connection portion 23, and the photoelectric conversion layer connection portion 33, the other set of the first connection portion 13, the second connection portion 23, and the photoelectric conversion layer connection portion 33 can properly connect the two sets of the first electrode section 12, the second electrode section 22, and the photoelectric conversion layer generation section 32 adjacent to each other.

FIG. 17 illustrates a variation of the present invention. In this variation, the elements same as or similar to those of the foregoing embodiment are given the same numeral.

FIG. 17 illustrates a variation of the organic thin film solar cell module A1. In this variation, the first perforated portion 131 is not formed in the first connection portion 13 of the first block 11 (first block 11-2 in FIG. 17). In other words, the base substrate 41 is covered with the first connection portion 13 (in the first block 11-2 in FIG. 17) of the first conductive layer 1, in the region enclosed in the photoelectric conversion layer perforated portion 331 in z-direction view. Such a configuration can be obtained by employing green laser beam as the laser beam Lz2 in the laser patterning process to form the photoelectric conversion layer perforated portion 331 in the organic film 30, and appropriately adjusting the output and irradiation time. In addition, the projection 332 is not formed in the photoelectric conversion layer 3, in this variation.

The configuration according to the mentioned variation also suppresses a decrease in area of the photoelectric conversion layer generation section 32, which actually contributes to the power generation.

The organic thin film solar cell module and the electronic device according to the present invention are in no way limited to the foregoing embodiments. The specific configurations of the elements of the organic thin film solar cell module and the electronic device according to the present invention may be modified in various manners.

### Second to Fourth Embodiments

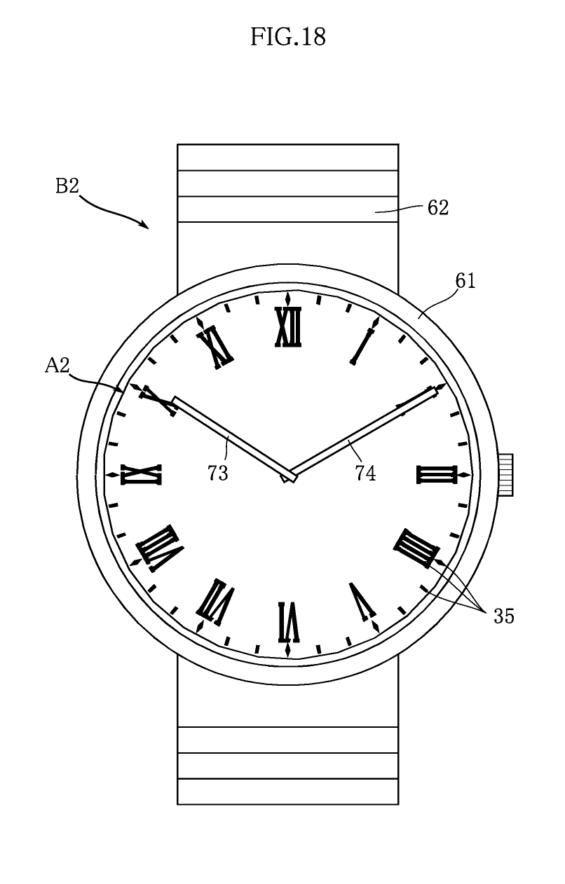

The reference numerals used for second to fourth embodiments and FIG. 18 to FIG. 43 are given for these particular embodiments and drawings, and independent of numerals used for other embodiments and drawings. It should be noted, however, the arrangements of the second to fourth embodiments and any other embodiment may be combined and exchanged in an appropriate manner.

The term “transparent” used herein may be defined as having a transmittance of approximately 50% or higher. The term “transparent” may also be used for visible light when it is colorless and clear. The visible light corresponds to a wavelength range of approximately 360 nm to 830 nm and an energy range of approximately 3.45 eV to 1.49 eV. When a transmittance of a substance is 50% or higher in these ranges, that substance may be regarded as transparent.

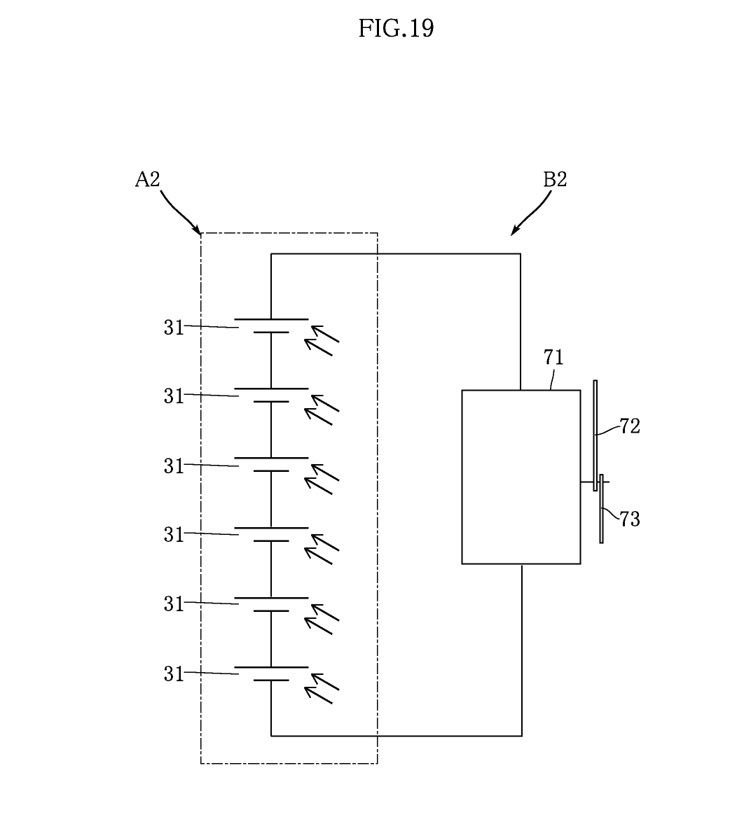

FIG. 18 and FIG. 19 illustrate an electronic device according to the second embodiment of the present invention. The electronic device B2 according to this embodiment includes an organic thin film solar cell module A2, a case 61, a strap 62, a drive unit 71, a minute hand 72, and an hour hand 73.

FIG. 18 is a plan view showing the electronic device B2. FIG. 19 is a system diagram of the electronic device B2.

The organic thin film solar cell module A2 serves as a power source module for the electronic device B2, and converts light, such as sunlight, into electric power.

The drive unit 71 operates by the power from the organic thin film solar cell module A2. The minute hand 72 and the hour hand 73 are driven by the drive unit 71. The drive unit 71 has a timer function. The drive unit 71 also drives the minute hand 72 and the hour hand 73 to an angle (position) according to the time of day. Further, the drive unit 71 may include a circuit for adjusting the level of voltage or current of the power acquired from the organic thin film solar cell module A2, so as to enable an IC having the timer function to utilize the power, or a secondary battery for storing the power acquired from the organic thin film solar cell module A2. In the photoelectric conversion layer 3, a plurality of design display sections 35 to be described below are displayed in the outer appearance. The design display sections 35 correspond to the design for identifying the time of day.

The organic thin film solar cell module A2, the drive unit 71, the minute hand 72 and the hour hand 73 are accommodated in the case 61 made of a metal or a resin. The strap 62 serves to fix the case 61 on the wrist of a user. Thus, the organic thin film solar cell module A2 is configured for a clock (wrist watch).

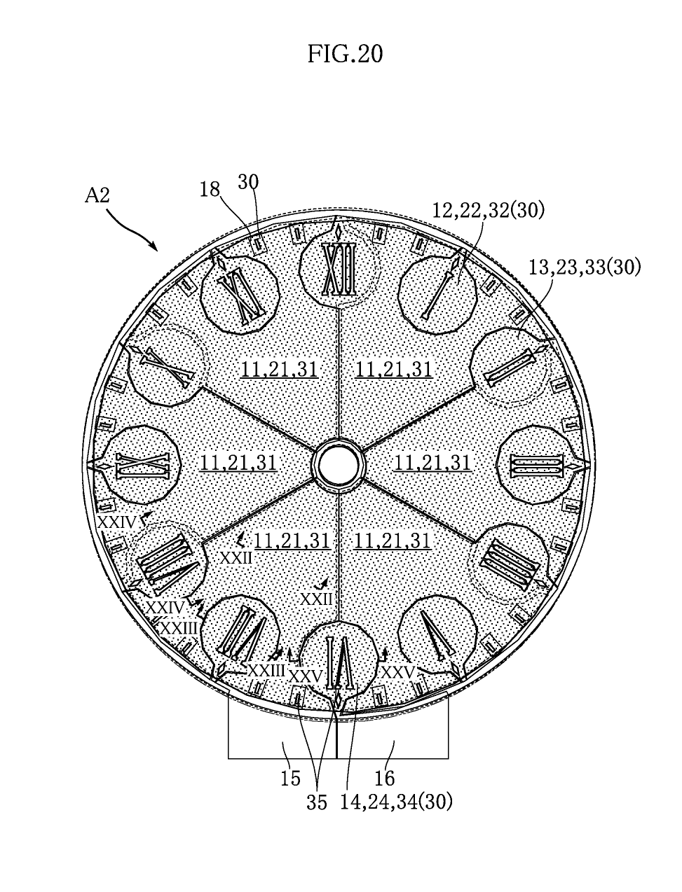

FIG. 20 to FIG. 25 illustrate the organic thin film solar cell module A2. The organic thin film solar cell module A2 includes the first conductive layer 1, the second conductive layer 2, the photoelectric conversion layer 3, the base substrate 41, a passivation film 42, a bonding layer 43, and a cover layer 44. Although the organic thin film solar cell module A2 has a circular shape in plan view in this embodiment, this is merely an example of the shape of the organic thin film solar cell module A2, and various other shapes may be adopted.

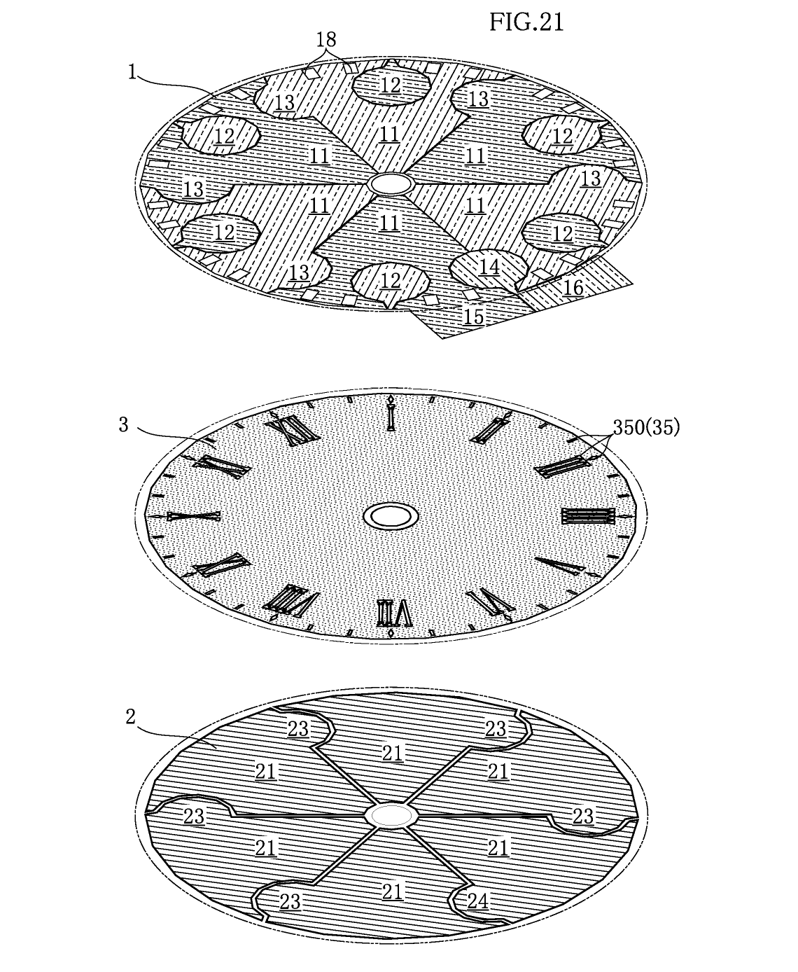

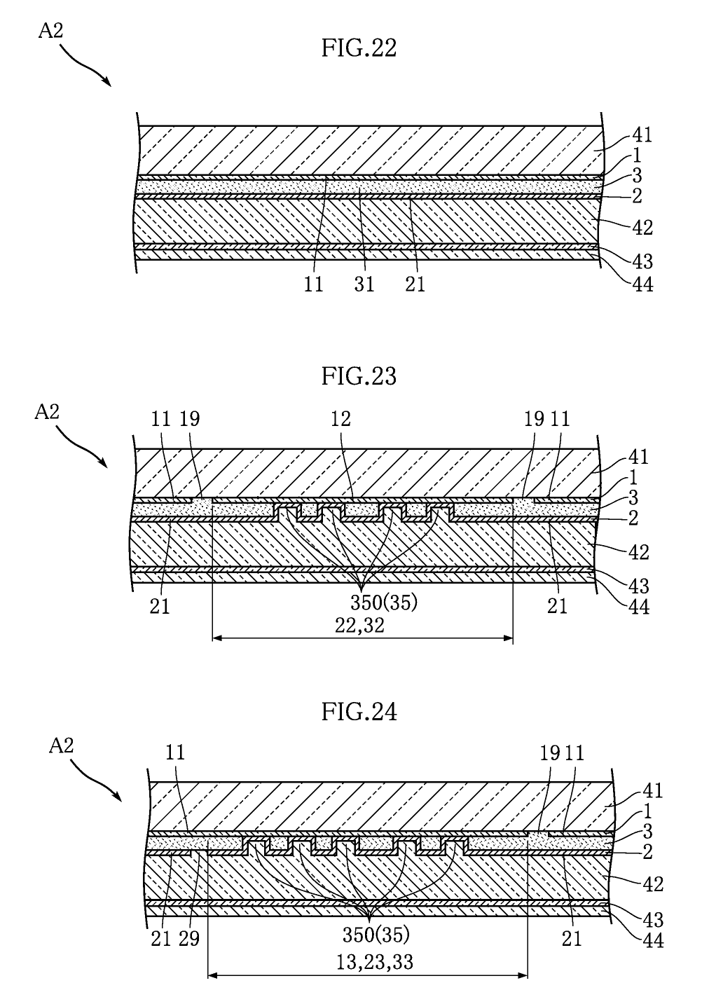

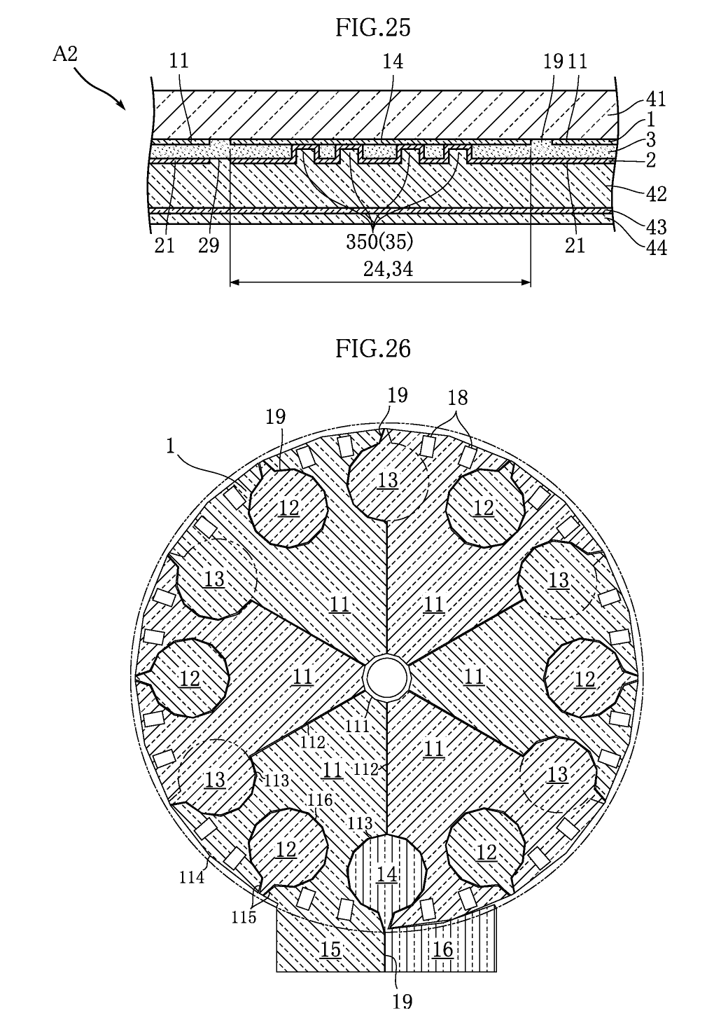

FIG. 20 is a plan view showing the organic thin film solar cell module A2. FIG. 21 is an exploded perspective view showing the organic thin film solar cell module A2. FIG. 22 is an enlarged partial cross-sectional view taken along a line XXII-XXII in FIG. 20. FIG. 23 is an enlarged partial cross-sectional view taken along a line XXIII-XXIII in FIG. 20. FIG. 24 is an enlarged partial cross-sectional view taken along a line XXIV-XXIV in FIG. 20. FIG. 25 is an enlarged partial cross-sectional view taken along a line XXV-XXV in FIG. 20. For the sake of clarity, in FIG. 20 the first conductive layer 1 is indicated by a solid line as a transmissive part, and the second conductive layer 2 is indicated by a hidden line (dot line). In addition, a non-perforated region in the photoelectric conversion layer 3 is shaded with scattered dots. In FIG. 22 to FIG. 25, it will be assumed that the sunlight is incident from above.

The base substrate 41 serves as the base of the organic thin film solar cell module A2. The base substrate 41 is formed of, for example, transparent glass or a resin. The base substrate 41 has a thickness of, for example, 0.05 mm to 2.0 mm.

The first conductive layer 1 is formed on the base substrate 41. The first conductive layer 1 is transparent, and formed of ITO in this embodiment. The first conductive layer 1 includes a plurality of first blocks 11, and a third block 15. FIG. 26 is a plan view showing the first conductive layer 1. As shown therein, the first conductive layer 1 includes a plurality of first electrode sections 11, a plurality of first blocks 12, a plurality of first communication portions 13, a first end portion 14, a first extended portion 15, a second extended portion 16, a plurality of openings 18 and a plurality of slits 19. In this embodiment, the first conductive layer 1 has a generally circular shape in plan view, except for the first extended portion 15 and the second extended portion 16, which is, however, merely an example of the shape of the first conductive layer 1. The first conductive layer 1 may be formed in various shapes. The first conductive layer 1 has a thickness of, for example, 100 nm to 300 nm. In FIG. 26, the first electrode section 11, the first block 12, the first communication portion 13, the first end portion 14, the first extended portion 15 and the second extended portion 16 of the first conductive layer 1 are hatched with oblique lines.

The first electrode sections 11 adjacent to each other, the first electrode section 11 and the first block 12 adjacent to each other, the first electrode section 11 and the first communication portion 13 adjacent to each other, and the first electrode section 11 and the first end portion 14 adjacent to each other, all in plan view, are formed with a spacing therebetween, and the slits 19 each correspond to the gap between the regions spaced apart from each other.

The first electrode sections 11 are layers in which holes created by the photoelectric conversion layer 3 are collected, and each act as what is known as an anode electrode. In this embodiment, six first electrode sections 11 are concentrically arranged. The first electrode section 11 according to this embodiment includes an arcuate edge 111 located close to the center of the first conductive layer 1. The respective arcuate edges 111 of the six first electrode sections 11 define an opening of a circular shape in plan view, at the center of the first conductive layer 1. The first electrode section 11 also includes a pair of linear edges 112 extending radially outward from the respective ends of the arcuate edge 111, and a pair of arcuate edges 113, respectively connected to the linear edges 112, and inwardly recessed. In FIG. 26, a portion of the first communication portion 13 to be defined by the shape of the second conductive layer 2, which will be described below, is indicated by imaginary lines (dash-dot-dot lines) to facilitate understanding, and one of the pair of arcuate edges 113 corresponds to such a portion. The portion defined by the shape of the second conductive layer 2 is a boundary for defining the first electrode section 11, and such a boundary will be referred to as the arcuate edge 113 in this embodiment, though this is not an edge physically formed in the first conductive layer 1. The first electrode section 11 also includes an arcuate edge 114 located at a radially outer position from the pair of arcuate edges 113. The respective arcuate edges 114 of the six first electrode section 11 constitute the outline of the portion of the first conductive layer 1 that is generally circular in plan view. Further, the first electrode section 11 includes an inwardly recessed edge at a generally central position of the arcuate edge 114. The inwardly recessed edge includes a pair of linear portions 115 each inclined with respect to the radial direction, and a circular portion 116 of a generally circular shape, connected to the linear portions 115, and surrounds the first block 12. Some positions of the first electrode section 11 are opened, and each of such open portions will be referred to as opening 18. The first electrode sections 11 adjacent to each other are aligned with the slit 19 therebetween. Here, although the first electrode section 11 includes the inwardly recessed edge at the generally central position of the arcuate edge, located at the radially outermost position thereof in this embodiment, the arcuate edge of the first electrode section 11, located at the radially outermost position, may continuously extend without the recessed edge formed halfway.

The first blocks 12 are each surrounded by the first electrode section 11, via the slit 19. Since the first electrode section 11 and the first block 12 are spaced apart from each other in plan view with the slit 19 therebetween, the first electrode section 11 and the first block 12 are insulated from each other. The first block 12 is in contact with a part of the second conductive layer 2, via a design display section 35 (perforated portion 350) to be described below. Accordingly, the first block 12 does not serve as an electrode for power generation in the photoelectric conversion layer 3. In contrast, since the first electrode section 11 is insulated from the first block 12, the function as electrode for power generation is secured. In addition, the first block 12 encloses therein the design display section 35 of the photoelectric conversion layer 3, to be described below, in plan view. In this embodiment, the first blocks 12 are respectively surrounded by the first electrode sections 11, and located closer to the outer circumference, than to the center, in the radial direction of the generally circular portion of the first conductive layer 1 in plan view. The first block 12 includes, for example, the generally circular portion in plan view, and a wedge-shaped portion radially outwardly protruding from the generally circular portion.

The first communication portions 13 each extend from one of the two first electrode sections 11 adjacent to each other, and located adjacent to the other of the two first electrode sections 11, with the slit 19 therebetween. In this embodiment, the first communication portion 13 includes a circular portion in plan view, composed of a semicircular protruding portion defined by the slit 19 and a semicircular portion extending from the protruding portion and extending inwardly of the first electrode section 11 (indicated by imaginary lines in FIG. 26), and a wedge-shaped portion radially outwardly protruding from the circular portion. The semicircular portion of the first communication portion 13 extending inwardly of the first electrode section 11 is defined by the shape of the second conductive layer 2 to be described below. In addition, the first communication portion 13 encloses therein the design display section 35 of the photoelectric conversion layer 3 to be described below, in plan view. In this embodiment, the first communication portions 13 are, like the first blocks 12, located closer to the outer circumference, than to the center, in the radial direction of the generally circular portion of the first conductive layer 1 in plan view.

The first extended portion 15 extends from one of the first electrode sections 11. In FIG. 26, the first extended portion 15 extends from the right portion of the arcuate edge 114 of the first electrode section 11 at the lower left position in the drawing, radially outwardly of the first conductive layer 1. Although the first extended portion 15 of this embodiment has a generally rectangular shape in plan view, the first extended portion 15 may be formed in various shapes.

The first end portion 14 is located between the first electrode section 11 continuously extending from the first extended portion 15, and the first electrode section 11 adjacent to the mentioned first electrode section 11 via the slit 19. In this embodiment, the first end portion 14 is located between the first electrode section 11 continuously extending from the first extended portion 15, and the first electrode section 11 on the right of the mentioned first electrode section 11, in FIG. 26. The first end portion 14 includes, for example, a portion of a circular shape in plan view, and a wedge-shaped portion radially outwardly protruding from the circular portion. In this embodiment, the first end portion 14 is, like the first block 12 and the first communication portion 13, located closer to the outer circumference, than to the center, in the radial direction of the generally circular portion of the first conductive layer 1 in plan view.

The second extended portion 16 extends from the first end portion 14, and extends radially outwardly of the first conductive layer 1, from the first end portion 14 and the first electrode section 11 adjacent to the first end portion 14. Although the second extended portion 16 of this embodiment has a generally rectangular shape in plan view, the second extended portion 16 may be formed in various shapes. In this embodiment, the second extended portion 16 is located under the first electrode section 11 at the lower right in FIG. 26. In addition, the first extended portion 15 and the second extended portion 16 are located adjacent to each other in the left-right direction in FIG. 26. The left portion of the first end portion 14 in FIG. 26 overlaps with a part of the first extended portion 15 in the left-right direction, and the right portion of the first end portion 14 overlaps with a part of the second extended portion 16, in the left-right direction in FIG. 26.

The openings 18 each penetrate through the first conductive layer 1 in the thickness direction. In this embodiment, the opening 18 has a rectangular shape relatively smaller in plan-view area than, for example, the first block 12, the first communication portion 13, and the first end portion 14, however this is merely an example of the size and shape of the opening 18. The opening 18 may be formed in different sizes and shapes, for example in a larger plan-view size than the first block 12, or in a circular shape. The openings 18 are located closer to the outer circumference, than to the center of the first block 12, the first communication portion 13, and the first end portion 14, in plan view.

A major part of the second conductive layer 2 is disposed on the first conductive layer 1 via the photoelectric conversion layer 3. A part of the second conductive layer 2 is in direct contact with the first conductive layer 1. The material of the second conductive layer 2 is not specifically limited, and may be transparent or non-transparent. In this embodiment, the second conductive layer 2 is formed of a metal, typically A1, W, Mo, Mn, or Mg. In the following example, the second conductive layer 2 is formed of A1. Accordingly, the second conductive layer 2 is non-transparent. In this case, a non-illustrated passive film formed of Al₂O₃ may be formed on the surface of the second conductive layer 2 opposite to the base substrate 41. The second conductive layer 2 has a thickness of, for example, 30 nm to 150 nm.

FIG. 27 is a plan view showing the second conductive layer 2. As shown therein, the second conductive layer 2 includes a plurality of second electrode sections 21, a plurality of second blocks 22, a plurality of second communication portions 23, a second end portion 24, and a plurality of slits 29. Although the second conductive layer 2 has a generally circular shape in plan view in this embodiment, this is merely an example of the shape of the second conductive layer 2. The second conductive layer 2 may be formed in various shapes. In FIG. 27, the second electrode section 21, the second block 22, the second communication portion 23, and the second end portion 24 of the second conductive layer 2 are hatched with oblique lines.

The second electrode sections 21 adjacent to each other, and the second electrode section 21 and the second communication portion 23 adjacent to each other are formed with a spacing therebetween in plan view, and the slits 29 each correspond to the gap between the regions spaced apart from each other.

The second electrode sections 21 are layers in which electrons created by the photoelectric conversion layer 3 are collected, and each act as what is known as a cathode electrode. The second electrode section 21 coincides with the first electrode section 11 in plan view. Accordingly, the second electrode section 21 of this embodiment includes an arcuate edge 211 located close to the center of the second conductive layer 2. The respective arcuate edges 211 of the six second electrode sections 21 define an opening of a circular shape in plan view, at the center of the second conductive layer 2. The second electrode section 21 also includes a pair of linear edges 212 extending radially outward from the respective ends of the arcuate edge 211, and a pair of arcuate edges 213, respectively connected to the linear edges 212, and inwardly recessed. In FIG. 27, a portion of the second communication portion 23 to be defined by the shape of the second conductive layer 2, which will be described below, is indicated by imaginary lines (dash-dot-dot lines) to facilitate understanding, and one of the pair of arcuate edges 213 corresponds to such a portion. The portion defined by the shape of the second conductive layer 2 is a boundary for defining the second electrode section 21, and such a boundary will be referred to as the arcuate edge 213 in this embodiment, though this is not an edge physically formed in the second conductive layer 2. The second electrode section 21 also includes an arcuate edge 214 located at a radially outer position from the pair of arcuate edges 213. The respective arcuate edges 214 of the six second electrode section 21 constitute the outline of the portion of the second conductive layer 2 that is generally circular in plan view. In the second electrode section 21, an edge inwardly recessed from a generally central position of the arcuate edge 214 can be defined. The inwardly recessed edge corresponds to the boundary defined by the shape of the first block 12 of the first conductive layer 1, and such a boundary will be referred to as the edge in this embodiment, though this is not an edge physically formed in the second conductive layer 2. The edge includes a pair of linear portions 215 each inclined with respect to the radial direction, and a circular portion 216 of a generally circular shape connected to the linear portions 215, so as to surround the second block 22. In this embodiment, six second electrode sections 21 are concentrically arranged. The second electrode sections 21 adjacent to each other are aligned with the slit 29 therebetween.

As shown in FIG. 20, the second blocks 22 respectively overlap with the first blocks 12 of the first conductive layer 1, in plan view. The second block 22 encloses therein the design display section 35 of the photoelectric conversion layer 3 to be described below, in plan view. The second block 22 is electrically connected to the first block 12 via the design display section 35, and does not act as the electrode for power generation in the photoelectric conversion layer 3, like the first block 12. In this embodiment, the second blocks 22 are respectively surrounded by the second electrode sections 21, and are located closer to the outer circumference, than to the center, in the radial direction of the generally circular portion of the second conductive layer 2 in plan view. The second block 22 includes, for example, a generally circular portion in plan view, and a wedge-shaped portion radially outwardly protruding from the generally circular portion.

The second communication portions 23 extends from one of the two second electrode sections 21 adjacent to each other, and located adjacent to the other of the two second electrode sections 21, with the slit 29 therebetween. In this embodiment, the second communication portion 23 includes a circular portion in plan view, composed of a semicircular protruding portion defined by the slit 29 and a semicircular portion extending from the protruding portion and extending inwardly of the second electrode section 21 (indicated by imaginary lines in FIG. 27), and a wedge-shaped portion radially outwardly protruding from the circular portion. The semicircular portion of the second communication portion 23 extending inwardly of the second electrode section 21 is defined by the first communication portion 13 of the first conductive layer 1 shown in FIG. 26. The semicircular portion of the first communication portion 13 extending inwardly of the first electrode section 11 is defined by the second communication portion 23. Thus, as seen from FIG. 20, the first communication portion 13 and the second communication portion 23 have a generally circular shape in plan view. In addition, the second communication portion 23 encloses therein the design display section 35 of the photoelectric conversion layer 3 to be described below, in plan view. In this embodiment, the second communication portions 23 are, like the second blocks 22, located closer to the outer circumference, than to the center, of the second conductive layer 2 of the generally circular shape in plan view.

The second end portion 24 is formed at the position coinciding with the first end portion 14 of the first conductive layer 1 in plan view, and extends from the adjacent second electrode section 21. As shown in FIG. 20, the second end portion 24 includes, like the first end portion 14, a portion of a circular shape in plan view, and a wedge-shaped portion radially outwardly protruding from the circular portion. In this embodiment, the second end portion 24 is, like the second block 22 and the second communication portion 23, located closer to the outer circumference, than to the center, in the radial direction of the second conductive layer 2 of the generally circular shape in plan view.

The photoelectric conversion layer 3 is interposed between the first conductive layer 1 and the second conductive layer 2, and disposed on the base substrate 41. The photoelectric conversion layer 3 is formed of an organic thin film, and configured to perform a photoelectric conversion function, to convert received light into electric power. Although the configuration of the photoelectric conversion layer 3 is not specifically limited, the photoelectric conversion layer 3 may include, for example, a bulk heterojunction organic active layer and a hole transport layer disposed on the bulk heterojunction organic active layer on the side of the first conductive layer 1. In this embodiment, the photoelectric conversion layer 3 is formed in a circular shape in plan view, however this is merely an example and the photoelectric conversion layer 3 may be formed in various shapes. The photoelectric conversion layer 3 has a thickness of, for example, 50 nm to 300 nm.

In the bulk heterojunction organic active layer, p-type organic active layer regions and n-type organic active layer regions are intermixed, forming a complicated bulk hetero pn junction. The p-type organic active layer region is, for example, formed of poly(3-hexylthiophene-2,5diyl) (P3HT), and the n-type organic active layer region is formed of 6,6-phenyl-C61-butyric acid methyl ester (PCBM), for example. The hole transport layer is formed of, for example, PEDOT:PSS.

Examples of materials that may be utilized to form the photoelectric conversion layer 3 include phthalocyanine (Pc), zinc-phthalocyanine (ZnPc), N,N′-dimethyl perylene-3,4,9,10-dicarboximide (Me-Ptcdi), and Buckminster fullerene (C60). These materials are, for example, utilized for vacuum vapor deposition.

In addition, poly[2-methoxy-5-(3,7-dimethyl octyloxy)]-1,4-phenylene vinylene (MDMO-PPV), poly[N-9′-hepta-decanyl-2,7-carbazole-alt-5,5-(4′,7′-di-thienyl-2′1′,3′-b3nzothiadizaole)] (PCDTBT), 6,6-phenyl-C61-butyric acid methyl ester (PC60BM), or 6,6-phenyl-C71-butyric acid methyl ester (PC70BM) may be utilized to form the photoelectric conversion layer 3. These materials are, for example, utilized for a solution process.

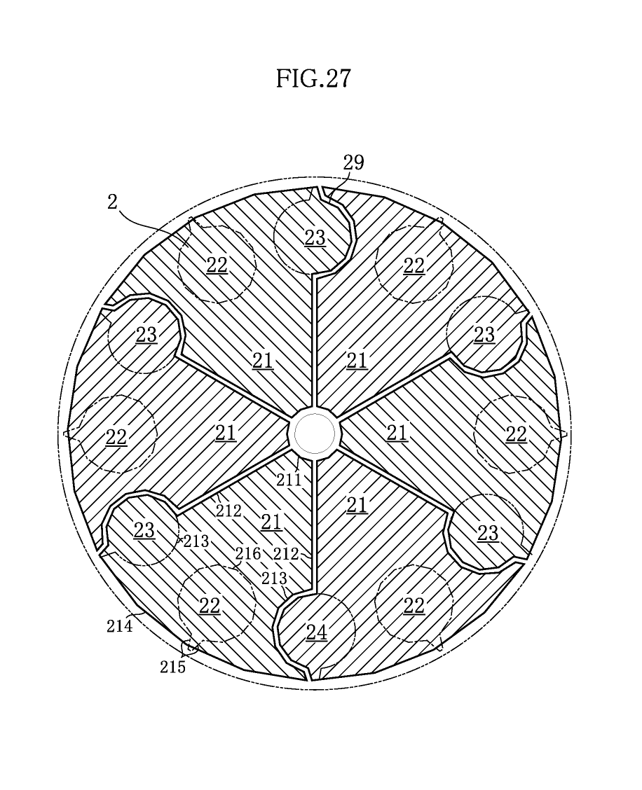

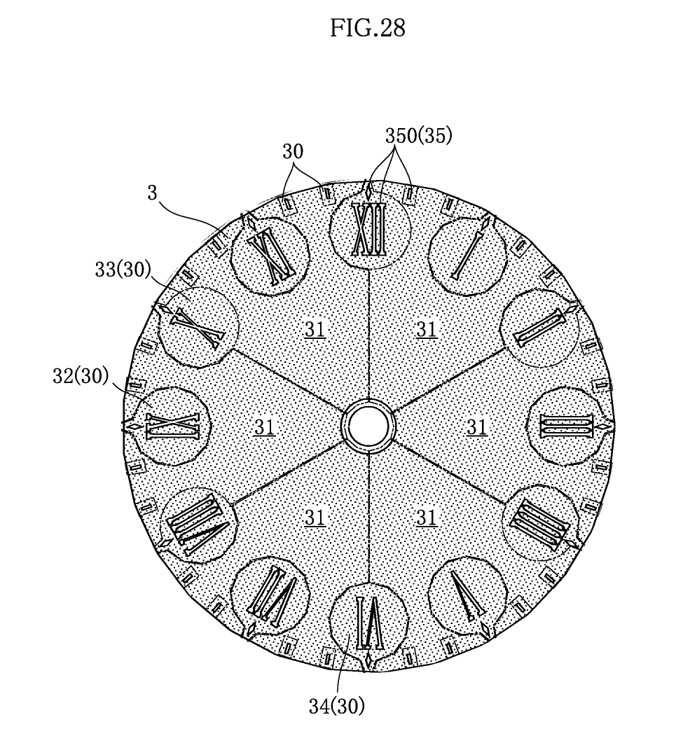

FIG. 28 is a plan view showing the photoelectric conversion layer 3. As shown in FIG. 20 and FIG. 28, the photoelectric conversion layer 3 includes a plurality of non-generation regions 30, a plurality of generation regions 31, and a plurality of design display sections 35. In FIG. 28, the boundary between the non-generation region 30 and the generation region 31 is indicated by an imaginary line (dash-dot-dot line) for convenience. In addition, non-perforated portions of the photoelectric conversion layer 3 are shaded with scattered dots.

The design display section 35 constitutes a design exhibited in the outer appearance through the first conductive layer 1. The design constituted by the design display section include those that the user can visually recognize as visually singular feature, such as characters, marks, and patterns.

In this embodiment, the design display section 35 is composed of a plurality of perforated portions 350. The perforated portions 350 are each formed so as to penetrate through the photoelectric conversion layer 3 in the thickness direction. Such perforated portions 350 are visible in the outer appearance through the first conductive layer 1. In this embodiment, the perforated portion 350 exposes the second conductive layer 2 on the side of the first conductive layer 1. In other words, a part of the second conductive layer 2 is visible in the outer appearance, through the perforated portion 350.

In this embodiment, totally twelve perforated portions 350 (design display sections 35) each represent a Roman numeral indicating the time of day. In addition, totally twelve perforated portions 350 (design display sections 35) of a diamond shape are located on the radially outer position of the respective perforated portions 350 representing the Roman numeral. Further, totally twenty-four perforated portions 350 (design display sections 35) of a rectangular shape of a relatively small size, for identifying the time, are aligned along the outer circumference of the photoelectric conversion layer 3, having a generally circular shape in plan view.

As shown in FIG. 20 and FIG. 22, the generation region 31 is interposed between the first electrode section 11 of the first conductive layer 1 and the second electrode section 21 of the second conductive layer 2, and performs the photoelectric conversion function to contribute to the power generation. The shape of the generation region 31 coincides with the first electrode section 11 and the second electrode section 21, in plan view. In this embodiment, six generation regions 31 are concentrically arranged.

The non-generation region 30 corresponds to a portion of the photoelectric conversion layer 3 deviated, in plan view, from the first electrode section 11 of the first conductive layer 1 and the second electrode section 21 of the second conductive layer 2, and overlapping with the first block 12, the first communication portion 13, the first end portion 14, the openings 18, and the slits 19. The first block 12, the first communication portion 13, and the first end portion 14 are each in contact with a part of the second conductive layer 2, and hence the collected holes and electrons are instantly coupled. In addition, in the region of the photoelectric conversion layer 3 overlapping with the openings 18 and the slits 19, the holes acquired through the photoelectric conversion are not collected into the first conductive layer 1. Therefore, the non-generation region 30 is not involved in the power generation. Thus, the regions of the photoelectric conversion layer 3 other than the generation regions 31 are the non-generation region 30.

Further, as shown in FIG. 20, the non-generation regions each include a plurality of partitioned sections 32, a plurality of communication regions 33, and a terminal region 34.

As shown in FIG. 20 and FIG. 23, the partitioned section 32 overlaps with the first block 12 of the first conductive layer 1 and the second block 22 of the second conductive layer 2. The partitioned section 32 includes perforated portions 350 (design display sections 35). In this embodiment, the perforated portions 350 (design display sections 35) in the partitioned section 32 represent the Roman numeral. The first block 12 of the first conductive layer 1 and the second block 22 of the second conductive layer 2 are in contact with each other, via the perforated portion 350 in the partitioned section 32.

As shown in FIG. 20 and FIG. 24, the communication regions 33 are each interposed between the first communication portion 13 of the first conductive layer 1 and the second communication portion 23 of the second conductive layer 2. The communication region 33 includes the perforated portions 350 (design display sections 35). In this embodiment, the perforated portions 350 (design display sections 35) in the communication region 33 represent the Roman numeral. The first communication portion 13 of the first conductive layer 1 and the second communication portion 23 of the second conductive layer 2 are in contact with each other, via the perforated portion 350 in the communication region 33.

As shown in FIG. 20 and FIG. 25, the terminal region 34 includes the perforated portions 350 (design display sections 35) enclosed in the first end portion 14 of the first conductive layer 1, and overlaps with the first end portion 14 of the first conductive layer 1, in plan view. The terminal region 34 also overlaps with the second end portion 24 of the second conductive layer 2. The first end portion 14 of the first conductive layer 1 and the second end portion 24 of the second conductive layer 2 are in contact with each other, via the perforated portions 350 in the terminal region 34. In this embodiment, the perforated portions 350 (design display sections 35) in the terminal region 34 represent the Roman numeral.

Further, as shown in FIG. 20, a region of the photoelectric conversion layer 3 enclosed in the opening 18 of the first conductive layer 1 is the non-generation region 30.

The first extended portion 15 and the second extended portion 16 of the first conductive layer 1 radially outwardly extend from the photoelectric conversion layer 3, in plan view.

As described thus far, in the organic thin film solar cell module A2 the six generation regions 31 are connected in series. The connection route will be sequentially described. First, the first extended portion 15 is connected to one of the first electrode sections 11. The first electrode section 11 is opposed to the second electrode section 21, via the generation region 31. The second communication portion 23 extending from the second electrode section 21 is in contact with the first communication portion 13, via the perforated portions 350 in the communication region 33. To the first electrode section 11, extending from the first communication portion 13, the next second electrode section 21 is opposed via the generation region 31. In other words, the generation regions 31 adjacent to each other are connected in series, via the first communication portion 13, the second communication portion 23, and the communication region 33. More specifically, the route from the generation region 31 at the lower left in FIG. 20 to the generation region 31 at the lower right is connected in series. Then the second end portion 24 extends from the second electrode section 21 overlapping with the generation region 31 at the lower right in FIG. 20. The second end portion 24 is in contact with the first end portion 14 via the perforated portions 350 in the terminal region 34. Then the second extended portion 16 extends from the first end portion 14. As result, the first extended portion 15 and the second extended portion 16 each act as an output terminal of the organic thin film solar cell module A2. Referring to FIG. 19, the first extended portion 15 and the second extended portion 16 are connected to the drive unit 71.

As shown in FIG. 22 to FIG. 25, the passivation film 42 is disposed on the second conductive layer 2, so as to protect the second conductive layer 2 and the photoelectric conversion layer 3. The passivation film 42 is, for example, formed of SiN or SiON. The passivation film 42 has a thickness of, for example, 0.5 μm to 2.0 μm and, in this embodiment, approximately 1.5 μm. Thus, the passivation film 42 is thicker than the photoelectric conversion layer 3. Therefore, intrusion of moisture or particles from outside into the photoelectric conversion layer 3 can be prevented, and the strength of the organic thin film solar cell module A1 can be improved. In addition, as shown in FIG. 23 to FIG. 25, a portion of the passivation film 42 covering the design display sections 35 and covering a portion of the photoelectric conversion layer 3 adjacent to the design display section 35 are formed so as to have a flat surface. Therefore, damage to the passivation film 42 such as a crack can be prevented, and hence the second conductive layer 2, the photoelectric conversion layer 3, and the first conductive layer 1 can be securely prevented from collapsing. The passivation film 42 having the flat surface as above can be formed, for example, by making the passivation layer 42 thicker than the photoelectric conversion layer 3, and through a CVD process to be described below.

The bonding layer 43, which serves to bond the passivation film 42 and the cover layer 44 together, is, for example, a resin-based adhesive layer.

The cover layer 44 serves to protect the organic thin film solar cell module A2 on the opposite side to the base substrate 41. Preferably the cover layer 44 is formed of glass, however any transparent material capable of protecting the organic thin film solar cell module A2 may be adopted, as the case may be. The cover layer 44 may have a thickness of, for example, 30 μm to 100 μm and, in this embodiment, approximately 50 μm.

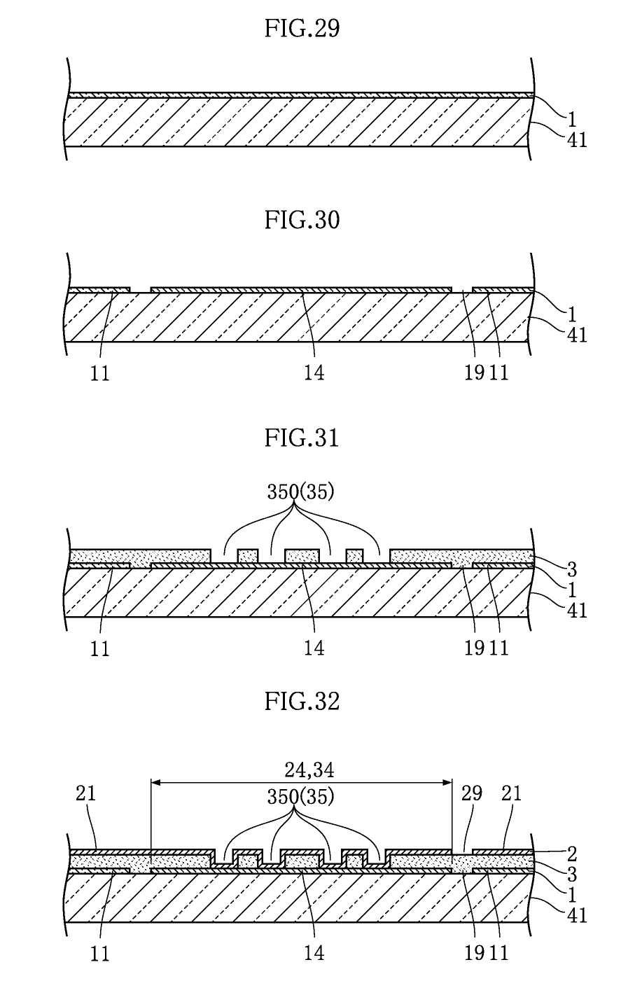

Referring now to FIG. 29 to FIG. 32, a manufacturing method of the organic thin film solar cell module A2 will be described hereunder. The cited drawings are turned upside down from FIG. 22 to FIG. 25, to facilitate understanding. In addition, FIG. 22 to FIG. 25 illustrate the formation process of the portion corresponding to the cross-section of the organic thin film solar cell module A2, taken along the line XXV-XXV in FIG. 20.

Referring first to FIG. 29, the base substrate 41 is prepared. On one of the surfaces of the base substrate 41, ITO is formed by a known method such as sputtering. Proceeding to FIG. 30, the ITO is patterned to form the first conductive layer 1. The steps shown in FIG. 29 and FIG. 30 may be performed either separately or at a time. For the patterning of the ITO, for example, wet etching, oxygen plasma etching, or laser patterning is adopted as the case may be. Without limitation to the above, the first conductive layer 1 may be formed by directly patterning the ITO on the base substrate 41, for example through a nanoimprint lithography process.

Proceeding to FIG. 31, the photoelectric conversion layer 3 is formed. To form the photoelectric conversion layer 3, an organic film is deposited on the base substrate 41 and the first conductive layer 1, for example by spin coating, and the organic film is patterned to form the perforated portions 350 (design display sections 35) of desired shapes, by oxygen plasma etching or laser patterning. Without limitation to the above, the photoelectric conversion layer 3 may be formed by directly patterning the organic film on the base substrate 41 and the first conductive layer 1, for example by slit coating, capillary coating, or gravure printing.

Proceeding to FIG. 32, the second conductive layer 2 is formed. To form the second conductive layer 2, for example, one of the aforementioned metals is deposited by vacuum vapor deposition on the base substrate 41, the first conductive layer 1, and the photoelectric conversion layer 3, to deposit a metal film thereon. Then the metal film is patterned, for example by etching with a mask layer. Through such patterning, the second conductive layer 2 is formed on the first conductive layer 1 and the photoelectric conversion layer 3. Thereafter, SiN or SiON is deposited on the base substrate 41, the first conductive layer 1, the photoelectric conversion layer 3, and the second conductive layer 2, for example by plasma CVD, to form the passivation film 42. Then the cover layer 44 is bonded to the passivation film 42, via the bonding layer 43. Through the mentioned process, the organic thin film solar cell module A2 can be obtained.

The organic thin film solar cell module A2 and the electronic device B2 provide the following advantageous effects.

In the organic thin film solar cell module A2 and the electronic device B2 according to this embodiment, the design display sections 35 are provided in the photoelectric conversion layer 3, so that the design is exhibited in the outer appearance through the first conductive layer 1. Therefore, the design according to the design display sections 35 can be exhibited in the outer appearance, without the need to form an additional component in the organic thin film solar cell module A2 or print a pattern on the outer surface.

In the organic thin film solar cell module A2 and the electronic device B2 according to this embodiment, the design display section 35 is constituted of the perforated portion 350. Therefore, the design can be more clearly exhibited. In particular, since the second conductive layer 2 is visible in the outer appearance through the perforated portion 350, the design can be more vividly expressed because of the contrast between the second conductive layer 2 and the photoelectric conversion layer 3.

Further, in the organic thin film solar cell module A2 and the electronic device B2 according to this embodiment, the first electrode section 11 and the first block 12 are spaced apart from each other via the slit 19 in the first conductive layer 1, and the design display section 35 is formed in the non-generation region 30 overlapping with the first block 12 in plan view. Therefore, an accidental short circuit between the first electrode section 11 and the second electrode section 21 can be prevented, despite the design display section 35 being constituted of the perforated portion 350 penetrating through the photoelectric conversion layer 3.

Forming the first communication portion 13, the second communication portion 23, and the communication region 33 enables the generation regions 31 adjacent to each other to be connected in series. Accordingly, the voltage outputted from the organic thin film solar cell module A2 can be increased to a desired value. In addition, the perforated portion 350 enclosed in the communication region 33 represents the Roman numeral for identifying the time. Thus, an efficient arrangement can be attained in which the communication region 33 and the perforated portion 350 included therein serve to both connect the generation regions 31 in series, and display the design that is indispensable as a watch.

Forming the first end portion 14, the second end portion 24, and the terminal region 34 enables one of the generation regions 31 at a terminal position to be located adjacent to the one at the opposite terminal. In addition, forming the first extended portion 15 and the second extended portion 16 enables the power from the generation region 31 to be led out without improperly decreasing the area of the generation region 31.

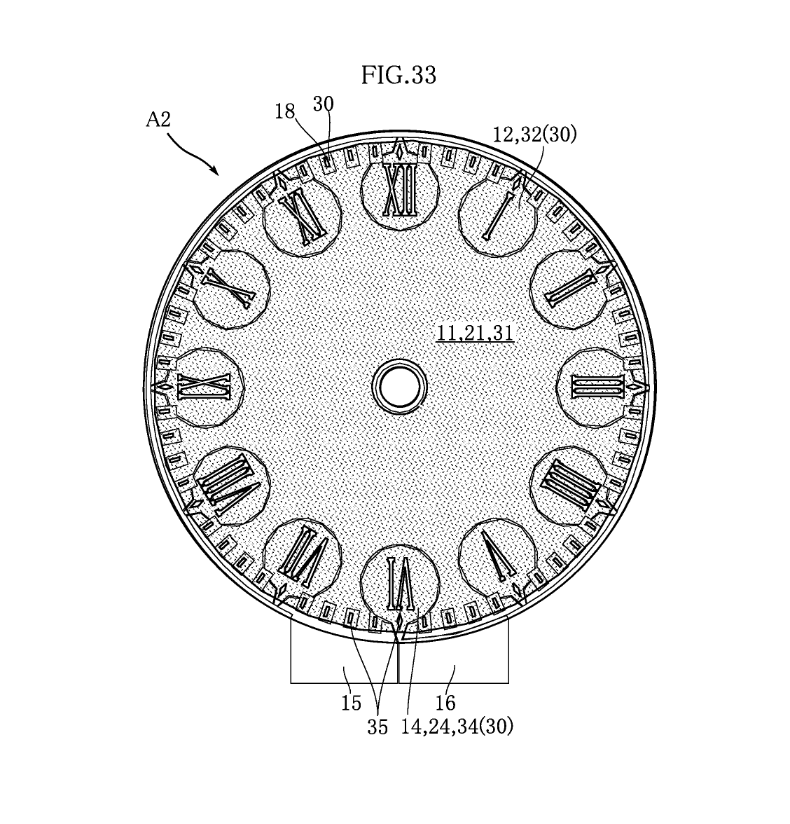

FIG. 33 to FIG. 42 illustrate a variation and other embodiments of the present invention. In the mentioned drawings, the elements same as or similar to those of the foregoing embodiments are given the same numeral.

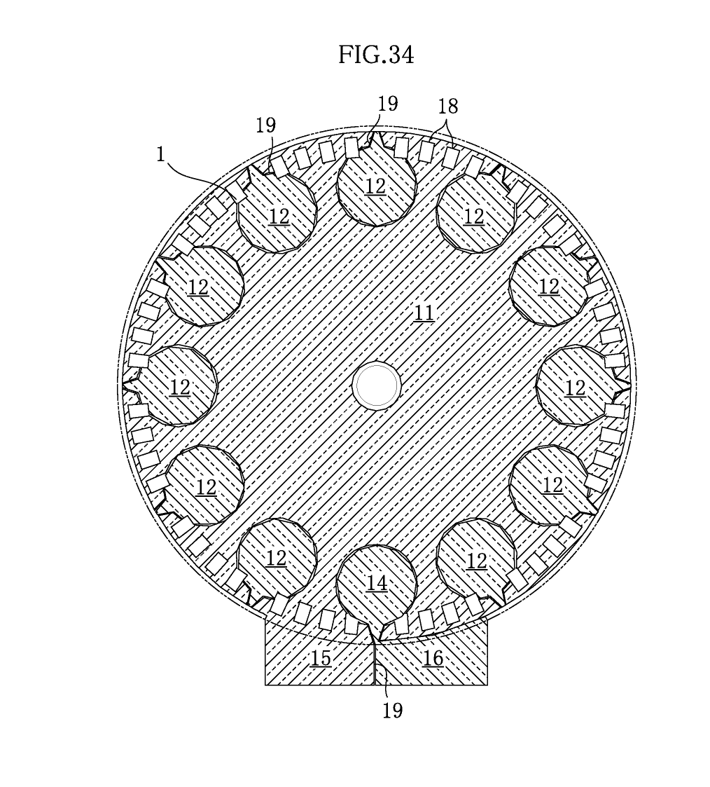

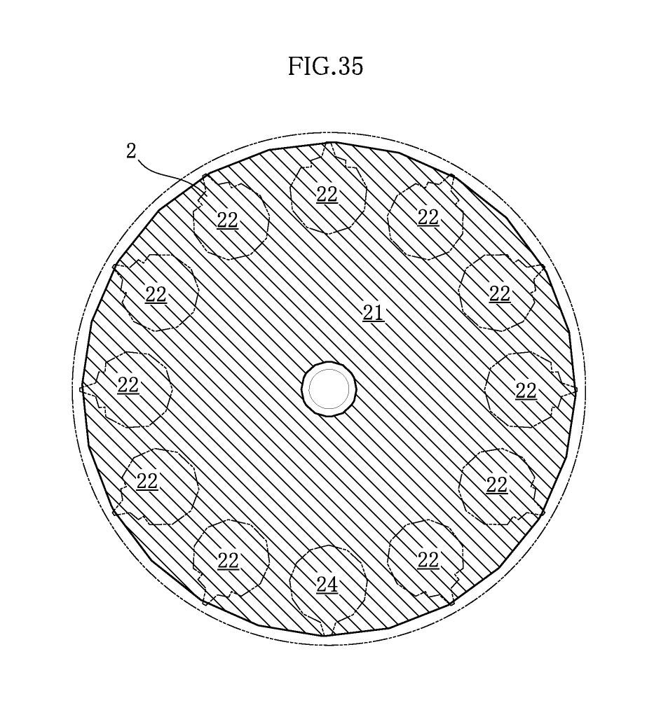

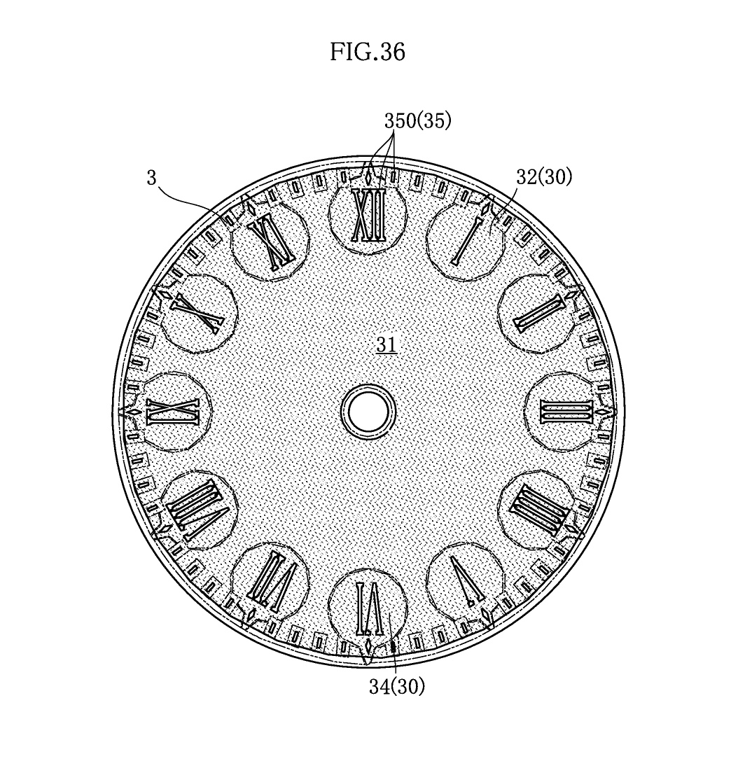

FIG. 33 to FIG. 35 illustrate a variation of the organic thin film solar cell module A2. In this variation, the photoelectric conversion layer 3 includes a single generation region 31. FIG. 33 is a plan view showing the variation of the organic thin film solar cell module A2. FIG. 34 is a plan view showing a first conductive layer 1 according to this variation. FIG. 35 is a plan view showing a second conductive layer 2 according to this variation. FIG. 36 is a plan view showing a photoelectric conversion layer 3 according to this variation.

The first conductive layer 1 includes one first electrode section 11, eleven first blocks 12, the first end portion 14, the first extended portion 15 and the second extended portion 16. The first conductive layer 1 is without the first communication portion 13 included in the foregoing embodiments.

The second conductive layer 2 includes, according to the configuration of the first conductive layer 1, one second electrode section 21, eleven second blocks 22, and the second end portion 24.

The photoelectric conversion layer 3 includes one generation region 31, eleven partitioned sections 32, and the terminal region 34.

In the organic thin film solar cell module A2 configured as above, the power generated in the one generation region 31 is outputted through the first extended portion 15 and the second extended portion 16.

The configuration according to the foregoing variation also enables the design according to the design display sections 35 to be exhibited in the outer appearance, without the need to form an additional component in the organic thin film solar cell module A2 or print a pattern on the outer surface.

A plurality of generation regions 31 may be connected in parallel, instead of providing one generation region 31. In this case, for example, the first electrode sections 11 may be electrically connected to each other, and the second electrode sections 21 may be electrically connected to each other.

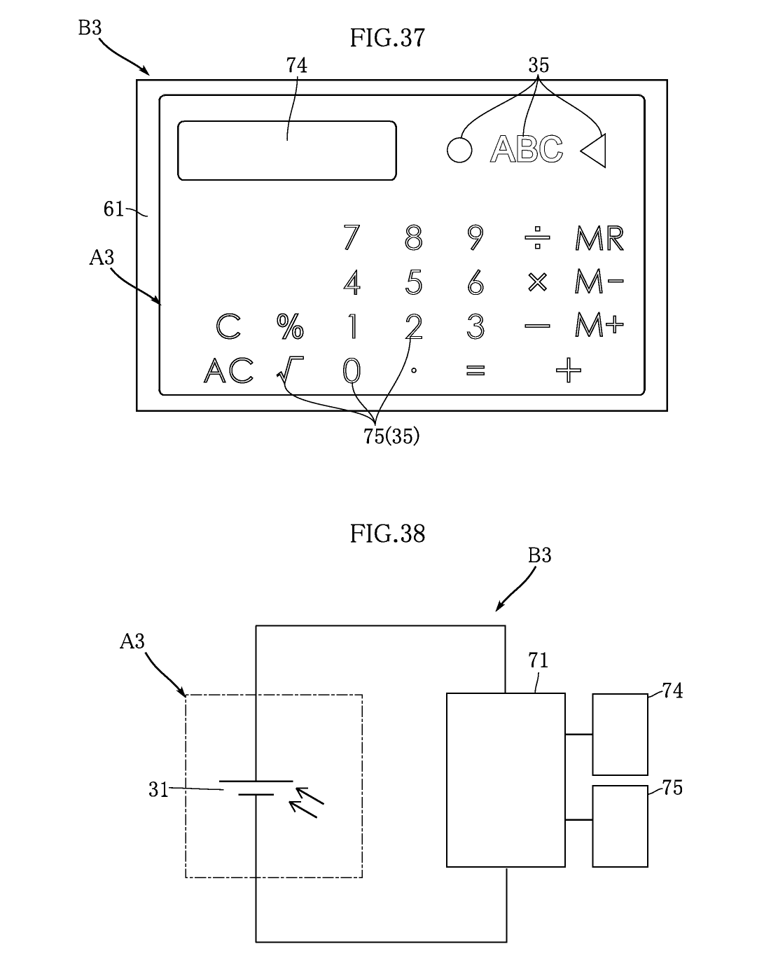

FIG. 37 and FIG. 38 illustrate an electronic device according to a third embodiment of the present invention. The electronic device B3 according to this embodiment is configured as an electronic calculator.

The electronic device B3 includes an organic thin film solar cell module A3, a case 61, the drive unit 71, a display unit 74 and an input unit 75.

The organic thin film solar cell module A3 serves as a power generator for the electronic device B3. The case 61 is a thin, rectangular-shaped component, in which the organic thin film solar cell module A3, the drive unit 71, the display unit 74, and the input unit 75 are accommodated.

The drive unit 71 performs a calculation function by receiving power from the organic thin film solar cell module A3. The drive unit 71 also applies the input signals from the input unit 75 to the calculation function. The drive unit 71 further causes the display unit 74 to display the information regarding the calculation function.

The display unit 74, on which the information regarding the calculation function is displayed, is constituted of an LCD, for example. The input unit 75 is used to make inputs for performing the calculation, and constituted of, for example, a touch sensor. In this embodiment, the design display sections 35 constitute the input unit 75, so that the input unit 75 can be visually distinguished.

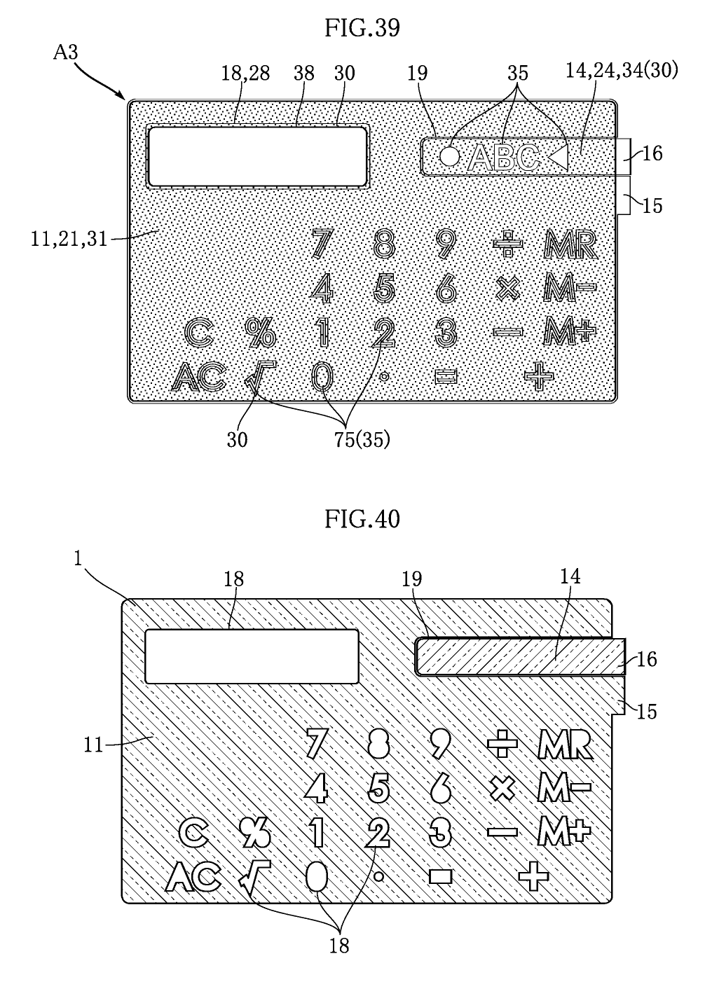

FIG. 39 illustrates the organic thin film solar cell module A3 according to this embodiment. The organic thin film solar cell module A3 is configured to output the power generated in the one generation region 31, through the first extended portion 15 and the second extended portion 16.

FIG. 40 is a plan view showing the first conductive layer 1 according to this embodiment. FIG. 41 is a plan view showing the second conductive layer 2 according to this embodiment. FIG. 42 is a plan view showing the photoelectric conversion layer 3 according to this embodiment.

The first conductive layer 1 includes a rectangular opening 18, the second conductive layer 2 includes a rectangular opening 28, and the photoelectric conversion layer 3 includes a rectangular opening 38. The opening 18, the opening 28, and the opening 38 are for exhibiting the display unit 74 in the outer appearance. The opening 18 and the opening 28 are slightly larger than the opening 38. Thus, a region of the photoelectric conversion layer 3 enclosed in the opening 18 and the opening 28 is the non-generation region 30.

As shown in FIG. 42, the photoelectric conversion layer 3 includes a plurality of perforated portions 350 (design display sections 35). The perforated portions 350 located in the lower position in FIG. 42 each represent numerals and arithmetic symbols, and are arranged so as to correspond to the associated portion of the input unit 75. As shown in FIG. 40, the first conductive layer 1 includes plurality of opening 18 located in the lower position in FIG. 40. These openings 18 are each formed so as to enclose the perforated portion 350 representing the corresponding numeral or arithmetic symbol. Thus, regions of the photoelectric conversion layer 3 enclosed in these openings 18 are the non-generation region 30.

In addition, as shown in FIG. 42, a plurality of perforated portions 350 (design display sections 35) are provided in the upper right position of FIG. 42. These perforated portions 350 each represent a character, a mark, or a pattern. Such perforated portions 350 are used to exhibit, for example, a company name or a product name.

As shown in FIG. 39 and FIG. 40, the first conductive layer 1 includes the first end portion 14, in the upper right position in the cited drawings. The perforated portions 350 of the photoelectric conversion layer 3 in the upper right position are enclosed in the first end portion 14, in plan view. Accordingly, a region of the photoelectric conversion layer 3 overlapping with the first end portion 14 corresponds to the terminal region 34. Likewise, a region of the second conductive layer 2 overlapping with the first end portion 14 corresponds to the second end portion 24.

The configuration according to the foregoing embodiment also enables the design according to the design display sections 35 to be exhibited in the outer appearance, without the need to form an additional component in the organic thin film solar cell module A3 or print a pattern on the outer surface.

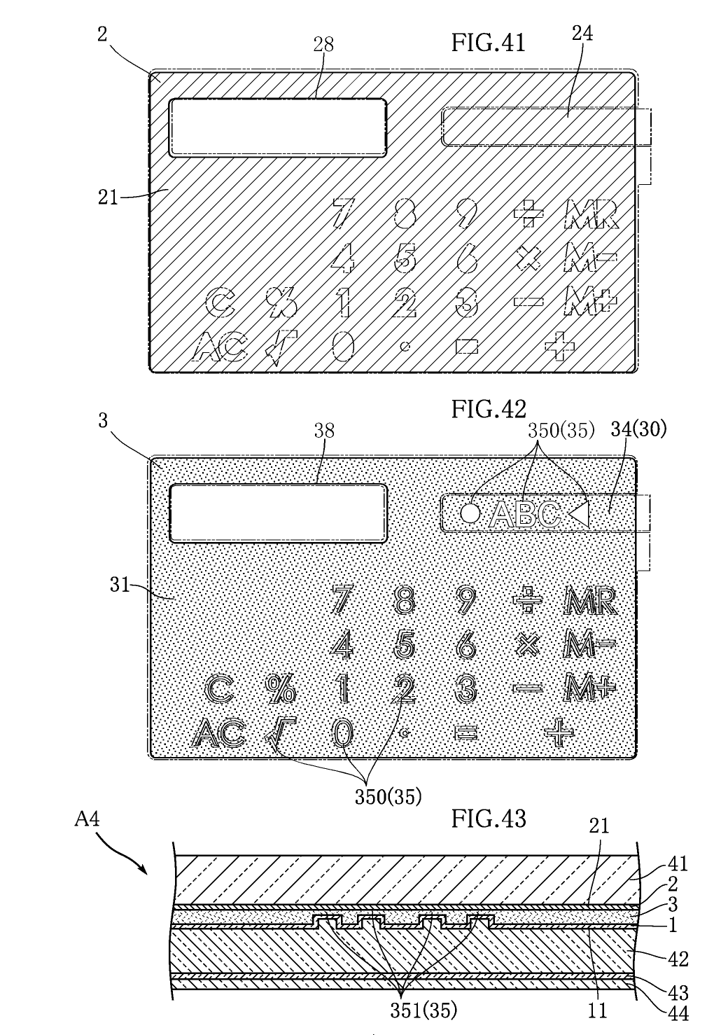

FIG. 43 illustrates an organic thin film solar cell module according to a fourth embodiment of the present invention. In the organic thin film solar cell module A4 according to this embodiment, the design display sections 35 of the photoelectric conversion layer 3 each include a thin-wall portion 351.

The thin-wall portion 351 has a thinner wall thickness than the surrounding portions. Stepped portions formed because of the presence of the thin-wall portion 351 create a visually recognizable shape, to thereby constitute the design to be exhibited by the design display section 35.

The surface of the photoelectric conversion layer 3 on the side of the base substrate 41 is flat, and the stepped portion formed by the thin-wall portion 351 is located on the side opposite to the base substrate 41. In this embodiment, therefore, the second conductive layer 2 is formed on the base substrate 41, and the first conductive layer 1 is disposed thereon via the photoelectric conversion layer 3. In this embodiment, the sunlight is incident from below in the drawings.

The configuration according to the foregoing embodiment also enables the design according to the design display sections 35 to be exhibited in the outer appearance, without the need to form an additional component in the organic thin film solar cell module A4 or print a pattern on the outer surface.

The organic thin film solar cell module and the electronic device according to the present invention are in no way limited to the foregoing embodiments. The specific configurations of the elements of the organic thin film solar cell module and the electronic device according to the present invention may be modified in various manners.

The technical features of the present invention may be expressed as the following appendices.

### Appendix 1A

An organic thin film solar cell module including:

a transparent first conductive layer;

a second conductive layer; and

a photoelectric conversion layer formed of an organic thin film and interposed between the first conductive layer and the second conductive layer,

in which the photoelectric conversion layer includes one or more design display sections constituting a design displayed on the outer appearance through the first conductive layer.

### Appendix 2A

The organic thin film solar cell module according to appendix 1A, further including a transparent base substrate on which the first conductive layer is disposed.

### Appendix 3A

The organic thin film solar cell module according to appendix 1A or 2A, further including a passivation layer covering the second conductive layer.

### Appendix 4A

The organic thin film solar cell module according to appendix 3A, in which the passivation film covers the design display section.

### Appendix 5A

The organic thin film solar cell module according to appendix 4A, in which a portion of the passivation film covering the design display section, and a portion of the passivation film covering a portion of the photoelectric conversion layer adjacent to the design display section, are formed in a flat shape.

### Appendix 6A

The organic thin film solar cell module according to any one of appendices 3A to 5A, in which the passivation film is thicker than the photoelectric conversion layer.

### Appendix 7A

The organic thin film solar cell module according to any one of appendices 3A to 6A, further including a cover layer disposed on the passivation film.

### Appendix 8A

The organic thin film solar cell module according to appendix 7A, further including a bonding layer bonding the passivation film and the cover layer together.

### Appendix 9A

The organic thin film solar cell module according to any one of appendices 1A to 8A, in which the first conductive layer is formed of ITO.

### Appendix 10A

The organic thin film solar cell module according to any one of appendices 1A to 9A, in which the second conductive layer is formed of a metal.

### Appendix 11A

The organic thin film solar cell module according to appendix 10A, in which the second conductive layer is formed of A1.

### Appendix 12A

The organic thin film solar cell module according to any one of appendices 1A to 11A, in which the design display section is constituted of a perforated portion formed so as to penetrate through the photoelectric conversion layer, in the thickness direction.

### Appendix 13A

The organic thin film solar cell module according to any one of appendices 1A to 11A, in which the design display section is constituted of a thin-wall portion thinner than a surrounding region.

### Appendix 14A

The organic thin film solar cell module according to appendix 12A, in which the first conductive layer includes a first electrode section,

the second conductive layer includes a second electrode section coinciding with the first electrode section in plan view, and

the photoelectric conversion layer includes a generation region interposed between the first electrode section and the second electrode section, and configured to perform a photoelectric conversion function thereby contributing to power generation.

### Appendix 15A

The organic thin film solar cell module according to appendix 14A, in which the photoelectric conversion layer includes a non-generation region spaced apart from the first electrode section and the second electrode section in plan view, and not involved in the power generation.

### Appendix 16A

The organic thin film solar cell module according to appendix 15A, in which the first conductive layer includes a first block enclosing therein the design display section and surrounded by a slit formed so as to penetrate in the thickness direction, in plan view.

### Appendix 17A

The organic thin film solar cell module according to appendix 16A, in which the non-generation region of the photoelectric conversion layer includes a partitioned section overlapping with the first block of the first conductive layer.

### Appendix 18A

The organic thin film solar cell module according to appendix 17A, in which the first conductive layer and the second conductive layer is in contact with each other, via the design display section included in the partitioned section of the photoelectric conversion layer.

### Appendix 19A

The organic thin film solar cell module according to any one of appendices 15A to 18A, in which the first conductive layer includes two of the first electrode sections adjacent to each other via a slit,

the second conductive layer includes two of the second electrode sections coinciding with the two first electrode sections in plan view, and

the photoelectric conversion layer includes two of the generation regions interposed between the two first electrode sections and the two second electrode sections.

### Appendix 20A

The organic thin film solar cell module according to appendix 19A, in which the two generation regions are connected in series to each other.

### Appendix 21A

The organic thin film solar cell module according to appendix 19A, in which the two generation regions are connected in parallel to each other.

### Appendix 22A

The organic thin film solar cell module according to appendix 20A, in which the first conductive layer includes a first communication portion connected to one of the two first electrode sections and located adjacent to the other of the two first electrode sections via the slit,

the second conductive layer includes a second communication portion connected to the second electrode section coinciding with the other of the two first electrode sections in plan view, and located adjacent to the other of the two second electrode sections via the slit and in contact with the first communication portion, and

the non-generation region of the photoelectric conversion layer includes a communication region interposed between the first communication portion and the second communication portion.

### Appendix 23A

The organic thin film solar cell module according to appendix 22A, in which the communication region includes the design display section, and

the first communication portion and the second communication portion are in contact with each other via the design display section included in the communication region.

### Appendix 24A

The organic thin film solar cell module according to appendix 23A, in which the first conductive layer includes a plurality of the first electrode sections and the first communication portion concentrically arranged with respect to each other,

the second conductive layer includes a plurality of the second electrode sections and the second communication portion concentrically arranged with respect to each other, and

the photoelectric conversion layer includes a plurality of the generation regions and a plurality of the communication regions concentrically arranged with respect to each other.

### Appendix 25A

The organic thin film solar cell module according to any one of appendices 15A to 24A, in which the first conductive layer includes a first extended portion extending outwardly of the photoelectric conversion layer in plan view, from one of the first electrode sections.

### Appendix 26A

The organic thin film solar cell module according to appendix 25A, in which the first conductive layer includes a first end portion located between, via a slit, the first electrode section extending from the first extended portion and the first electrode section adjacent to the first mentioned first electrode section,

the photoelectric conversion layer includes a terminal region including the design display section enclosed in the first end portion in plan view, the terminal region overlapping with the first end portion, and

the second conductive layer includes a second end portion coinciding with the first end portion in plan view and connected to the adjacent second electrode section, the second end portion being in contact with the first end portion via the design display section in the terminal region.

### Appendix 27A

The organic thin film solar cell module according to appendix 26A, in which the first conductive layer includes a second extended portion extending outwardly of the photoelectric conversion layer in plan view, from the first end portion.

### Appendix 28A

The organic thin film solar cell module according to appendix 22A, in which the design display section included in the communication region displays characters for identifying a time.

### Appendix 29A

The organic thin film solar cell module according to appendix 18A, in which the design display section included in the partitioned section displays characters for identifying a time.

### Appendix 30A

The organic thin film solar cell module according to any one of appendices 15A to 29A, in which the first conductive layer includes an opening enclosing therein the design display section in plan view, and

a portion of the photoelectric conversion layer coinciding with the opening of the first conductive layer serves as the non-generation region.

### Appendix 31A

The organic thin film solar cell module according to appendix 30A, in which the design display section enclosed in the opening displays a pattern for identifying a time.

### Appendix 32A

An electronic device including:

the organic thin film solar cell module according to any one of appendices 1A to 31A; and

a drive unit to operate by power supplied from the organic thin film solar cell module.

### Appendix 33A

The electronic device according to appendix 32A, further including a minute hand and an hour hand driven by the drive unit, thus to be utilized as a watch.

### Appendix 34A

The electronic device according to appendix 32A, in which the drive unit has an arithmetic function, and

the organic thin film solar cell module includes a display unit for displaying a calculation result provided by the drive unit, thus to be utilized as an electronic calculator.

### Fifth and Sixth Embodiments

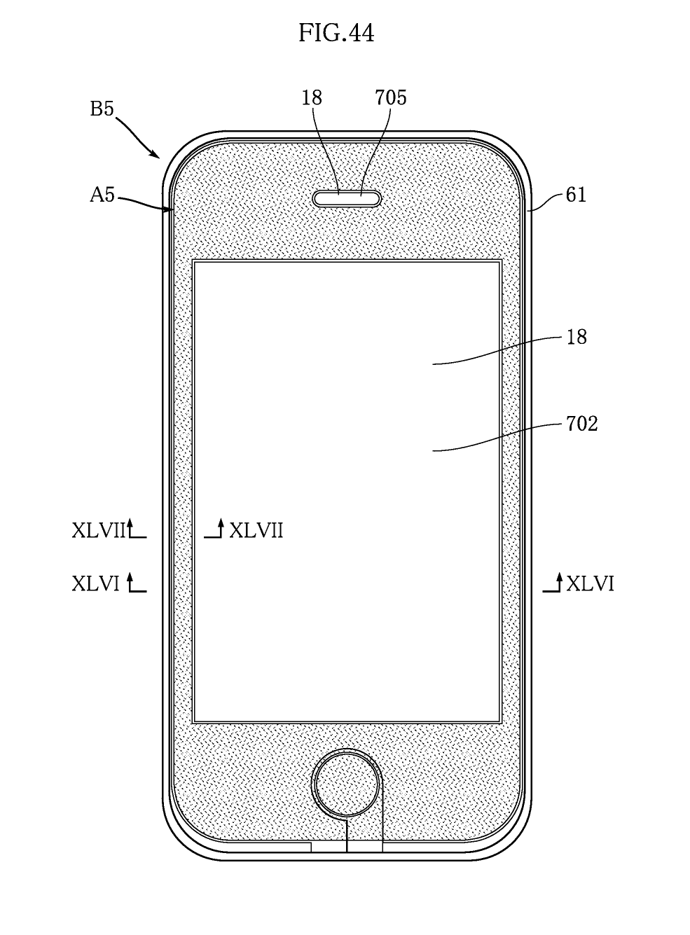

The reference numerals used for fifth and sixth embodiments and FIG. 44 to FIG. 67 are given for these particular embodiment and drawings, and independent of numerals used for other embodiments and drawings. I should be noted, however, that the arrangements of the fifth and sixth embodiments and those of any other embodiment may be combined or exchanged in an appropriate manner.

The term “transparent” used herein may be defined as having a transmittance of approximately 50% or higher. The term “transparent” may also be used for visible light when it is colorless and clear. The visible light corresponds to a wavelength range of approximately 360 nm to 830 nm and an energy range of approximately 3.45 eV to 1.49 eV. When a transmittance of a substance is 50% or higher in these ranges, that substance may be regarded as transparent.

FIG. 44 to FIG. 48 illustrate an electronic device according to the fifth embodiment of the present invention, and an organic thin film solar cell module according to the fifth and sixth embodiments of the present invention. The electronic device B5 according to this embodiment includes an organic thin film solar cell module A5, an organic thin film solar cell module A6, a case 61, a control unit 701, a display unit 702, an input unit 703, a microphone 704, a speaker 705, a wireless communication unit 706, and a battery 707, and is configured as a mobile phone terminal.

The case 61, which accommodates therein other components of the electronic device B5, is formed of a metal, a resin, or glass.

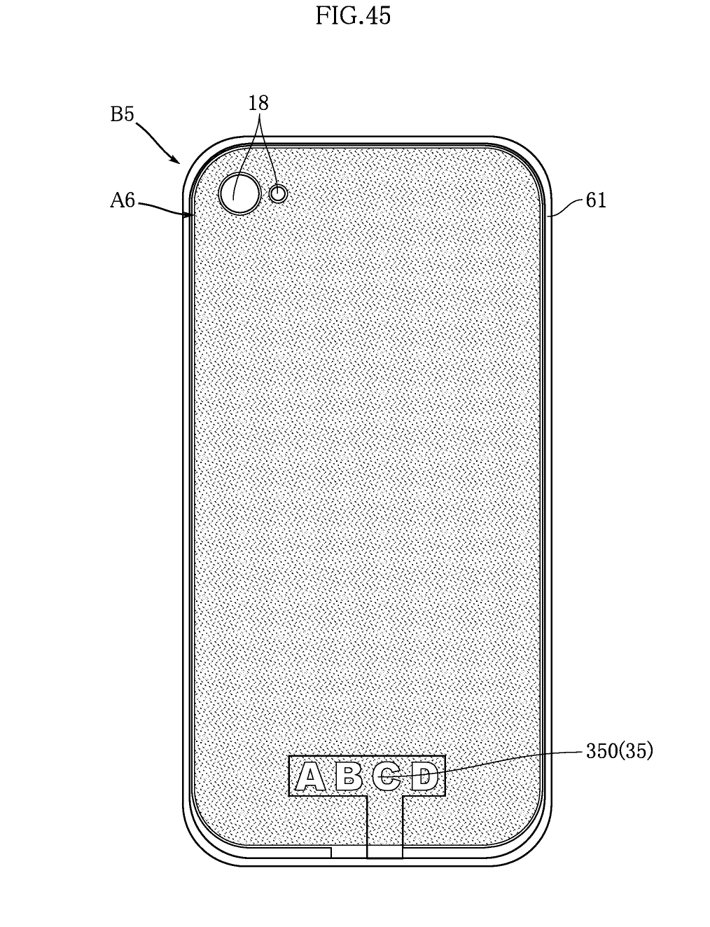

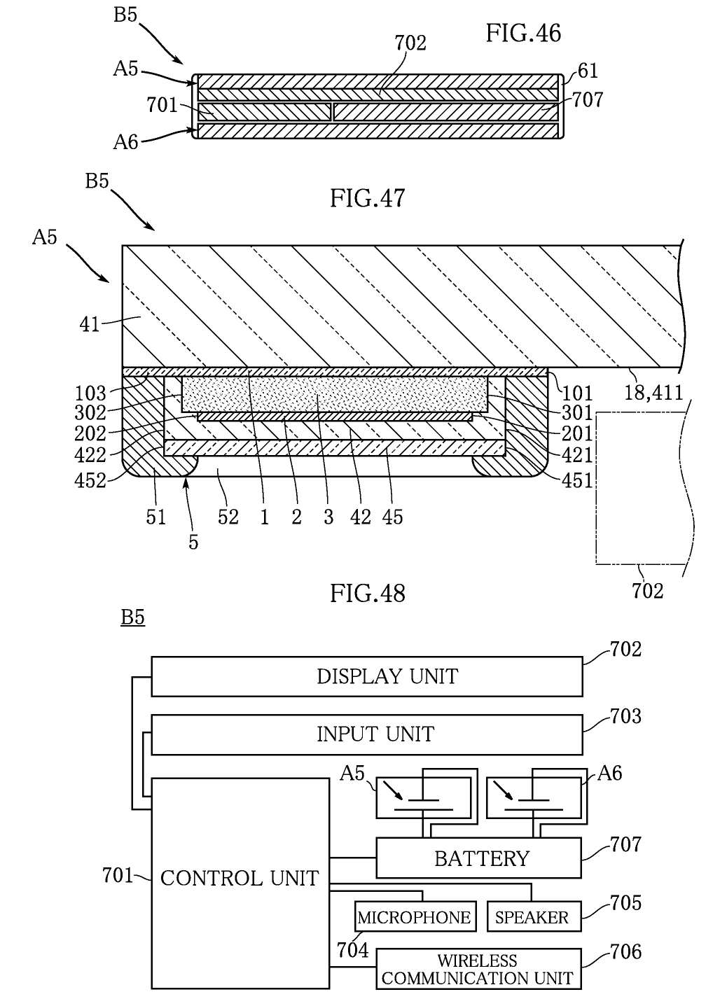

FIG. 44 is a plan view showing organic thin film solar cell modules A5 and A6, and an electronic device B5 incorporated with the organic thin film solar cell modules. FIG. 45 is a bottom view showing the organic thin film solar cell modules A5 and A6 and the electronic device B5. FIG. 46 is a schematic cross-sectional view taken along a line XLVI-XLVI in FIG. 44. FIG. 47 is an enlarged partial cross-sectional view taken along a line XLVII-XLVII in FIG. 44. FIG. 48 is a system diagram of the electronic device B5. In FIG. 46, the elements other than the case 61, the organic thin film solar cell module A5, the organic thin film solar cell module A6, the control unit 701, the display unit 702, and the battery 707 are omitted, to facilitate understanding.

The organic thin film solar cell module A5 and the organic thin film solar cell module A6, serving as the power source module for the electronic device B5, convert light, such as sunlight, into electric power. Further details will be described below.

The control unit 701 corresponds to the drive unit in the present invention, and operates by the power supplied from the organic thin film solar cell module A5 and the organic thin film solar cell module A6. The control unit 701 may receive power directly from the organic thin film solar cell module A5 and the organic thin film solar cell module A6, or from the battery 707, after the power from the organic thin film solar cell module A5 and the organic thin film solar cell module A6 is once charged in the battery 707. The control unit 701 includes, for example, a CPU, a memory, and an interface.

The display unit 702 serves to display various types of information in the outer appearance of the electronic device B5. The display unit 702 is constituted of, for example, an LCD panel or an organic EL display panel. In this embodiment, the display unit 702 displays the information in the outer appearance, through the organic thin film solar cell module A5.

The input unit 703 outputs an electric signal according to inputs made by the user, to the control unit 701. The input unit 703 is constituted of, for example, a touch panel disposed on the display unit 702. The display unit 702 and the input unit 703 may be integrally formed.

The microphone 704 is a device that converts the voice of the user into electric signals. The speaker 705 is a device that outputs the voice of a counterpart of the call and various message tones.

The wireless communication unit 706 is a device for bidirectional wireless communication, in compliance with a wireless communication standard.

The battery 707 is a device for storing power for driving the electronic device B5. The battery 707 is rechargeable. The battery 707 may be charged by the power from commercial power supply through a non-illustrated adapter, or from the organic thin film solar cell module A5 and the organic thin film solar cell module A6.

The organic thin film solar cell module A5 and the organic thin film solar cell module A6 each include the first conductive layer 1, the second conductive layer 2, the photoelectric conversion layer 3, the base substrate 41, the passivation film 42, a resin cover layer 45, and a bypass conductive section 5. In this embodiment, the organic thin film solar cell module A5 and the organic thin film solar cell module A6 each have a rectangular shape in plan view, however this is merely an example, and various shapes may be adopted. The organic thin film solar cell module A5 and the organic thin film solar cell module A6 have the same configuration, except for some details. Hereunder, the organic thin film solar cell module A5 will first be described.

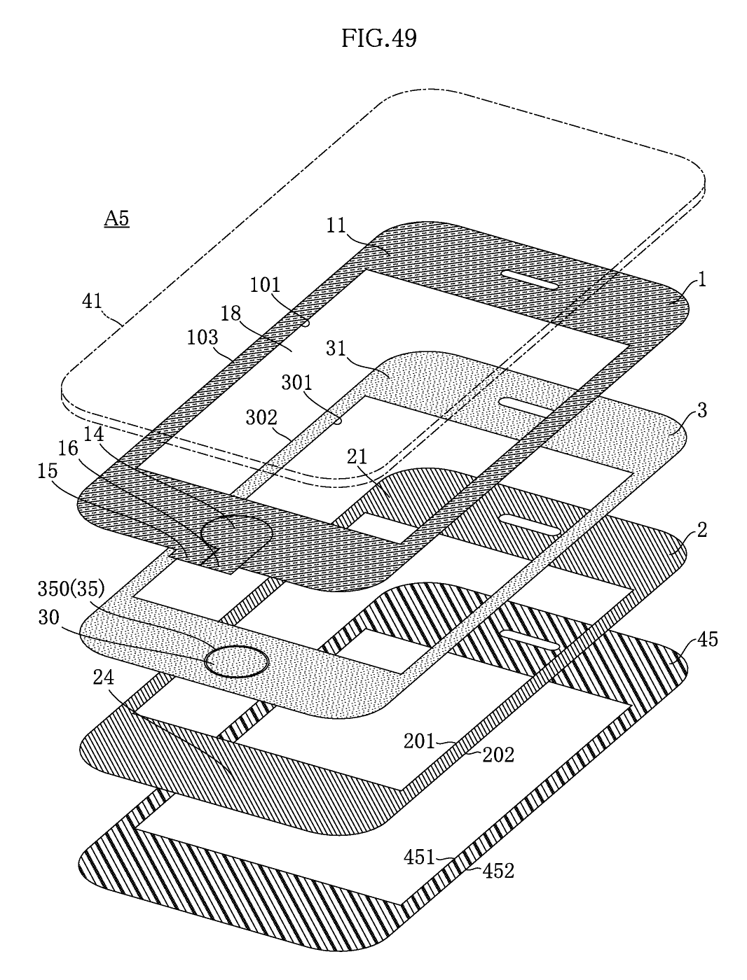

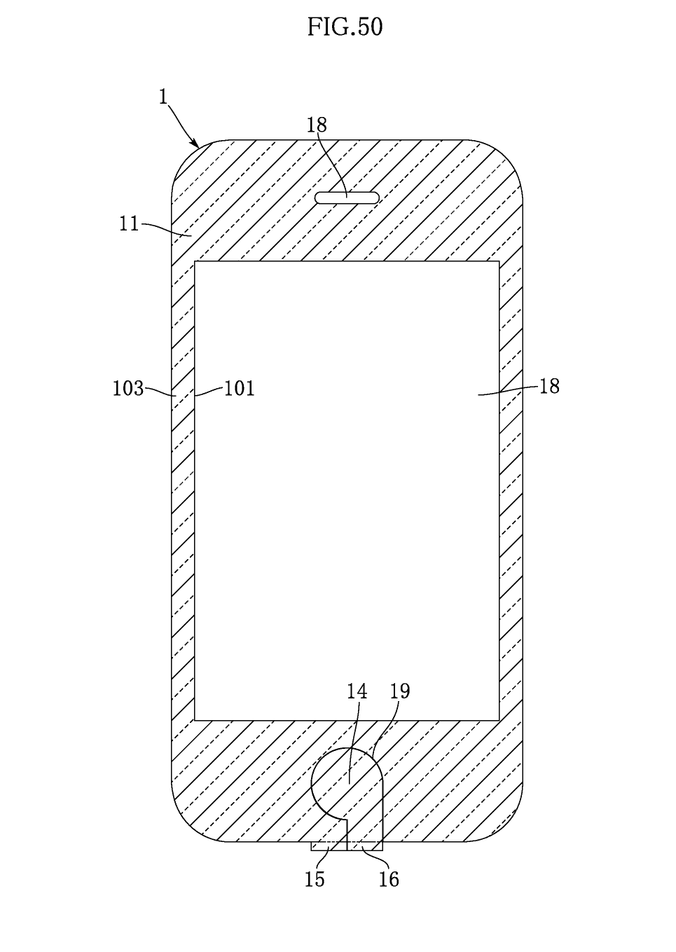

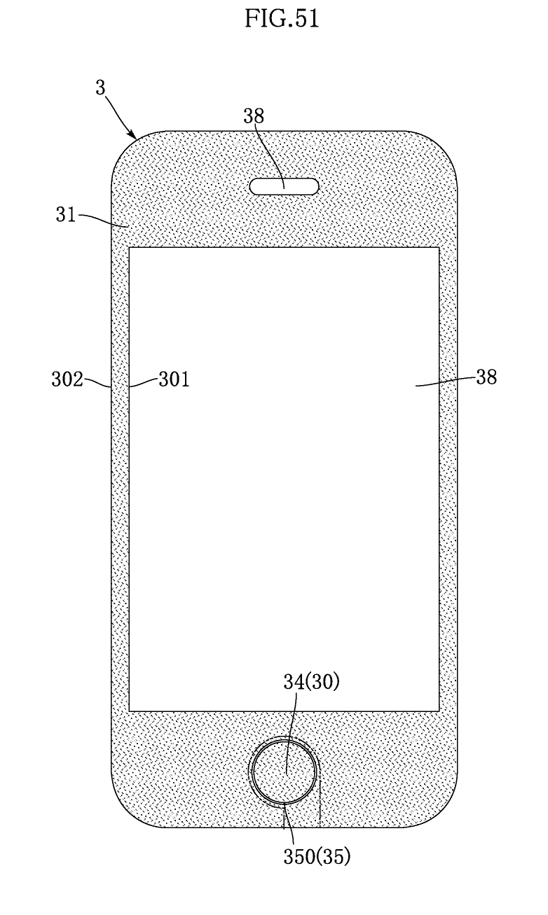

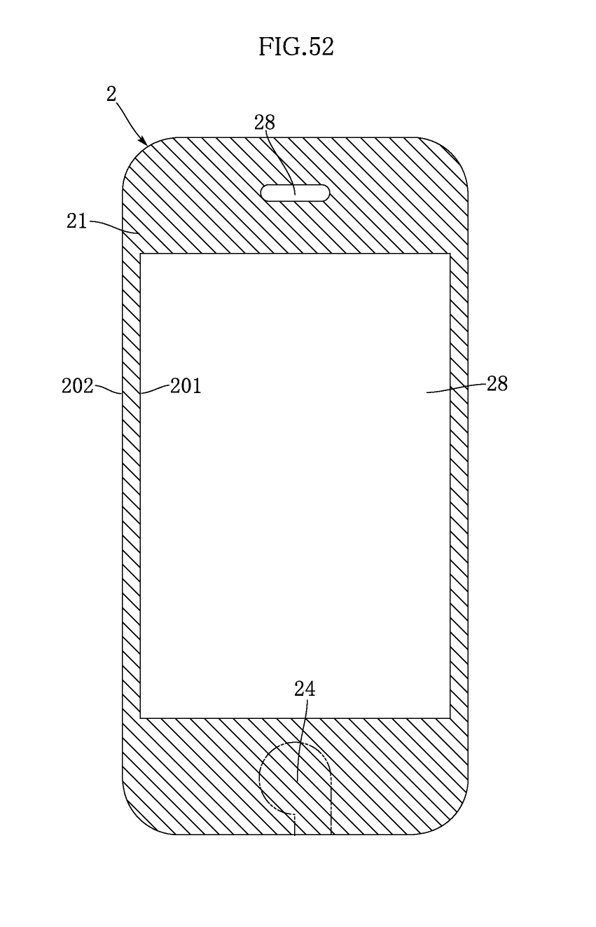

FIG. 49 is a partial exploded perspective view showing the first conductive layer 1, the second conductive layer 2, the photoelectric conversion layer 3, the base substrate 41, and the resin cover layer 45 of the organic thin film solar cell module A5. For the sake of clarity, the base substrate 41 is indicated by an imaginary line (dash-dot-dot line). FIG. 50 is a plan view showing the first conductive layer 1 of the organic thin film solar cell module A5. FIG. 51 is a plan view showing the photoelectric conversion layer 3 of the organic thin film solar cell module A5. FIG. 52 is a plan view showing the second conductive layer 2 of the organic thin film solar cell module A5. FIG. 53 is a plan view showing the resin cover layer 45 and the bypass conductive section 5 of the organic thin film solar cell module A5.

The base substrate 41 serves as the base of the organic thin film solar cell module A5. The base substrate 41 is formed of, for example, transparent glass or a resin. The base substrate 41 has a thickness of, for example, 0.05 mm to 2.0 mm.

The first conductive layer 1 is formed on the base substrate 41. The first conductive layer 1 is transparent, and formed of ITO in this embodiment. As shown in FIG. 49 and FIG. 50, the first conductive layer 1 includes the first electrode section 11, the first end portion 14, the first extended portion 15, the second extended portion 16, a plurality of openings 18, the slits 19, a third edge 101, and an extended portion 103. In this embodiment, the first conductive layer 1 has a generally circular shape in plan view, which is, however, merely an example of the shape of the first conductive layer 1. The first conductive layer 1 may be formed in various shapes. The first conductive layer 1 has a thickness of, for example, 100 nm to 300 nm. In FIG. 50, the first electrode section 11, the first end portion 14, the first extended portion 15, and the second extended portion 16 are hatched with oblique lines.

The first electrode section 11 is a layer in which holes created by the photoelectric conversion layer 3 are collected, and acts as what is known as an anode electrode. In this embodiment, a major part of the first conductive layer 1 acts as one first electrode section 11.

The first extended portion 15 extends from the first electrode section 11 outwardly of the photoelectric conversion layer 3 in plan view. In FIG. 50, the boundary between the first electrode section 11 and the first extended portion 15 is indicated by an imaginary line (dash-dot-dot line). Through the first extended portion 15, the holes originating from the power generation by the photoelectric conversion layer 3 can be led to outside of the organic thin film solar cell module A5.

The first end portion 14 is isolated from the first electrode section 11 via the slit 19. In this embodiment, the first end portion 14 has, for example, a circular shape in plan view. In this embodiment, the first end portion 14 is composed of a generally circular portion and a rectangular portion.

The second extended portion 16 extends from the first end portion 14 outwardly of the photoelectric conversion layer 3 in plan view. In FIG. 50, the boundary between the first end portion 14 and the second extended portion 16 is indicated by an imaginary line (dash-dot-dot line). In this embodiment, the first extended portion 15 and the second extended portion 16 are located adjacent to each other. Through the second extended portion 16, the holes originating from the power generation by the photoelectric conversion layer 3 can be led to outside of the organic thin film solar cell module A5.

The openings 18 are formed so as to penetrate through the first conductive layer 1 in the thickness direction. In this embodiment, two openings 18 are provided. The opening 18 at an upper position in FIG. 50 is formed, for example, to allow the speaker 705 to perform its function. The larger opening 18 at the central position in FIG. 50 is for exhibiting the information displayed by the display unit 702, in the outer appearance.

The third edge 101 defines the opening 18 at the central position in FIG. 50. In this embodiment, the third edge 101 surrounds the opening 18 from four directions, in a rectangular ring shape in plan view. However, it is not mandatory that the third edge 101 surrounds the opening 18 from four directions. For example, the third edge 101 may define the opening 18 from three directions, such that the opening 18 is open to outside through the first electrode section 11, in plan view. Alternatively, the third edge 101 may be formed so as to define the opening 18 from one or two directions. In the region adjacent to the third edge 101, in other words the opening 18 at the central position in FIG. 50, the base substrate 41 is exposed. In addition, the third edge 101 corresponds to the inner edge of a portion of the first conductive layer 1 extending from a second edge 451 of the resin cover layer 45 and a first edge 421 of the passivation film 42, to be described below.

The extended portion 103 outwardly extends from the passivation film 42 and the resin cover layer 45. In this embodiment, the extended portion 103 is formed generally along the entire outer peripheral edge of the first conductive layer 1.

A major part of the second conductive layer 2 is disposed on the first conductive layer 1 via the photoelectric conversion layer 3. A part of the second conductive layer 2 is in direct contact with the first conductive layer 1. The material of the second conductive layer 2 is not specifically limited, and may be transparent or non-transparent. In this embodiment, the second conductive layer 2 is formed of a metal, typically A1, W, Mo, Mn, or Mg. In the following example, the second conductive layer 2 is formed of A1. Accordingly, the second conductive layer 2 is non-transparent. In this case, a non-illustrated passive film formed of Al₂O₃ may be formed on the surface of the second conductive layer 2 opposite to the base substrate 41. The second conductive layer 2 has a thickness of, for example, 30 nm to 150 nm.

As shown in FIG. 52, the second conductive layer 2 includes the second electrode section 21, the second end portion 24, and a plurality of openings 28. Although the second conductive layer 2 has a generally rectangular shape in plan view in this embodiment, this is merely an example of the shape of the second conductive layer 2. The second conductive layer 2 may be formed in various shapes. In FIG. 52, the second electrode section 21 and the second end portion 24 are hatched with oblique lines.

The second electrode section 21 is a layer in which electrons created by the photoelectric conversion layer 3 are collected, and acts as what is known as a cathode electrode. The second electrode section 21 coincides with the first electrode section 11 in plan view. In this embodiment, a major portion of the second conductive layer 2 acts as the second electrode section 21.

The second end portion 24 coincides with the first end portion 14 of the first conductive layer 1 in plan view, and extends from the second electrode section 21. In FIG. 52, the shape of the second end portion 24 is indicated by an imaginary line (dash-dot-dot line), to facilitate understanding. The second end portion 24 is, like the first end portion 14, composed of a generally circular portion and a rectangular portion.

The openings 28 are formed so as to penetrate through the second conductive layer 2 in the thickness direction. In this embodiment, two openings 28 are provided. The opening 28 at an upper position in FIG. 52 is formed, for example, to allow the speaker 705 to perform its function. The larger opening 28 at the central position in FIG. 52 is for exhibiting the information displayed by the display unit 702, in the outer appearance.

A fourth inner recessed edge 201 defines the opening 28 at the central position in FIG. 52. In this embodiment, the fourth inner recessed edge 201 surrounds the opening 28 from four directions, in a rectangular ring shape in plan view. However, it is not mandatory that the fourth inner recessed edge 201 surrounds the opening 28 from four directions. For example, the fourth inner recessed edge 201 may define the opening 28 from three directions, such that the opening 28 is open to outside through the second electrode section 21, in plan view. Alternatively, the fourth inner recessed edge 201 may be formed so as to define the opening 28 from one or two directions. As shown in FIG. 47, the fourth inner recessed edge 201 is inwardly recessed (opposite to the direction toward the inner space of the opening 18) with respect to the third edge 101.

A fourth outer recessed edge 202 is, as shown in FIG. 47, inwardly recessed (to the right in FIG. 47), with respect to a first outer edge 422 of the passivation film 42 and a second outer edge 452 of the resin cover layer 45 to be described below, in plan view. In this embodiment, the fourth outer recessed edge 202 has an annular shape in plan view.

The photoelectric conversion layer 3 is interposed between the first conductive layer 1 and the second conductive layer 2, and disposed on the base substrate 41. The photoelectric conversion layer 3 is formed of an organic thin film, and configured to perform a photoelectric conversion function, to convert received light into electric power. Although the configuration of the photoelectric conversion layer 3 is not specifically limited, the photoelectric conversion layer 3 may include, for example, a bulk heterojunction organic active layer and a hole transport layer disposed on the bulk heterojunction organic active layer on the side of the first conductive layer 1. In this embodiment, the photoelectric conversion layer 3 is formed in a rectangular shape in plan view, however this is merely an example and the photoelectric conversion layer 3 may be formed in various shapes. The photoelectric conversion layer 3 has a thickness of, for example, 50 nm to 300 nm.

In the bulk heterojunction organic active layer, p-type organic active layer regions and n-type organic active layer regions are intermixed, forming a complicated bulk hetero pn junction. The p-type organic active layer region is, for example, formed of poly(3-hexylthiophene-2,5diyl) (P3HT), and the n-type organic active layer region is formed of 6,6-phenyl-C61-butyric acid methyl ester (PCBM), for example. The hole transport layer is formed of, for example, PEDOT:PSS.

Examples of materials that may be utilized to form the photoelectric conversion layer 3 include phthalocyanine (Pc), zinc-phthalocyanine (ZnPc), N,N′-dimethyl perylene-3,4,9,10-dicarboximide (Me-Ptcdi), and Buckminster fullerene (C60). These materials are, for example, utilized for vacuum vapor deposition.

In addition, poly[2-methoxy-5-(3,7-dimethyl octyloxy)]-1,4-phenylene vinylene (MDMO-PPV), poly[N-9′-hepta-decanyl-2,7-carbazole-alt-5,5-(4′,7′-di-thienyl-2′1′,3′-b3nzothiadizaole)] (PCDTBT), 6,6-phenyl-C61-butyric acid methyl ester (PC60BM), or 6,6-phenyl-C71-butyric acid methyl ester (PC70BM) may be utilized to form the photoelectric conversion layer 3. These materials are, for example, utilized for a solution process.

As shown in FIG. 51, the photoelectric conversion layer 3 includes the non-generation region 30, the generation region 31, the design display section 35, a plurality of openings 38, a fifth inner recessed edge 301, and a fifth outer recessed edge 302. In FIG. 51, the non-generation region 30 and the generation region 31 are shaded with scattered dots.

The design display section 35 constitutes a design exhibited in the outer appearance through the first conductive layer 1. The design constituted by the design display section include those that the user can visually recognize as visually singular feature, such as characters, marks, and patterns. In this embodiment, the design display section 35 represents an annular shape.

In this embodiment, the design display section 35 is constituted of a perforated portion 350. The perforated portion 350 is formed so as to penetrate through the photoelectric conversion layer 3 in the thickness direction. The perforated portion 350 is visible in the outer appearance through the first conductive layer 1. In this embodiment, the perforated portion 350 exposes the second conductive layer 2 on the side of the first conductive layer 1. In other words, a part of the second conductive layer 2 is visible in the outer appearance, through the perforated portion 350.

The generation region 31 is interposed between the first electrode section 11 of the first conductive layer 1 and the second electrode section 21 of the second conductive layer 2, and performs the photoelectric conversion function to contribute to the power generation. The shape of the generation region 31 coincides with the first electrode section 11 and the second electrode section 21, in plan view.

The non-generation region 30 corresponds to a portion of the photoelectric conversion layer 3 deviated, in plan view, from the first electrode section 11 of the first conductive layer 1 and the second electrode section 21 of the second conductive layer 2, and overlapping with the first end portion 14 of the first conductive layer 1. The first end portion 14 is in contact with the second end portion 24 of the second conductive layer 2, and hence the collected holes and electrons are instantly coupled. Therefore, the non-generation region 30 is not involved in the power generation. Thus, the region of the photoelectric conversion layer 3 other than the generation regions 31 corresponds to the non-generation region 30.

In this embodiment, the non-generation region 30 is located in a terminal region 34. The terminal region 34 includes the perforated portion 350 (design display section 35). The terminal region 34 includes the perforated portion 350 (design display section 35) enclosed in the first end portion 14 of the first conductive layer 1 in plan view, and overlaps with the first end portion 14 of the first conductive layer 1 in plan view. In addition, the terminal region 34 overlaps with the second end portion 24 of the second conductive layer 2. The first end portion 14 of the first conductive layer 1 and the second end portion 24 of the second conductive layer 2 are in contact with each other, via the perforated portion 350 in the terminal region 34.

The openings 38 are formed so as to penetrate through the photoelectric conversion layer 3 in the thickness direction. In this embodiment, two openings 38 are provided. The opening 38 at an upper position in FIG. 51 is formed, for example, to allow the speaker 705 to perform its function. The larger opening 38 at the central position in FIG. 51 is for exhibiting the information displayed by the display unit 702, in the outer appearance.

The fifth inner recessed edge 301 defines the opening 38 at the central position in FIG. 51. In this embodiment, the fifth inner recessed edge 301 surrounds the opening 38 from four directions, in a rectangular ring shape in plan view. However, it is not mandatory that the fifth inner recessed edge 301 surrounds the opening 38 from four directions. For example, the fifth inner recessed edge 301 may define the opening 38 from three directions, such that the opening 38 is open to outside through the generation region 31, in plan view. Alternatively, the fifth inner recessed edge 301 may be formed so as to define the opening 38 from one or two directions. In addition, as shown in FIG. 47, the fifth inner recessed edge 301 is inwardly recessed (opposite to the direction toward the inner space of the opening 18) with respect to the third edge 101.

The fifth outer recessed edge 302 is, as shown in FIG. 47, inwardly recessed (to the right in FIG. 47), with respect to the first outer edge 422 of the passivation film 42 and the second outer edge 452 of the resin cover layer 45 to be described below, in plan view. In this embodiment, the fifth outer recessed edge 302 has an annular shape in plan view.

With the configuration described above, in the organic thin film solar cell module A5 the first extended portion 15 extends from the first electrode section 11. The second electrode section 21 extends from the second end portion 24. The second end portion 24 is in contact with the first end portion 14 via the perforated portion 350 in the terminal region 34. The second extended portion 16 extends from the first end portion 14. As result, the first extended portion 15 and the second extended portion 16 each act as an output terminal of the organic thin film solar cell module A5.

The passivation film 42 is disposed on the second conductive layer 2, so as to protect the second conductive layer 2 and the photoelectric conversion layer 3. The passivation film 42 is, for example, formed of SiN or SiON. The passivation film 42 has a thickness of, for example, 0.5 μm to 2.0 μm and, in this embodiment, approximately 1.5 μm.

The resin cover layer 45 covers the passivation film 42. The resin cover layer 45 is formed of, for example, a UV-curable resin. The resin cover layer 45 has a thickness of, for example, 3 μm to 20 μm and, in this embodiment, approximately 10 μm.

As shown in FIG. 53, the resin cover layer 45 includes a plurality of openings 458, a second edge 451, and a second outer edge 452. In FIG. 53, the resin cover layer 45 is hatched with oblique lines.

The openings 458 are each formed by removing a part of the resin cover layer 45, so as to penetrate therethrough. In this embodiment, two openings 458 are provided. The opening 458 at an upper position in FIG. 53 is formed, for example, to allow the speaker 705 to perform its function. The larger opening 458 at the central position in FIG. 53 is for exhibiting the information displayed by the display unit 702, in the outer appearance.

The second edge 451 defines the opening 458 at the central position in FIG. 53. In this embodiment, the second edge 451 surrounds the opening 458 from four directions, in a rectangular ring shape in plan view. However, it is not mandatory that the second edge 451 surrounds the opening 458 from four directions. For example, the second edge 451 may define the opening 18 from three directions, such that the opening 458 is open to outside through the resin cover layer 45, in plan view. Alternatively, the second edge 451 may be formed so as to define the opening 458 from one or two directions.

The second outer edge 452 is located on the side opposite to the second edge 451, across at least a part of the photoelectric conversion layer 3 in plan view, and corresponds, in this embodiment, to the outer peripheral edge of the resin cover layer 45.

The passivation film 42 includes the first edge 421 and the first outer edge 422.

The first edge 421 coincides with the second edge 451 in plan view. In this embodiment, the first edge 421 forms a continuous surface with the second edge 451. The first outer edge 422 coincides with the second outer edge 452 in plan view. In this embodiment, the first outer edge 422 forms a continuous surface with the second outer edge 452.

As shown in FIG. 47, a part of the base substrate 41 is exposed through the opening 458 surrounded by the second edge 451 and the first edge 421, to form an exposed region 411. The exposed region 411 is not covered with the first conductive layer 1 or other components, and the surface of the base substrate 41 is directly exposed.

The bypass conductive section 5 provides a route having a lower resistance than the first conductive layer 1, for collecting the holes that have reached the first conductive layer 1. In this embodiment, the bypass conductive section 5 includes two bus-bar sections 51, a plurality of communication portions 52, and two collector electrodes 53. The bypass conductive section 5 is formed of a material lower in resistance than the first conductive layer 1, and includes, for example, Ag or carbon.

As shown in FIG. 47 and FIG. 53, one of the bus-bar sections 51 covers the second edge 451 and the first edge 421 over the entire length. The bus-bar section 51 covers a portion of the first conductive layer 1 located between the third edge 101 and the first edge 421 (second edge 451). The inner edge of the bus-bar section 51 coincides with the third edge 101, in plan view. The other bus-bar section 51 covers the second outer edge 452 and the first outer edge 422 over the entire length. This bus-bar section 51 covers the extended portion 103 of the first conductive layer 1. Thus, each of the two bus-bar sections 51 is electrically connected to the first conductive layer 1.

The communication portions 52 are formed on the resin cover layer 45, and connects the bus-bar section 51 on the inner side in FIG. 53 and the communication portion 52 on the outer side in FIG. 53. One of the two collector electrodes 53 is electrically connected to the first conductive layer, and the other is electrically connected to the second conductive layer 2.

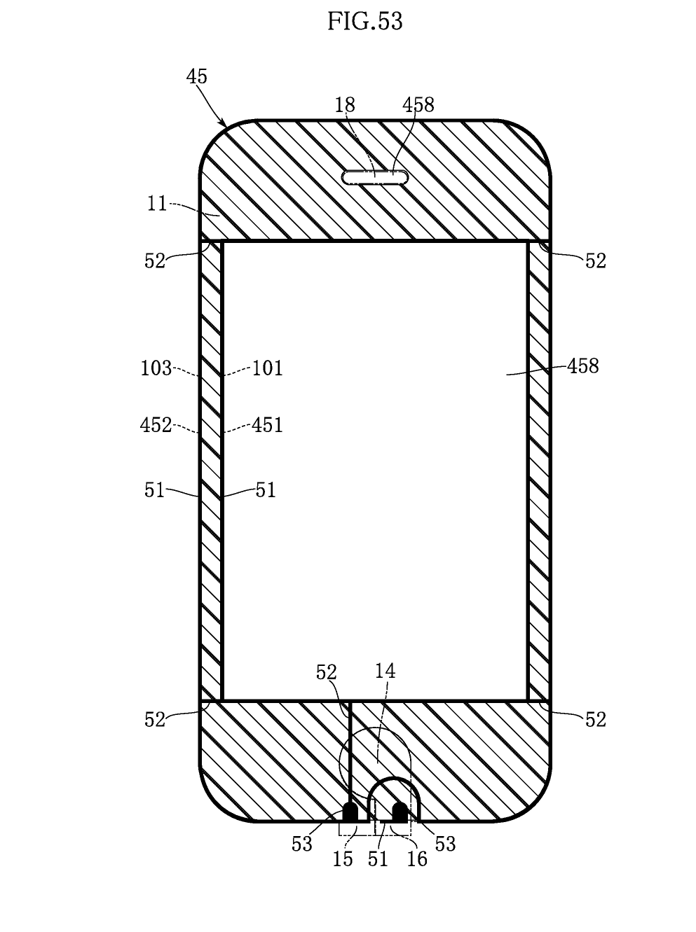

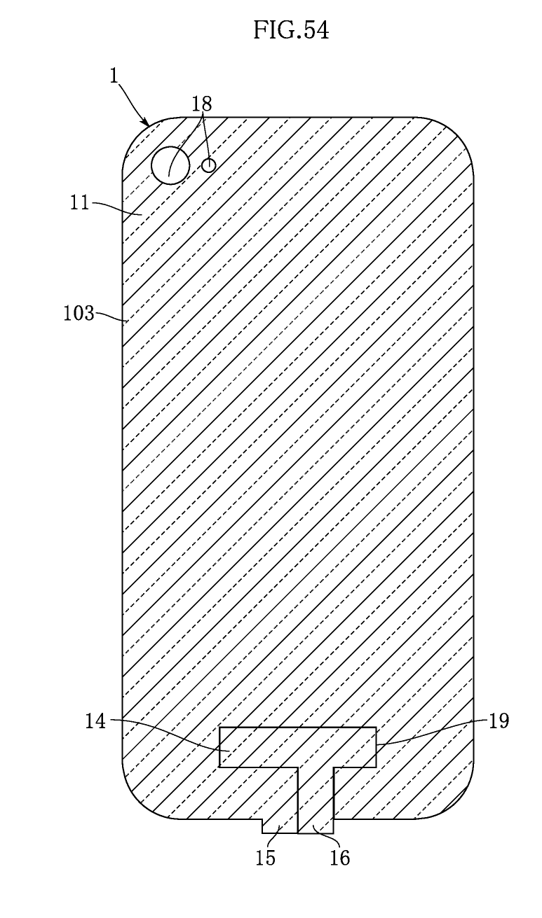

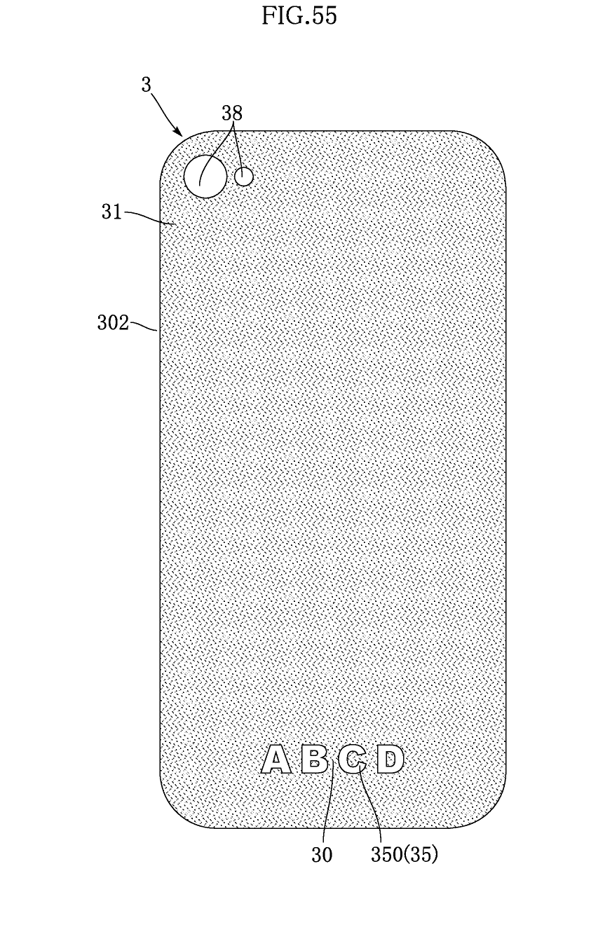

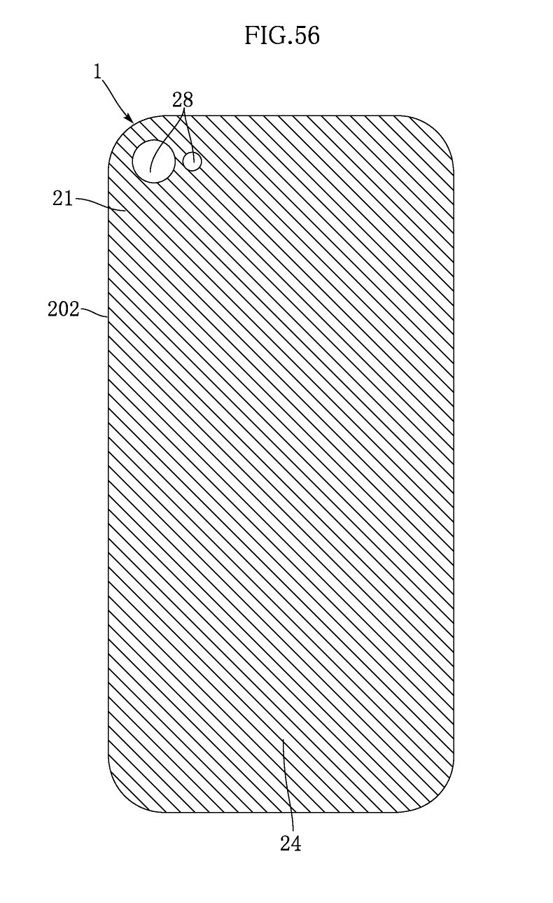

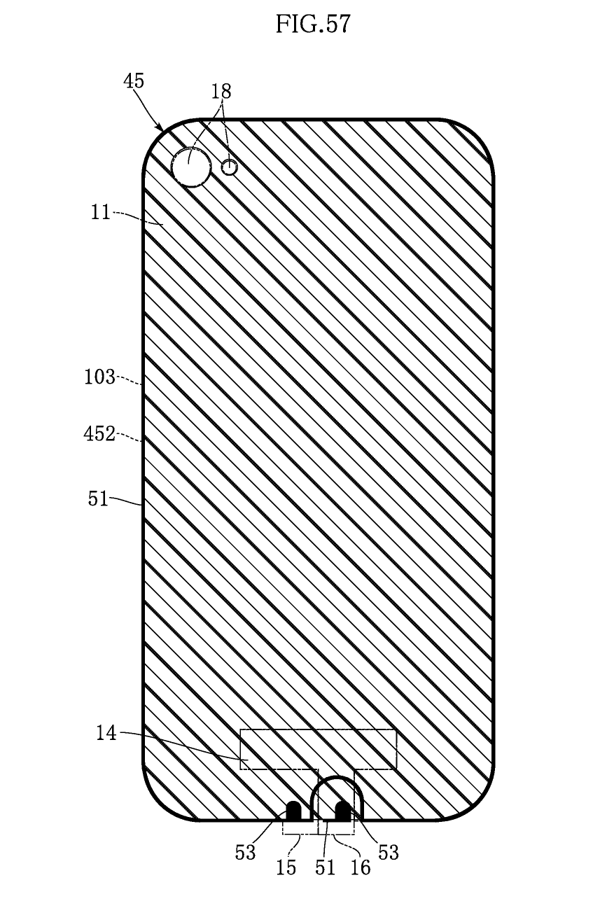

FIG. 54 is a plan view showing the first conductive layer 1 of the organic thin film solar cell module A6. FIG. 55 is a plan view showing a photoelectric conversion layer 3 of the organic thin film solar cell module A6. FIG. 56 is a plan view showing a second conductive layer 2 of the organic thin film solar cell module A6. FIG. 57 is a plan view showing a resin cover layer 45 and a bypass conductive section 5 of the organic thin film solar cell module A6.

The organic thin film solar cell module A6 is without the opening 18, the opening 28, the opening 38, and the opening 458 for exhibiting the display unit 702 in the outer appearance. Accordingly, the third edge 101, the fourth inner recessed edge 201, the fifth inner recessed edge 301, the first edge 421, and the second edge 451 are not provided. The bypass conductive section 5 includes the bus-bar sections 51 formed along the outer periphery, and is without the communication portion 52.

In this embodiment, as shown in FIG. 55, the photoelectric conversion layer 3 includes a plurality of perforated portions 350 (35). The perforated portions 350 each represent an alphabet. The first end portion 14 of the first conductive layer 1 and the second end portion 24 of the second conductive layer 2 are in contact with each other via the perforated portions 350, as in the organic thin film solar cell module A5.

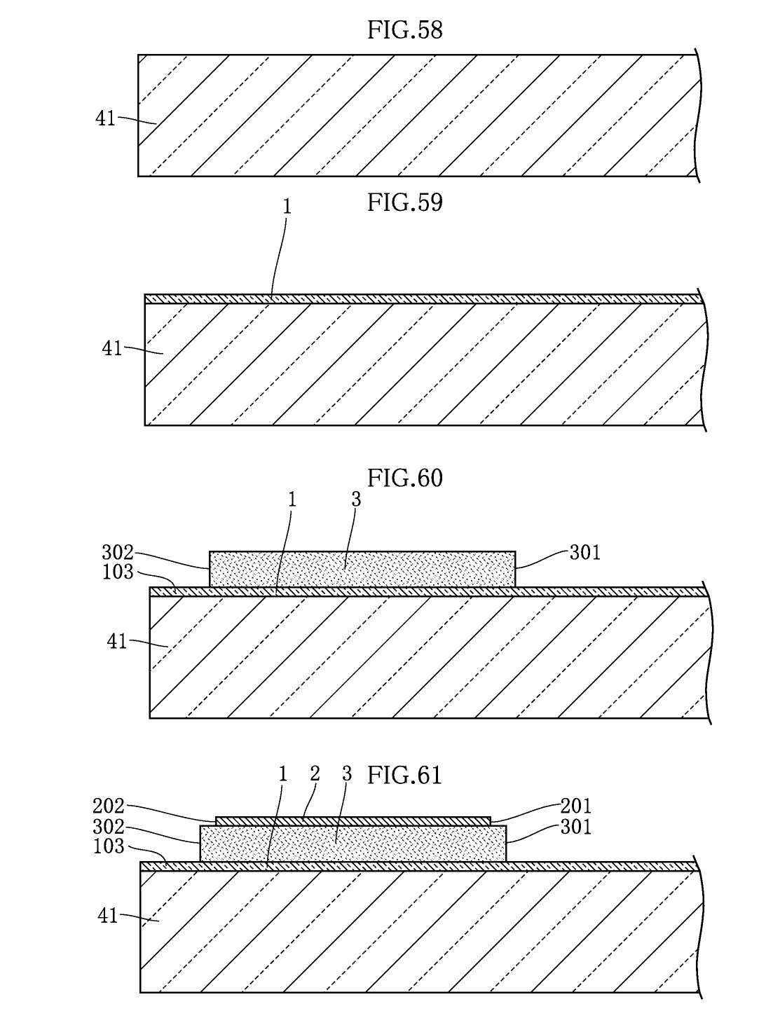

Referring now to FIG. 58 to FIG. 65, a manufacturing method of the organic thin film solar cell module A5 will be described hereunder. The cited drawings are turned upside down from FIG. 47, to facilitate understanding. In addition, FIG. 58 to FIG. 65 illustrate the formation process of the portion corresponding to the cross-section of the electronic device B5, taken along the line XLVII-XLVII in FIG. 44.

Referring first to FIG. 58, the base substrate 41 is prepared. On one of the surfaces of the base substrate 41, the first conductive layer 1 formed of ITO is deposited by a known method such as sputtering, as shown in FIG. 59. Then the ITO is patterned to form the patterns of the openings 18 and the slits 19. For the patterning of the ITO, for example, wet etching, oxygen plasma etching, or laser patterning is adopted as the case may be. Without limitation to the above, the first conductive layer 1 may be formed by directly patterning the ITO on the base substrate 41, for example through a nanoimprint lithography process.

Proceeding to FIG. 60, the photoelectric conversion layer 3 is formed. To form the photoelectric conversion layer 3, an organic film is deposited on the base substrate 41 and the first conductive layer 1, for example by spin coating, and the organic film is patterned to form the fifth inner recessed edge 301, the fifth outer recessed edge 302, the openings 38, and the perforated portion 350 (design display section 35), by oxygen plasma etching or laser patterning. Without limitation to the above, the photoelectric conversion layer 3 may be formed by directly patterning the organic film on the base substrate 41 and the first conductive layer 1, for example by slit coating, capillary coating, or gravure printing.

Proceeding to FIG. 61, the second conductive layer 2 is formed. To form the second conductive layer 2, for example, one of the aforementioned metals is deposited by vacuum vapor deposition on the base substrate 41, the first conductive layer 1, and the photoelectric conversion layer 3, to deposit a metal film thereon. Then the metal film is patterned, for example by etching with a mask layer. Through such patterning, the second conductive layer 2 including the fourth inner recessed edge 201 and the fourth outer recessed edge 202 is formed on the photoelectric conversion layer 3.

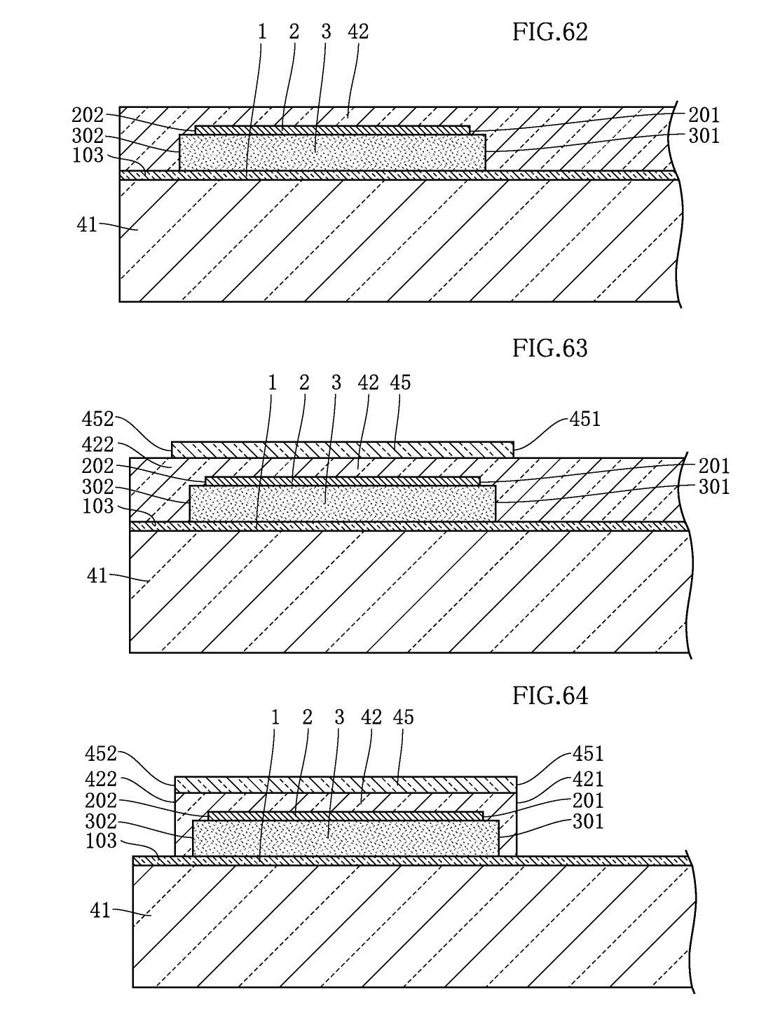

Proceeding to FIG. 62, the passivation film 42 is formed. To form the passivation film 42, SiN or SiON is deposited on the base substrate 41, the first conductive layer 1, the photoelectric conversion layer 3, and the second conductive layer 2, for example by plasma CVD.

Proceeding to FIG. 63, the resin cover layer 45 is formed. To form the resin cover layer 45, for example, a liquid resin material containing a UV-curable resin is applied to the passivation film 42 by screen printing, and the resin is irradiated with UV light thus to be cured. Thus, the resin cover layer 45 including the second edge 451 and the second outer edge 452 is obtained.

Proceeding to FIG. 64, the passivation film 42 is patterned, using the resin cover layer 45 as a mask. This patterning is performed through a wet etching process using hydrofluoric acid containing 0.55% to 4.5% of hydrogen fluoride. Such hydrofluoric acid barely dissolves the resin cover layer 45 formed of a UV-curable resin, but selectively dissolves the passivation film 42 formed of SiN or SiON. In addition, the hydrofluoric acid barely dissolves the first conductive layer 1 formed of ITO. As result, the first edge 421 and the first outer edge 422 are formed in the passivation film 42. The first edge 421 coincides with the second edge 451 in plan view. The first edge 421 and the second edge 451 form a continuous surface. Likewise, the first outer edge 422 coincides with the second outer edge 452 in plan view. The first outer edge 422 and the second outer edge 452 form a continuous surface.

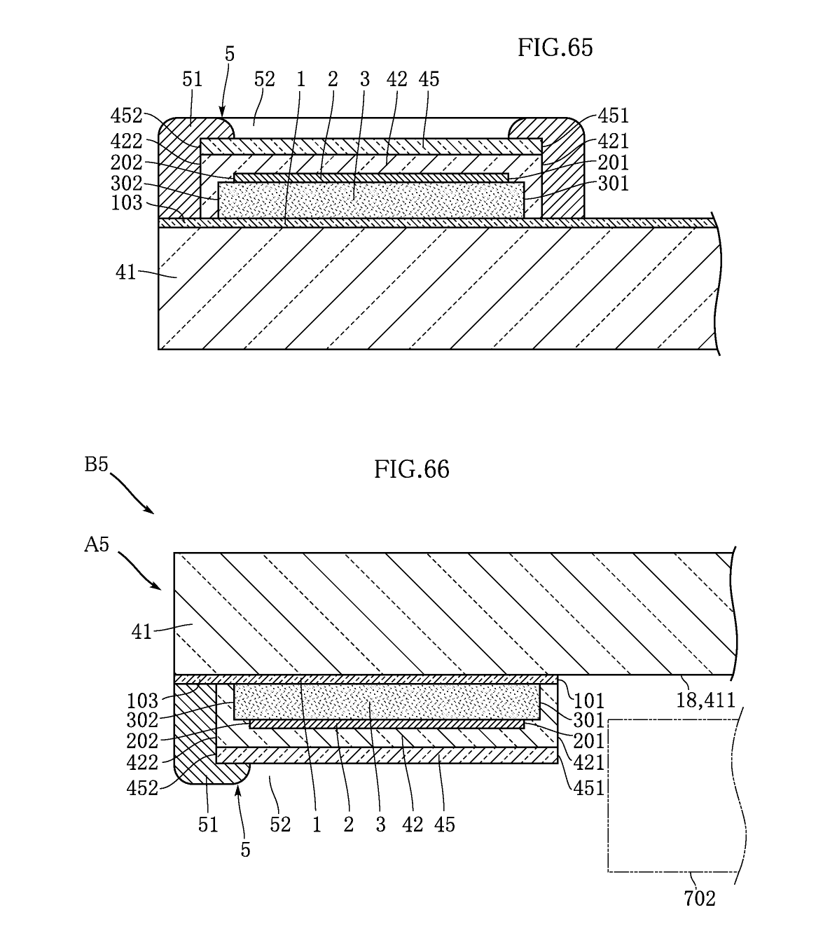

Proceeding to FIG. 65, the bypass conductive section 5 is formed. To form the bypass conductive section 5, for example, a paste containing Ag or carbon is applied, and then dried to harden the paste.

Then the first conductive layer 1 is patterned, for example with aqua regia in which concentrated hydrochloric acid and concentrated nitric acid are mixed in a ratio of 3 to 1. By such patterning, portions of the first conductive layer 1 exposed from the bypass conductive section 5 and the resin cover layer 45 are selectively removed. Thus, the third edge 101 and so forth are formed in the first conductive layer 1. Through the mentioned process, the organic thin film solar cell module A5 can be obtained. The organic thin film solar cell module A6 can also be obtained through the same process.

The organic thin film solar cell module A5 and the electronic device B5 provide the following advantageous effects.

In this embodiment, the base substrate 41 is exposed in the regions adjacent to the second edge 451 and the second outer edge 452. In such regions, the passivation film 42 and the resin cover layer 45 are not formed. Therefore, the mentioned regions can be finished with higher transparency, so that the display unit 702 can be more clearly exhibited in the outer appearance.

The first conductive layer 1 is not formed on the base substrate 41, except for a small region covered with the bus-bar section 51, in the region adjacent to the second edge 451 and the first edge 421. Although the first conductive layer 1 is formed of ITO, the first conductive layer 1 may be visually recognized as a faintly colored portion, depending on the condition of ambient light. The configuration according to this embodiment enables the region for exhibiting the display unit 702 in the outer appearance to be finished with prominent transparency, thereby realizing a more exquisite outer appearance.

The fifth inner recessed edge 301 of the photoelectric conversion layer 3 and the fourth inner recessed edge 201 of the second conductive layer 2 are spaced apart from the first edge 421 and the second edge 451. Accordingly, the second conductive layer 2 and the photoelectric conversion layer 3 can be prevented from being electrically connected improperly, to the bypass conductive section 5. In addition, the passivation film 42 is interposed between the fourth inner recessed edge 201 and the fifth inner recessed edge 301, and between the first edge 421 and the second edge 451. Therefore, a short circuit between the second conductive layer 2 or photoelectric conversion layer 3 and the bus-bar section 51 of the bypass conductive section 5.

By the patterning of the passivation film 42 using the resin cover layer 45 as the mask, the passivation film 42 can be formed in the same shape as the resin cover layer 45. In other words, forming the resin cover layer 45 from a material having high shape formability, such as the UV-curable resin, enables the passivation film 42 to be formed in a desired shape, despite the material thereof having lower shape formability. The resin cover layer 45 may be removed after the passivation film 42 is formed. However, keeping the resin cover layer 45 unremoved prevents intrusion of moisture and particles into the first conductive layer 1, the second conductive layer 2, and the photoelectric conversion layer 3, and contributes to improving the strength of the organic thin film solar cell module A5.

Providing the bypass conductive section 5 allows the holes diffused to the first conductive layer 1 to be led to the collector electrode 53, through the bus-bar section 51. Since the bypass conductive section 5 has lower resistance than the first conductive layer 1, the power is prevented from being converted into heat. Such an effect reduces the power generation loss of the organic thin film solar cell module A5 and the organic thin film solar cell module A6, and enables the power generation from the generation region 31 having a larger area.

Since the first conductive layer 1 is patterned after the bypass conductive section 5 is formed, the communication portion 52 of the bypass conductive section 5 enters into contact with a portion of the first conductive layer 1 having a significant area in plan view (for example, extended portion 103), instead of the end face of the first conductive layer 1. Such a configuration reduces contact resistance between the first conductive layer 1 and bypass conductive section 5, thereby assuring the electrical conduction therebetween.

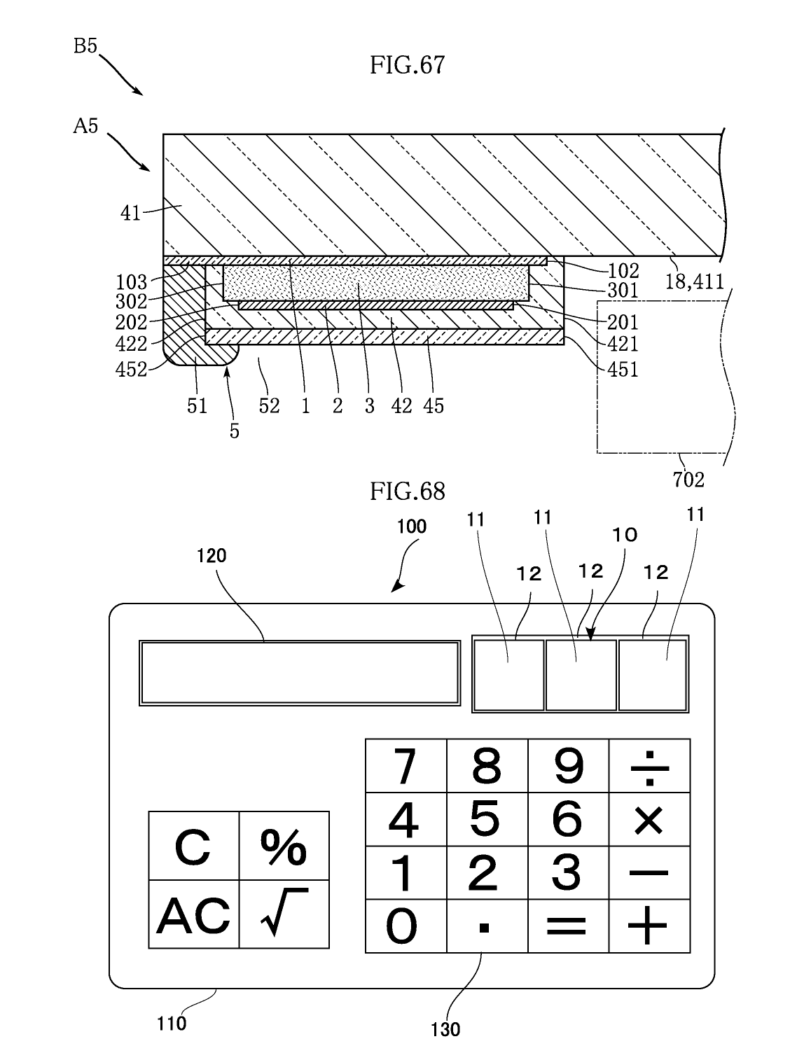

FIG. 66 and FIG. 67 illustrates variations of the present invention. In these drawings, the elements same as or similar to those of the foregoing embodiments are given the same numeral as above.

FIG. 66 illustrates a variation of the electronic device B5 and the organic thin film solar cell module A5. In this variation, the third edge 101 of the first conductive layer 1 is located at a position coinciding with the first edge 421 and the second edge 451, in plan view. In addition, the bus-bar section 51 on the inner side in the foregoing embodiment is not provided. Such a variation can be obtained by patterning the first conductive layer 1 with the aqua regia, using the resin cover layer 45 as the mask.

The mentioned variation also enables the portion adjacent to the first edge 421 and the second edge 451 to be finished with higher transparency, thereby allowing the display unit 702 to be more clearly exhibited in the outer appearance.

FIG. 67 illustrates another variation of the electronic device B5 and the organic thin film solar cell module A5. In this variation, the first conductive layer 1 includes a third inner recessed edge 102, instead of the third edge 101. The third inner recessed edge 102 is inwardly recessed with respect to the first edge 421 and the second edge 451, in plan view. In addition, the bus-bar section 51 on the inner side in the foregoing embodiment is not provided. Such a variation can be obtained by forming the third inner recessed edge 102 at the same time as the slit 19 and so forth, after forming the first conductive layer 1 on the base substrate 41.

The configuration according to the mentioned variation also enables the portion adjacent to the first edge 421 and the second edge 451 to be finished with higher transparency, thereby allowing the display unit 702 to be more clearly exhibited in the outer appearance.

The organic thin film solar cell module and the electronic device according to the present invention are in no way limited to the foregoing embodiments. The specific configurations of the elements of the organic thin film solar cell module and the electronic device according to the present invention may be modified in various manners.

The foregoing configuration according to the present invention is broadly applicable, in addition to the mobile phone terminal, to various electronic devices that utilize the photovoltaic generation, such as a wrist watch and an electronic calculator.

The technical features of the present invention may be expressed as the following appendices.

### Appendix 1B

An organic thin film solar cell module including:

a transparent base substrate;

a transparent first conductive layer disposed on the base substrate;

a second conductive layer;

a photoelectric conversion layer formed of an organic thin film and interposed between the first conductive layer and the second conductive layer; and

a passivation layer covering the second conductive layer,

in which the passivation film includes a first edge, and

the base substrate is exposed in a region adjacent to the first edge.

### Appendix 2B

The organic thin film solar cell module according to appendix 1B, in which the first conductive layer includes a third edge coinciding with the first edge in plan view.

### Appendix 3B

The organic thin film solar cell module according to appendix 1B, in which the first conductive layer includes a third inner recessed edge inwardly recessed with respect to the first edge, in plan view.

### Appendix 4B

The organic thin film solar cell module according to appendix 2B, in which the second conductive layer includes a fourth inner recessed edge inwardly recessed with respect to the first edge, in plan view.

### Appendix 5B

The organic thin film solar cell module according to appendix 4B, in which the photoelectric conversion layer includes a fifth inner recessed edge, inwardly recessed with respect to the first edge in plan view.

### Appendix 6B

The organic thin film solar cell module according to appendix 5B, in which the fourth inner recessed edge is inwardly recessed with respect to the fifth inner recessed edge, in plan view.

### Appendix 7B

The organic thin film solar cell module according to any one of appendices 4B to 6B, in which the first edge has an annular shape in plan view.

### Appendix 8B

The organic thin film solar cell module according to appendix 7B, in which the third edge has an annular shape in plan view.

### Appendix 9B

The organic thin film solar cell module according to appendix 3B, in which the third inner recessed edge has an annular shape in plan view.

### Appendix 10B

The organic thin film solar cell module according to appendix 8B or 9B, in which the fourth inner recessed edge has an annular shape in plan view.

### Appendix 11B

The organic thin film solar cell module according to appendix 10B, in which the fifth inner recessed edge has an annular shape in plan view.

### Appendix 12B

The organic thin film solar cell module according to any one of appendices 1B to 11B, in which the first conductive layer is formed of ITO.

### Appendix 13B

The organic thin film solar cell module according to any one of appendices 1B to 12B, in which the second conductive layer is formed of a metal.

### Appendix 14B

The organic thin film solar cell module according to appendix 13B, in which the second conductive layer is formed of A1.

### Appendix 15B

The organic thin film solar cell module according to any one of appendices 1B to 14B, in which the passivation film is formed of SiN.

### Appendix 16B

The organic thin film solar cell module according to any one of appendices 1B to 15B, further including a resin cover layer covering the passivation film, the resin cover layer including a second edge coinciding with the first edge in plan view.

### Appendix 17B

The organic thin film solar cell module according to appendix 16B, in which the second edge and the first edge form a continuous surface.

### Appendix 18B

The organic thin film solar cell module according to appendix 16B or 17B, in which the second edge has an annular shape in plan view.

### Appendix 19B

The organic thin film solar cell module according to any one of appendices 16B to 18B, in which the resin cover layer is formed of a UV-curable resin.

### Appendix 20B

The organic thin film solar cell module according to any one of appendices 16B to 19B, in which the resin cover layer includes a second outer edge located opposite to the second edge across at least a part of the photoelectric conversion layer in plan view,

the passivation film includes a first outer edge coinciding with the second outer edge in plan view,

the first conductive layer includes an extended portion extending outward from the second outer edge and the first outer edge, and

the organic thin film solar cell module further includes a bypass conductive section covering at least a part of the extended portion, and formed of a material having lower resistance than a material of the first conductive layer.

### Appendix 21B

The organic thin film solar cell module according to appendix 20B, in which the second outer edge and the first outer edge form a continuous surface.

### Appendix 22B

The organic thin film solar cell module according to appendix 20B or 21B, in which the bypass conductive section covers the second outer edge and the first outer edge.

### Appendix 23B

The organic thin film solar cell module according to any one of appendices 20B to 22B, in which the bypass conductive section includes AgB or carbon.

### Appendix 24B

The organic thin film solar cell module according to any one of appendices 20B to 23B, in which the second conductive layer includes a fourth outer recessed edge, inwardly recessed with respect to the second outer edge and the first outer edge, in plan view.

### Appendix 25B

The organic thin film solar cell module according to any one of appendices 20B to 24B, in which the photoelectric conversion layer includes a fifth outer recessed edge, inwardly recessed with respect to the second outer edge and the first outer edge in plan view.

### Appendix 26B

An electronic device including:

the organic thin film solar cell module according to any one of appendices 1B to 25B; and

a drive unit to operate by power supplied from the organic thin film solar cell module.

### Appendix 27B

A method of manufacturing an organic thin film solar cell module, the method including:

disposing a transparent first conductive layer on a transparent base substrate;

disposing a photoelectric conversion layer formed of an organic thin film on the first conductive layer;

disposing a second conductive layer on the photoelectric conversion layer;

forming a passivation film so as to cover the second conductive layer;

partially removing the passivation film in a region delimited by the second edge, thereby forming, in the passivation film, a first edge coinciding with the second edge in plan view; and partially removing the first conductive layer, thereby exposing the base substrate in a region adjacent to the second edge and the first edge.

### Appendix 28B

The method according to appendix 27B, in which the exposing of the base substrate includes forming, in the first conductive layer, a third edge coinciding with the second edge and the first edge in plan view.

### Appendix 29B

The method according to appendix 28B, in which the second edge and the first edge are formed in an annular shape in plan view.

### Appendix 30B

The method according to appendix 29B, in which the third edge is formed in an annular shape in plan view.

### Appendix 31B

The method according to any one of appendices 27B to 30B, in which the first conductive layer is formed of ITO.

### Appendix 32B

The method according to any one of appendices 27B to 31B, in which the second conductive layer is formed of a metal.

### Appendix 33B

The method according to appendix 32B, in which the second conductive layer is formed of A1.

### Appendix 34B

The method according to any one of appendices 27B to 33B, in which the passivation film is formed of SiN.

### Appendix 35B

The method according to any one of appendices 27B to 34B, in which the resin cover layer is formed of a UV-curable resin.

### Appendix 36B

The method according to any one of appendices 27B to 35B, in which the disposing of the resin cover layer includes forming a second outer edge at a position opposite to the second edge across at least a part of the photoelectric conversion layer in plan view,

partially removing the insulation film in a region delimited by the second edge, thereby forming, in the passivation layer, a first outer edge coinciding with the second outer edge in plan view, and

forming a bypass conductive section so as to cover at least a part of an extended portion extending outward from the second outer edge and the first outer edge of the first conductive layer, the bypass conductive section being formed of a material having lower resistance than a material of the first conductive layer.

### Appendix 37B

The method according to appendix 36B, in which the forming of the bypass conductive section includes covering the second outer edge and the first outer edge with the bypass conductive section.

### Appendix 38B

The method according to appendix 36B or 37B, in which forming of the bypass conductive section includes employing AgB or carbon.

### Seventh to Twelfth Embodiments

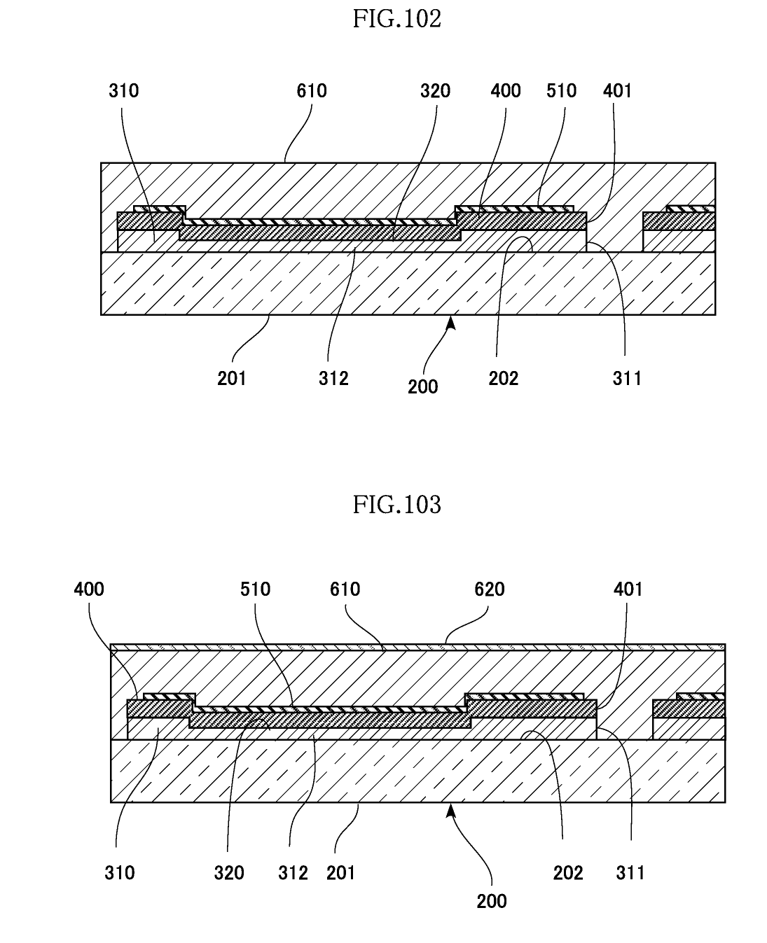

The reference numerals used for seventh to twelfth embodiments and FIG. 68 to FIG. 112 are given for these particular embodiment and drawings, and independent of numerals used for other embodiments and drawings. It should be noted, however, that the arrangements of the fifth and sixth embodiments and those of any other embodiment may be combined or exchanged in an appropriate manner.

The term “transparent” used herein may be defined as having a transmittance of approximately 50% or higher. The term “transparent” may also be used for visible light when it is colorless and clear. The visible light corresponds to a wavelength range of approximately 360 nm to 830 nm and an energy range of approximately 3.45 eV to 1.49 eV. When a transmittance of a substance is 50% or higher in these ranges, that substance may be regarded as transparent.

FIG. 68 illustrates an electronic device 100 including an organic thin film solar cell 10 according to the present invention. The electronic device 100 is a desktop electronic calculator. The electronic device 100 includes a display unit 120 located on the surface of a casing 110, an input unit 130, and the organic thin film solar cell 10. The display unit 120 is, for example, an LCD device. The input unit 130 is what is known as a tenkey. The electronic device 100 displays a result of calculation performed according to inputs made through the input unit 130, on the display unit 120. The power used for the calculation and the display is generated by the organic thin film solar cell 10. In the organic thin film solar cell 10, a light receiving surface 11 is incorporated so as to appear in the surface of the casing 110. In the organic thin film solar cell 10, a plurality of rectangular cells 12 are aligned in a transverse direction, each of the cells 12 representing a design D that can be visually recognized from outside, made up as desired based on the configuration described hereunder, in which the distinctive feature of the present invention is reflected.

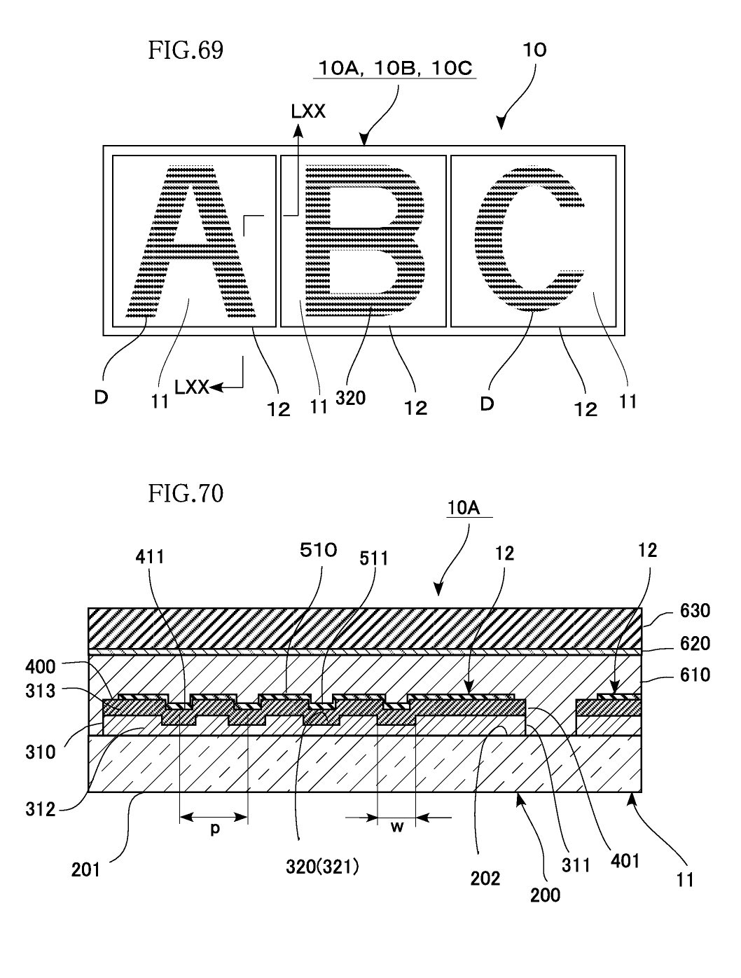

FIG. 69 is a plan view showing organic thin film solar cells 10A to 10C according to seventh to ninth embodiments of the present invention, respectively, and FIG. 70 is a cross-sectional view taken along a line LXX-LXX in FIG. 69, showing a configuration of the organic thin film solar cell 10A according to the seventh embodiment. In FIG. 70, the light receiving surface 11 is oriented downward.

The organic thin film solar cell 10A includes a base substrate 200, a first electrode layer 310, a photoelectric conversion layer 400, a second electrode layer 510, a passivation layer 610, a bonding layer 620, and a cover layer 630.

The base substrate 200 has a first surface 201, and a second surface 202 opposite thereto, and is formed of a transparent material such as glass or a resin. The thickness of the base substrate 200 is, for example, 0.05 mm to 2.0 mm, but not limited to such values.

The first electrode layer 310 is formed on the second surface 202 of the base substrate 200. The first electrode layer 310 is transparent, and formed of UTO in this embodiment. The first electrode layer 310 is partitioned into the individual cells 12, by a slit 311 formed so as to penetrate in the thickness direction. The first electrode layer 310 also includes thin-wall portions 312, formed on the surface opposite to the base substrate 200 by making recesses (opening sections) 320. An ordinary portion 313 of the first electrode layer 310 has a thickness of 100 to 200 nm for example, and the thin-wall portions 312 have a thickness of 50 to 100 nm, for example, and further details and the technical significance of the thin-wall portions 312 will be described below. In the first electrode layer 310, carriers created by the photoelectric conversion layer 400 are collected.

The photoelectric conversion layer 400 is disposed on the first electrode layer 310, on the opposite side to the base substrate 200. The photoelectric conversion layer 400 is partitioned into the cells 12 by slits 401 coinciding with the slits 311 of the first electrode layer 310 in plan view. Accordingly, the end face of the first electrode layer 310 defining the slit 311 and the end face of the photoelectric conversion layer 400 defining the slit 401 are flush with each other. The photoelectric conversion layer 400 is formed of an organic thin film, and configured to perform a photoelectric conversion function, to convert received light into electric power. Although the configuration of the photoelectric conversion layer 400 is not specifically limited, the photoelectric conversion layer 3 may include, for example, a bulk heterojunction organic active layer and a hole transport layer disposed on the bulk heterojunction organic active layer on the side of the first conductive layer 310. The photoelectric conversion layer 400 has a thickness of, for example, 100 nm to 200 nm. The photoelectric conversion layer 400 includes an uneven portion 411 that reflects the shape of the recess 320 formed in the first electrode layer 310. Here, it is not mandatory that the photoelectric conversion layer 400 includes the uneven portion 411.

In the bulk heterojunction organic active layer, p-type organic active layer regions and n-type organic active layer regions are intermixed, forming a complicated bulk hetero pn junction. The p-type organic active layer region is, for example, formed of poly(3-hexylthiophene-2,5diyl) (P3HT), and the n-type organic active layer region is formed of 6,6-phenyl-C61-butyric acid methyl ester (PCBM), for example. The hole transport layer is formed of, for example, PEDOT:PSS.

Examples of materials that may be utilized to form the photoelectric conversion layer 3 include phthalocyanine (Pc), zinc-phthalocyanine (ZnPc), N,N′-dimethyl perylene-3,4,9,10-dicarboximide (Me-Ptcdi), and Buckminster fullerene (C60). These materials are, for example, utilized for vacuum vapor deposition.

In addition, poly[2-methoxy-5-(3,7-dimethyl octyloxy)]-1,4-phenylene vinylene (MDMO-PPV), poly[N-9′-hepta-decanyl-2,7-carbazole-alt-5,5-(4′,7′-di-thienyl-2′1′,3′-b3nzothiadizaole)] (PCDTBT), 6,6-phenyl-C61-butyric acid methyl ester (PC60BM), or 6,6-phenyl-C71-butyric acid methyl ester (PC70BM) may be utilized to form the photoelectric conversion layer 3. These materials are, for example, utilized for a solution process.

Each of the cells 12 of the second electrode layer 510 is disposed on the photoelectric conversion layer 400, such that the photoelectric conversion layer 400 is interposed between the first electrode layer 310 and the second surface 202 of the base substrate 200, in the thickness direction. In this embodiment the second electrode layer 510 is formed of A1, however the material of the second electrode layer 510 is not specifically limited, and one of polarizable metals, typically W, Mo, Mn, Mg, Au, and Ag, may be adopted. Therefore, the second electrode layer 2 is not transparent but non-transparent, according to the aforementioned definition. In this case, a non-illustrated passive film of Al₂O₃ may be formed on the surface of the second electrode layer 510 opposite to the base substrate 200. The second conductive layer 2 has a thickness of, for example, 100 nm to 200 nm. In the second electrode layer 510, the carriers created by the photoelectric conversion layer are collected. The second electrode layer 510 includes, like the photoelectric conversion layer 400, an uneven portion 511 reflecting the shape of the recess 320 formed in the first electrode layer 310. However, it is not mandatory that the second electrode layer 510 includes the uneven portion 511.

The passivation layer 610 is disposed on the second electrode layer 510, so as to protect the second electrode layer 510 and the photoelectric conversion layer 400, and also enters the slit 311 defining each of the cells 12 so as to closely contact the base substrate 200 at the bottom of the slit 311. The passivation layer 610 is, for example, formed of SiN, SiO2, or SiON. The passivation layer 42 has a thickness of, for example, 0.5 μm to 2.0 μm, which is thicker than the first electrode layer 310, the photoelectric conversion layer 400, and the second electrode layer 510. Accordingly, the passivation layer 42 prevents intrusion of moisture or particles from outside into the photoelectric conversion layer 400, thereby improving the durability of the organic thin film solar cell 10A. It is preferable to form the passivation layer 610 in such a thickness that the surface thereof can be made flat, without being affected by the recess 320 formed in the first electrode layer 310.

The bonding layer 620 serves to bond the passivation layer 610 and the cover layer 630 and is, for example, a resin-based adhesive layer.

The cover layer 630 serves to protect the organic thin film solar cell 10A from the opposite side of the base substrate 200. Preferably, the cover layer 630 may be formed of glass or a film, however other transparent materials may be adopted as the case may be, provided that the material is capable of protecting the organic thin film solar cell 10A. The cover layer 44 has a thickness of, for example, 30 μm to 100 μm.

As described above, the first electrode layer 310 includes the thin-wall portions 312, formed on the surface opposite to the base substrate 200 by making recesses (opening sections). The thin-wall portions 312 are utilized to exhibit the design D to be visually recognized from the side of the first surface 201 of the base substrate 200. In this embodiment, as illustrated in detail in FIG. 70, a plurality of linearly extending fine recessed grooves 321, each having a width w of 5 to 20 μm for example, are formed at a pitch p as narrow as 30 to 50 μm, on the surface of the first electrode layer 310 opposite to the base substrate 200. Because of such recessed grooves 321, the region where the recessed grooves 321 are formed can be visually recognized as a hologram when viewed from the side of the first surface 201 of the base substrate 200, owing to the diffraction of light at the stepped portions of the finely formed recessed grooves 321. Therefore, the design D, such as a character or a pattern, can be exhibited as a hologram, as shown in FIG. 69, on the first surface 201 of the base substrate 200, in other words the light receiving surface 11 of the organic thin film solar cell 10A, by determining as desired the plan-view shape of the region where the fine recessed grooves 321 are to be formed. Further, as mentioned above, the photoelectric conversion layer 400 and the second electrode layer 510 respectively include the uneven portions 411 and 511 reflecting the shape of the recess 320 formed in the first electrode layer 310. Therefore, provided that the passivation layer 610, the bonding layer 620, and the cover layer 630 are transparent, the design D is exhibited as a hologram as shown in FIG. 78, even when the organic thin film solar cell 10A is observed from the rear side.

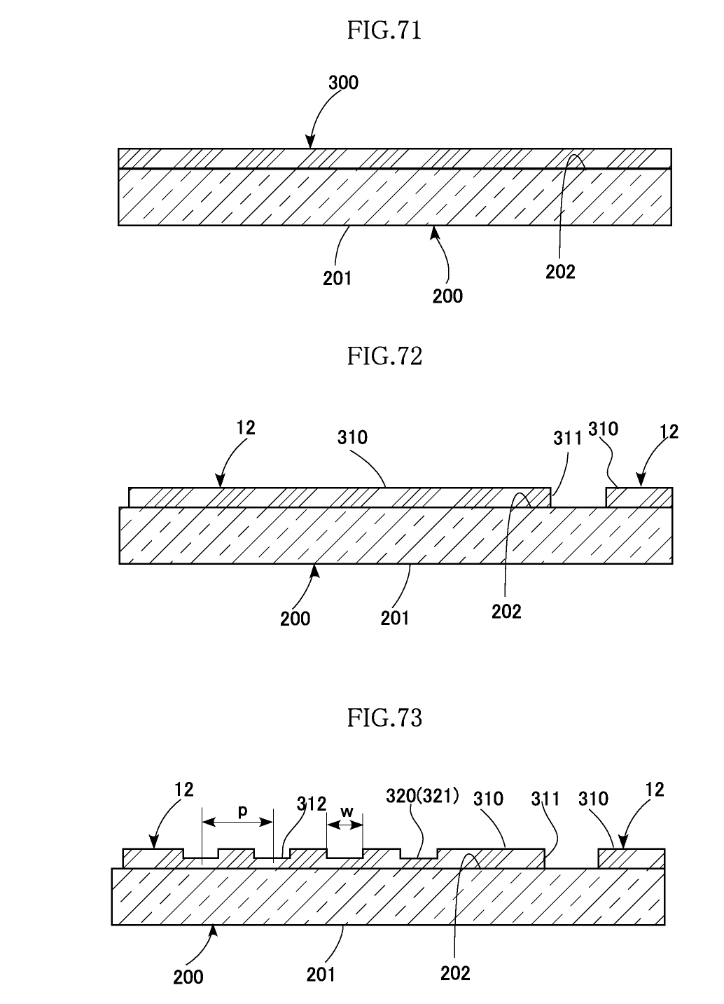

Referring now to FIG. 71 to FIG. 77, a manufacturing method of the organic thin film solar cell 10A will be described hereunder.

Referring first to FIG. 71, the base substrate 200 is prepared, and ITO 300 is formed on the second surface 202 of the base substrate 200 by a known method such as sputtering. Proceeding to FIG. 72, the ITO 300 is patterned to form the first electrode layer 310 partitioned into the rectangular cells 12. The partitioned portions of the first electrode layer 310 are independent from each other, such that the first electrode layers 310 adjacent to each other are isolated by the slit 311. For the patterning of the ITO, for example, wet etching, dry etching, or laser patterning is adopted as the case may be. Without limitation to the above, the first electrode layer 310 may be formed by directly patterning the ITO on the second surface 202 of the base substrate 200, for example through a printing process.

Proceeding to FIG. 73, the recessed grooves (opening sections) 321 are formed on the exposed surface of the first electrode layer 310 (opposite to the base substrate 200), to form the thin-wall portions 312. More specifically, the recessed grooves 321 are formed on the region of the first electrode layer 310 where the design D is to be exhibited. In this embodiment, as mentioned above, the first electrode layer 310 has a thickness of 100 to 200 nm, the recessed grooves 321 are fine lines having a width w of 5 to 20 μm for example, and aligned at a pitch p of 30 to 50 μm. The thin-wall portions 312 have a thickness of 50 to 100 nm, and hence the depth of the recessed groove 321 is 50 to 100 nm. To form such fine recessed groove 321 having a narrow width w at a fine pitch p, on the first electrode layer 310 which is extremely thin, it is preferable to scan the first electrode layer 310 with a laser spot with a predetermined output. Here, the process of forming the slit 311 in the ITO 300 thereby forming the first electrode layer 310 partitioned into individual cells 12 (FIG. 72) and the process of forming the recessed groove 321 in the first electrode layer 310 thereby forming the thin-wall portions 312 (FIG. 73) may be performed in a reversed order.

The process of forming the recessed groove 321 in the first electrode layer 310 may be performed at the same time as forming the slit 311 in the ITO 300, by dry etching. In this case, the recessed grooves 321 and the slit 311, different in removal depth from each other, can be formed at the same time, by setting the opening width for the recessed groove 321 in the resist to be narrower than the opening width for the slit 311, and performing the etching at different etching rates.

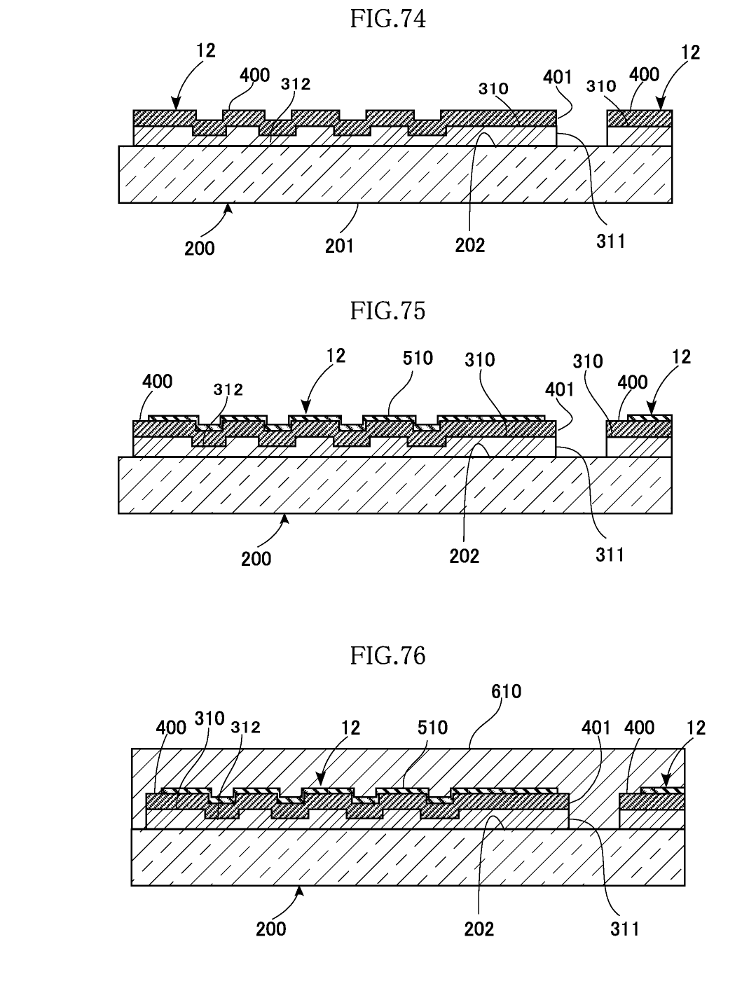

Proceeding to FIG. 74, the photoelectric conversion layer 400 is formed. To form the photoelectric conversion layer 400, an organic film is deposited on the base substrate 200 and the first electrode layer 310 for example by spin coating, and the organic film is patterned into a planar shape that matches the planar shape of the first electrode layer 310 of a rectangular shape, by oxygen plasma etching or laser patterning. Without limitation to the above, the photoelectric conversion layer 400 may be formed by directly patterning the organic film on the base substrate 200 and the first electrode layer 310, for example by slit coating, capillary coating, gravure printing, or screen printing.

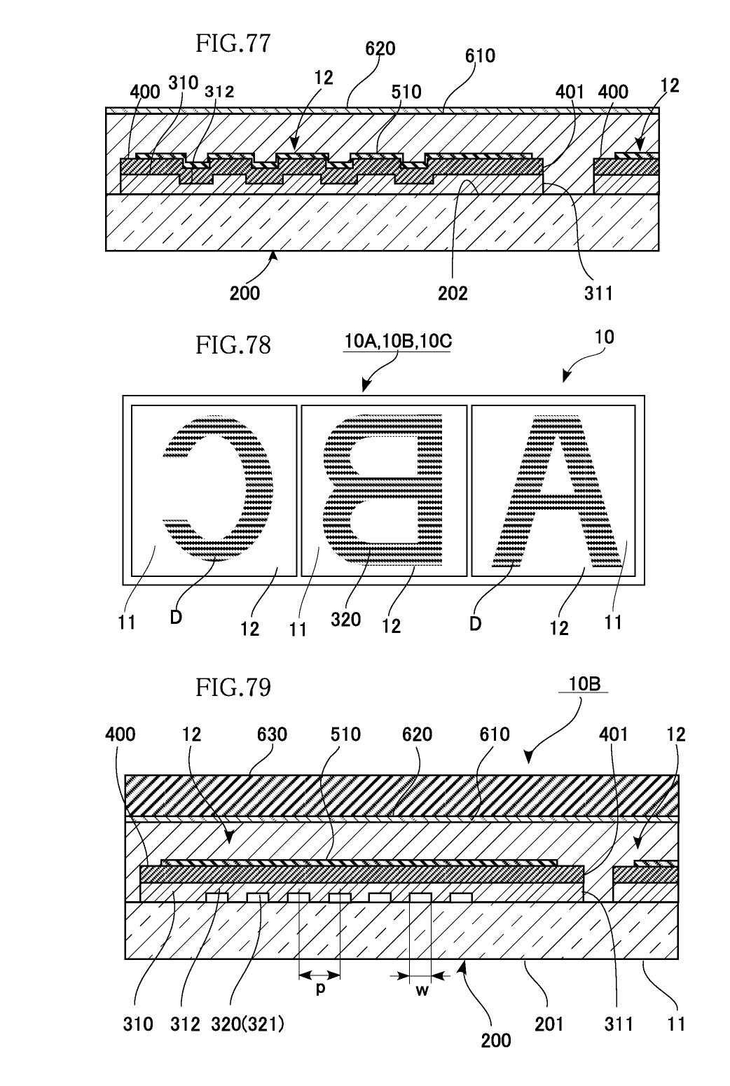

Proceeding to FIG. 75, the second electrode layer 510 is formed. To form the second electrode layer 510, for example, one of the aforementioned metals is deposited by vacuum vapor deposition on the base substrate 200, the first electrode layer 310, and the photoelectric conversion layer 400, to deposit a metal film thereon. Then the metal film is patterned, for example by etching with a mask layer. Through such patterning, the second electrode layer 510 is formed on the photoelectric conversion layer 400. Thereafter, as shown in FIG. 76, SiN, SiO₂, or SiON is deposited over the base substrate 200, the first electrode layer 310, the photoelectric conversion layer 400, and the second electrode layer 510, for example by plasma CVD, to form the passivation layer 610. Then a cover layer is bonded to the passivation layer 610, via the bonding layer 620 (FIG. 77). Through the mentioned process, the organic thin film solar cell 10A shown in FIG. 70 can be obtained.

The organic thin film solar cell 10A provides the following advantageous effects.

In the organic thin film solar cell 10A according to this embodiment, the recesses (opening sections) 320 are formed in the first electrode layer 310 between the base substrate 200 and the photoelectric conversion layer 400 to form the thin-wall portions 312 constituting the design D, such that the design D can be visually recognized from the side of the base substrate 200. Therefore, the design D can be exhibited on light receiving surface 11 of the organic thin film solar cell 10A, without the need to form an additional component in the organic thin film solar cell 10 or print a pattern on the outer surface. Further, the display quality of the design D can be maintained, without the risk of quality degradation or disappearance of the design itself, because of contacts or friction with other objects.

In the organic thin film solar cell 10A according to this embodiment, the design D can be exhibited as a hologram such that the design D can be visually recognized in the light receiving surface 11, by processing the first electrode layer 310. This is useful as countermeasure against imitations of the organic thin film solar cell 10A, or the electronic device 100 incorporated with the same.

In the organic thin film solar cell 10A according to this embodiment, further, the thin-wall portions 312 are formed in the first electrode layer 310 so as not to penetrate therethrough, to constitute the design D. Accordingly, the effective generation area in the photoelectric conversion layer 400 is not affected at all, by the forming of the design D. Consequently, degradation in power generation efficiency of the organic thin film solar cell 10A can be prevented, despite forming the design D.

FIG. 79 is an enlarged cross-sectional view corresponding to the view taken along the line LXX-LXX in FIG. 69, and showing a configuration of an organic thin film solar cell 10B according to the eighth embodiment of the present invention. In FIG. 79, the elements same as or similar to those of the organic thin film solar cell 10A according to the seventh embodiment shown in FIG. 70 are given the same numeral.

The organic thin film solar cell 10B includes the base substrate 200, the first electrode layer 310, the photoelectric conversion layer 400, the second electrode layer 510, the passivation layer 610, the bonding layer 620, and the cover layer 630.

The base substrate 200 has a first surface 201, and a second surface 202 opposite thereto, and is formed of a transparent material such as glass or a resin. The thickness of the base substrate 200 is, for example, 0.05 mm to 2.0 mm, but not limited to such values.

The first electrode layer 310 is formed on the second surface 202 of the base substrate 200. The first electrode layer 310 is transparent, and formed of UTO in this embodiment. The first electrode layer 310 is partitioned into the individual cells 12, by the slit 311 formed so as to penetrate in the thickness direction. The first electrode layer 310 also includes the thin-wall portions 312, formed on the surface opposite to the base substrate 200 by making the recesses (opening sections) 320. An ordinary portion 313 of the first electrode layer 310 has a thickness of 100 to 200 nm for example, and the thin-wall portions 312 have a thickness of 50 to 100 nm, for example. In the first electrode layer 310, carriers created by the photoelectric conversion layer 400 are collected.

The photoelectric conversion layer 400 is disposed on the first electrode layer 310, on the opposite side to the base substrate 200. The photoelectric conversion layer 400 is partitioned into the cells 12 by the slits 401 coinciding with the slits 311 of the first electrode layer 310 in plan view. Accordingly, the end face of the first electrode layer 310 defining the slit 311 and the end face of the photoelectric conversion layer 400 defining the slit 401 are flush with each other. The photoelectric conversion layer 400 is formed of an organic thin film, and configured to perform a photoelectric conversion function, to convert received light into electric power. The specific configuration of the photoelectric conversion layer 400 is the same as that of the organic thin film solar cell 10A of the seventh embodiment. The photoelectric conversion layer 400 has a thickness of, for example, 100 nm to 200 nm.

Each of the cells 12 of the second electrode layer 510 is disposed on the photoelectric conversion layer 400, such that the photoelectric conversion layer 400 is interposed between the first electrode layer 310 and the second surface 202 of the base substrate 200, in the thickness direction. In this embodiment the second electrode layer 510 is formed of A1, however the material of the second electrode layer 510 is not specifically limited and, as described regarding the seventh embodiment, one of polarizable metals, typically W, Mo, Mn, Mg, Au, and Ag, may be adopted. Therefore, the second electrode layer 2 is not transparent but non-transparent, according to the aforementioned definition. In this case, a non-illustrated passive film of Al₂O₃ may be formed on the surface of the second electrode layer 510 opposite to the base substrate 200. The second conductive layer 2 has a thickness of, for example, 100 nm to 200 nm. In the second electrode layer 510, the carriers created by the photoelectric conversion layer are collected.

The passivation layer 610 is disposed on the second electrode layer 510, so as to protect the second electrode layer 510 and the photoelectric conversion layer 400, and also enters the slit 311 defining each of the cells 12 so as to closely contact the base substrate 200 at the bottom of the slit 311. The passivation layer 610 is, for example, formed of SiN, SiO2, or SiON. The passivation layer 42 has a thickness of, for example, 0.5 μm to 2.0 μm, which is thicker than the first electrode layer 310, the photoelectric conversion layer 400, and the second electrode layer 510. Accordingly, the passivation layer 42 prevents intrusion of moisture or particles from outside into the photoelectric conversion layer 400, thereby improving the durability of the organic thin film solar cell 10B.

The bonding layer 620 serves to bond the passivation layer 610 and the cover layer 630 and is, for example, a resin-based adhesive layer.

The cover layer 630 serves to protect the organic thin film solar cell 10B from the opposite side of the base substrate 200. Preferably, the cover layer 630 may be formed of glass or a film, however other transparent materials may be adopted as the case may be, provided that the material is capable of protecting the organic thin film solar cell 10B. The cover layer 44 has a thickness of, for example, 30 μm to 100 μm.

As described above, the first electrode layer 310 includes the thin-wall portions 312, formed on the surface opposite to the base substrate 200 by making the recesses (opening sections). The thin-wall portions 312 are, as will be described below, utilized to exhibit the design D to be visually recognized from the side of the first surface 201 of the base substrate 200. In this embodiment, as illustrated in detail in FIG. 78, a plurality of linearly extending fine recessed grooves 321, each having a width w of 5 to 20 μm for example, are formed at a pitch p as narrow as 30 to 50 μm, on the surface of the first electrode layer 310 on the side of the base substrate 200. Because of such recessed grooves 321, the region where the recessed grooves 321 are formed can be visually recognized as a hologram when viewed from the side of the first surface 201 of the base substrate 200, owing to the diffraction of light at the stepped portions of the finely formed recessed grooves 321. Therefore, the design D, such as a character or a pattern, can be exhibited as a hologram, as shown in FIG. 70, on the first surface of the base substrate 200, in other words the light receiving surface 11 of the organic thin film solar cell 10B, by determining as desired the plan-view shape of the region where the fine recessed grooves 321 are to be formed. Further, in the organic thin film solar cell 10B, the first electrode layer 310 includes the recessed grooves 321 formed on the side of the base substrate 200. Accordingly, the surface of the first electrode layer 310 opposite to the base substrate 200 can be made flat, and hence the surface of the photoelectric conversion layer 400 and the second electrode layer 610 can also be made flat.

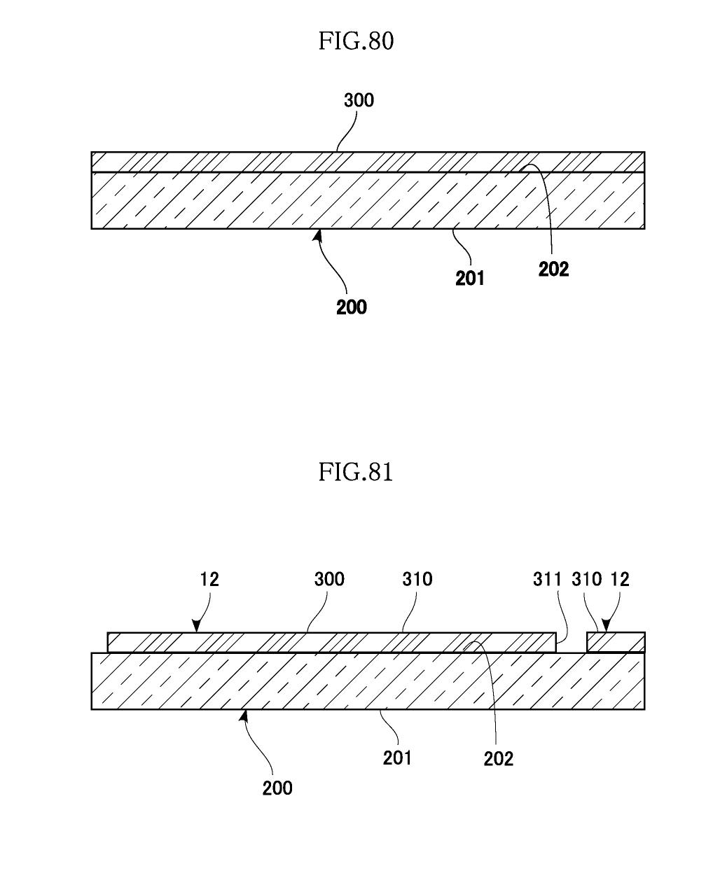

Referring now to FIG. 80 to FIG. 86, a manufacturing method of the organic thin film solar cell 10B will be described hereunder.

Referring first to FIG. 80, the base substrate 200 is prepared, and the ITO 300 is formed on the second surface 202 of the base substrate 200 by a known method such as sputtering. Proceeding to FIG. 81, the ITO 300 is patterned to form the first electrode layer 310 partitioned into the rectangular cells 12. The partitioned portions of the first electrode layer 310 are independent from each other, such that the first electrode layers 310 adjacent to each other are isolated by the slit 311. For the patterning of the ITO, for example, wet etching, dry etching, or laser patterning is adopted as the case may be. Without limitation to the above, the first electrode layer 310 may be formed by directly patterning the ITO on the second surface 202 of the base substrate 200, for example through a printing process.

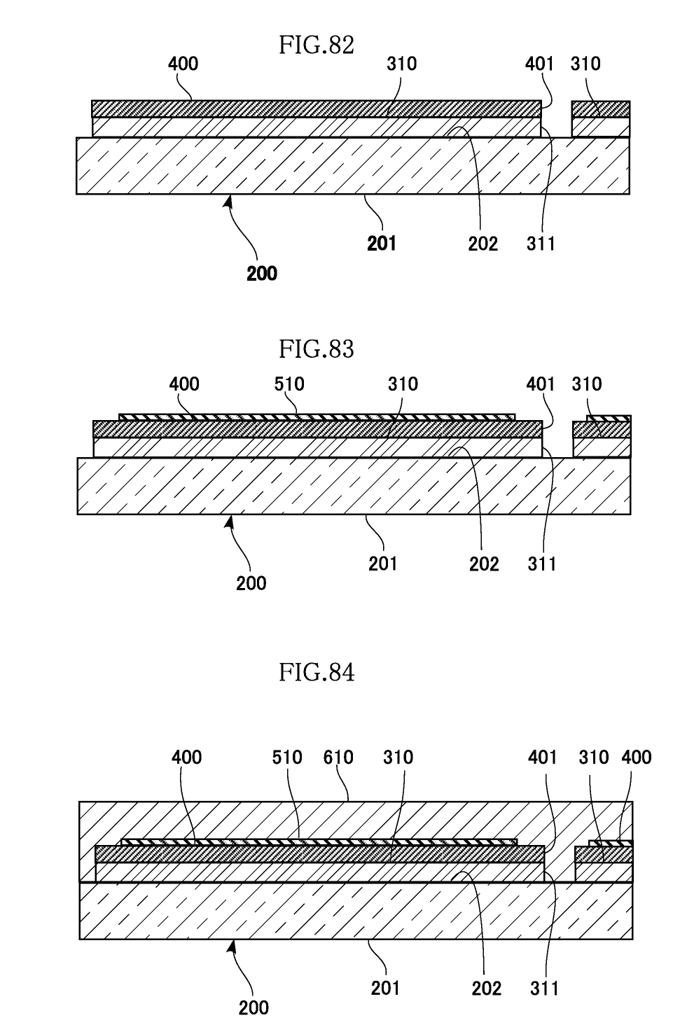

Proceeding to FIG. 82, the photoelectric conversion layer 400 is formed. To form the photoelectric conversion layer 400, an organic film is deposited on the base substrate 200 and the first electrode layer 310 for example by spin coating, and the organic film is patterned into a planar shape that matches the planar shape of the first electrode layer 310 of a rectangular shape, by oxygen plasma etching or laser patterning. Without limitation to the above, the photoelectric conversion layer 400 may be formed by directly patterning the organic film on the base substrate 200 and the first electrode layer 310, for example by slit coating, capillary coating, gravure printing, or screen printing.

Proceeding to FIG. 83, the second electrode layer 510 is formed. To form the second electrode layer 510, for example, one of the aforementioned metals is deposited by vacuum vapor deposition on the base substrate 200, the first electrode layer 310, and the photoelectric conversion layer 400, to deposit a metal film thereon. Then the metal film is patterned, for example by etching with a mask layer. Through such patterning, the second electrode layer 510 is formed on the photoelectric conversion layer 400. Thereafter, as shown in FIG. 84, SiN, SiO₂, or SiON is deposited over the base substrate 200, the first electrode layer 310, the photoelectric conversion layer 400, and the second electrode layer 510, for example by plasma CVD, to form the passivation layer 610.

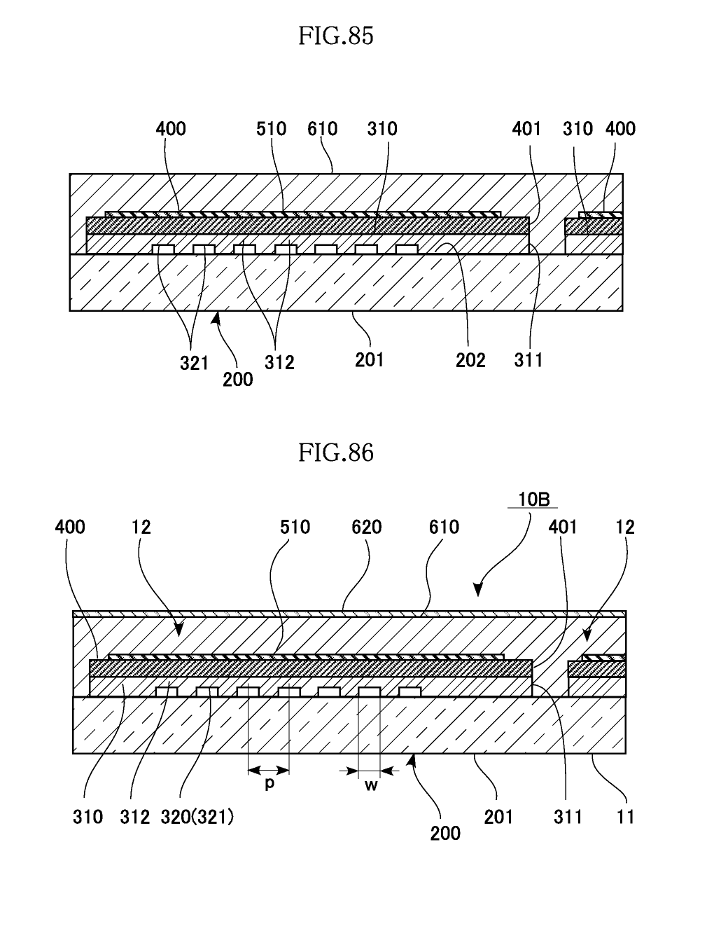

Proceeding to FIG. 85, the recessed grooves (opening sections) 321 are formed on the surface of the first electrode layer 310 on the side of the base substrate 200, to form the thin-wall portions 312. More specifically, the recessed grooves 321 are formed on the region of the first electrode layer 310 where the design D is to be exhibited. In this embodiment, as mentioned above, the first electrode layer 310 has a thickness of 100 to 200 nm, the recessed grooves 321 each have a width w of 5 to 20 μm for example, and are aligned at a pitch p of 30 to 50 μm. The thin-wall portions 312 have a thickness of 50 to 100 nm, and hence the depth of the recessed groove 321 is 50 to 100 nm. To form such fine recessed groove 321 having a narrow width w at a fine pitch p, on the first electrode layer 310 which is extremely thin, it is preferable to scan the first electrode layer 310 with a laser spot with a predetermined output.

Then the cover layer 630 is bonded to the passivation layer 610, via the bonding layer 620 (FIG. 86). Through the mentioned process, the organic thin film solar cell 10B shown in FIG. 79 can be obtained.

To form the recessed grooves (opening sections) 321 in the surface of the first electrode layer 310 on the side of the base substrate 200, to thereby form the thin-wall portions 312, the first surface is irradiated with the laser beam from the side of the base substrate 200, and also scanned with the laser spot, as described above. This process may be performed at a desired point among after the formation of the first electrode layer 310, after the formation of the photoelectric conversion layer 400, after the formation of the second electrode layer 510, and after the formation of the cover layer 630. In the case of forming the recessed grooves 321 in the surface of the first electrode layer 310 on the side of the base substrate 200 after forming the cover layer 630, the recessed grooves 321 are formed after the solar cell 10B is further reinforced with the cover layer 630 in the manufacturing process. Therefore, the reliability of the solar cell 10B can be improved.

The organic thin film solar cell 10B provides the following advantageous effects.

In the organic thin film solar cell 10B according to this embodiment, the recessed grooves (opening sections) 321 are formed in the first electrode layer 310 between the base substrate 200 and the photoelectric conversion layer 400 to form the thin-wall portions 312 constituting the design D, such that the design D can be visually recognized from the side of the base substrate 200. Therefore, the design D can be exhibited on light receiving surface 11 of the organic thin film solar cell 10B, without the need to form an additional component in the organic thin film solar cell 10B or print a pattern on the outer surface. Further, the display quality of the design D can be maintained, without the risk of quality degradation or disappearance of the design itself, because of contacts or friction with other objects.

In the organic thin film solar cell 10B according to this embodiment, the design D can be exhibited as a hologram such that the design D can be visually recognized in the light receiving surface 11, by processing the first electrode layer 310. This is useful as countermeasure against imitations of the organic thin film solar cell 10B, or the electronic device 100 incorporated with the same.

In the organic thin film solar cell 10B according to this embodiment, further, the thin-wall portions 312 are formed in the first electrode layer 310 so as not to penetrate therethrough, to constitute the design D. Accordingly, the effective generation area in the photoelectric conversion layer 400 is not affected at all, by the forming of the design D. Consequently, degradation in power generation efficiency of the organic thin film solar cell 10B can be prevented, despite forming the design D.

In the organic thin film solar cell 10B according to this embodiment, further, the recessed grooves (opening sections) 321 are formed in the surface of the first electrode layer 310 on the side of the base substrate 200. Therefore, light incident from the side of the base substrate 200 is scattered in the space surrounded by the base substrate 200 and the recessed groove 321. Consequently, the amount of light incident onto the photoelectric conversion layer 400 can be increased, and the power generation efficiency can be improved.

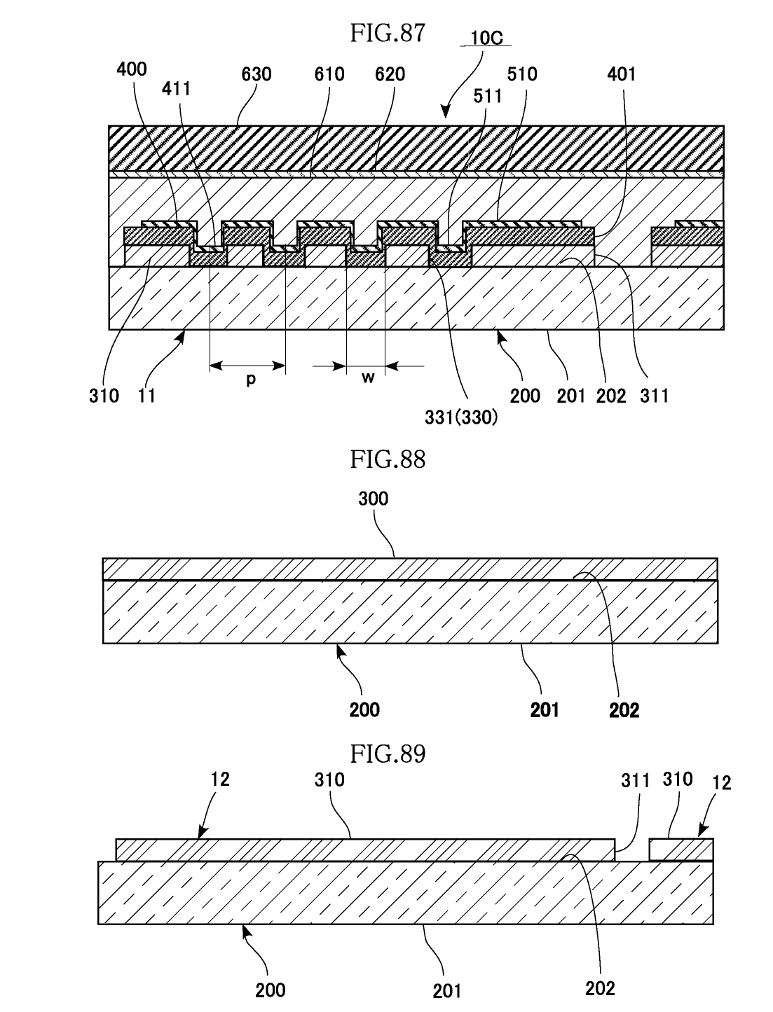

FIG. 87 is a cross-sectional view corresponding to the view taken along the line LXX-LXX in FIG. 69, and showing a configuration of an organic thin film solar cell 10C according to the ninth embodiment of the present invention. In FIG. 87, the elements same as or similar to those of the organic thin film solar cell 10A according to the seventh embodiment shown in FIG. 70 are given the same numeral.

The organic thin film solar cell 10C includes the base substrate 200, the first electrode layer 310, the photoelectric conversion layer 400, the second electrode layer 510, the passivation layer 610, the bonding layer 620, and the cover layer 630.

The base substrate 200 has a first surface 201, and a second surface 202 opposite thereto, and is formed of a transparent material such as glass or a resin. The thickness of the base substrate 200 is, for example, 0.05 mm to 2.0 mm, but not limited to such values.

The first electrode layer 310 is formed on the second surface 202 of the base substrate 200. The first electrode layer 310 is transparent, and formed of UTO in this embodiment. The first electrode layer 310 is partitioned into the individual cells 12, by a slit 311 formed so as to penetrate in the thickness direction. The first electrode layer 310 also includes perforated portions (opening sections) 330 formed so as to penetrate therethrough in the thickness direction. An ordinary portion 313 of the first electrode layer 310 has a thickness of, for example, 100 to 200 nm, and further details and the technical significance of the perforated portion 330 will be described below. In the first electrode layer 310, carriers created by the photoelectric conversion layer 400 are collected.

The photoelectric conversion layer 400 is disposed on the first electrode layer 310, on the opposite side to the base substrate 200. The photoelectric conversion layer 400 is partitioned into the cells 12 by the slits 401 coinciding with the slits 311 of the first electrode layer 310 in plan view. Accordingly, the end face of the first electrode layer 310 defining the slit 311 and the end face of the photoelectric conversion layer 400 defining the slit 401 are flush with each other. The photoelectric conversion layer 400 is formed of an organic thin film, and configured to perform a photoelectric conversion function, to convert received light into electric power. The specific configuration of the photoelectric conversion layer 400 is the same as that of the organic thin film solar cell 10 of the seventh embodiment. The photoelectric conversion layer 400 has a thickness of, for example, 100 nm to 200 nm. The photoelectric conversion layer 400 includes the uneven portion 411 that reflects the shape of the perforated portion 330 formed in the first electrode layer 310. Here, it is not mandatory that the photoelectric conversion layer 400 includes the uneven portion 411.

Each of the cells 12 of the second electrode layer 510 is disposed on the photoelectric conversion layer 400, such that the photoelectric conversion layer 400 is interposed between the first electrode layer 310 and the second surface 202 of the base substrate 200, in the thickness direction. In this embodiment the second electrode layer 510 is formed of A1, however the material of the second electrode layer 510 is not specifically limited and, as described regarding the seventh embodiment, one of polarizable metals, typically W, Mo, Mn, Mg, Au, and Ag, may be adopted. Therefore, the second electrode layer 2 is not transparent according to the aforementioned definition, in other word non-transparent. In this case, a non-illustrated passive film of Al₂O₃ may be formed on the surface of the second electrode layer 510 opposite to the base substrate 200. The second conductive layer 2 has a thickness of, for example, 100 nm to 200 nm. In the second electrode layer 510, the carriers created by the photoelectric conversion layer are collected. The second electrode layer 510 includes, like the photoelectric conversion layer 400, an uneven portion 511 reflecting the shape of the perforated portion 330 formed in the first electrode layer 310. However, it is not mandatory that the second electrode layer 510 includes the uneven portion 511.

The passivation layer 610 is disposed on the second electrode layer 510, so as to protect the second electrode layer 510 and the photoelectric conversion layer 400, and also enters the slit 311 defining each of the cells 12 so as to closely contact the base substrate 200 at the bottom of the slit 311. The passivation layer 610 is, for example, formed of SiN, SiO2, or SiON. The passivation layer 42 has a thickness of, for example, 0.5 μm to 2.0 μm, which is thicker than the first electrode layer 310, the photoelectric conversion layer 400, and the second electrode layer 510. Accordingly, the passivation layer 42 prevents intrusion of moisture or particles from outside into the photoelectric conversion layer 400, thereby improving the durability of the organic thin film solar cell 10C. It is preferable to form the passivation layer 610 in such a thickness that the surface thereof can be made flat, without being affected by the recess 320 formed in the first electrode layer 310.

The bonding layer 620 serves to bond the passivation layer 610 and the cover layer 630 and is, for example, a resin-based adhesive layer.

The cover layer 630 serves to protect the organic thin film solar cell 10C from the opposite side of the base substrate 200. Preferably, the cover layer 630 may be formed of glass or a film, however other transparent materials may be adopted as the case may be, provided that the material is capable of protecting the organic thin film solar cell 10C. The cover layer 44 has a thickness of, for example, 30 μm to 100 μm.

As described above, the first electrode layer 310 includes the perforated portions (opening sections) 330, formed so as to penetrate therethrough in the thickness direction. The perforated portions 330 are utilized to exhibit the design D to be visually recognized from the side of the first surface 201 of the base substrate 200. In this embodiment, as illustrated in detail in FIG. 87, a plurality of linearly extending fine slits 331, each having a width w of 5 to 20 μm for example, are formed at a pitch p as narrow as 30 to 50 μm, on the surface of the first electrode layer 310 opposite to the base substrate 200. Because of such slits 331, the region where the slits 331 are formed can be visually recognized as a hologram when viewed from the side of the first surface 201 of the base substrate 200, owing to the diffraction of light at the stepped portions of the finely formed slits 331. Therefore, the design D, such as a character or a pattern, can be exhibited as a hologram, as shown in FIG. 69, on the first surface of the base substrate 200, in other words the light receiving surface 11 of the organic thin film solar cell 10C, by determining as desired the plan-view shape of the region where the fine slits 331 are to be formed. Further, with the organic thin film solar cell 10C according to this embodiment also, the design formed as a hologram is visible from the rear side, as with the organic thin film solar cell 10A according to the seventh embodiment.

Referring now to FIG. 88 to FIG. 94, a manufacturing method of the organic thin film solar cell 10A will be described hereunder.

Referring first to FIG. 88, the base substrate 200 is prepared, and ITO 300 is formed on the second surface 202 of the base substrate 200 by a known method such as sputtering. Proceeding to FIG. 72, the ITO 300 is patterned to form the first electrode layer 310 partitioned into the rectangular cells 12. The partitioned portions of the first electrode layer 310 are independent from each other, such that the first electrode layers 310 adjacent to each other are isolated by the slit 311. For the patterning of the ITO, for example, wet etching, dry etching, or laser patterning is adopted as the case may be. Without limitation to the above, the first electrode layer 310 may be formed by directly patterning the ITO on the second surface 202 of the base substrate 200, for example through a printing process.

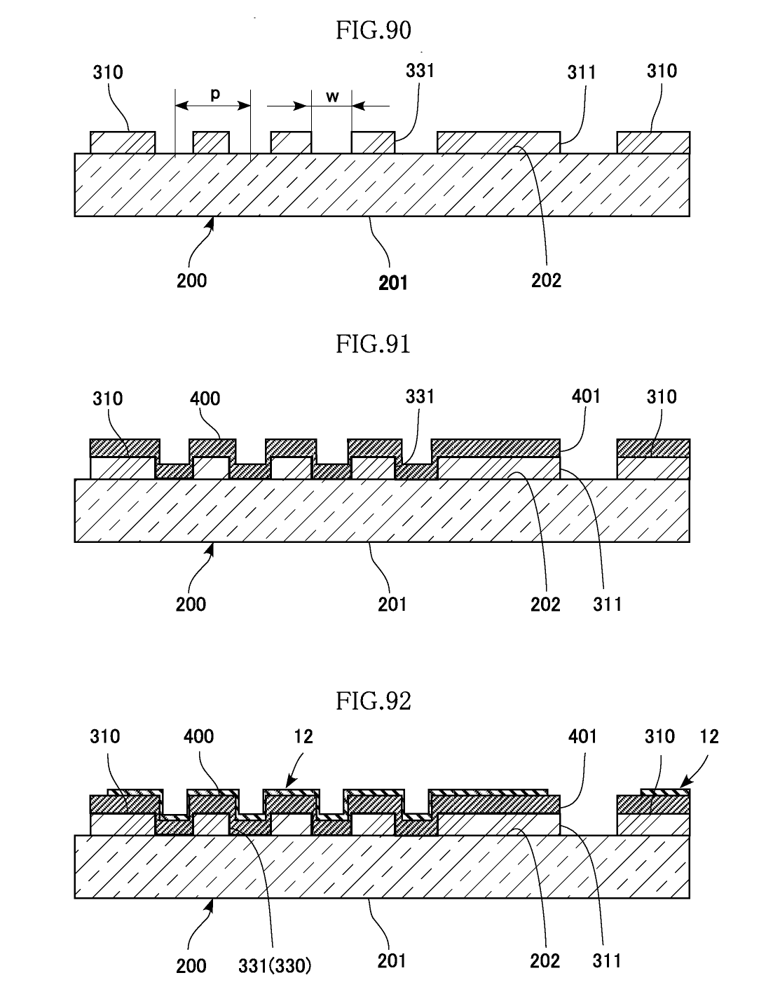

Proceeding to FIG. 90, the fine slits 331 are formed on the first electrode layer 310. More specifically, the slits 331 are formed on the region of the first electrode layer 310 where the design D is to be exhibited. In this embodiment, as mentioned above, the first electrode layer 310 has a thickness of 100 to 200 nm, the slits 331 have a width w of 5 to 20 μm for example, and are aligned at a pitch p of 30 to 50 μm. To form such slits 331 having a narrow width w at a fine pitch p, on the first electrode layer 310 which is extremely thin, it is preferable to scan the first electrode layer 310 with a laser spot with a predetermined output. Here, the process of forming the slit 311 in the ITO 300 thereby forming the first electrode layer 310 partitioned into individual cells 12 (FIG. 89) and the process of forming the slits 331 in the first electrode layer 310 (FIG. 90) may be performed in a reversed order.

The process of forming the slits 331 in the first electrode layer 310 may be performed at the same time as forming the slit 311 in the ITO 300, by dry etching.

Proceeding to FIG. 91, the photoelectric conversion layer 400 is formed. To form the photoelectric conversion layer 400, an organic film is deposited on the base substrate 200 and the first electrode layer 310 for example by spin coating, and the organic film is patterned into a planar shape that matches the planar shape of the first electrode layer 310 of a rectangular shape, by oxygen plasma etching or laser patterning. Without limitation to the above, the photoelectric conversion layer 400 may be formed by directly patterning the organic film on the base substrate 200 and the first electrode layer 310, for example by slit coating, capillary coating, gravure printing, or screen printing.

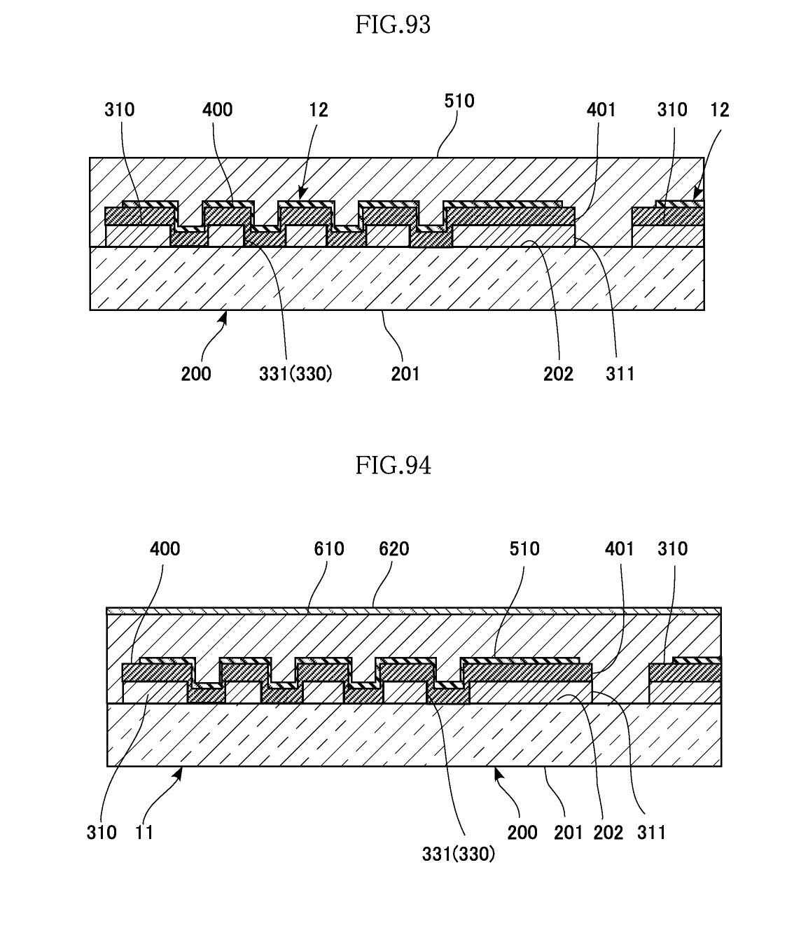

Proceeding to FIG. 92, the second electrode layer 510 is formed. To form the second electrode layer 510, for example, one of the aforementioned metals is deposited by vacuum vapor deposition on the base substrate 200, the first electrode layer 310, and the photoelectric conversion layer 400, to deposit a metal film thereon. Then the metal film is patterned, for example by etching with a mask layer. Through such patterning, the second electrode layer 510 is formed on the photoelectric conversion layer 400. Thereafter, as shown in FIG. 93, SiN, SiO₂, or SiON is deposited over the base substrate 200, the first electrode layer 310, the photoelectric conversion layer 400, and the second electrode layer 510, for example by plasma CVD, to form the passivation layer 610. Then the cover layer 630 is bonded to the passivation layer 610, via the bonding layer 620 (FIG. 94). Through the mentioned process, the organic thin film solar cell 10A shown in FIG. 70 can be obtained.

The organic thin film solar cell 10C provides the following advantageous effects.

In the organic thin film solar cell 10C according to this embodiment, the perforated portions (opening sections) 330 are formed in the first electrode layer 310 between the base substrate 200 and the photoelectric conversion layer 400, so as to constitute the design D, such that the design D can be visually recognized from the side of the base substrate 200. Therefore, the design D can be exhibited on light receiving surface 11 of the organic thin film solar cell 10C, without the need to form an additional component in the organic thin film solar cell 10 or print a pattern on the outer surface. Further, the display quality of the design D can be maintained, without the risk of quality degradation or disappearance of the design itself, because of contacts or friction with other objects.

In the organic thin film solar cell 10C according to this embodiment, the design D can be exhibited as a hologram such that the design D can be visually recognized in the light receiving surface 11, by processing the first electrode layer 310. This is useful as countermeasure against imitations of the organic thin film solar cell 10C, or the electronic device 100 incorporated with the same.

In each of the foregoing embodiments, the thin-wall portions 312 or slits 331 are formed in the first electrode layer 310 such that the hologram appears when viewed from the side of the first surface 201 of the base substrate 200. However, the planar shape of the thin-wall portions 312 or slits 331 themselves is not specifically limited, and the generation method of the hologram is not limited to utilizing the group of the thin-wall portions 312 or slits 331.

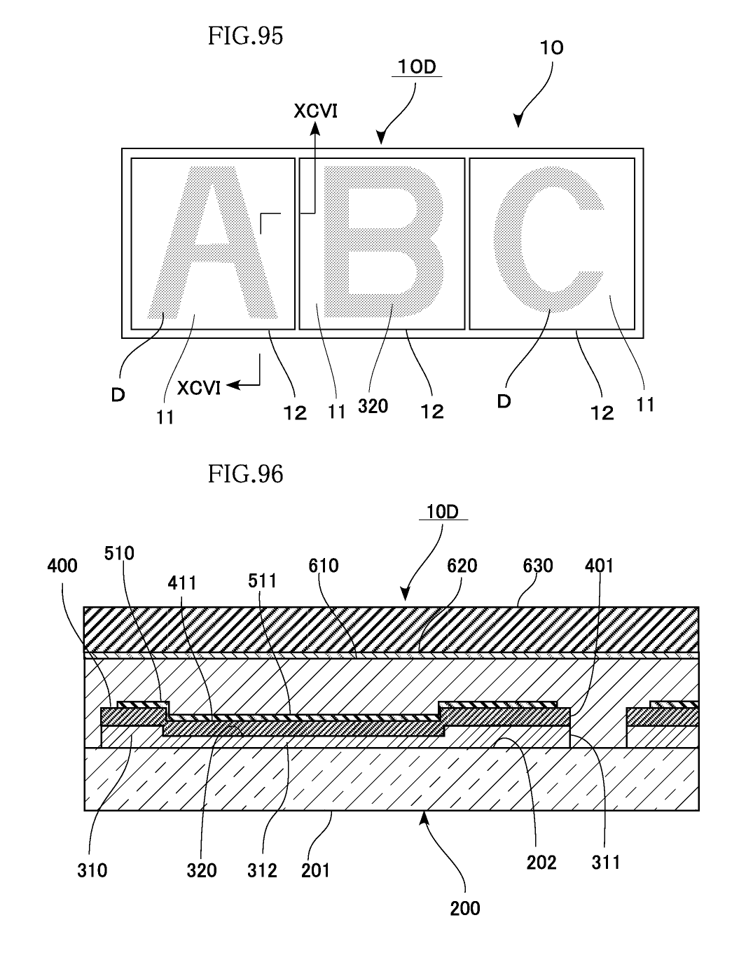

FIG. 95 is a plan view showing an organic thin film solar cell 10D according to the tenth embodiment of the present invention, and FIG. 96 is an enlarged cross-sectional view taken along a line XCVI-XCVI in FIG. 95. In these drawings, the elements same as or similar to those of the organic thin film solar cell 10A according to the seventh embodiment shown in FIG. 70 are given the same numeral.

In the organic thin film solar cell 10D, a recess (opening section) 340, having a shape corresponding to the contour of the design D to be exhibited, is formed in the surface of the first electrode layer 310 opposite to the base substrate 200, to form the thin-wall portion 312. For example, when the coloring of the photoelectric conversion layer 400 is weakened and the first electrode layer 310 is colored, the planar shape of the thin-wall portion 312 becomes visually recognizable from the first surface of the base substrate 200, because of the difference of the color tone, and thus the design D representing a desired pattern can be exhibited.

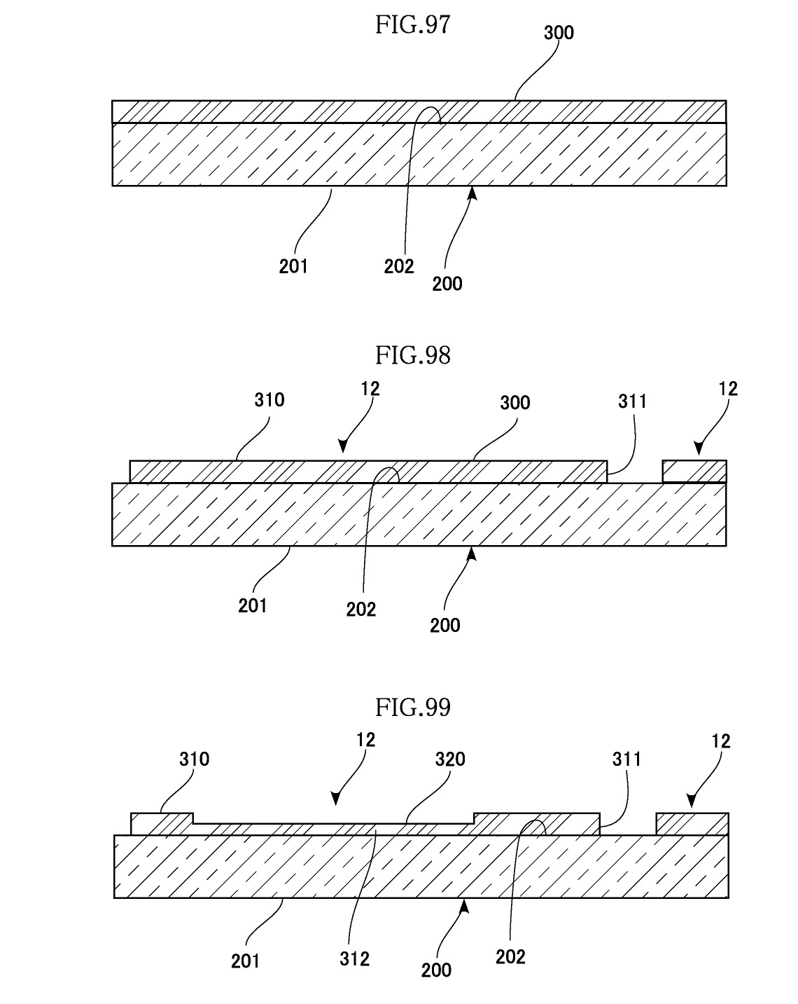

Referring now to FIG. 97 to FIG. 103, a manufacturing method of the organic thin film solar cell 10D will be described hereunder.

Referring first to FIG. 97, the base substrate 200 is prepared, and ITO 300 is formed on the second surface 202 of the base substrate 200 by a known method such as sputtering. Proceeding to FIG. 72, the ITO 300 is patterned to form the first electrode layer 310 partitioned into the rectangular cells 12. The partitioned portions of the first electrode layer 310 are independent from each other, such that the first electrode layers 310 adjacent to each other are isolated by the slit 311. For the patterning of the ITO, for example, wet etching, oxygen plasma etching, or laser patterning is adopted as the case may be. Without limitation to the above, the first electrode layer 310 may be formed by directly patterning the ITO on the second surface 202 of the base substrate 200, for example through a printing process.

Proceeding to FIG. 99, the recesses (opening sections) 340, of the same shape as the contour of the design D to be displayed, are formed on the first electrode layer 310, to form the thin-wall portions 312. To form the thin-wall portions 312, it is preferable to scan the first electrode layer 310 with a laser spot with a predetermined output.

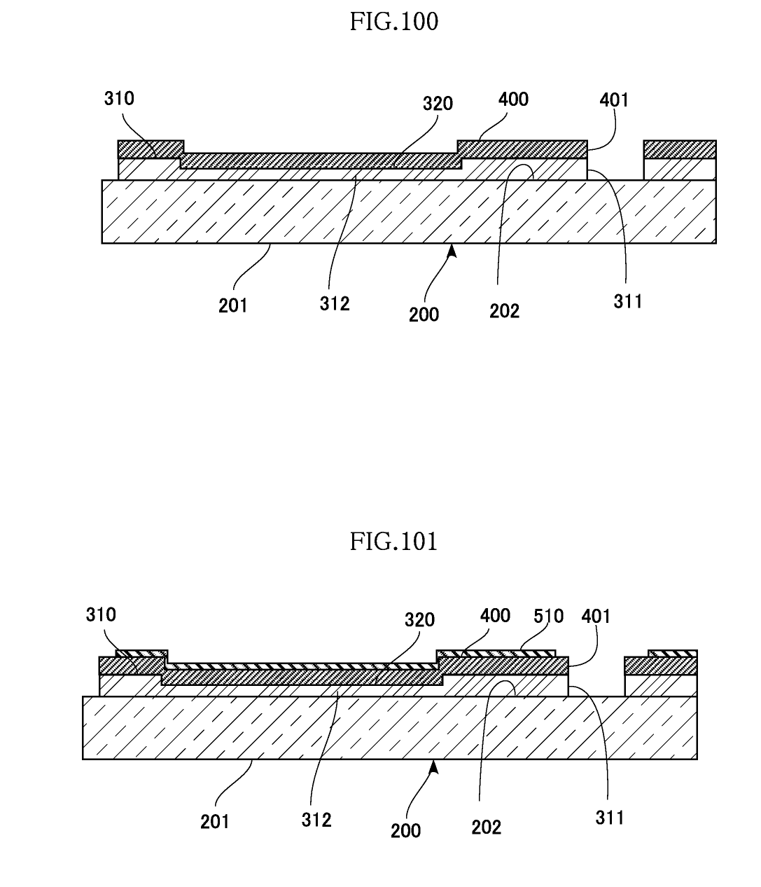

Proceeding to FIG. 100, the photoelectric conversion layer 400 is formed. To form the photoelectric conversion layer 400, an organic film is deposited on the base substrate 200 and the first electrode layer 310 for example by spin coating, and the organic film is patterned into a planar shape that matches the planar shape of the first electrode layer 310 of a rectangular shape, by dry etching or laser patterning. Without limitation to the above, the photoelectric conversion layer 400 may be formed by directly patterning the organic film on the base substrate 200 and the first electrode layer 310, for example by slit coating, capillary coating, gravure printing, or screen printing.

Proceeding to FIG. 101, the second electrode layer 510 is formed. To form the second electrode layer 510, for example, one of the aforementioned metals is deposited by vacuum vapor deposition on the base substrate 200, the first electrode layer 310, and the photoelectric conversion layer 400, to deposit a metal film thereon. Then the metal film is patterned, for example by etching with a mask layer. Through such patterning, the second electrode layer 510 is formed on the photoelectric conversion layer 400. Thereafter, as shown in FIG. 101, SiN, SiO₂, or SiON is deposited over the base substrate 200, the first electrode layer 310, the photoelectric conversion layer 400, and the second electrode layer 510, for example by plasma CVD, to form the passivation layer 610. Then the cover layer 44 is bonded to the passivation layer 610, via the bonding layer 620 (FIG. 103). Through the mentioned process, the organic thin film solar cell 10D shown in FIG. 96 can be obtained.

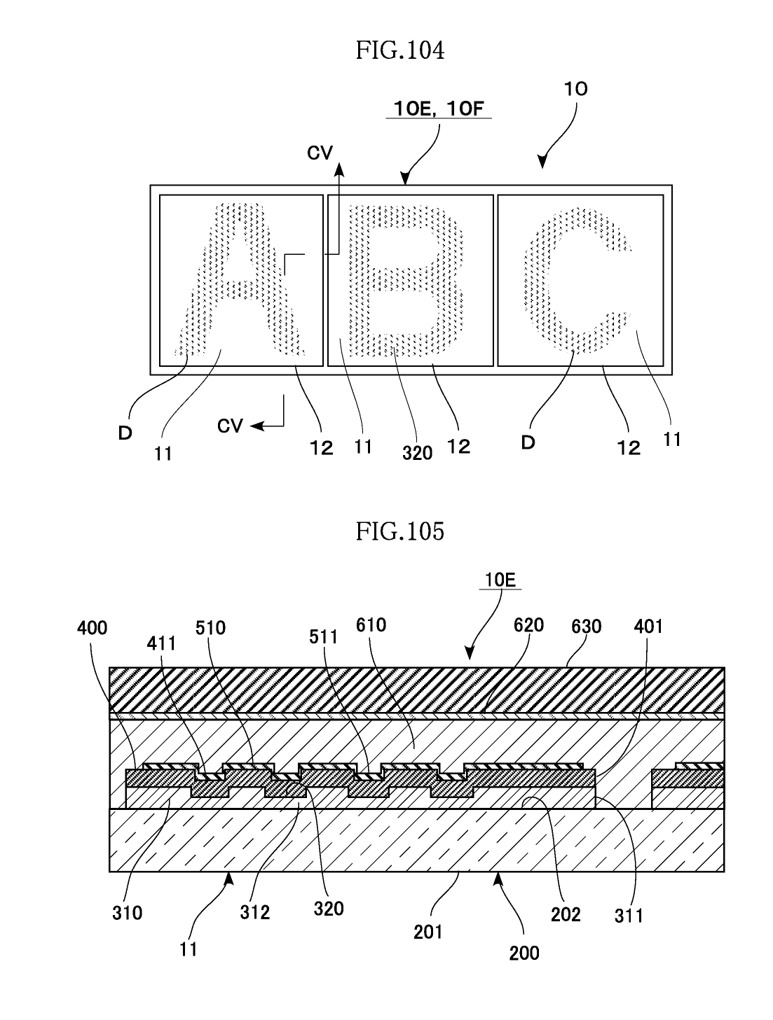

FIG. 104 is a plan view showing organic thin film solar cells 10E and 10F according to eleventh and twelfth embodiments of the present invention, respectively, and FIG. 105 is an enlarged cross-sectional view taken along a line CV-CV in FIG. 104, showing the organic thin film solar cell 10E according to the eleventh embodiment. In these drawings, the elements same as or similar to those of the organic thin film solar cell 10A according to the seventh embodiment shown in FIG. 70 are given the same numeral.

In the organic thin film solar cell 10E, a multitude of thin-wall portions 312, each of which is a dot-shaped recess (opening section) 340, are formed in the surface of the first electrode layer 310 opposite to the base substrate 200, so that the set of the multitude of dots corresponds to the planar shape of the design D to be exhibited. Such a configuration also enables creation of the design D that can be visually recognized in the light receiving surface 11 of the organic thin film solar cell 10E. In this case, filling the dot-shaped recesses 340 with a coloring agent allows the design D to be more clearly exhibited.

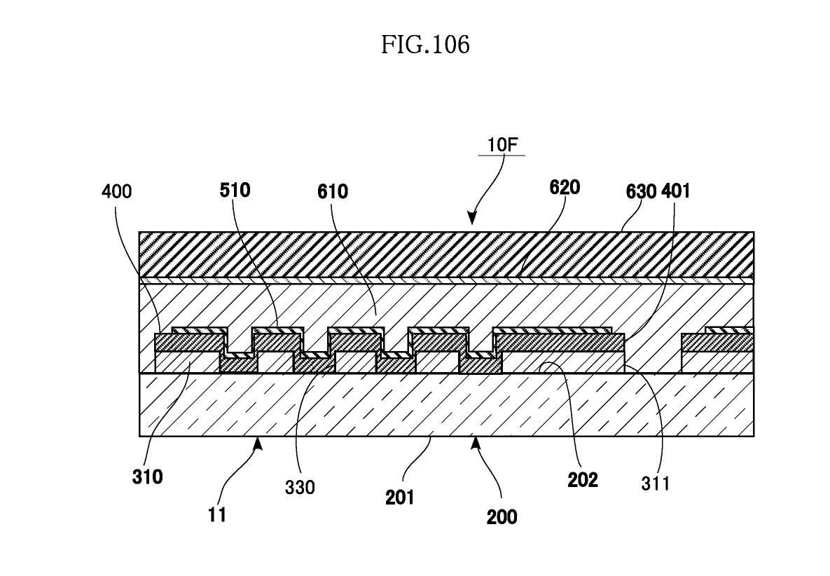

FIG. 106 is an enlarged cross-sectional view corresponding to the view taken along a line CV-CV in FIG. 104, and showing the organic thin film solar cell 10F according to the twelfth embodiment. In the organic thin film solar cell 10F, a multitude of dot-shaped perforated portions (opening sections) 330 are formed in the surface of the first electrode layer 310 opposite to the base substrate 200, so that the set of the multitude of dots corresponds to the planar shape of the design D to be exhibited. Such a configuration also enables creation of the design D that can be visually recognized in the light receiving surface 11 of the organic thin film solar cell 10F. In this case, filling the dot-shaped perforated portions with a coloring agent allows the design D to be more clearly exhibited.

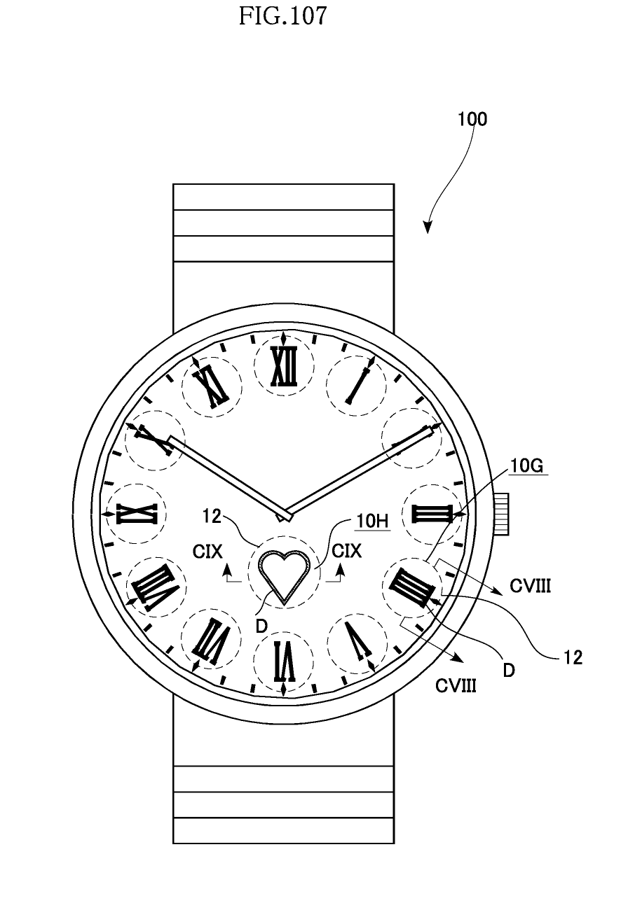

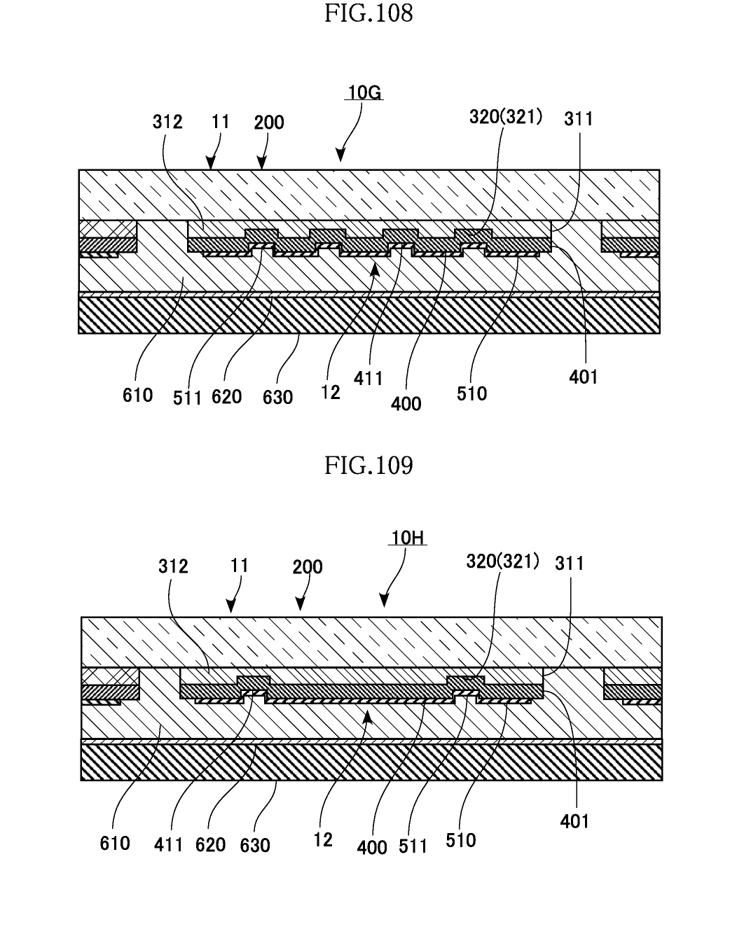

In FIG. 107 to FIG. 109, the electronic device 100 is exemplified by a watch in which an organic thin film solar cell 10G or 10H according to the present invention is incorporated, such that the design D, in this case the dial face or a pattern, is exhibited in the light receiving surface. FIG. 107 is a plan view showing a watch, another example of the electronic device 100. FIG. 108 is an enlarged cross-sectional view taken along a line CVIII-CVIII in FIG. 107. FIG. 109 is an enlarged cross-sectional view taken along a line CIX-CIX in FIG. 107. In these drawings, the elements same as or similar to those of the organic thin film solar cell 10A according to the seventh embodiment shown in FIG. 70 are given the same numeral. In FIG. 108 and FIG. 109, the light receiving surface 11 is oriented upward.

In the organic thin film solar cell 10G, a Roman numeral representing a time is exhibited as the design D, in each of the cells 12 partitioned in a desired shape. For example, the configuration of the organic thin film solar cell 10D according to the tenth embodiment shown in FIG. 96 may preferably be applied to the organic thin film solar cell 10G. However, instead, the configuration of one of the organic thin film solar cells 10A to 10C, 10E, and 10F according to the foregoing embodiments may also be adopted.

In the organic thin film solar cell 10H, a pattern representing a heart-shaped contour of a predetermined width is exhibited as the design D, in one of the cells 12 partitioned in a desired shape. In the case of the organic thin film solar cell 10H also, the configuration of the organic thin film solar cell 10D according to the tenth embodiment shown in FIG. 96 may preferably be adopted, however the configuration of one of the organic thin film solar cells 10A to 10C, 10E, and 10F according to the foregoing embodiments may also be adopted. Naturally, the pattern that can be represented by the organic thin film solar cell 10 according to the present invention, in an electronic device such as the watch, is not limited to the heart shape.

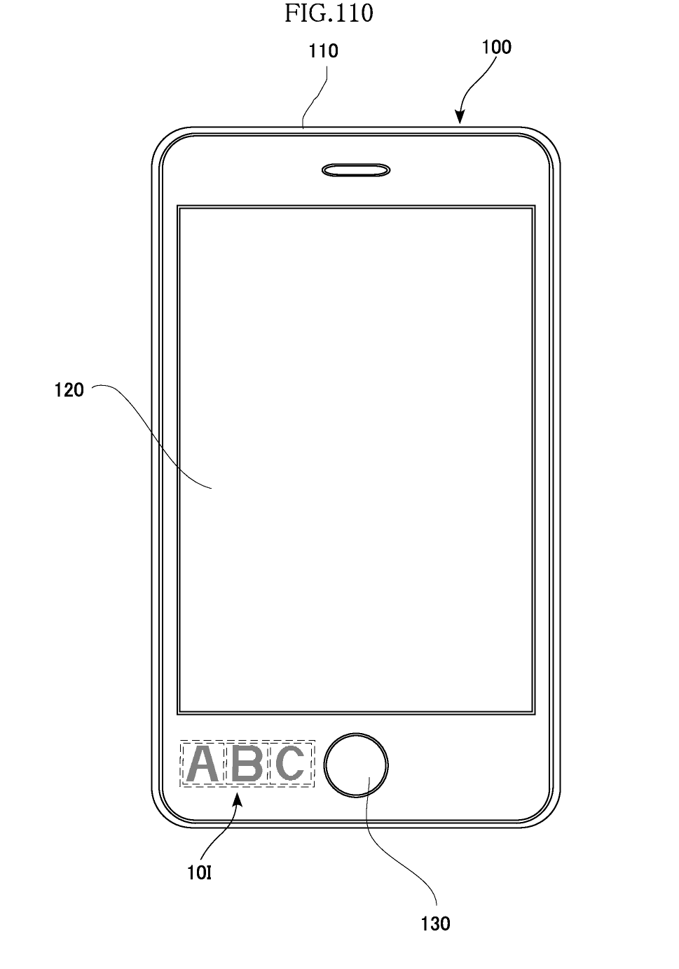

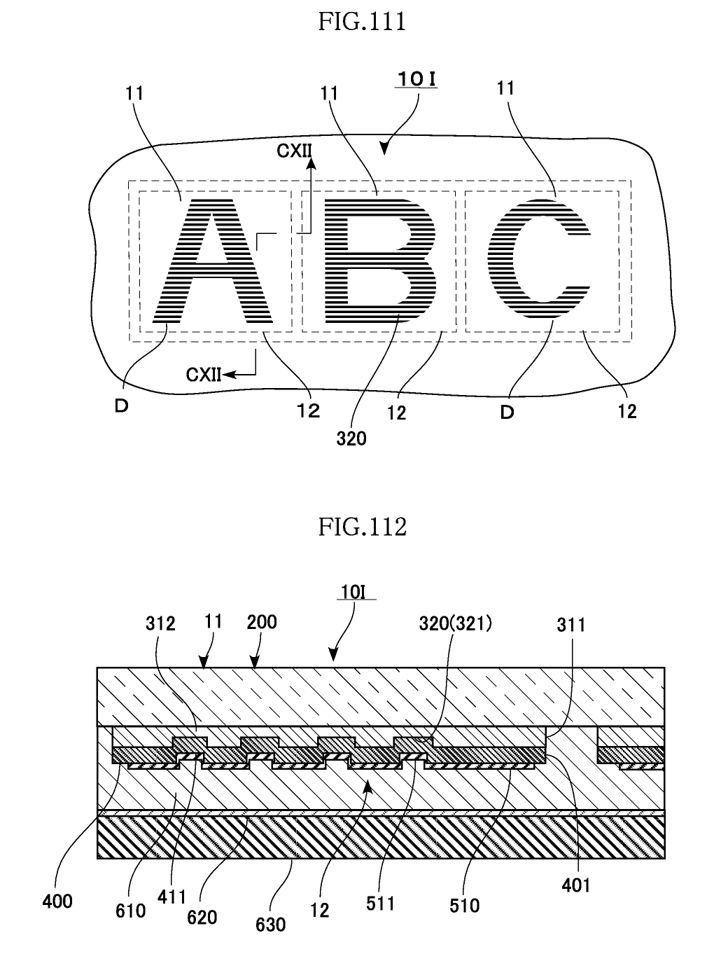

In FIG. 110 to FIG. 112, the electronic device 100 is exemplified by a smartphone, on the surface of which an organic thin film solar cell 10I is incorporated so as to exhibit the design D. FIG. 107 is a plan view showing the smartphone exemplifying the electronic device 100, FIG. 108 is an enlarged plan view showing the organic thin film solar cell 10I, and FIG. 112 is an enlarged cross-sectional view taken along a line CXII-CXII in FIG. 111. In these drawings, the elements same as or similar to those of the organic thin film solar cell 10A according to the seventh embodiment shown in FIG. 70 are given the same numeral. In FIG. 112, the light receiving surface 11 is oriented upward.

In the organic thin film solar cell 10I, the design D representing a character is exhibited as a hologram, in one of the cells 12 partitioned in a desired shape in the organic thin film solar cell provided all over the surface of the smartphone except for the display unit 120 and an operation button 130. Although the configuration of the organic thin film solar cell 10A according to the seventh embodiment shown in FIG. 70 may preferably be applied to the organic thin film solar cell 10I, the configuration of one of the organic thin film solar cells 10B to 1° F. according to the foregoing embodiments may also be adopted.

The organic thin film solar cell according to the present invention are in no way limited to the materials and numerical values cited in the foregoing embodiments and variations, but may be modified in various manners within the scope of the present invention.

The technical features of the present invention may be expressed as the following appendices.

### Appendix 1C

An organic thin film solar cell including:

a transparent base substrate having a first surface, and a second surface opposite thereto;

a transparent first electrode layer located on the side of the second surface of the base substrate;

a photoelectric conversion layer formed of an organic thin film, and disposed on the first electrode layer on the opposite side of the base substrate; and

a second electrode layer disposed on the photoelectric conversion layer on the opposite side to the base substrate,

in which the first electrode layer includes an opening section formed on a surface thereof, the opening section being configured to display a design on the first surface of the base substrate.

### Appendix 2C

The organic thin film solar cell according to appendix 1C, in which an outer edge of the opening section in plan view constitutes a part of an outer edge of the design to be displayed.

### Appendix 3C

The organic thin film solar cell according to appendix 1C, in which the opening section includes a group of dots each having a predetermined plan-view shape.

### Appendix 4C

The organic thin film solar cell according to appendix 3C, in which the group of the dots constitutes a part of the design to be displayed.

### Appendix 5C

The organic thin film solar cell according to appendix 1C, in which the opening section includes a plurality of lines aligned at a predetermined interval, the lines each having a predetermined width and extending in a predetermined direction.

### Appendix 6C

The organic thin film solar cell according to appendix 5C, in which the lines constitute a part of the design to be displayed.

### Appendix 7C

The organic thin film solar cell according to appendix 5C or 6C, in which the opening section generates a hologram, when viewed from outside of the first surface of the base substrate.

### Appendix 8C

The organic thin film solar cell according to appendix 7C, in which the lines constituting the opening section each have a width of 5 to 20 μm, and are aligned at intervals of 30 to 50 μm.

### Appendix 9C

The organic thin film solar cell according to any one of appendices 1C to 8C, in which the first electrode layer has a thickness of 100 to 200 nm, except for a portion corresponding to the opening section.

### Appendix 10C

The organic thin film solar cell according to appendix 9C, in which the opening section is a recess having a predetermined depth, formed in a surface of the first electrode layer opposite to the base substrate.

### Appendix 11C

The organic thin film solar cell according to appendix 9C, in which the opening section is a recess having a predetermined depth, formed in a surface of the first electrode layer on the side of the base substrate.

### Appendix 12C

The organic thin film solar cell according to appendix 10C or 11C, in which the opening section is formed in such a depth that leaves a thin-wall portion having a thickness of 50 to 100 nm.

### Appendix 13C

The organic thin film solar cell according to any one of appendices 1C to 7C, in which the opening section is formed so as to penetrate through the first electrode layer in the thickness direction.

### Appendix 14C

The organic thin film solar cell according to any one of appendices 9C to 13C, further including a passivation layer, covering the second electrode layer on the opposite side of the photoelectric conversion layer.

### Appendix 15C

The organic thin film solar cell according to appendix 14C, further including a cover layer, covering the passivation layer on the opposite side to the second electrode layer.

### Appendix 16C

The organic thin film solar cell according to appendix 15C, further including a bonding layer bonding the passivation layer and the cover layer together.

### Appendix 17C

The organic thin film solar cell according to any one of appendices 9C to 16C, in which the first electrode layer is formed of ITO.

### Appendix 18C

The organic thin film solar cell according to any one of appendices 9C to 17C, in which the photoelectric conversion layer has a thickness of 100 to 200 nm.

### Appendix 19C

The organic thin film solar cell according to any one of appendices 9C to 18C, in which the second electrode layer has a thickness of 100 to 200 nm.

### Appendix 20C

The organic thin film solar cell according to appendix 19C, in which the second electrode layer is formed of a metal.

### Appendix 21C

The organic thin film solar cell according to appendix 20C, in which the second electrode layer is formed of A1.

### Appendix 22C

The organic thin film solar cell according to any one of appendices 9C to 21C, in which a total thickness of the first electrode layer, the photoelectric conversion layer, the second electrode layer, and the passivation layer is 1.0 to 2.0 μm.

### Appendix 23C

A method of manufacturing an organic thin film solar cell, the method including:

forming, on a second surface of a transparent base substrate having a first surface and the second surface opposite thereto, a transparent first electrode layer having a predetermined thickness and including an opening formed in a surface thereof;

forming a photoelectric conversion layer on the first electrode layer; and

forming a second electrode layer on the photoelectric conversion layer.

### Appendix 24C

The method according to appendix 23C, in which the forming of the opening section includes removing with respect to the first electrode layer in the thickness direction to a predetermined depth.

### Appendix 25C

The method according to appendix 24C, in which the forming of the opening section includes removing with respect to the first electrode layer in the thickness direction to a predetermined depth.

### Appendix 26C

The method according to appendix 25C, in which the forming of the opening section includes removing with respect to the first electrode layer having a thickness of 100 to 200 nm, so as to leave a thin-wall portion having a thickness of 50 to 100 nm.

### Appendix 27C

The method according to appendix 25C o 26C, in which the forming of the opening section includes removing with respect to the first electrode layer from the side opposite to the base substrate.

### Appendix 28C

The method according to appendix 27C, in which the forming of the opening section is performed after the forming of the first electrode layer, in which the opening section is yet to be formed.

### Appendix 29C

The method according to appendix 26C, in which the forming of the opening section includes removing with respect to the first electrode layer from the side of the first surface of the base substrate.

### Appendix 30C

The method according to appendix 29C, in which the forming of the opening section is performed on the first electrode layer in which the opening section is yet to be formed, after the forming of the second electrode layer.

### Appendix 31C

The method according to appendix 24C, in which the forming of the opening section includes forming a perforated portion so as to penetrate through the first electrode layer, in the thickness direction.

### Appendix 32C

The method according to any one of appendices 24C to 31C, in which the forming of the opening section includes aligning a plurality of lines each having a width of 5 to 20 μm and extending in a predetermined direction, at intervals of 30 to 50 μm.

### Appendix 33C

The method according to any one of appendices 24C to 31C, in which the forming of the opening section is performed by laser irradiation.

### Appendix 34C

An electronic device including a casing, and the organic thin film solar cell according to any one of appendices 1C to 22C, arranged such that the first surface of the base substrate is exposed in a surface of the casing.

### Thirteenth to Fifteenth Embodiments

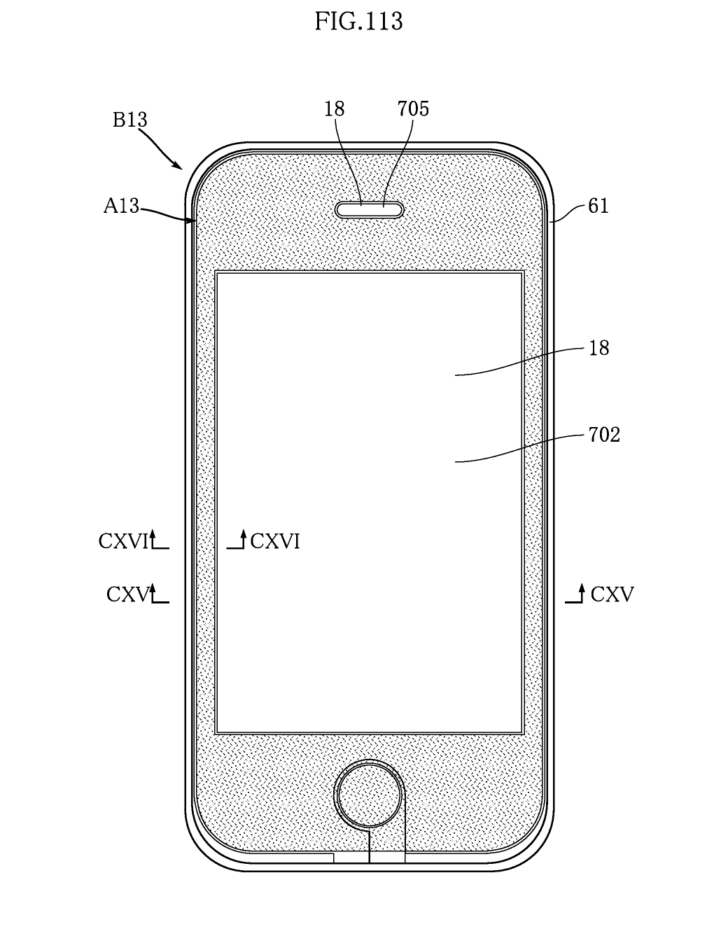

The reference numerals used for thirteenth to fifteenth embodiments and FIG. 113 to FIG. 145 are given for these particular embodiment and drawings, and independent of numerals used for other embodiments and drawings. It should be noted, however, that the arrangements of the thirteenth to fifteenth embodiments and those of any other embodiment may be combined or exchanged in an appropriate manner.

The term “transparent” used herein may be defined as having a transmittance of approximately 50% or higher. The term “transparent” may also be used for visible light when it is colorless and clear. The visible light corresponds to a wavelength range of approximately 360 nm to 830 nm and an energy range of approximately 3.45 eV to 1.49 eV. When a transmittance of a substance is 50% or higher in these ranges, that substance may be regarded as transparent.

FIG. 113 to FIG. 117 illustrate an electronic device according to the thirteenth embodiment of the present invention, and an organic thin film solar cell module according to the thirteenth and fourteenth embodiments of the present invention. The electronic device B13 according to this embodiment includes an organic thin film solar cell module A13, an organic thin film solar cell module A14, the case 61, the control unit 701, the display unit 702, the input unit 703, the microphone 704, the speaker 705, the wireless communication unit 706, and the battery 707, and is configured as a mobile phone terminal.

The case 61, which accommodates therein other components of the electronic device B13, is formed of a metal, a resin, or glass.

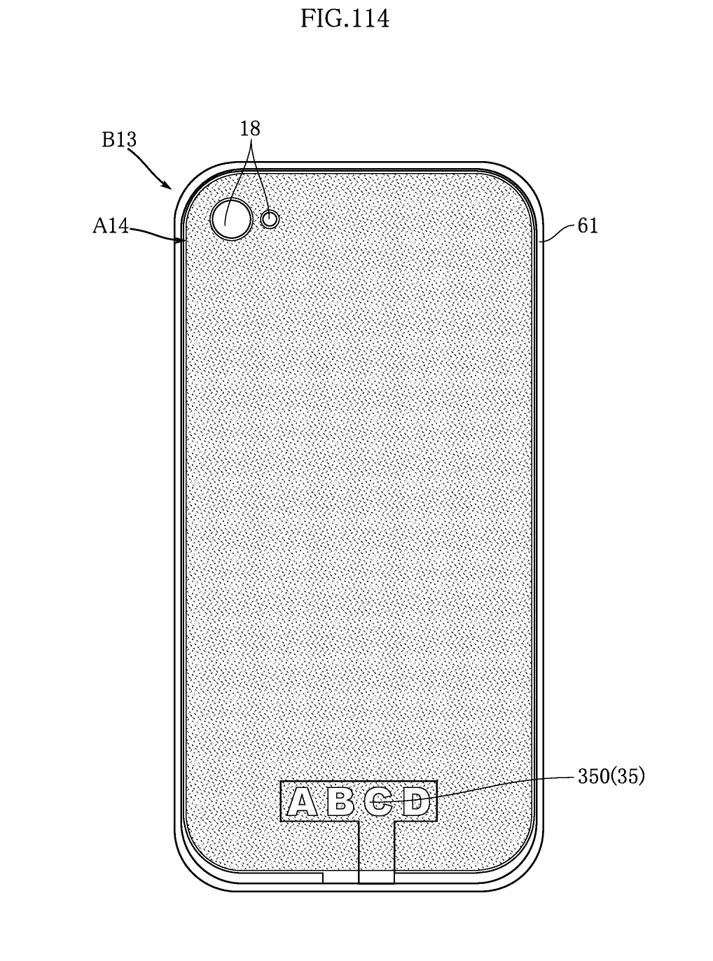

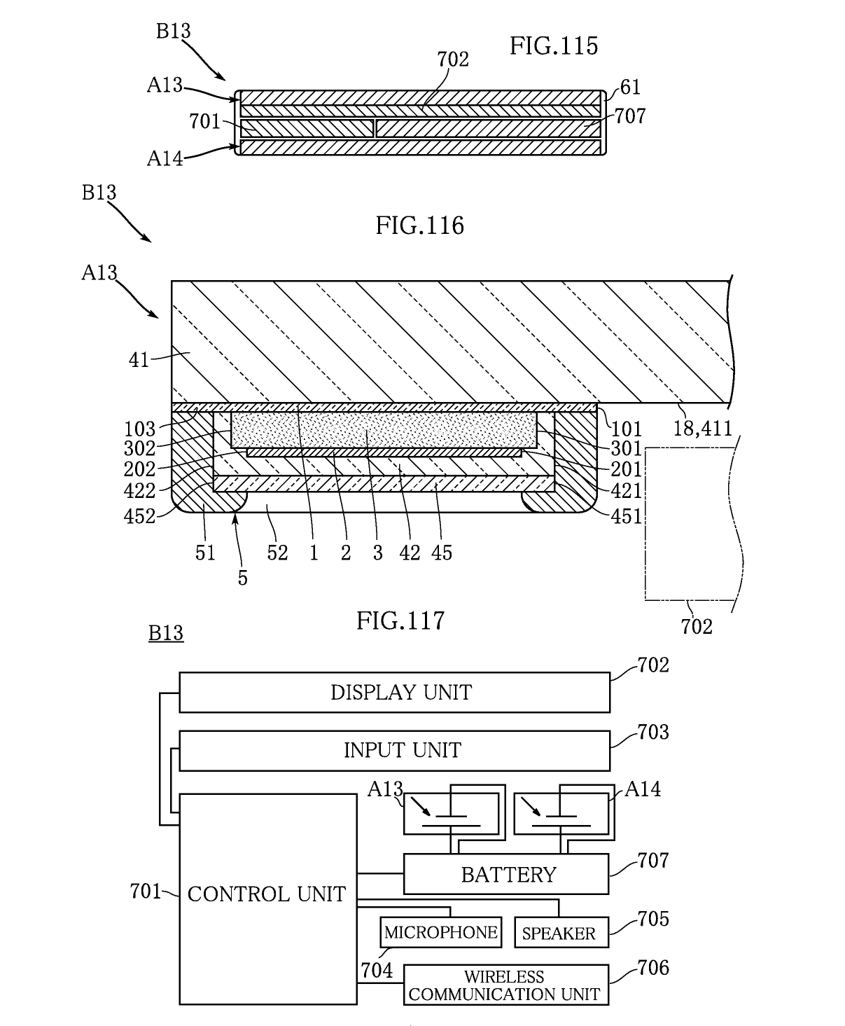

FIG. 113 is a plan view showing organic thin film solar cell modules A13 and A14, and an electronic device B13 incorporated with the organic thin film solar cell modules. FIG. 114 is a bottom view showing the organic thin film solar cell modules A13 and A14, and the electronic device B13. FIG. 115 is a schematic cross-sectional view taken along a line CXV-CXV in FIG. 113. FIG. 116 is an enlarged partial cross-sectional view taken along a line CXVI-CXVI in FIG. 113. FIG. 117 is a system diagram of the electronic device B13. In FIG. 115, the elements other than the case 61, the organic thin film solar cell module A13, the organic thin film solar cell module A14, the control unit 701, the display unit 702, and the battery 707 are omitted, to facilitate understanding.

The organic thin film solar cell module A13 and the organic thin film solar cell module A14, serving as the power source module for the electronic device B13, convert light, such as sunlight, into electric power. Further details will be described below.

The control unit 701 corresponds to the drive unit in the present invention, and operates by the power supplied from the organic thin film solar cell module A13 and the organic thin film solar cell module A14. The control unit 701 may receive power directly from the organic thin film solar cell module A13 and the organic thin film solar cell module A14, or from the battery 707, after the power from the organic thin film solar cell module A13 and the organic thin film solar cell module A14 is once charged in the battery 707. The control unit 701 includes, for example, a CPU, a memory, and an interface.

The display unit 702 serves to display various types of information in the outer appearance of the electronic device B13. The display unit 702 is constituted of, for example, an LCD panel or an organic EL display panel. In this embodiment, the display unit 702 displays the information in the outer appearance, through the organic thin film solar cell module A13.

The input unit 703 outputs an electric signal according to inputs made by the user, to the control unit 701. The input unit 703 is constituted of, for example, a touch panel disposed on the display unit 702. The display unit 702 and the input unit 703 may be integrally formed.

The microphone 704 is a device that converts the voice of the user into electric signals. The speaker 705 is a device that outputs the voice of a counterpart of the call and various message tones.

The wireless communication unit 706 is a device for bidirectional wireless communication, in compliance with a wireless communication standard.

The battery 707 is a device for storing power for driving the electronic device B13. The battery 707 is rechargeable. The battery 707 may be charged by the power from commercial power supply through a non-illustrated adapter, or from the organic thin film solar cell module A13 and the organic thin film solar cell module A14.

The organic thin film solar cell module A13 and the organic thin film solar cell module A14 each include the first conductive layer 1, the second conductive layer 2, the photoelectric conversion layer 3, the base substrate 41, the passivation film 42, the resin cover layer 45, and the bypass conductive section 5. In this embodiment, the organic thin film solar cell module A13 and the organic thin film solar cell module A14 each have a rectangular shape in plan view, however this is merely an example, and various shapes may be adopted. The organic thin film solar cell module A13 and the organic thin film solar cell module A14 have the same configuration, except for some details. Hereunder, the organic thin film solar cell module A13 will first be described.

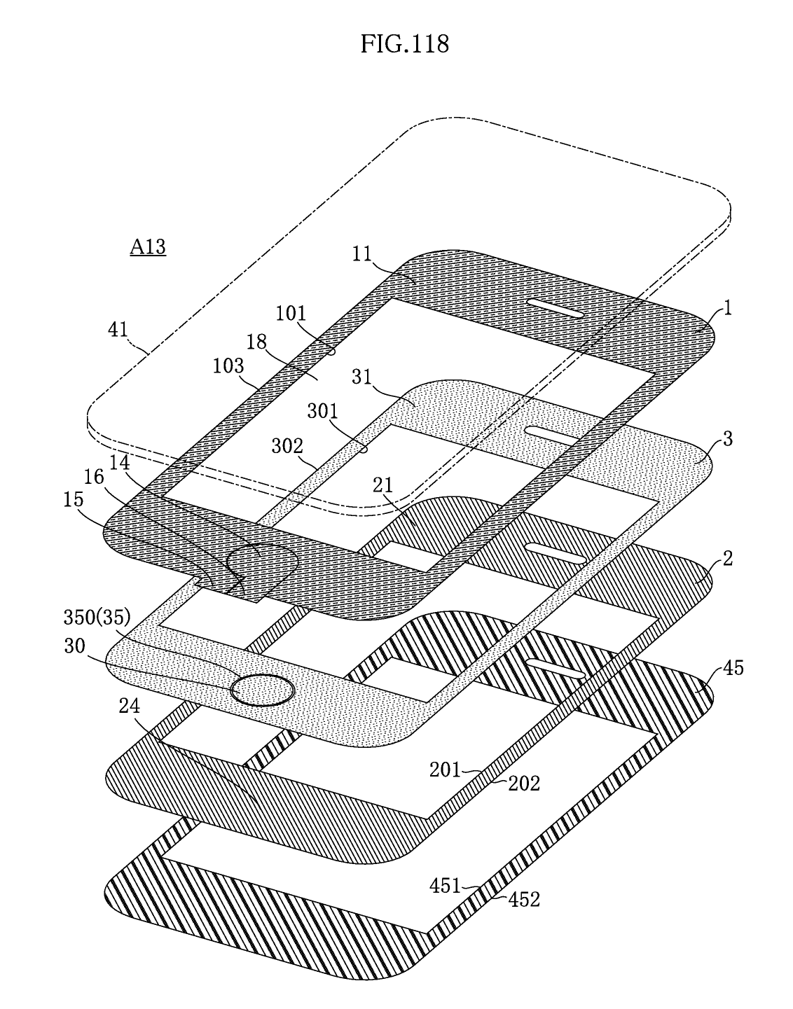

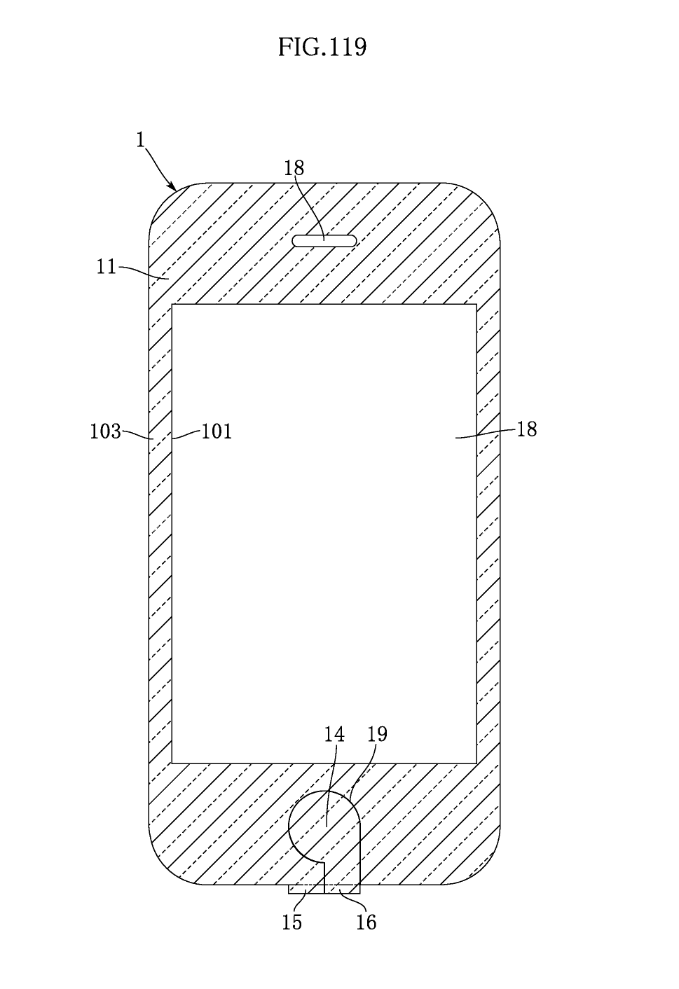

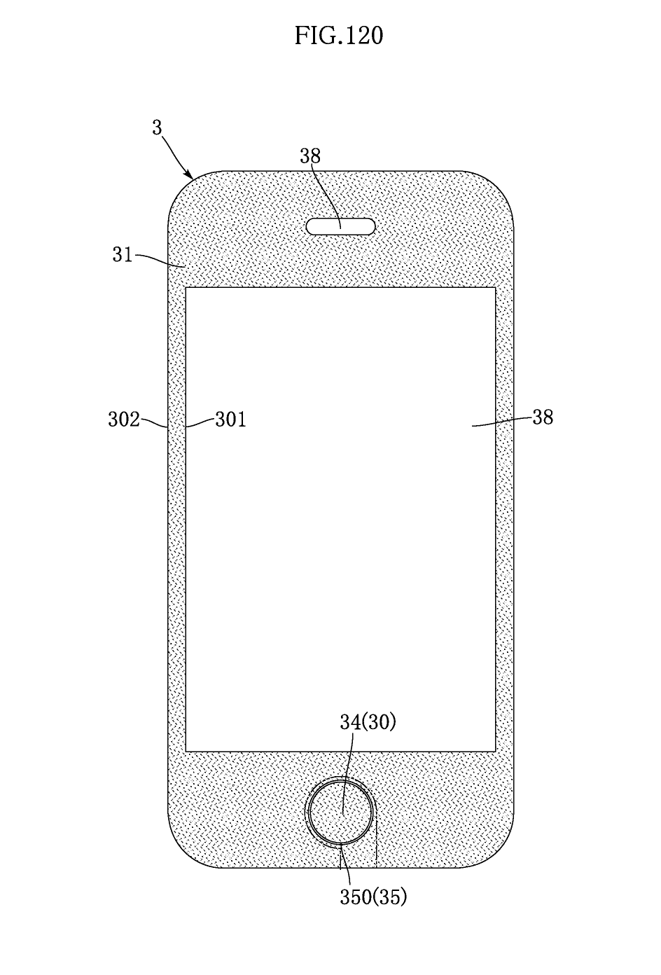

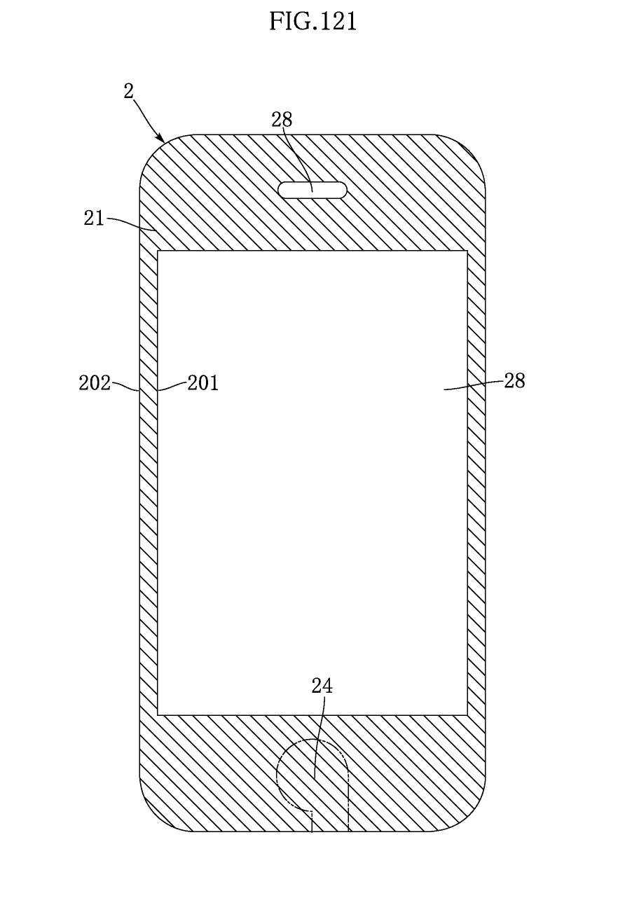

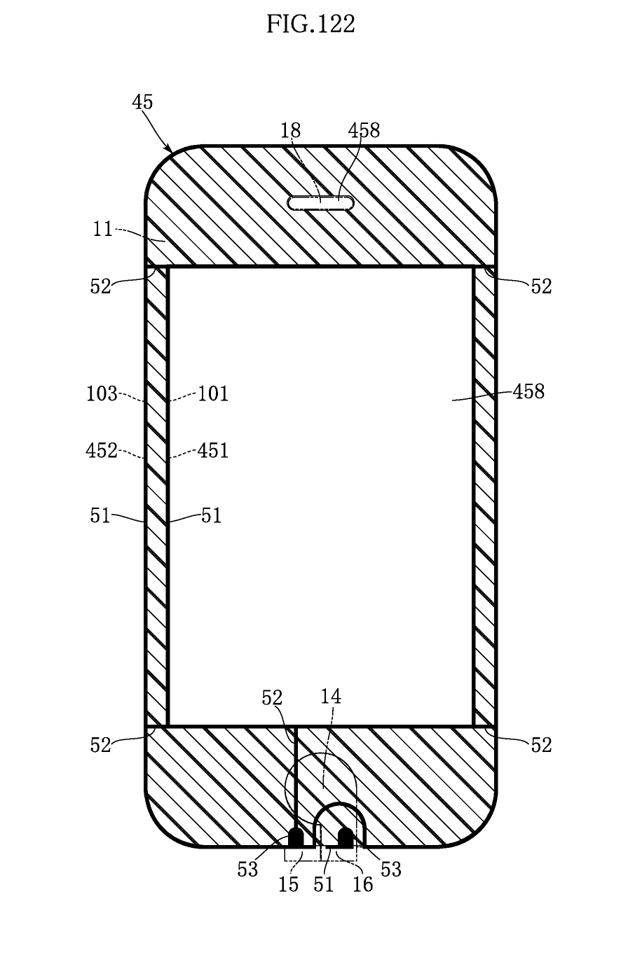

FIG. 118 is a partial exploded perspective view showing the first conductive layer 1, the second conductive layer 2, the photoelectric conversion layer 3, the base substrate 41, and the resin cover layer 45 of the organic thin film solar cell module A13. For the sake of clarity, the base substrate 41 is illustrated in imaginary lines (dash-dot-dot-lines). FIG. 119 is a plan view showing the first conductive layer 1 of the organic thin film solar cell module A13. FIG. 120 is a plan view showing the photoelectric conversion layer 3 of the organic thin film solar cell module A13. FIG. 121 is a plan view showing the second conductive layer 2 of the organic thin film solar cell module A13. FIG. 122 is a plan view showing the resin cover layer 45 and the bypass conductive section 5 of the organic thin film solar cell module A13.

The base substrate 41 serves as the base of the organic thin film solar cell module A13. The base substrate 41 is formed of, for example, transparent glass or a resin. The base substrate 41 has a thickness of, for example, 0.05 mm to 2.0 mm.

The first conductive layer 1 is formed on the base substrate 41. The first conductive layer 1 is transparent, and formed of ITO in this embodiment. As shown in FIG. 118 and FIG. 119, the first conductive layer 1 includes the first electrode section 11, the first end portion 14, the first extended portion 15, the second extended portion 16, a plurality of openings 18, the slits 19, the third edge 101, and the extended portion 103. In this embodiment, the first conductive layer 1 has a generally circular shape in plan view, which is, however, merely an example of the shape of the first conductive layer 1. The first conductive layer 1 may be formed in various shapes. The first conductive layer 1 has a thickness of, for example, 100 nm to 300 nm. In FIG. 119, the first electrode section 11, the first end portion 14, the first extended portion 15, and the second extended portion 16 are hatched with oblique lines.

The first electrode section 11 is a layer in which holes created by the photoelectric conversion layer 3 are collected, and acts as what is known as an anode electrode. In this embodiment, a major part of the first conductive layer 1 acts as one first electrode section 11.

The first extended portion 15 extends from the first electrode section 11 outwardly of the photoelectric conversion layer 3 in plan view. In FIG. 119, the boundary between the first electrode section 11 and the first extended portion 15 is indicated by an imaginary line (dash-dot-dot line). Through the first extended portion 15, the holes originating from the power generation by the photoelectric conversion layer 3 can be led to outside of the organic thin film solar cell module A13.

The first end portion 14 is isolated from the first electrode section 11 via the slit 19. In this embodiment, the first end portion 14 has, for example, a circular shape in plan view. In this embodiment, the first end portion 14 is composed of a generally circular portion and a rectangular portion.

The second extended portion 16 extends from the first end portion 14 outwardly of the photoelectric conversion layer 3 in plan view. In FIG. 119, the boundary between the first end portion 14 and the second extended portion 16 is indicated by an imaginary line (dash-dot-dot line). In this embodiment, the first extended portion 15 and the second extended portion 16 are located adjacent to each other. Through the second extended portion 16, the holes originating from the power generation by the photoelectric conversion layer 3 can be led to outside of the organic thin film solar cell module A13.

The openings 18 are formed so as to penetrate through the first conductive layer 1 in the thickness direction. In this embodiment, two openings 18 are provided. The opening 18 at an upper position in FIG. 119 is formed, for example, to allow the speaker 705 to perform its function. The larger opening 18 at the central position in FIG. 119 is for exhibiting the information displayed by the display unit 702, in the outer appearance.

The third edge 101 defines the opening 18 at the central position in FIG. 119. In this embodiment, the third edge 101 surrounds the opening 18 from four directions, in a rectangular ring shape in plan view. However, it is not mandatory that the third edge 101 surrounds the opening 18 from four directions. For example, the third edge 101 may define the opening 18 from three directions, such that the opening 18 is open to outside through the first electrode section 11, in plan view. Alternatively, the third edge 101 may be formed so as to define the opening 18 from one or two directions. In the region adjacent to the third edge 101, in other words the opening 18 at the central position in FIG. 119, the base substrate 41 is exposed. In addition, the third edge 101 corresponds to the inner edge of a portion of the first conductive layer 1 extending from the second edge 451 of the resin cover layer 45 and the first edge 421 of the passivation layer 42, to be described below.

The extended portion 103 outwardly extends from the passivation layer 42 and the resin cover layer 45. In this embodiment, the extended portion 103 is formed generally along the entire outer peripheral edge of the first conductive layer 1.

A major part of the second conductive layer 2 is disposed on the first conductive layer 1 via the photoelectric conversion layer 3. A part of the second conductive layer 2 is in direct contact with the first conductive layer 1. The material of the second conductive layer 2 is not specifically limited, and may be transparent or non-transparent. In this embodiment, the second conductive layer 2 is formed of a metal, typically A1, W, Mo, Mn, or Mg. In the following example, the second conductive layer 2 is formed of A1. Accordingly, the second conductive layer 2 is non-transparent. In this case, a non-illustrated passive film formed of Al₂O₃ may be formed on the surface of the second conductive layer 2 opposite to the base substrate 41. The second conductive layer 2 has a thickness of, for example, 30 nm to 150 nm.

As shown in FIG. 121, the second conductive layer 2 includes the second electrode section 21, the second end portion 24, and a plurality of openings 28. Although the second conductive layer 2 has a generally rectangular shape in plan view in this embodiment, this is merely an example of the shape of the second conductive layer 2. The second conductive layer 2 may be formed in various shapes. In FIG. 121, the second electrode section 21 and the second end portion 24 are hatched with oblique lines.

The second electrode section 21 is a layer in which electrons created by the photoelectric conversion layer 3 are collected, and acts as what is known as a cathode electrode. The second electrode section 21 is located so as to coincide with the first electrode section 11 in plan view. In this embodiment, a major portion of the second conductive layer 2 acts as the second electrode section 21.

The second end portion 24 coincides with the first end portion 14 of the first conductive layer 1 in plan view, and extends from the second electrode section 21. In FIG. 121, the shape of the second end portion 24 is indicated by an imaginary line (dash-dot-dot line), to facilitate understanding. The second end portion 24 is, like the first end portion 14, composed of a generally circular portion and a rectangular portion.

The openings 28 are formed so as to penetrate through the second conductive layer 2 in the thickness direction. In this embodiment, two openings 28 are provided. The opening 28 at an upper position in FIG. 121 is formed, for example, to allow the speaker 705 to perform its function. The larger opening 28 at the central position in FIG. 121 is for exhibiting the information displayed by the display unit 702, in the outer appearance.

The fourth inner recessed edge 201 defines the opening 28 at the central position in FIG. 121. In this embodiment, the fourth inner recessed edge 201 surrounds the opening 28 from four directions, in a rectangular ring shape in plan view. However, it is not mandatory that the fourth inner recessed edge 201 surrounds the opening 28 from four directions. For example, the fourth inner recessed edge 201 may define the opening 28 from three directions, such that the opening 28 is open to outside through the second electrode section 21, in plan view. Alternatively, the fourth inner recessed edge 201 may be formed so as to define the opening 28 from one or two directions. As shown in FIG. 116, the fourth inner recessed edge 201 is inwardly recessed (opposite to the direction toward the inner space of the opening 18) with respect to the third edge 101.

The fourth outer recessed edge 202 is, as shown in FIG. 116, inwardly recessed (to the right in FIG. 116), with respect to the first outer edge 422 of the passivation layer 42 and the second outer edge 452 of the resin cover layer 45 to be described below, in plan view. In this embodiment, the fourth outer recessed edge 202 has an annular shape in plan view.

The photoelectric conversion layer 3 is interposed between the first conductive layer 1 and the second conductive layer 2, and disposed on the base substrate 41. The photoelectric conversion layer 3 is formed of an organic thin film, and configured to perform the photoelectric conversion function, to convert received light into electric power. Although the configuration of the photoelectric conversion layer 3 is not specifically limited, the photoelectric conversion layer 3 may include, for example, a bulk heterojunction organic active layer and a hole transport layer disposed on the bulk heterojunction organic active layer on the side of the first conductive layer 1. In this embodiment, the photoelectric conversion layer 3 is formed in a rectangular shape in plan view, however this is merely an example and the photoelectric conversion layer 3 may be formed in various shapes. The photoelectric conversion layer 3 has a thickness of, for example, 50 nm to 300 nm.

In the bulk heterojunction organic active layer, p-type organic active layer regions and n-type organic active layer regions are intermixed, forming a complicated bulk hetero pn junction. The p-type organic active layer region is, for example, formed of poly(3-hexylthiophene-2,5diyl) (P3HT), and the n-type organic active layer region is formed of 6,6-phenyl-C61-butyric acid methyl ester (PCBM), for example. The hole transport layer is formed of, for example, PEDOT:PSS.

Examples of materials that may be utilized to form the photoelectric conversion layer 3 include phthalocyanine (Pc), zinc-phthalocyanine (ZnPc), N,N′-dimethyl perylene-3,4,9,10-dicarboximide (Me-Ptcdi), and Buckminster fullerene (C60). These materials are, for example, utilized for vacuum vapor deposition.

In addition, poly[2-methoxy-5-(3,7-dimethyl octyloxy)]-1,4-phenylene vinylene (MDMO-PPV), poly[N-9′-hepta-decanyl-2,7-carbazole-alt-5,5-(4′,7′-di-thienyl-2′1′,3′-b3nzothiadizaole)] (PCDTBT), 6,6-phenyl-C61-butyric acid methyl ester (PC60BM), or 6,6-phenyl-C71-butyric acid methyl ester (PC70BM) may be utilized to form the photoelectric conversion layer 3. These materials are, for example, utilized for a solution process.

As shown in FIG. 120, the photoelectric conversion layer 3 includes the non-generation region 30, the generation region 31, the design display section 35, a plurality of openings 38, the fifth inner recessed edge 301, and the fifth outer recessed edge 302. In FIG. 120, the non-generation region 30 and the generation region 31 are shaded with scattered dots.

The design display section 35 constitutes a design exhibited in the outer appearance through the first conductive layer 1. The design constituted by the design display section include those that the user can visually recognize as visually singular feature, such as characters, marks, and patterns. In this embodiment, the design display section 35 represents an annular shape.

In this embodiment, the design display section 35 is constituted of the perforated portion 350. The perforated portion 350 is formed so as to penetrate through the photoelectric conversion layer 3 in the thickness direction. The perforated portion 350 is visible in the outer appearance through the first conductive layer 1. In this embodiment, the perforated portion 350 exposes the second conductive layer 2 on the side of the first conductive layer 1. In other words, a part of the second conductive layer 2 is visible in the outer appearance, through the perforated portion 350.

The generation region 31 is interposed between the first electrode section 11 of the first conductive layer 1 and the second electrode section 21 of the second conductive layer 2, and performs the photoelectric conversion function to contribute to the power generation. The shape of the generation region 31 coincides with the first electrode section 11 and the second electrode section 21, in plan view.

The non-generation region 30 corresponds to a portion of the photoelectric conversion layer 3 deviated, in plan view, from the first electrode section 11 of the first conductive layer 1 and the second electrode section 21 of the second conductive layer 2, and overlapping with the first end portion 14 of the first conductive layer 1. The first end portion 14 is in contact with the second end portion 24 of the second conductive layer 2, and hence the collected holes and electrons are instantly coupled. Therefore, the non-generation region 30 is not involved in the power generation. Thus, the region of the photoelectric conversion layer 3 other than the generation regions 31 corresponds to the non-generation region 30.

In this embodiment, the non-generation region 30 is located in the terminal region 34. The terminal region 34 includes the perforated portion 350 (design display section 35). The terminal region 34 includes the perforated portion 350 (design display section 35) enclosed in the first end portion 14 of the first conductive layer 1 in plan view, and overlaps with the first end portion 14 of the first conductive layer 1 in plan view. In addition, the terminal region 34 overlaps with the second end portion 24 of the second conductive layer 2. The first end portion 14 of the first conductive layer 1 and the second end portion 24 of the second conductive layer 2 are in contact with each other, via the perforated portion 350 in the terminal region 34.

The openings 38 are formed so as to penetrate through the photoelectric conversion layer 3 in the thickness direction. In this embodiment, two openings 38 are provided. The opening 38 at an upper position in FIG. 120 is formed, for example, to allow the speaker 705 to perform its function. The larger opening 38 at the central position in FIG. 120 is for exhibiting the information displayed by the display unit 702, in the outer appearance.

The fifth inner recessed edge 301 defines the opening 38 at the central position in FIG. 120. In this embodiment, the fifth inner recessed edge 301 surrounds the opening 38 from four directions, in a rectangular ring shape in plan view. However, it is not mandatory that the fifth inner recessed edge 301 surrounds the opening 38 from four directions. For example, the fifth inner recessed edge 301 may define the opening 38 from three directions, such that the opening 38 is open to outside through the generation region 31, in plan view. Alternatively, the fifth inner recessed edge 301 may be formed so as to define the opening 38 from one or two directions. In addition, as shown in FIG. 116, the fifth inner recessed edge 301 is inwardly recessed (opposite to the direction toward the inner space of the opening 18) with respect to the third edge 101.

The fifth outer recessed edge 302 is, as shown in FIG. 116, inwardly recessed (to the right in FIG. 116), with respect to the first outer edge 422 of the passivation layer 42 and the second outer edge 452 of the resin cover layer 45 to be described below, in plan view. In this embodiment, the fifth outer recessed edge 302 has an annular shape in plan view.

With the configuration described above, in the organic thin film solar cell module A13 the first extended portion 15 extends from the first electrode section 11. The second electrode section 21 extends from the second end portion 24. The second end portion 24 is in contact with the first end portion 14 via the perforated portion 350 in the terminal region 34. The second extended portion 16 extends from the first end portion 14. As result, the first extended portion 15 and the second extended portion 16 each act as an output terminal of the organic thin film solar cell module A13.

The passivation layer 42 is disposed on the second conductive layer 2, so as to protect the second conductive layer 2 and the photoelectric conversion layer 3. The passivation layer 42 is, for example, formed of SiN or SiON. The passivation layer 42 has a thickness of, for example, 0.5 μm to 2.0 μm and, in this embodiment, approximately 1.5 μm.

The resin cover layer 45 covers the passivation layer 42. The resin cover layer 45 is formed of, for example, a UV-curable resin. The resin cover layer 45 has a thickness of, for example, 3 μm to 20 μm and, in this embodiment, approximately 10 μm.

As shown in FIG. 122, the resin cover layer 45 includes a plurality of openings 458, the second edge 451, and the second outer edge 452. In FIG. 122, the resin cover layer 45 is hatched with oblique lines.

The openings 458 are each formed by removing a part of the resin cover layer 45, so as to penetrate therethrough. In this embodiment, two openings 458 are provided. The opening 458 at an upper position in FIG. 122 is formed, for example, to allow the speaker 705 to perform its function. The larger opening 458 at the central position in FIG. 122 is for exhibiting the information displayed by the display unit 702, in the outer appearance.

The second edge 451 defines the opening 458 at the central position in FIG. 122. In this embodiment, the second edge 451 surrounds the opening 458 from four directions, in a rectangular ring shape in plan view. However, it is not mandatory that the second edge 451 surrounds the opening 458 from four directions. For example, the second edge 451 may define the opening 18 from three directions, such that the opening 458 is open to outside through the resin cover layer 45, in plan view. Alternatively, the second edge 451 may be formed so as to define the opening 458 from one or two directions.

The second outer edge 452 is located on the side opposite to the second edge 451, across at least a part of the photoelectric conversion layer 3 in plan view, and corresponds, in this embodiment, to the outer peripheral edge of the resin cover layer 45.

The passivation layer 42 includes the first edge 421 and the first outer edge 422.

The first edge 421 coincides with the second edge 451 in plan view. In this embodiment, the first edge 421 forms a continuous surface with the second edge 451. The first outer edge 422 coincides with the second outer edge 452 in plan view. In this embodiment, the first outer edge 422 forms a continuous surface with the second outer edge 452.

As shown in FIG. 116, a part of the base substrate 41 is exposed through the opening 458 surrounded by the second edge 451 and the first edge 421, to form an exposed region 411. The exposed region 411 is not covered with the first conductive layer 1 or other components, and the surface of the base substrate 41 is directly exposed.

The bypass conductive section 5 provides a route having a lower resistance than the first conductive layer 1, for collecting the holes that have reached the first conductive layer 1. In this embodiment, the bypass conductive section 5 includes two bus-bar sections 51, a plurality of communication portions 52, and two collector electrodes 53. The bypass conductive section 5 is formed of a material lower in resistance than the first conductive layer 1, and includes, for example, Ag or carbon.

As shown in FIG. 116 and FIG. 122, one of the bus-bar sections 51 covers the second edge 451 and the first edge 421 over the entire length. The bus-bar section 51 covers a portion of the first conductive layer 1 located between the third edge 101 and the first edge 421 (second edge 451). The inner edge of the bus-bar section 51 coincides with the third edge 101, in plan view. The other bus-bar section 51 covers the second outer edge 452 and the first outer edge 422 over the entire length. This bus-bar section 51 covers the extended portion 103 of the first conductive layer 1. Thus, each of the two bus-bar sections 51 is electrically connected to the first conductive layer 1.

The communication portions 52 are formed on the resin cover layer 45, and connects the bus-bar section 51 on the inner side in FIG. 122 and the communication portion 52 on the outer side in FIG. 122. One of the two collector electrodes 53 is electrically connected to the first conductive layer, and the other is electrically connected to the second conductive layer 2.

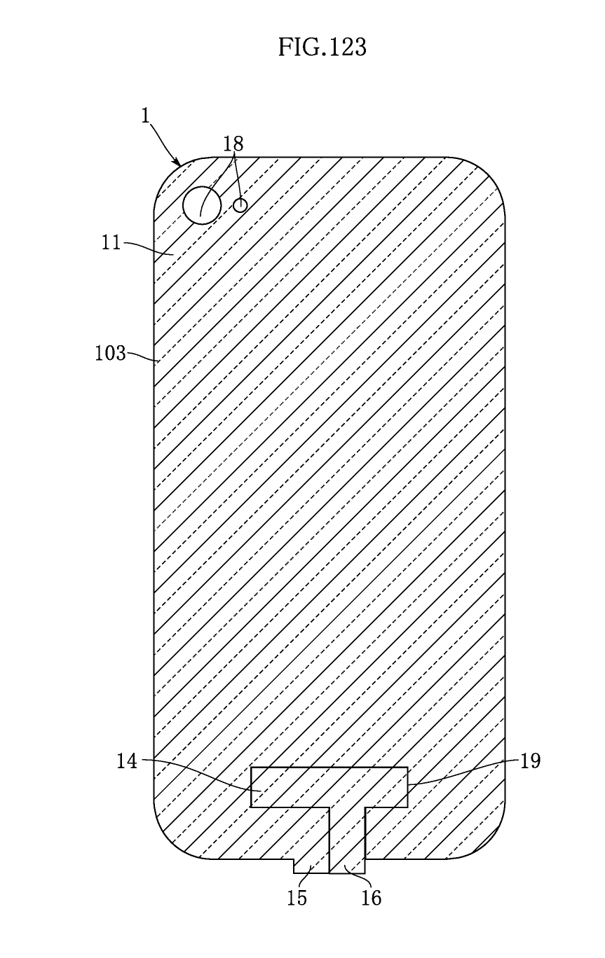

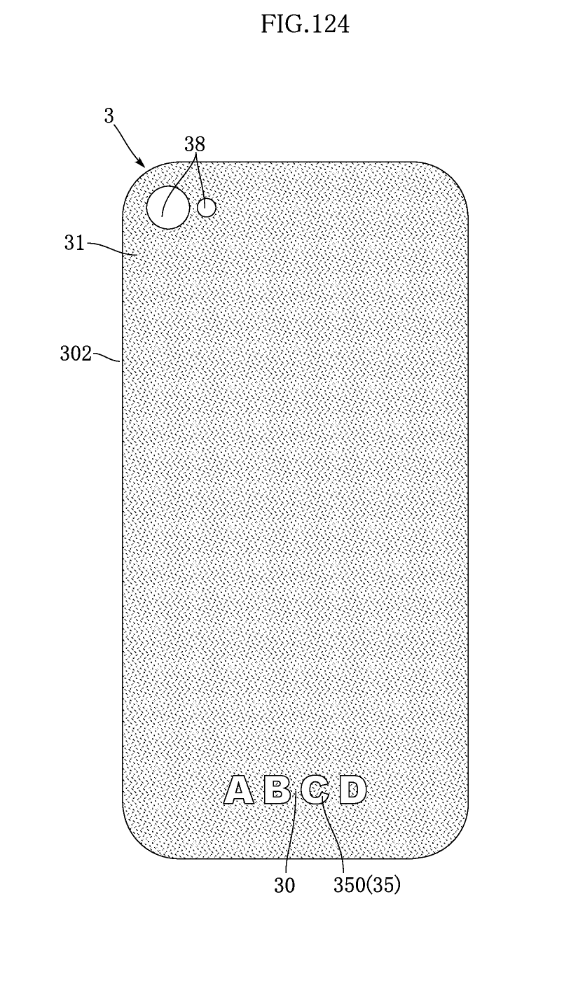

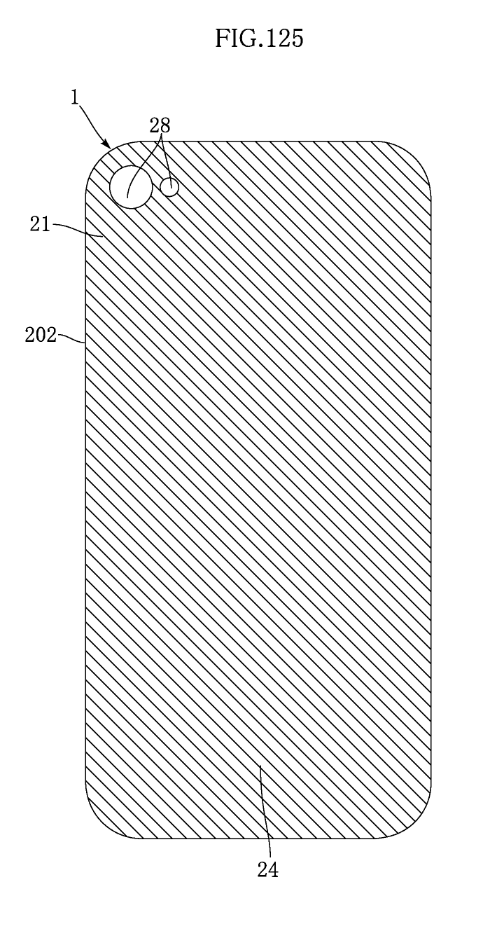

FIG. 123 is a plan view showing the first conductive layer 1 of the organic thin film solar cell module A14. FIG. 124 is a plan view showing the photoelectric conversion layer 3 of the organic thin film solar cell module A14. FIG. 125 is a plan view showing the second conductive layer 2 of the organic thin film solar cell module A14. FIG. 126 is a plan view showing the resin cover layer 45 and the bypass conductive section 5 of the organic thin film solar cell module A14.

The organic thin film solar cell module A14 is without the opening 18, the opening 28, the opening 38, and the opening 458 for exhibiting the display unit 702 in the outer appearance. Accordingly, the third edge 101, the fourth inner recessed edge 201, the fifth inner recessed edge 301, the first edge 421, and the second edge 451 are not provided. The bypass conductive section 5 includes the bus-bar sections 51 formed along the outer periphery, and is without the communication portion 52.

In this embodiment, as shown in FIG. 124, the photoelectric conversion layer 3 includes a plurality of perforated portions 350 (35). The perforated portions 350 each represent an alphabet. The first end portion 14 of the first conductive layer 1 and the second end portion 24 of the second conductive layer 2 are in contact with each other via the perforated portions 350, as in the organic thin film solar cell module A13.

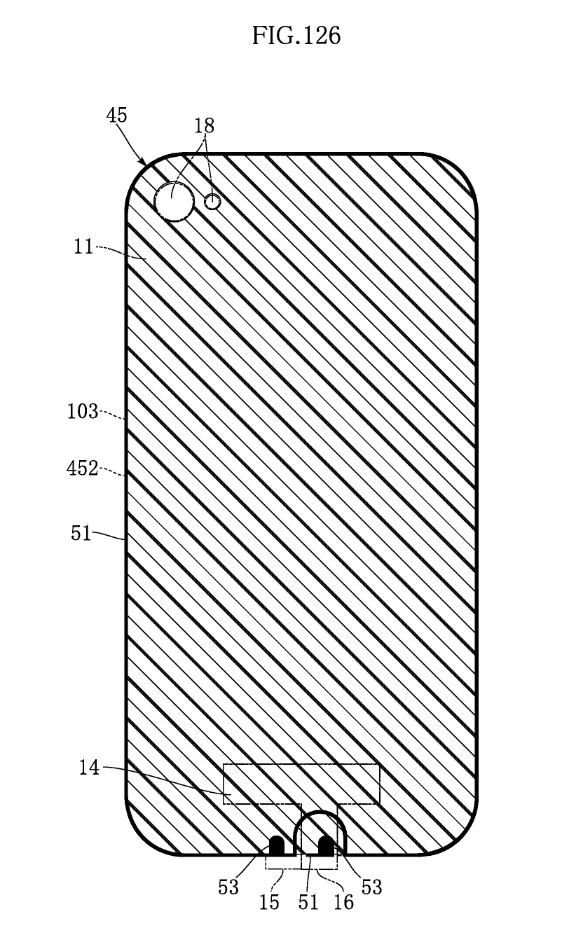

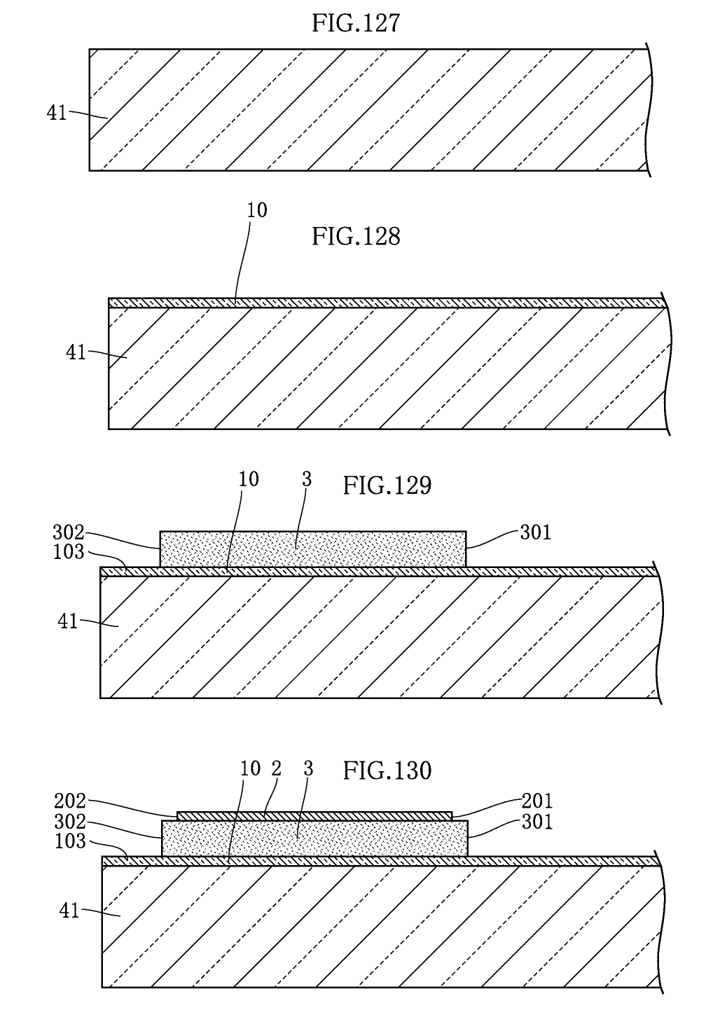

Referring now to FIG. 127 to FIG. 134, a manufacturing method of the organic thin film solar cell module A13 will be described hereunder. The cited drawings are turned upside down from FIG. 116, to facilitate understanding. In addition, FIG. 127 to FIG. 134 illustrate the formation process of the portion corresponding to the cross-section of the electronic device B5, taken along the line CXVI-CXVI in FIG. 113.

Referring first to FIG. 127, the base substrate 41 is prepared. Proceeding to FIG. 128, the first conductive film 10 formed of ITO is deposited on one of the surfaces of the base substrate 41, by a known method such as sputtering. Then the ITO is patterned to form the patterns of the openings 18 and the slits 19. For the patterning of the ITO, for example, wet etching, oxygen plasma etching, or laser patterning with green laser is adopted as the case may be. Without limitation to the above, the first conductive film 10 may be formed by directly patterning of the ITO on the base substrate 41, for example through a nanoimprint lithography process.

Proceeding to FIG. 129, the photoelectric conversion layer 3 is formed. To form the photoelectric conversion layer 3, an organic film is deposited on the base substrate 41 and the first conductive layer 1 for example by spin coating, and the organic film is patterned to form the fifth inner recessed edge 301, the fifth outer recessed edge 302, the openings 38, and the perforated portion 350 (design display section 35), by oxygen plasma etching or laser patterning. Without limitation to the above, the photoelectric conversion layer 3 may be formed by directly patterning the organic film on the base substrate 41 and the first conductive film 10, for example by slit coating, capillary coating, or gravure printing.

Proceeding to FIG. 130, the second conductive layer 2 is formed. To form the second conductive layer 2, for example, one of the aforementioned metals is deposited by vacuum vapor deposition on the base substrate 41, the first conductive film 10, and the photoelectric conversion layer 3, to deposit a metal film thereon. Then the metal film is patterned, for example by etching with a mask layer. Through such patterning, the second conductive layer 2 including the fourth inner recessed edge 201 and the fourth outer recessed edge 202 is formed on the photoelectric conversion layer 3.

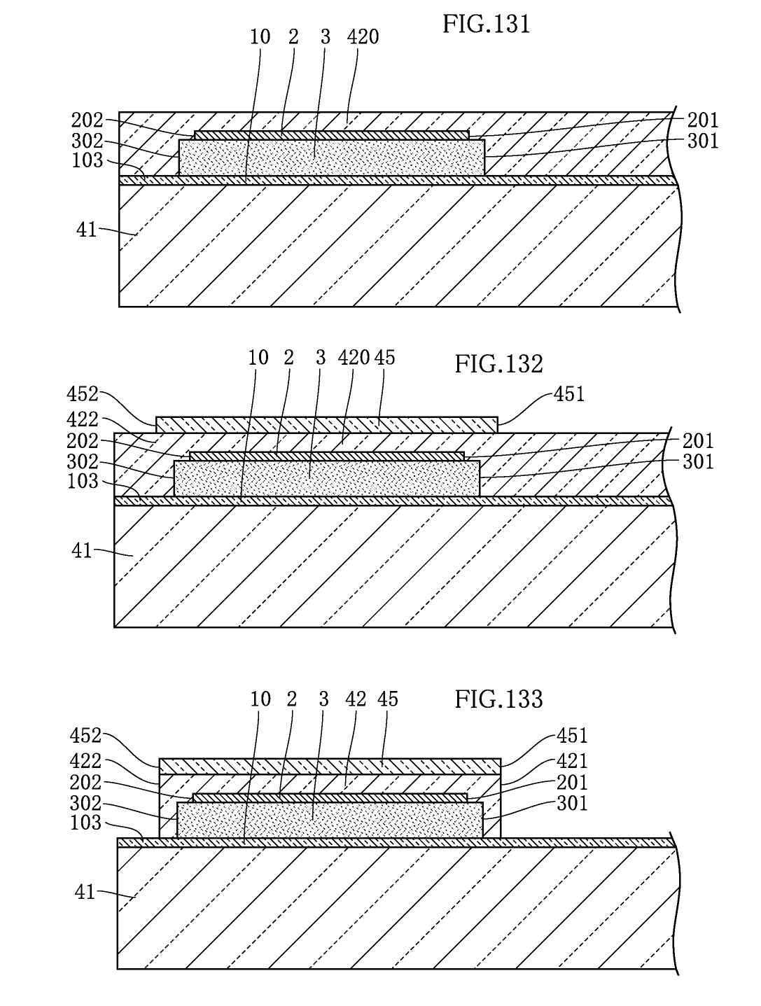

Proceeding to FIG. 131, the insulation film 420 is formed. To form the insulation film 420, SiN or SiON is deposited on the base substrate 41, the first conductive layer 1, the photoelectric conversion layer 3, and the second conductive layer 2, for example by plasma CVD.

Proceeding to FIG. 132, the resin cover layer 45 is formed. To form the resin cover layer 45, for example, a liquid resin material containing a UV-curable resin is applied to the insulation film 420 by screen printing, and the resin is irradiated with UV light thus to be cured. Thus, the resin cover layer 45 including the second edge 451 and the second outer edge 452 is obtained.

Proceeding to FIG. 133, the insulation film 420 is patterned, using the resin cover layer 45 as the mask. This patterning is performed through a wet etching process using hydrofluoric acid containing 0.55% to 4.5% of hydrogen fluoride. Such hydrofluoric acid barely dissolves the resin cover layer 45 formed of a UV-curable resin, but selectively dissolves the insulation film 420 formed of SiN or SiON. In addition, the hydrofluoric acid barely dissolves the first conductive film 10 formed of ITO. As result, the passivation layer 42 including the first edge 421 and the first outer edge 422 is formed. The first edge 421 coincides with the second edge 451 in plan view. The first edge 421 and the second edge 451 form a continuous surface. Likewise, the first outer edge 422 coincides with the second outer edge 452 in plan view. The first outer edge 422 and the second outer edge 452 form a continuous surface.

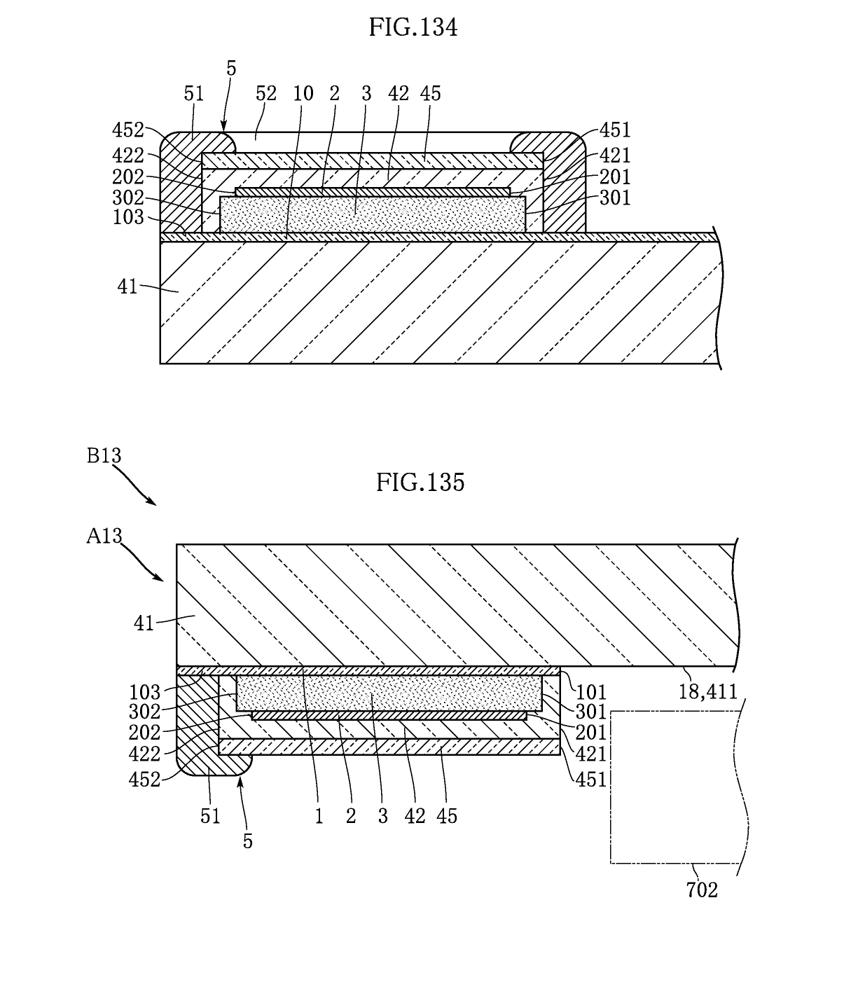

Proceeding to FIG. 134, the bypass conductive section 5 is formed. To form the bypass conductive section 5, for example, a paste containing Ag or carbon is applied, and then dried to harden the paste.

Then the first conductive film 10 is patterned. The patterning is performed, for example, with aqua regia in which concentrated hydrochloric acid and concentrated nitric acid are mixed in a ratio of 3 to 1. By such patterning, portions of the first conductive film 10 exposed from the bypass conductive section 5 and the resin cover layer 45 are selectively removed. As result, the first conductive layer 1 including the third edge 101 and so forth is formed. Through the mentioned process, the organic thin film solar cell module A13 can be obtained. The organic thin film solar cell module A14 can also be obtained through the same process.

The organic thin film solar cell module A13 and the electronic device B13 provide the following advantageous effects.

In this embodiment, the base substrate 41 is exposed in the regions adjacent to the second edge 451 and the second outer edge 452. In such regions, the passivation layer 42 and the resin cover layer 45 are not formed. Therefore, the mentioned regions can be finished with higher transparency, so that the display unit 702 can be more clearly exhibited in the outer appearance.

The first conductive layer 1 is not formed on the base substrate 41, except for a small region covered with the bus-bar section 51, in the region adjacent to the second edge 451 and the first edge 421. Although the first conductive layer 1 is formed of ITO, the first conductive layer 1 may be visually recognized as a faintly colored portion, depending on the condition of ambient light. The configuration according to this embodiment enables the region for exhibiting the display unit 702 in the outer appearance to be finished with prominent transparency, thereby realizing a more exquisite outer appearance.

The fifth inner recessed edge 301 of the photoelectric conversion layer 3 and the fourth inner recessed edge 201 of the second conductive layer 2 are spaced apart from the first edge 421 and the second edge 451. Accordingly, the second conductive layer 2 and the photoelectric conversion layer 3 can be prevented from being electrically connected improperly, to the bypass conductive section 5. In addition, the passivation layer 42 is interposed between the fourth inner recessed edge 201 and the fifth inner recessed edge 301, and between the first edge 421 and the second edge 451. Therefore, a short circuit between the second conductive layer 2 or photoelectric conversion layer 3 and the bus-bar section 51 of the bypass conductive section 5.

By the patterning of the insulation film 420 using the resin cover layer 45 as the mask, the passivation layer 42 can be formed in the same shape as the resin cover layer 45. In other words, forming the resin cover layer 45 from a material having high shape formability, such as the UV-curable resin, enables the passivation layer 42 to be formed in a desired shape, despite the material thereof having lower shape formability. The resin cover layer 45 may be removed after the passivation layer 42 is formed. However, keeping the resin cover layer 45 unremoved prevents intrusion of moisture and particles into the first conductive layer 1, the second conductive layer 2, and the photoelectric conversion layer 3, and contributes to improving the strength of the organic thin film solar cell module A13.

Providing the bypass conductive section 5 allows the holes diffused to the first conductive layer 1 to be led to the collector electrode 53, through the bus-bar section 51. Since the bypass conductive section 5 has lower resistance than the first conductive layer 1, the power is prevented from being converted into heat. Such an effect reduces the power generation loss of the organic thin film solar cell module A13 and the organic thin film solar cell module A14, and enables the power generation from the generation region 31 having a larger area.

Since the first conductive layer 1 is patterned after the bypass conductive section 5 is formed, the communication portion 52 of the bypass conductive section 5 enters into contact with a portion of the first conductive layer 1 having a significant area in plan view (for example, extended portion 103), instead of the end face of the first conductive layer 1. Such a configuration reduces contact resistance between the first conductive layer 1 and bypass conductive section 5, thereby assuring the electrical conduction therebetween.

FIG. 135 and FIG. 145 illustrate a variation and other embodiments of the present invention. In these drawings, the elements same as or similar to those of the foregoing embodiments are given the same numeral as above, and the description will not be repeated.

FIG. 135 illustrates a variation of the electronic device B13 and the organic thin film solar cell module A13. In this variation, the third edge 101 of the first conductive layer 1 is located at a position coinciding with the first edge 421 and the second edge 451, in plan view. In addition, the bus-bar section 51 on the inner side in the foregoing embodiment is not provided. Such a variation can be obtained by patterning the first conductive film 10 with the aqua regia, using the resin cover layer 45 as the mask.

The mentioned variation also enables the portion adjacent to the first edge 421 and the second edge 451 to be finished with higher transparency, thereby allowing the display unit 702 to be more clearly exhibited in the outer appearance.

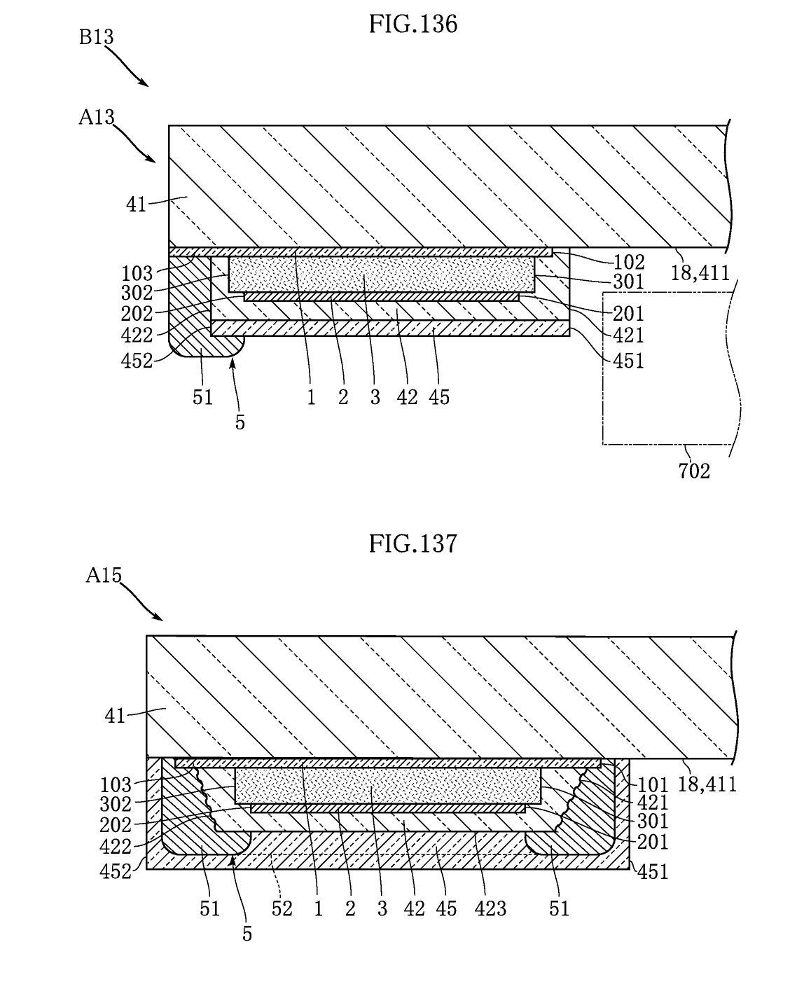

FIG. 136 illustrates another variation of the electronic device B13 and the organic thin film solar cell module A13. In this variation, the first conductive layer 1 includes the third inner recessed edge 102, instead of the third edge 101. The third inner recessed edge 102 is inwardly recessed with respect to the first edge 421 and the second edge 451, in plan view. In addition, the bus-bar section 51 on the inner side in the foregoing embodiment is not provided. Such a variation can be obtained by forming the third inner recessed edge 102 at the same time as the slit 19 and so forth, after forming the first conductive film 10 on the base substrate 41.

The configuration according to the mentioned variation also enables the portion adjacent to the first edge 421 and the second edge 451 to be finished with higher transparency, thereby allowing the display unit 702 to be more clearly exhibited in the outer appearance.

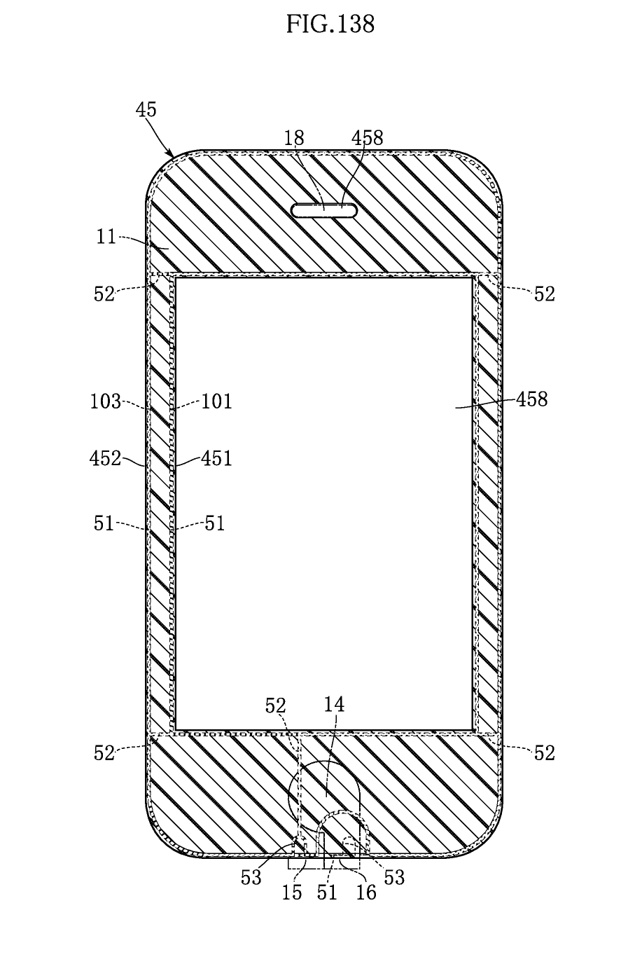

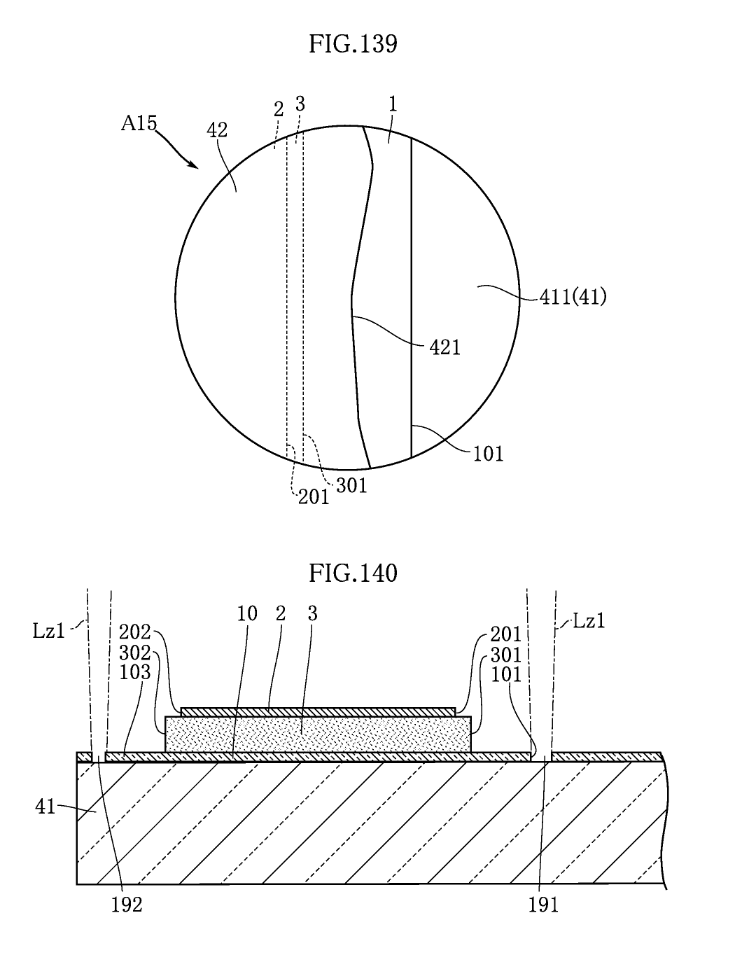

FIG. 137 to FIG. 139 illustrate the organic thin film solar cell module according to the fifteenth embodiment of the present invention. The organic thin film solar cell module A15 includes the first conductive layer 1, the second conductive layer 2, the photoelectric conversion layer 3, the base substrate 41, the passivation layer 42, the resin cover layer 45 and the bypass conductive section 5. The plan-view shape of the organic thin film solar cell module A15 is not specifically limited, and the illustrated example represents the same shape as that of the organic thin film solar cell module A13. FIG. 137 is an enlarged cross-sectional view of the organic thin film solar cell module A13, corresponding to FIG. 116. FIG. 138 is a partial plan view showing the resin cover layer and the bypass conductive section of the organic thin film solar cell module A15. FIG. 139 is an enlarged cross-sectional view, in which the resin cover layer 45 and the bypass conductive section 5 are omitted.

In this embodiment, the first edge 421 and the first outer edge 422 of the passivation layer 42 are, as shown in FIG. 137, formed in an uneven shape. In addition, the first edge 421 is, as a whole, inclined so as to be farther from the extended portion 103 of the first conductive layer 1 in plan view, at a position farther from the base substrate 41 in the thickness direction thereof. Likewise, the first outer edge 422 is inclined so as to be farther from the third edge 101 in plan view, at a position farther from the base substrate 41 in the thickness direction thereof. Further, the first edge 421 according to this embodiment has, as shown in FIG. 139, a non-linear shape spaced apart from the third edge 101, in plan view. The first edge 421 has a shape in which, for example, a plurality of bent lines and curved lines are connected. The first outer edge 422 also has a non-linear shape in plan view.

The bypass conductive section 5 includes two bus-bar sections 51 and the communication portion 52. The bypass conductive section 5 is formed of a material lower in resistance than the first conductive layer 1, and contains, for example, Ag or carbon.

One of the bus-bar sections 51 covers the first edge 421 of the passivation layer 42, over the entire length. The bus-bar section 51 covers a portion of the first conductive layer 1 located between the third edge 101 and the first edge 421. The inner edge of the bus-bar section 51 protrudes from the third edge 101, in plan view. Accordingly, the bus-bar section 51 is in direct contact with the base substrate 41. The other bus-bar section 51 covers the first outer edge 422 of the passivation layer 42, over the entire length. This bus-bar section 51 covers the extended portion 103 of the first conductive layer 1, and is in direct contact with the base substrate 41. Thus, each of the two bus-bar sections 51 is electrically connected to the first conductive layer 1.

The communication portion 52 is formed on a surface 423 of the passivation layer 42. The communication portion 52 connects, for example, the two bus-bar sections 51 to each other, or a portion of the bypass conductive section 5 other than the bus-bar section 51 and the communication portion 52, to the bus-bar section 51.

The resin cover layer 45, which covers the passivation layer 42 and the bypass conductive section 5 as shown in FIG. 137 and FIG. 138, is formed of, for example, a UV-curable resin. The resin cover layer 45 may also serve as a transparent bonding layer for bonding the organic thin film solar cell module A15 and the display unit 702 together. In the illustrated example, the second the edge 451 and the second outer edge 452 of the resin cover layer 45 extend, in plan view, from a portion of the surface 423 of the passivation layer 42 exposed from the bus-bar section 51, beyond the first edge 421 and the first outer edge 422 of the passivation layer 42 and the bypass conductive section 5. Accordingly, the resin cover layer 45 includes a portion in direct contact with the base substrate 41. In addition, the resin cover layer 45 is in close contact with the portion of the surface 423 of the passivation layer 42 exposed from the bus-bar section 51.

A manufacturing method of the organic thin film solar cell module A15 will now be described hereunder. The drawings referred to in the following description are turned upside down from FIG. 137, to facilitate understanding.

First, the base substrate 41 shown in FIG. 127 is prepared. Proceeding to FIG. 128, the first conductive film 10 formed of ITO is deposited on one of the surfaces of the base substrate 41, by a known method such as sputtering. Then the photoelectric conversion layer 3 is formed as shown in FIG. 129, and the second conductive layer 2 is formed as shown in FIG. 130.

Proceeding to FIG. 140, the first conductive film 10 is patterned by laser patterning utilizing the laser beam Lz1, to form the slit 191 and the slit 192. The type of the laser beam Lz1 is not specifically limited provided that the laser is capable of patterning the first conductive film 10 and, for example, the IR laser beam may be employed. One of the edges of the first conductive film 10 defining the slit 191, on the side of the second conductive layer 2 and the photoelectric conversion layer 3 shown in FIG. 140, corresponds to the third edge 101. The portion of the first conductive film 10 between the slit 192 and the fifth outer recessed edge 302 of the photoelectric conversion layer 3 corresponds to the extended portion 103.

The patterning for forming the slit 191 and the slit 192 in the first conductive film 10 may be performed before the formation of the photoelectric conversion layer 3. For this patterning, for example, wet etching or oxygen plasma etching may be adopted, as the case may be. Without limitation to the above, the first conductive film 10 may be formed by directly patterning the ITO on the base substrate 41, for example through a nanoimprint lithography process.

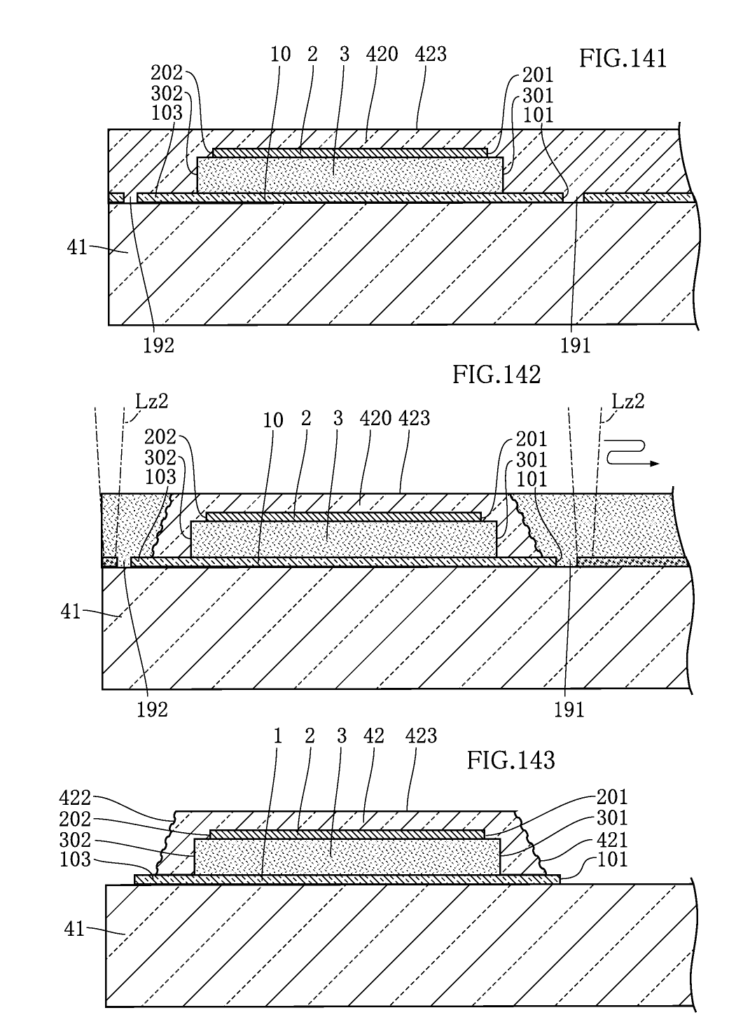

Proceeding to FIG. 141, the insulation film 420 is formed. To form the insulation film 420, a film of SiN or SiON is deposited on the base substrate 41, the first conductive film 10, the photoelectric conversion layer 3, and the second conductive layer 2, for example by plasma CVD.

Then the base substrate 41 is exposed in a region adjacent to the first edge 421, by partially removing the insulation film 420 thereby forming the passivation layer 42 having the first edge 421, and partially removing the first conductive film 10 thereby forming the first conductive layer 1. In this embodiment, the exposing of the includes, as shown in FIG. 142, irradiating the first conductive film 10 with the laser beam Lz2 through the insulation film 420, thereby partially removing the first conductive film 10 and the insulation film 420. In FIG. 142, a portion of the first conductive film 10 shaded with scattered dots that are relatively larger is the area irradiated with the laser beam Lz2. A portion of the insulation film 420 shaded with scattered dots that are relatively smaller is the portion removed owing to the irradiation of the laser beam Lz2. Here, for example an etching process may be adopted, without limitation of the irradiation of the laser beam Lz2.

More specifically, the portions of the first conductive film 10 opposite to the second conductive layer 2 and the photoelectric conversion layer 3 shown in FIG. 142, across the slit 191 and the slit 192 respectively, are irradiated with the laser beam Lz2 through the insulation film 420. For example, the IR laser beam having a wavelength of approximately 1,064 nm may be adopted as the laser beam Lz2. The portion of the first conductive film 10 irradiated with the laser beam Lz2 instantly volatilizes, upon being exposed to a significant amount of energy.

The laser beam Lz2 having the mentioned wavelength is barely absorbed by the insulation film 420, unlike the case of the first conductive film 10. Accordingly, the insulation film 420 is not directly destroyed by the laser beam Lz2. However, a portion of the insulation film 420 in contact with the first conductive film 10 is supported by the base substrate 41, via the first conductive film 10. When the first conductive film 10 volatilizes owing to the irradiation of the laser beam Lz2, the portion of the insulation film 420 is no longer supported by the base substrate 41. In addition, a portion of the insulation film 420, superposed on the portion of the first conductive film 10 irradiated with the laser beam Lz2 (portion shaded with the scattered dots that are relatively larger in FIG. 142), partially splashes owing to the volatilization pressure of the first conductive film 10.

Further, through investigations carried out by the present inventor, it has proved that a portion of the insulation film 420 adjacent to the portion of the first conductive film 10 irradiated with the laser beam Lz2 also splashes owing to the volatilization pressure of the first conductive film 10. In FIG. 142, the portion of the insulation film 420 that splashes as result of the irradiation of the laser beam Lz2 is shaded with scattered dots that are relatively smaller. In this embodiment, the portion of the insulation film 420 that splashes is located on the side of the second conductive layer 2 and the photoelectric conversion layer 3, beyond the slit 191 and the slit 192. However, the size and position of the slit 191 and the slit 192, as well as the irradiation range and output of the laser beam Lz2 are properly adjusted, so as to prevent the passivation layer 42 from being destroyed to such an extent that a part of the second conductive layer 2 and the photoelectric conversion layer 3 is exposed. Accordingly, the edge of the insulation film 420 on the side of the slit 191 constitutes the first edge 421, and the edge on the side of the slit 192 constitutes the first outer edge 422. The portion of the first conductive film 10 adjacent to the slit 191, shaded with the scattered dots, is removed by the irradiation of the laser beam Lz2. Therefore, the edge of the first conductive film 10 on the side of the photoelectric conversion layer 3 with respect to the slit 191 in plan view constitutes the third edge 101. Likewise, the portion of the first conductive film 10 adjacent to the slit 192, shaded with the scattered dots, is also removed by the irradiation of the laser beam Lz2. In addition, a portion of the first conductive film 10 adjacent to the slit 192 is exposed from the passivation layer 420, since the portion of the insulation film 420 adjacent to the slit 192 partially splashes owing to the irradiation of the laser beam Lz2. The exposed portion constitutes the extended portion 103.

Upon partially removing as above the first conductive film 10 and the insulation film 420 by the irradiation of the laser beam Lz2, the passivation layer 42 having the first edge 421 and the first outer edge 422 is formed, as shown in FIG. 143. In addition, the first conductive layer 1 including the portions extending from the first edge 421 and the first outer edge 422 is formed. At the same time, the third edge 101 and the extended portion 103 are formed. Here, after the process shown in FIG. 142, the processed portion may be washed, for example with aqua regia, to remove the residue of the first conductive film 10 and other components remaining on the base substrate 41.

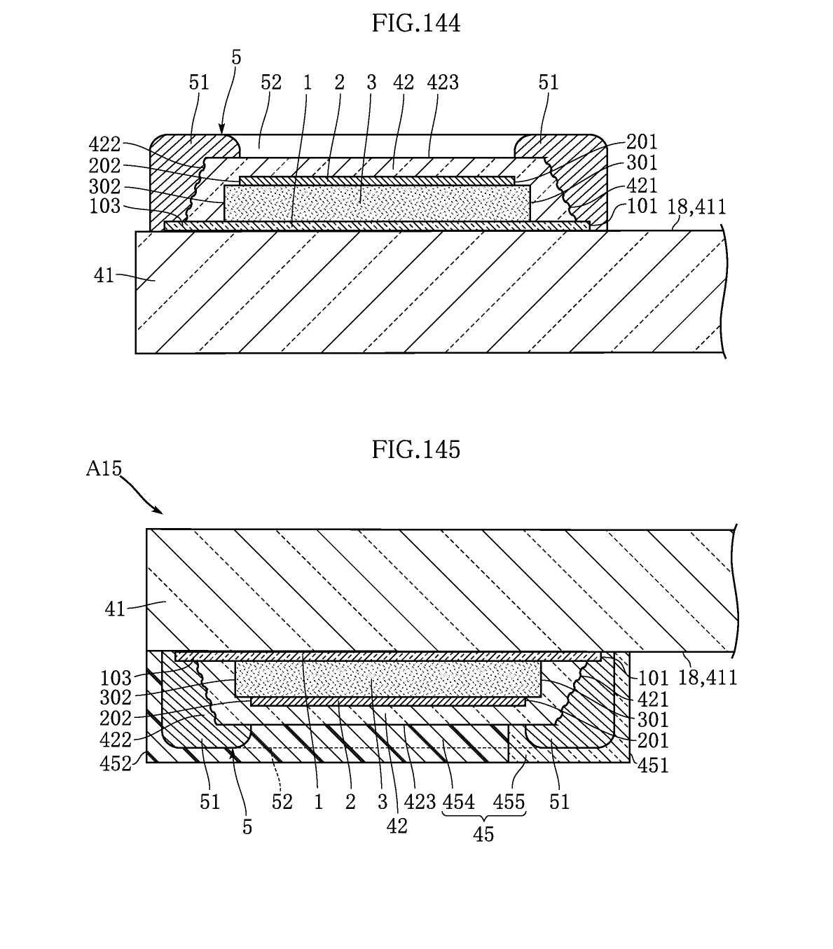

Proceeding to FIG. 144, the bypass conductive section 5 is formed. To form the bypass conductive section 5, for example, a paste containing Ag or carbon is applied, and then dried to harden the paste. The bypass conductive section 5 is formed so as to cover the portion of the first conductive layer 1 extending from the passivation layer 42. In addition, it is preferable to form the bypass conductive section 5 so as to make the bypass conductive section 5 directly contact the base substrate 41. Thus, the bypass conductive section 5 including the bus-bar section 51 and the communication portion 52 is obtained.

Thereafter, the resin cover layer 45 is formed so as to cover the bypass conductive section 5 and the passivation layer 42. To form the resin cover layer 45, for example, a liquid resin material containing a UV-curable resin is applied to the passivation layer 42 by screen printing, and the resin is irradiated with UV light thus to be cured. Through the mentioned process, the organic thin film solar cell module A15 shown in FIG. 137 can be obtained. The resin cover layer 45 covering the bypass conductive section 5 may also be provided in the organic thin film solar cell module A13 and the organic thin film solar cell module A14.

The configuration according to the above embodiments also allows the portion adjacent to the first edge 421 to be finished with higher transparency, and the display unit 702 to be more clearly exhibited in the outer appearance.

Since the bypass conductive section 5 is covered with the resin cover layer 45, the bypass conductive section 5 can be kept from being exposed to ambient air. Therefore, the bypass conductive section 5 can be prevented from being corroded, and reduction in resistance due to the presence of the bypass conductive section 5 can be maintained for an extended period of time.

Since the first edge 421 and the first outer edge 422 are formed in an uneven shape, the adhesion strength between the first edge 421 and the bus-bar section 51 of the bypass conductive section 5, and between the first outer edge 422 and the bus-bar section 51 can be improved.

As shown in FIG. 142, the passivation layer 42 is removed utilizing the volatilization of the first conductive layer 1 caused by the irradiation of the laser beam Lz2 on the first conductive layer 1. Therefore, there is no need to employ a single-purpose laser beam or chemical for removing the passivation layer 42. This is advantageous for reduction in cost and time for the manufacturing. Employing the IR laser beam as the laser beam Lz2 allows the first conductive film 10 to be irradiated with higher efficiency, with the laser beam Lz2 through the insulation film 420. In addition, employing the IR laser beam as the laser beam Lz2 provides the advantage in that the first edge 421 and the first outer edge 422 of the passivation layer 42 can be finished in an uneven shape. Here, SiN, which is an example of the material of the insulation film 420, transmits light having a wavelength longer than 400 nm. Accordingly, in the case where the insulation film 420 is formed of SiN, the green laser beam, which has the wavelength of 532 nm, may be employed as the laser beam Lz2. On the other hand, in the case where UV laser beam having the wavelength of 355 nm is employed as the laser beam Lz2, the insulation film 420 and the first conductive film 10 both absorb the laser beam Lz2, and therefore these films can both be removed at a time.

The partial removal of the passivation layer 42 and the first conductive layer 1 is performed with the laser beam Lz2. The irradiation range of the laser beam Lz2 can be accurately controlled. Therefore, the laser beam Lz2 is suitable for removing a desired portion of the passivation layer 42 and the first conductive layer 1.

The phenomenon that the passivation layer 42, located adjacent to a region of the first conductive layer 1 irradiated with the laser beam Lz2, is destroyed is utilized. Accordingly, in the region of the first conductive layer 1 exposed from the passivation layer 42 shown in FIG. 143, the portion of the passivation layer 42 that was covering this region is removed, despite that this region is not irradiated with the laser beam Lz2. Therefore, the region of the first conductive layer 1 exposed from the passivation layer 42 can be prevented from being accidentally destroyed, in the removal process of the passivation layer 42.

Forming the slit 191 and the slit 192 in the first conductive layer 1 prevents unintended expansion of the region of the passivation layer 42 that may be affected by the volatilization of the first conductive layer 1. In addition, forming the slit 191 and the slit 192 prevents, even when a part of the first conductive film 10 remains in the region to be removed, in the process of partially removing the first conductive film 10 shown in FIG. 142 and FIG. 143, accidental electrical connection between the residual part and the first conductive layer 1. However, the portion of the first conductive film 10 located opposite to the photoelectric conversion layer 3 across the slit 192 may remain as a part of the organic thin film solar cell module A15, without being removed. This portion is kept from being electrically connected to the first conductive layer 1, by the presence of the slit 192. Skipping the removal process of this portion contributes to reducing the manufacturing time. Here, the provision of the slit 191 and the slit 192 is merely an example, and these slits may be omitted.

FIG. 145 illustrates a variation of the organic thin film solar cell module A15. In this variation, the resin cover layer includes a non-translucent portion 454 and a translucent portion 455. The non-translucent portion 454 overlaps with the bypass conductive section 5 in plan view, and is located on the outer side with respect to the first edge 421. The non-translucent portion 454 is formed of a non-translucent material, for example a white resin. The translucent portion 455 is located in a region including a region located opposite to the first outer edge 422 with respect to the first edge 421. In the example shown in FIG. 145, the translucent portion 455 is formed so as to span over the bus-bar section 51 on the right in the drawing. In addition, a part of the translucent portion 455 is in contact with the base substrate 41. The configuration according to this variation can also protect the bypass conductive section 5. Further, the presence of the non-translucent portion 454 prevents degradation of the bypass conductive section 5 due to exposure to light, such as UV light.

The organic thin film solar cell module and the electronic device according to the present invention are in no way limited to the foregoing embodiments. The specific configurations of the elements of the organic thin film solar cell module and the electronic device according to the present invention may be modified in various manners.

The foregoing configuration according to the present invention is broadly applicable, in addition to the mobile phone terminal, to various electronic devices that utilize the photovoltaic generation, such as a wrist watch and an electronic calculator.

The technical features of the present invention may be expressed as the following appendices.

### Appendix 1D

An organic thin film solar cell module including:

a transparent base substrate;

a transparent first conductive layer disposed on the base substrate;

a second conductive layer;

a photoelectric conversion layer formed of an organic thin film and interposed between the first conductive layer and the second conductive layer; and

a passivation layer covering the second conductive layer,

in which the passivation layer includes a first edge, and

the base substrate is exposed in a region adjacent to the first edge.

### Appendix 2D

The organic thin film solar cell module according to appendix 1D, in which the first conductive layer includes a third edge coinciding with the first edge in plan view.

### Appendix 3D

The organic thin film solar cell module according to appendix 1D, in which the first conductive layer includes a third inner recessed edge inwardly recessed with respect to the first edge, in plan view.

### Appendix 4D

The organic thin film solar cell module according to appendix 2D, in which the second conductive layer includes a fourth inner recessed edge inwardly recessed with respect to the first edge, in plan view.

### Appendix 5D

The organic thin film solar cell module according to appendix 4D, in which the photoelectric conversion layer includes a fifth inner recessed edge, inwardly recessed with respect to the first edge in plan view.

### Appendix 6D

The organic thin film solar cell module according to appendix 5D, in which the fourth inner recessed edge is inwardly recessed with respect to the fifth inner recessed edge, in plan view.

### Appendix 7D

The organic thin film solar cell module according to any one of appendices 4D to 6D, in which the first edge has an annular shape in plan view.

### Appendix 8D

The organic thin film solar cell module according to appendix 7D, in which the third edge has an annular shape in plan view.

### Appendix 9D

The organic thin film solar cell module according to appendix 3D, in which the third inner recessed edge has an annular shape in plan view.

### Appendix 10D

The organic thin film solar cell module according to appendix 8D or 9D, in which the fourth inner recessed edge has an annular shape in plan view.

### Appendix 11D

The organic thin film solar cell module according to appendix 10D, in which the fifth inner recessed edge has an annular shape in plan view.

### Appendix 12D

The organic thin film solar cell module according to any one of appendices 1D to 11D, in which the first conductive layer is formed of ITO.

### Appendix 13D

The organic thin film solar cell module according to any one of appendices 1D to 12D, in which the second conductive layer is formed of a metal.

### Appendix 14D

The organic thin film solar cell module according to appendix 13D, in which the second conductive layer is formed of A1.

### Appendix 15D

The organic thin film solar cell module according to any one of appendices 1D to 14D, in which the passivation film is formed of SiN.

### Appendix 16D

The organic thin film solar cell module according to any one of appendices 1D to 15D, further including a resin cover layer covering the passivation film, the resin cover layer including a second edge coinciding with the first edge in plan view.

### Appendix 17D

The organic thin film solar cell module according to appendix 16D, in which the second edge and the first edge form a continuous surface.

### Appendix 18D

The organic thin film solar cell module according to appendix 16D or 17D, in which the second edge has an annular shape in plan view.

### Appendix 19D

The organic thin film solar cell module according to any one of appendices 16D to 18D, in which the resin cover layer is formed of a UV-curable resin.

### Appendix 20D

The organic thin film solar cell module according to any one of appendices 16D to 19D, in which the resin cover layer includes a second outer edge located opposite to the second edge across at least a part of the photoelectric conversion layer in plan view,

the passivation layer includes a first outer edge coinciding with the second outer edge in plan view,

the first conductive layer includes an extended portion extending outward from the second outer edge and the first outer edge, and

the organic thin film solar cell module further includes a bypass conductive section covering at least a part of the extended portion, and formed of a material having lower resistance than a material of the first conductive layer.

### Appendix 21D

The organic thin film solar cell module according to appendix 20D, in which the second outer edge and the first outer edge form a continuous surface.

### Appendix 22D

The organic thin film solar cell module according to appendix 20D or 21D, in which the bypass conductive section covers the second outer edge and the first outer edge.

### Appendix 23D

The organic thin film solar cell module according to any one of appendices 20D to 22D, in which the bypass conductive section includes Ag or carbon.

### Appendix 24D

The organic thin film solar cell module according to any one of appendices 1D to 15D, in which the passivation layer includes a first outer edge located opposite to the first edge across at least a part of the photoelectric conversion layer in plan view,

the first conductive layer includes an extended portion extending outward from the first outer edge, and

the organic thin film solar cell module further includes a bypass conductive section covering at least a part of the extended portion, and formed of a material having lower resistance than a material of the first conductive layer, and a resin cover layer covering the bypass conductive section.

### Appendix 25D

The organic thin film solar cell module according to appendix 24D, in which the bypass conductive section covers the first outer edge.

### Appendix 26D

The organic thin film solar cell module according to appendix 24D or 25D, in which the bypass conductive section includes Ag or carbon.

### Appendix 27D

The organic thin film solar cell module according to any one of appendices 24D to 26D, in which the resin cover layer includes a non-translucent portion overlapping with the bypass conductive section in plan view, and formed in a region on the side of the first outer edge, with respect to the first edge.

### Appendix 28D

The organic thin film solar cell module according to appendix 27D, in which the non-translucent portion is white.

### Appendix 29D

The organic thin film solar cell module according to any one of appendices 20D to 28D, in which the second conductive layer the second conductive layer includes a fourth outer recessed edge, inwardly recessed with respect to the second outer edge and the first outer edge, in plan view.

### Appendix 30D

The organic thin film solar cell module according to any one of appendices 20D to 29D, in which the photoelectric conversion layer includes a fifth outer recessed edge, inwardly recessed with respect to the second outer edge and the first outer edge in plan view.

### Appendix 31D

An electronic device including:

the organic thin film solar cell module according to any one of appendices 1D to 30D; and

a drive unit to operate by power supplied from the organic thin film solar cell module.

### Appendix 32D

A method of manufacturing an organic thin film solar cell module, the method including:

disposing a transparent first conductive layer on a transparent base substrate;

disposing a photoelectric conversion layer formed of an organic thin film on the first conductive layer;

disposing a second conductive layer on the photoelectric conversion layer;

disposing an insulation film covering the second conductive layer; and

exposing the base substrate in a region adjacent to a first edge of a passivation layer, including partially removing the insulation film thereby forming the passivation layer having the first edge, and partially removing the first conductive film thereby forming a first conductive layer.

### Appendix 33D

The method according to appendix 32D, further including:

after the forming of the insulation film and before the exposing of the base substrate,

disposing a resin cover layer having a second edge on the insulation film,

in which the exposing of the base substrate includes:

partially removing the insulation film in a region delimited by the second edge thereby forming the passivation layer having the first edge coinciding with the second edge in plan view; and

removing a portion of the first conductive film exposed from the first edge and the second edge, thereby forming the first conductive layer.

### Appendix 34D

The method according to appendix 33D, in which the exposing of the base substrate includes forming the first conductive layer, having a third edge coinciding with the second edge and the first edge in plan view.

### Appendix 35D

The method according to appendix 34D, in which the second edge and the first edge are formed in an annular shape in plan view.

### Appendix 36D

The method according to appendix 35D, in which the third edge is formed in an annular shape in plan view.

### Appendix 37D

The method according to any one of appendices 33D to 36D, in which the first conductive layer is formed of ITO.

### Appendix 38D

The method according to any one of appendices 33D to 37D, in which the second conductive layer is formed of a metal.

### Appendix 39D

The method according to appendix 38D, in which the second conductive layer is formed of A1.

### Appendix 40D

The method according to any one of appendices 33D to 39D, in which the passivation film is formed of SiN.

### Appendix 41D

The method according to any one of appendices 33D to 40D, in which the resin cover layer is formed of a UV-curable resin.

### Appendix 42D

The method according to any one of appendices 33D to 41D, in which the disposing of the resin cover layer includes forming a second outer edge at a position opposite to the second edge across at least a part of the photoelectric conversion layer in plan view,

the method further including:

partially removing the insulation film in a region delimited by the second edge, thereby forming, in the passivation layer, a first outer edge coinciding with the second outer edge in plan view; and

forming a bypass conductive section so as to cover at least a part of an extended portion extending outward from the second outer edge and the first outer edge of the first conductive layer, the bypass conductive section being formed of a material having lower resistance than a material of the first conductive layer.

### Appendix 43D

The method according to appendix 42D, in which the forming of the bypass conductive section includes covering the second outer edge and the first outer edge with the bypass conductive section.

### Appendix 44D

The method according to appendix 42D or 43D, in which forming of the bypass conductive section includes employing Ag or carbon.

### Appendix 45D

The method according to appendix 32D, in which the exposing of the base substrate includes irradiating the first conductive film with a laser beam through the insulation film, so as to partially remove the first conductive film and the insulation film.

### Appendix 46D

The method according to appendix 45D, in which the exposing of the base substrate includes removing a region of the insulation film adjacent in plan view to the region thereof irradiated with the laser beam in the partially removing process, thereby forming an extended portion by exposing a portion of the first conductive film unirradiated with the laser beam from the passivation layer,

the method further including:

forming a bypass conductive section so as to cover at least a part of the extended portion, from a material having lower resistance than a material of the first conductive layer; and

forming a resin cover layer covering the bypass conductive section.

### Appendix 47D

The method according to appendix 46D, in which the bypass conductive section includes Ag or carbon.

### Appendix 48D

The method according to appendix 46D or 47D, in which the forming of the resin cover layer includes forming a non-translucent portion in a region overlapping with the bypass conductive section in plan view, and on the side of the first outer edge, with respect to the first edge.

### Sixteenth to Eighteenth Embodiments

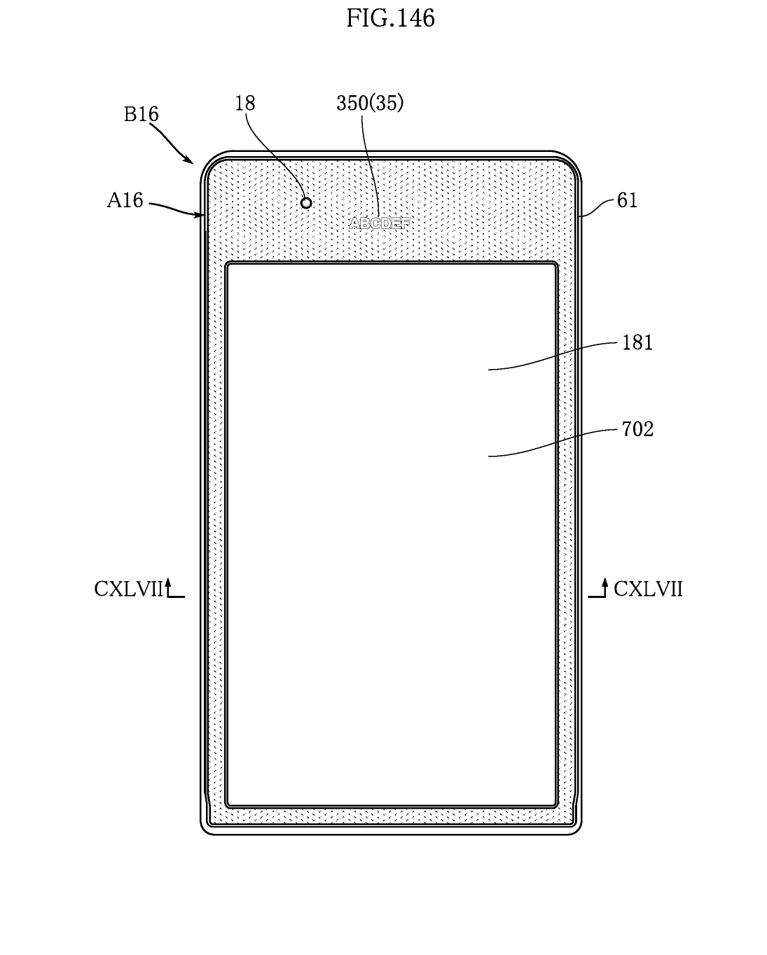

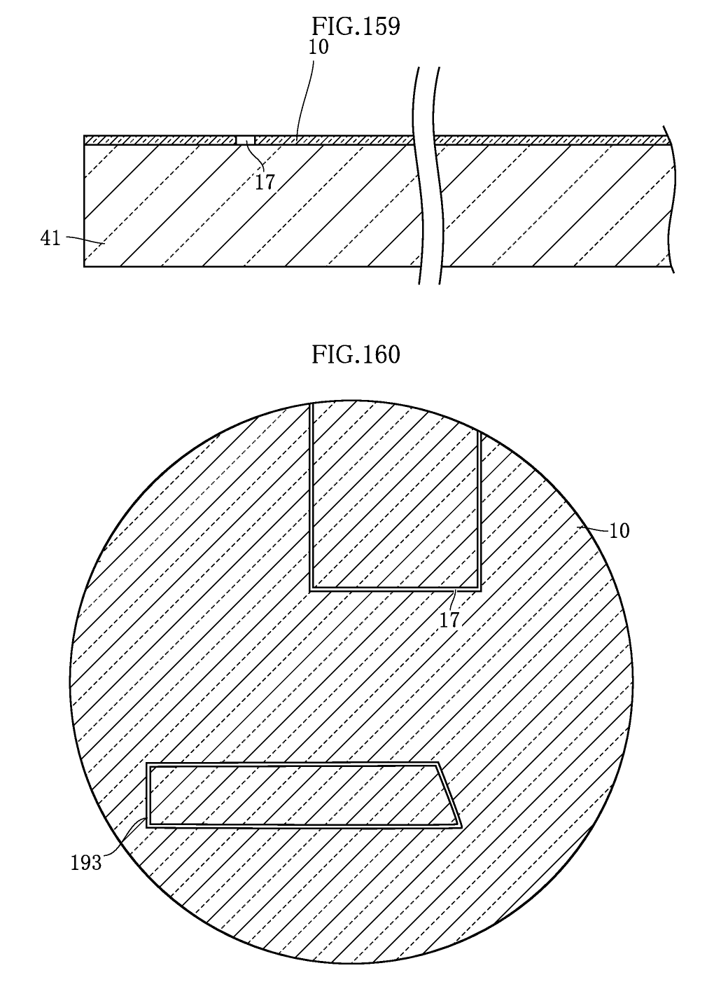

The reference numerals used for sixteenth to eighteenth embodiments and FIG. 146 to FIG. 183 are given for these particular embodiment and drawings, and independent of numerals used for other embodiments and drawings. It should be noted, however, that the arrangements of the sixteenth to eighteenth embodiments and those of any other embodiment may be combined or exchanged in an appropriate manner.

The term “transparent” used herein may be defined as having a transmittance of approximately 50% or higher. The term “transparent” may also be used for visible light when it is colorless and clear. The visible light corresponds to a wavelength range of approximately 360 nm to 830 nm and an energy range of approximately 3.45 eV to 1.49 eV. When a transmittance of a substance is 50% or higher in these ranges, that substance may be regarded as transparent.

FIG. 146 to FIG. 151 illustrate an electronic device according to the thirteenth embodiment of the present invention, and an organic thin film solar cell module according to the thirteenth and fourteenth embodiments of the present invention. The electronic device B16 according to this embodiment includes an organic thin film solar cell module A16, an organic thin film solar cell module A17, the case 61, the control unit 701, the display unit 702, the input unit 703, the microphone 704, the speaker 705, the wireless communication unit 706, and the battery 707, and is configured as a mobile phone terminal.

The case 61, which accommodates therein other components of the electronic device B16, is formed of a metal, a resin, or glass.

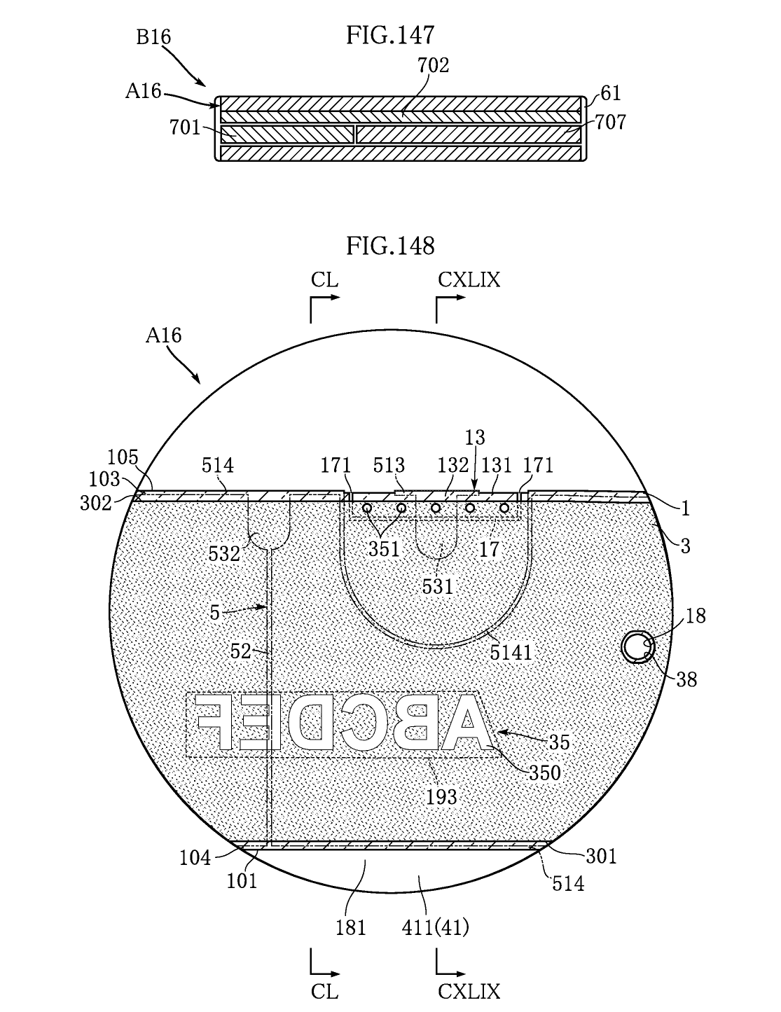

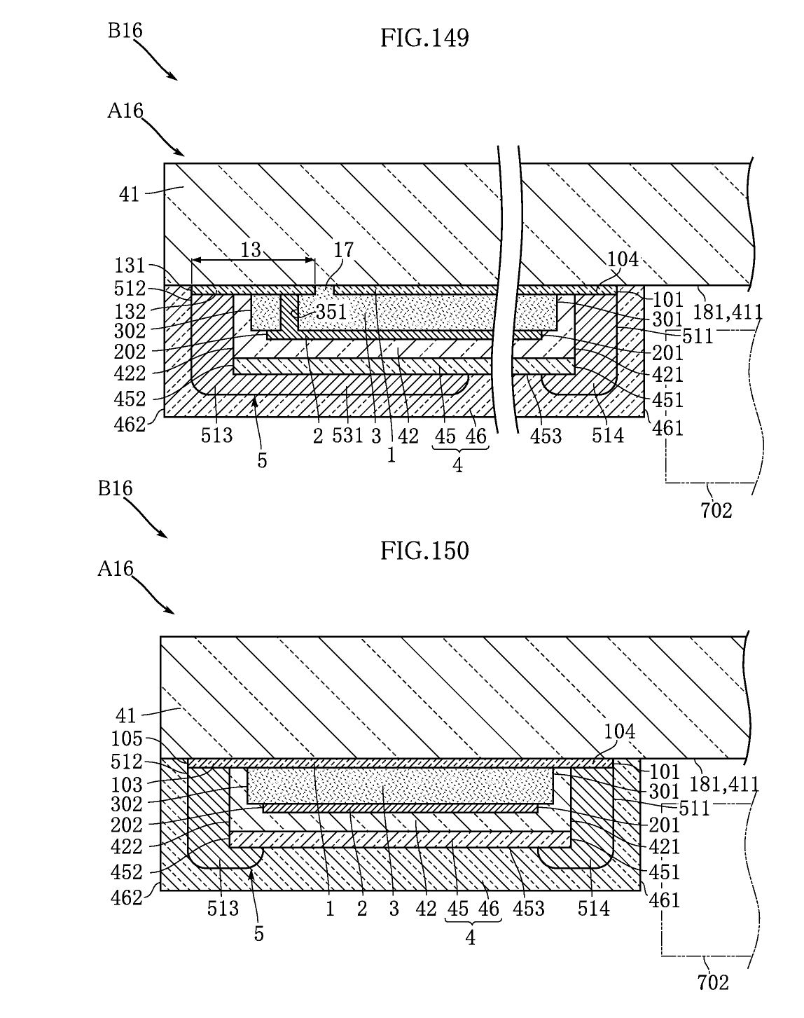

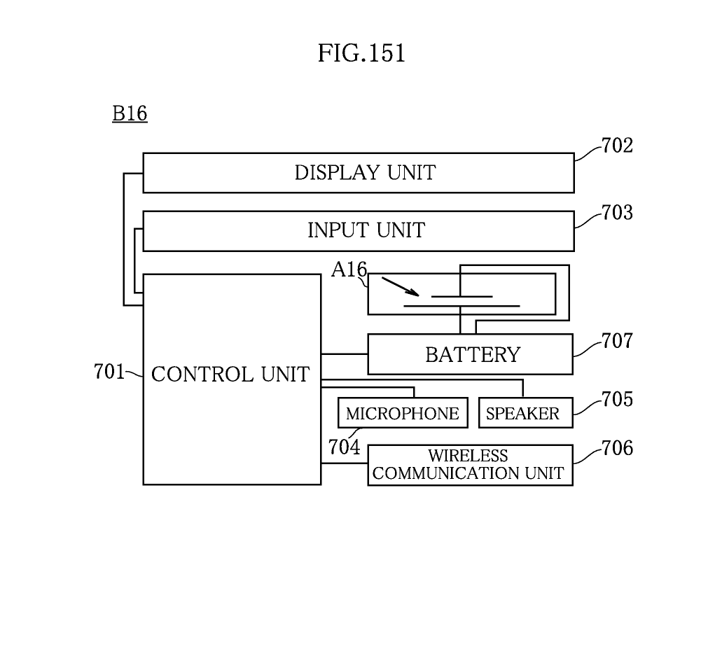

FIG. 146 is a plan view showing the organic thin film solar cell module A16, and the electronic device B16 incorporated with the organic thin film solar cell module A16. FIG. 147 is a schematic cross-sectional view taken along a line CXLVII-CXLVII in FIG. 146. FIG. 148 is an enlarged partial bottom view showing the organic thin film solar cell module A16. FIG. 149 is an enlarged partial cross-sectional view taken along a line CXLIX-CXLIX in FIG. 148. FIG. 150 is an enlarged partial cross-sectional view taken along a line CL-CL in FIG. 148. FIG. 151 is a system diagram of the electronic device B16. In FIG. 147, the elements other than the case 61, the organic thin film solar cell module A16, the organic thin film solar cell module A17, the control unit 701, the display unit 702, and the battery 707 are omitted, to facilitate understanding. In FIG. 148, the first conductive layer 1 and the photoelectric conversion layer are indicated by solid lines, and the bypass conductive section is indicated by an imaginary line, to facilitate understanding.

The organic thin film solar cell module A16 and the organic thin film solar cell module A17, serving as the power source module for the electronic device B16, convert light, such as sunlight, into electric power. Further details will be described below.

The control unit 701 corresponds to the drive unit in the present invention, and operates by the power supplied from the organic thin film solar cell module A16 and the organic thin film solar cell module A17. The control unit 701 may receive power directly from the organic thin film solar cell module A16 and the organic thin film solar cell module A17, or from the battery 707, after the power from the organic thin film solar cell module A16 and the organic thin film solar cell module A17 is once charged in the battery 707. The control unit 701 includes, for example, a CPU, a memory, and an interface.

The display unit 702 serves to display various types of information in the outer appearance of the electronic device B16. The display unit 70 is constituted of, for example, an LCD panel or an organic EL display panel. In this embodiment, the display unit 702 displays the information in the outer appearance, through the organic thin film solar cell module A16.

The input unit 703 outputs an electric signal according to inputs made by the user, to the control unit 701. The input unit 703 is constituted of, for example, a touch panel disposed on the display unit 702. The display unit 702 and the input unit 703 may be integrally formed.

The microphone 704 is a device that converts the voice of the user into electric signals. The speaker 705 is a device that outputs the voice of a counterpart of the call and various message tones.

The wireless communication unit 706 is a device for bidirectional wireless communication, in compliance with a wireless communication standard.

The battery 707 is a device for storing power for driving the electronic device B16. The battery 707 is rechargeable. The battery 707 may be charged by the power from commercial power supply through a non-illustrated adapter, or from the organic thin film solar cell module A16 and the organic thin film solar cell module A17.

The organic thin film solar cell module A16 includes the first conductive layer 1, the second conductive layer 2, the photoelectric conversion layer 3, the base substrate 41, the passivation layer 42, a resin cover layer 4, and the bypass conductive section 5. In this embodiment, the organic thin film solar cell module A16 has a rectangular shape in plan view, however this is merely an example, and various shapes may be adopted.

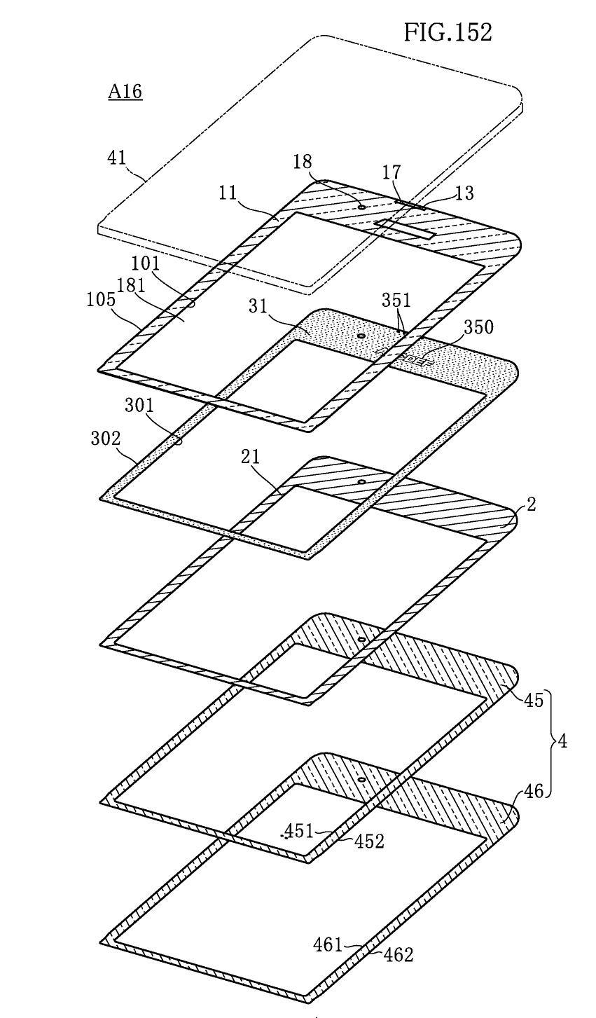

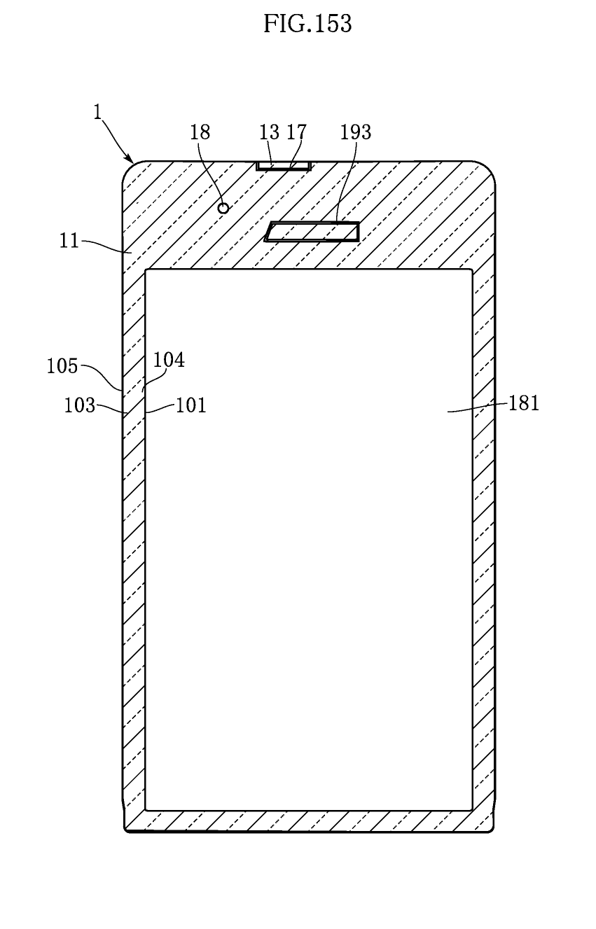

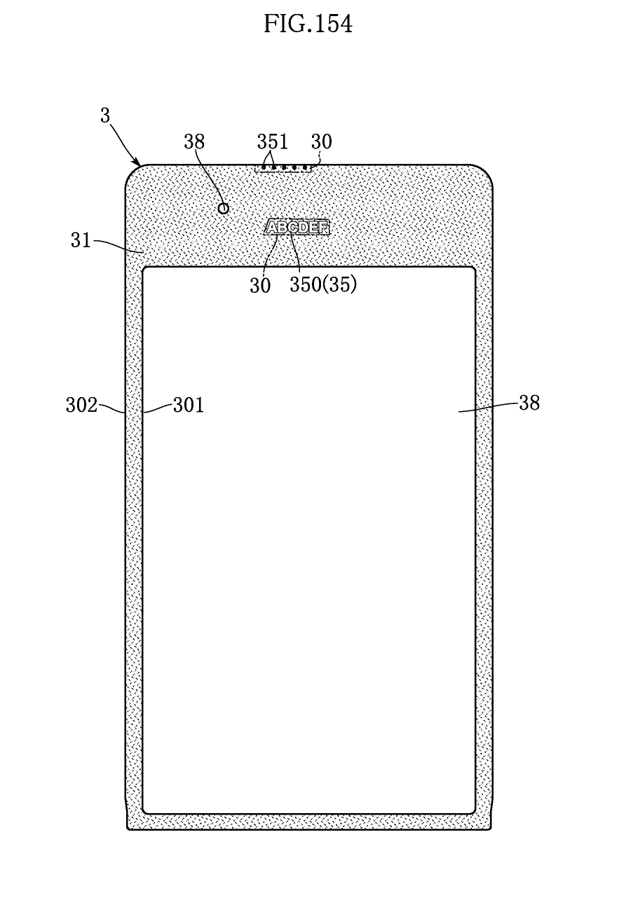

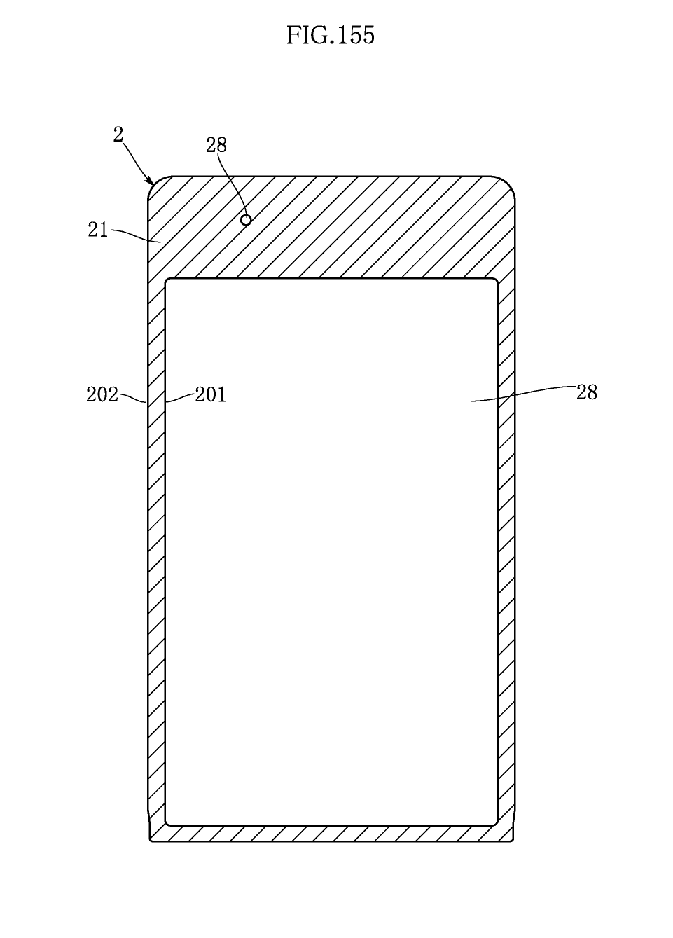

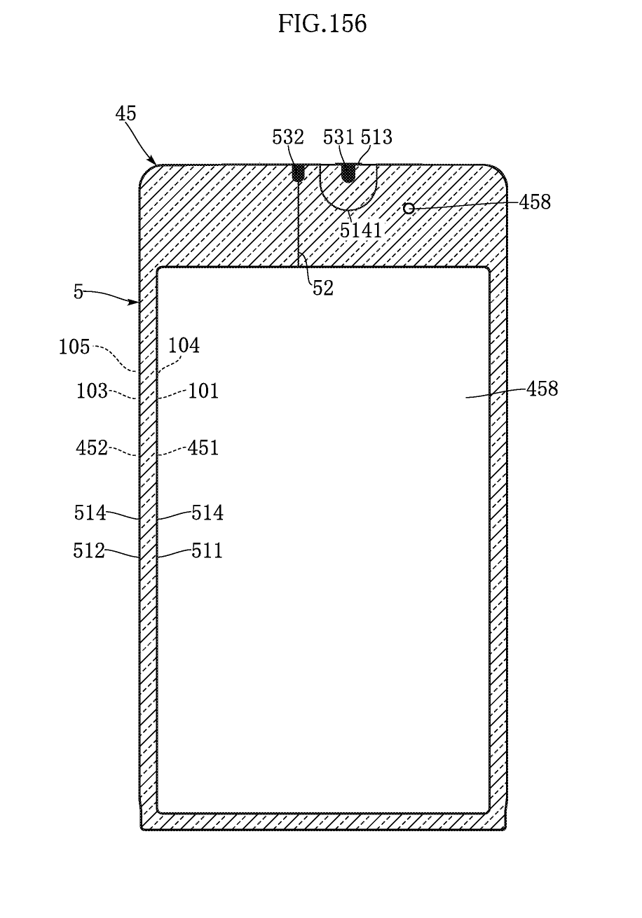

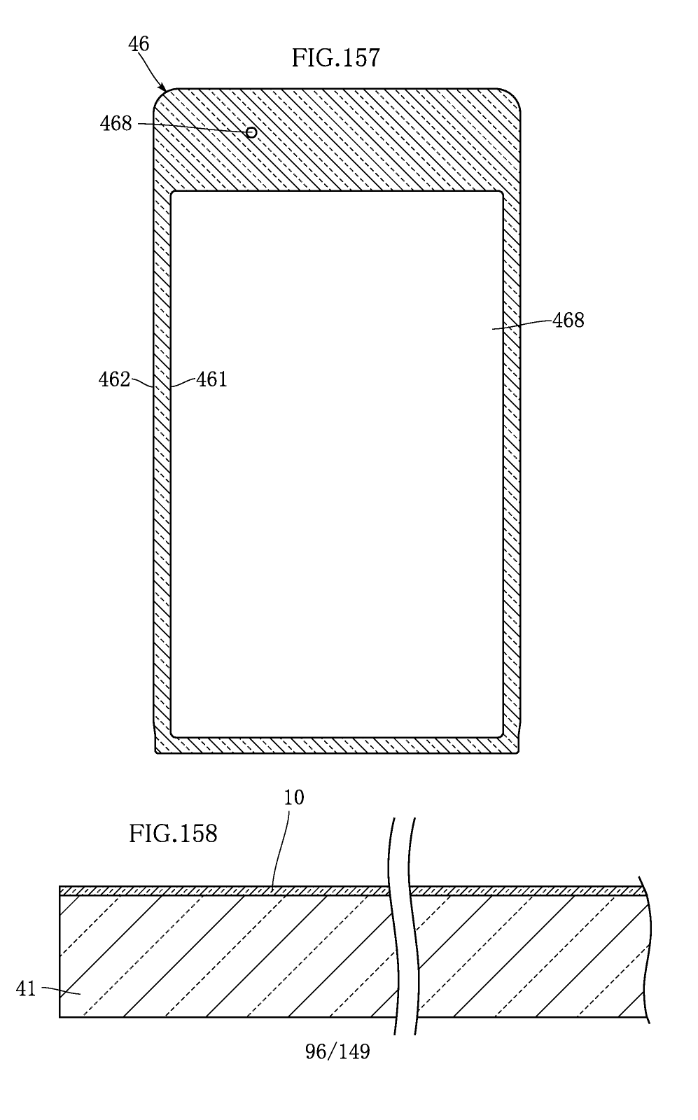

FIG. 152 is a partial exploded perspective view showing the first conductive layer 1, the second conductive layer 2, the photoelectric conversion layer 3, the base substrate 41, and the resin cover layer 4 of the organic thin film solar cell module A16. For the sake of clarity, the base substrate 41 is illustrated in imaginary lines (dash-dot-dot-lines). FIG. 153 is a plan view showing the first conductive layer 1 of the organic thin film solar cell module A16. FIG. 154 is a plan view showing the photoelectric conversion layer 3 of the organic thin film solar cell module A16. FIG. 155 is a plan view showing the second conductive layer 2 of the organic thin film solar cell module A16. FIG. 156 is a bottom view showing the first resin cover layer 45 of the resin cover layer 4 to be described below, and the bypass conductive section 5 of the organic thin film solar cell module A16. FIG. 157 is a plan view showing the second resin cover layer 46 of the resin cover layer 4 of the organic thin film solar cell module A16, to be described below.

The base substrate 41 serves as the base of the organic thin film solar cell module A16. The base substrate 41 is formed of, for example, transparent glass or a resin. The base substrate 41 has a thickness of, for example, 0.05 mm to 2.0 mm.

The first conductive layer 1 is formed on the base substrate 41. The first conductive layer 1 is transparent, and formed of ITO in this embodiment. As shown in FIG. 149, FIG. 150, and FIG. 153, the first conductive layer 1 includes the first electrode section 11, the connection portion 13, a slit 17, a display opening 181, the opening 18, a slit 193, the third edge 101, a third outer edge 105, a first extended portion 104, and a second extended portion 103. In this embodiment, the first conductive layer 1 has a generally circular shape in plan view, which is, however, merely an example of the shape of the first conductive layer 1. The first conductive layer 1 may be formed in various shapes. The first conductive layer 1 has a thickness of, for example, 100 nm to 300 nm.

The first electrode section 11 is a layer in which holes created by the photoelectric conversion layer 3 are collected, and acts as what is known as an anode electrode. In this embodiment, a major part of the first conductive layer 1 acts as one first electrode section 11.

The opening 18 is formed so as to penetrate through the first conductive layer 1 in the thickness direction. The opening 18 is formed, for example, to allow the speaker 705 to perform its function. The purpose of use of the opening 18 is not specifically limited, and the opening 18 may be utilized, for example, to enable a phone conversation, or to install a camera module. The display opening 181 is for exhibiting the information displayed by the display unit 702, in the outer appearance. In this embodiment, the display opening 181 has a rectangular shape in plan view.

The slit 193 has an annular shape, and partitions a part of the first conductive layer 1, from the first electrode section 11.

The third edge 101 defines the display opening 181. In this embodiment, the third edge 101 surrounds the display opening 181 from four directions, in a rectangular ring shape in plan view. However, it is not mandatory that the third edge 101 surrounds the display opening 181 from four directions. For example, the third edge 101 may define the display opening 181 from three directions, such that the display opening 181 is open to outside through the first electrode section 11, in plan view. Alternatively, the third edge 101 may be formed so as to define the display opening 181 from one or two directions. In the region adjacent to the third edge 101, in other words the display opening 181, the base substrate 41 is exposed. In addition, the third edge 101 corresponds to the inner edge of a portion of the first conductive layer 1 extending from the second edge 451 of the first resin cover layer 45 and the first edge 421 of the passivation layer 42, to be described below.

The first extended portion 104 inwardly extends (toward the display opening 181) from the passivation layer 42. In this embodiment, the second extended portion 103 is formed generally along the entire inner periphery of the first conductive layer 1.

The second extended portion 103 outwardly extends from the passivation layer 42. In this embodiment, the second extended portion 103 is formed generally along the entire outer periphery of the first conductive layer 1. The third outer edge 105 is the outer peripheral edge of the second extended portion 103.

As shown in FIG. 148 and FIG. 149, the connection portion 13 is defined by the slit 17, so as to be insulated from the first electrode section 11. Both ends 171 of the slit 17 reach the third outer edge 105. The connection portion 13 includes a connection portion edge 131 and an extended connection portion 132. The connection portion edge 131 is on the side of the connection portion 13 not opposed to the slit 17. In the illustrated example, the connection portion edge 131 is formed generally on the extension line of the third outer edge 105 adjacent thereto. The plan-view shape of the slit 17 is not specifically limited, and in this example the slit 17 has an elongate shape having the longitudinal side extending along the extending direction of the connection portion edge 131 (third outer edge 105), in other words an elongate rectangular shape. The extended connection portion 132 is a portion of the connection portion 13 exposed from the photoelectric conversion layer 3, in plan view. The connection portion 13 serves, for example, to lead electrons collected because of the power generation in the photoelectric conversion layer 3, to outside of the organic thin film solar cell module A16.

A major part of the second conductive layer 2 is disposed on the first conductive layer 1 via the photoelectric conversion layer 3. A part of the second conductive layer 2 is in direct contact with the first conductive layer 1. The material of the second conductive layer 2 is not specifically limited, and may be transparent or non-transparent. In this embodiment, the second conductive layer 2 is formed of a metal, typically A1, W, Mo, Mn, or Mg. In the following example, the second conductive layer 2 is formed of A1. Accordingly, the second conductive layer 2 is non-transparent. In this case, a non-illustrated passive film formed of Al₂O₃ may be formed on the surface of the second conductive layer 2 opposite to the base substrate 41. The second conductive layer 2 has a thickness of, for example, 30 nm to 150 nm.

As shown in FIG. 155, the second conductive layer 2 includes the second electrode section 21 and the opening 28. Although the second conductive layer 2 has a generally rectangular shape in plan view in this embodiment, this is merely an example of the shape of the second conductive layer 2. The second conductive layer 2 may be formed in various shapes.

The second electrode section 21 is a layer in which electrons created by the photoelectric conversion layer 3 are collected, and acts as what is known as a cathode electrode.

The openings 28 are formed so as to penetrate through the second conductive layer 2 in the thickness direction. The four openings 28 at an upper position in FIG. 155 are formed, for example, to allow the speaker 705 to perform its function. The larger opening 28 at the central position in FIG. 155 is for exhibiting the information displayed by the display unit 702, in the outer appearance.

The fourth inner recessed edge 201 defines the opening 28 at the central position in FIG. 155. In this embodiment, the fourth inner recessed edge 201 surrounds the opening 28 from four directions, in a rectangular ring shape in plan view. However, it is not mandatory that the fourth inner recessed edge 201 surrounds the opening 28 from four directions. For example, the fourth inner recessed edge 201 may define the opening 28 from three directions, such that the opening 28 is open to outside through the second electrode section 21, in plan view. Alternatively, the fourth inner recessed edge 201 may be formed so as to define the opening 28 from one or two directions. As shown in FIG. 149, the fourth inner recessed edge 201 is inwardly recessed (opposite to the direction toward the inner space of the display opening 181) with respect to the third edge 101.

The fourth outer recessed edge 202 is, as shown in FIG. 149, inwardly recessed (to the right in FIG. 149), with respect to the first outer edge 422 of the passivation layer 42 and the second outer edge 452 of the first resin cover layer 45 to be described below, in plan view. In this embodiment, the fourth outer recessed edge 202 has an annular shape in plan view.

The photoelectric conversion layer 3 is interposed between the first conductive layer 1 and the second conductive layer 2, and disposed on the base substrate 41. The photoelectric conversion layer 3 is formed of an organic thin film, and configured to perform a photoelectric conversion function, to convert received light into electric power. Although the configuration of the photoelectric conversion layer 3 is not specifically limited, the photoelectric conversion layer 3 may include, for example, a bulk heterojunction organic active layer and a hole transport layer disposed on the bulk heterojunction organic active layer on the side of the first conductive layer 1. In this embodiment, the photoelectric conversion layer 3 is formed in a rectangular shape in plan view, however this is merely an example and the photoelectric conversion layer 3 may be formed in various shapes. The photoelectric conversion layer 3 has a thickness of, for example, 50 nm to 300 nm.

In the bulk heterojunction organic active layer, p-type organic active layer regions and n-type organic active layer regions are intermixed, forming a complicated bulk hetero pn junction. The p-type organic active layer region is, for example, formed of poly(3-hexylthiophene-2,5diyl) (P3HT), and the n-type organic active layer region is formed of 6,6-phenyl-C61-butyric acid methyl ester (PCBM), for example. The hole transport layer is formed of, for example, PEDOT:PSS.

Examples of materials that may be utilized to form the photoelectric conversion layer 3 include phthalocyanine (Pc), zinc-phthalocyanine (ZnPc), N,N′-dimethyl perylene-3,4,9,10-dicarboximide (Me-Ptcdi), and Buckminster fullerene (C60). These materials are, for example, utilized for vacuum vapor deposition.

In addition, poly[2-methoxy-5-(3,7-dimethyl octyloxy)]-1,4-phenylene vinylene (MDMO-PPV), poly[N-9′-hepta-decanyl-2,7-carbazole-alt-5,5-(4′,7′-di-thienyl-2′1′,3′-b3nzothiadizaole)] (PCDTBT), 6,6-phenyl-C61-butyric acid methyl ester (PC60BM), or 6,6-phenyl-C71-butyric acid methyl ester (PC70BM) may be utilized to form the photoelectric conversion layer 3. These materials are, for example, utilized for a solution process.

As shown in FIG. 154, the photoelectric conversion layer 3 includes the non-generation region 30, the generation region 31, the design display section 35, the opening 38, the fifth inner recessed edge 301, and the fifth outer recessed edge 302. In FIG. 154, the non-generation region 30 and the generation region 31 are shaded with scattered dots. The design display section overlaps with, in plan view, the region of the first conductive layer 1 surrounded by the slit 193.

The design display section 35 constitutes a design exhibited in the outer appearance. The design constituted by the design display section 35 include those that the user can visually recognize as visually singular feature, such as characters, marks, and patterns. In this embodiment, the design display section 35 represents an annular shape.

In this embodiment, the design display section 35 is constituted of design display perforated portions 350. The design display perforated portions 350 are formed so as to penetrate through the photoelectric conversion layer 3 in the thickness direction. The design display perforated portions 350 are visible in the outer appearance. In this embodiment, the design display perforated portions 350 expose the second conductive layer 2 on the side of the first conductive layer 1. In other words, a part of the second conductive layer 2 is visible in the outer appearance, through the design display perforated portions 350. The shape of the design display perforated portion 350 is not specifically limited, and in the example shown in the corresponding drawings, a shape representing an alphabet is adopted.

The generation region 31 is interposed between the first electrode section 11 of the first conductive layer 1 and the second electrode section 21 of the second conductive layer 2, and performs the photoelectric conversion function to contribute to the power generation. The shape of the generation region 31 coincides with the first electrode section 11 and the second electrode section 21, in plan view.

As shown in FIG. 148, FIG. 149 and FIG. 154, a conductive perforated portion 351 is formed so as to penetrate through the photoelectric conversion layer 3. The conductive perforated portion 351 is located in a region enclosed in the connection portion 13 of the first conductive layer 1, in plan view. In the illustrated example, a plurality of the conductive perforated portion 351 are provided. The shape and the position of the conductive perforated portion 351 are not specifically limited. In the illustrated example, the conductive perforated portion 351 has a circular shape in plan view, and a diameter of, for example, approximately 40 μm. The conductive perforated portions 351 are aligned along the longitudinal direction of the connection portion 13. The connection portion 13 of the first conductive layer 1 and the second conductive layer 2 are electrically connected to each other, via the conductive perforated portion 351.

The non-generation region 30 corresponds to a portion of the photoelectric conversion layer 3 deviated, in plan view, from the first electrode section 11 of the first conductive layer 1 and the second electrode section 21 of the second conductive layer 2, and overlapping with the connection portion of the first conductive layer 1 and the region thereof surrounded by the slit 193. Therefore, the non-generation region 30 overlapping with the connection portion 13 in plan view is not involved in the power generation. In addition, the region of the photoelectric conversion layer 3 coinciding in plan view with the region surrounded by the slit 193, overlapping with the design display section 35 in plan view, is also the non-generation region 30. Thus, the region of the photoelectric conversion layer 3 other than the generation regions 31 corresponds to the non-generation region 30.

The openings 38 are formed so as to penetrate through the photoelectric conversion layer 3 in the thickness direction. The opening 38 at an upper position in FIG. 154 is formed, for example, to allow the speaker 705 to perform its function. The larger opening 38 at the central position in FIG. 154 is for exhibiting the information displayed by the display unit 702, in the outer appearance.

The fifth inner recessed edge 301 defines the opening 38 at the central position in FIG. 154. In this embodiment, the fifth inner recessed edge 301 surrounds the opening 38 from four directions, in a rectangular ring shape in plan view. However, it is not mandatory that the fifth inner recessed edge 301 surrounds the opening 38 from four directions. For example, the fifth inner recessed edge 301 may define the opening 38 from three directions, such that the opening 38 is open to outside through the generation region 31, in plan view. Alternatively, the fifth inner recessed edge 301 may be formed so as to define the opening 38 from one or two directions. In addition, as shown in FIG. 116, the fifth inner recessed edge 301 is inwardly recessed (opposite to the direction toward the inner space of the display opening 181) with respect to the third edge 101.

The fifth outer recessed edge 302 is, as shown in FIG. 148 and FIG. 149, inwardly recessed (to the right in FIG. 149), with respect to the first outer edge 422 of the passivation layer 42 to be described below, in plan view. In this embodiment, the fifth outer recessed edge 302 has an annular shape in plan view.

The passivation layer 42 is disposed on the second conductive layer 2, so as to protect the second conductive layer 2 and the photoelectric conversion layer 3. The passivation layer 42 is, for example, formed of SiN or SiON. The passivation layer 42 has a thickness of, for example, 0.5 μm to 2.0 μm and, in this embodiment, approximately 1.5 μm.

The resin cover layer 4 covers the passivation layer 42. The resin cover layer 4 also covers the passivation layer 42. The resin cover layer 4 is formed of, for example, a UV-curable resin. The resin cover layer 4 has a thickness of, for example, 3 μm to 20 μm and, in this embodiment, approximately 10 μm.

In this embodiment, the resin cover layer 4 includes a first resin cover layer 45 and a second resin cover layer 46. The first resin cover layer 45 covers the passivation layer 42. The second resin cover layer 46 is disposed on the first resin cover layer 45, so as to cover the bypass conductive section 5.

As shown in FIG. 148, FIG. 149, and FIG. 156, the first resin cover layer 45 includes a plurality of openings 458, the second edge 451, and the second outer edge 452.

The openings 458 are each formed by removing a part of the first resin cover layer 45, so as to penetrate therethrough. The three openings 458 at an upper position in FIG. 156 are formed, for example, to allow the speaker 705 to perform its function. The larger opening 458 at the central position in FIG. 156 is for exhibiting the information displayed by the display unit 702, in the outer appearance.

The second edge 451 defines the opening 458 at the central position in FIG. 156. In this embodiment, the second edge 451 surrounds the opening 458 from four directions, in a rectangular ring shape in plan view. However, it is not mandatory that the second edge 451 surrounds the opening 458 from four directions. For example, the second edge 451 may define the opening 458 from three directions, such that the opening 458 is open to outside through the first resin cover layer 45, in plan view. Alternatively, the second edge 451 may be formed so as to define the opening 458 from one or two directions.

The second outer edge 452 is located on the side opposite to the second edge 451, across at least a part of the photoelectric conversion layer 3 in plan view, and corresponds, in this embodiment, to the outer peripheral edge of the first resin cover layer 45.

As shown in FIG. 157, the second resin cover layer 46 includes a plurality of openings 468, a sixth edge 461, and a sixth outer edge 462. The second resin cover layer 46 may include, if necessary, an opening or a cutaway portion for exposing a first collector electrode 531 and a second collector electrode 532 to be described below.

The openings 468 are each formed by removing a part of the second resin cover layer 46, so as to penetrate therethrough. The three openings 468 at an upper position in FIG. 157 are formed, for example, to allow the speaker 705 to perform its function. The larger opening 468 at the central position in FIG. 157 is for exhibiting the information displayed by the display unit 702, in the outer appearance.

The sixth edge 461 defines the opening 458 at the central position in FIG. 157. In this embodiment, the sixth edge 461 surrounds the opening 468 from four directions, in a rectangular ring shape in plan view. However, it is not mandatory that the sixth edge 461 surrounds the opening 468 from four directions. For example, the sixth edge 461 may define the opening 468 from three directions, such that the opening 468 is open to outside through the second resin cover layer 46, in plan view. Alternatively, the sixth edge 461 may be formed so as to define the opening 468 from one or two directions.

The sixth outer edge 462 is located on the side opposite to the sixth edge 461, across at least a part of the photoelectric conversion layer 3 in plan view, and corresponds, in this embodiment, to the outer peripheral edge of the second resin cover layer 46.

As shown in FIG. 148 to FIG. 150, the passivation layer 42 includes the first edge 421 and the first outer edge 422.

The first edge 421 coincides with the second edge 451 in plan view. In this embodiment, the first edge 421 forms a continuous surface with the second edge 451. The first outer edge 422 coincides with the second outer edge 452 in plan view. In this embodiment, the first outer edge 422 forms a continuous surface with the second outer edge 452.

The bypass conductive section 5 provides a route having a lower resistance than at least the first conductive layer 1, for collecting the holes that have reached the first conductive layer 1 and the electrons that have reached the second conductive layer 2. In this embodiment, the bypass conductive section 5 includes a first bus-bar section 513, two second bus-bar sections 514, the first collector electrode 531, the second collector electrode 532, the communication portion 52, a seventh edge 511, and a seventh outer edge 512. The bypass conductive section 5 is formed of a material lower in resistance than at least the first conductive layer 1, and includes, for example, Ag or carbon.

As shown in FIG. 148 to FIG. 150 and FIG. 156, one of the bus-bar sections 514 covers the second edge 451 and the first edge 421 over the entire length. The second bus-bar section 514 covers the first extended portion 104 of the first conductive layer 1 located between the third edge 101 and the first edge 421 (second edge 451). The seventh edge 511 of the second bus-bar section 514 coincides with the third edge 101, in plan view. The other second bus-bar section 514 covers the second outer edge 452 and the first outer edge 422 over the entire length, except for a part thereof. This second bus-bar section 514 covers the second extended portion 103 of the first conductive layer 1. The seventh outer edge 512 of the bus-bar section 51 coincides with the third outer edge 105, in plan view. Thus, each of the two bus-bar sections 51 is electrically connected to the first conductive layer 1.

The second collector electrode 532 is electrically connected to the second bus-bar section 514, and serves to output holes collected by the first conductive layer 1 to, for example, a hole terminal provided in the electronic device B16. In this embodiment, the second collector electrode 532 is formed on the first resin cover layer 45 of the resin cover layer 4. The second collector electrode 532 overlaps with the second conductive layer 2 and the photoelectric conversion layer 3, in plan view. Between the photoelectric conversion layer 3 and the second collector electrode 532 in the thickness direction of the base substrate 41, the passivation layer 42 and the first resin cover layer 45 are interposed. The plan-view shape of the second collector electrode 532 is not specifically limited, and in the illustrated example the second collector electrode 532 has a generally semi-elliptical shape. In the illustrated example, further, the second collector electrode 532 is directly connected to one of the second bus-bar sections 514.

The communication portion 52 is formed on the first resin cover layer 45, and connects the bus-bar section 51 on the inner side in FIG. 156 and the second collector electrode 532. Accordingly, the holes collected to the two second bus-bar sections 514 are led to the second collector electrode 532.

As shown in FIG. 148, FIG. 149 and FIG. 156, the first bus-bar section 513 is spaced apart from the second bus-bar section 514, and covers a part of the extended connection portion 132 of the connection portion 13. More specifically, the first bus-bar section 513 covers a part of the extended connection portion 132, in the left-right direction in FIG. 148 (longitudinal direction of the connection portion 13). As shown in FIG. 149, the seventh edge 511 of the first bus-bar section 513 coincides with the connection portion edge 131 of the connection portion 13, in plan view. The second bus-bar section 514 includes a circumvent portion 5141. The circumvent portion 5141 extends from a portion of the second bus-bar section 514 located on both sides of the first bus-bar section 513, so as to circumvent the first bus-bar section 513 and the first collector electrode 531 in plan view.

The first collector electrode 531 is electrically connected to the first bus-bar section 513, and serves to output electrons collected by the second conductive layer 2 to, for example, an electron terminal provided in the electronic device B16. In this embodiment, the first collector electrode 531 is formed on the first resin cover layer 45 of the resin cover layer 4. The first collector electrode 531 overlaps with the second conductive layer 2 and the photoelectric conversion layer 3, in plan view. Between the photoelectric conversion layer 3 and the first collector electrode 531 in the thickness direction of the base substrate 41, the passivation layer 42 and the first resin cover layer 45 are interposed. The plan-view shape of the first collector electrode 531 is not specifically limited, and in the illustrated example the first collector electrode 531 has a generally semi-elliptical shape. In the illustrated example, further, the first collector electrode 531 is directly connected to the first bus-bar section 513.

As shown in FIG. 148, in this embodiment the design display section 35 (design display perforated portion 350) is located opposite to the connection portion edge 131 across the conductive perforated portions 351, in plan view. In other words, the conductive perforated portions 351 are located between the connection portion edge 131 and the design display section 35, in plan view.

As shown in FIG. 148 to FIG. 150, a part of the base substrate 41 is exposed from a region adjacent to the second edge 451 and the first edge 421, via the second bus-bar section 514 and the second resin cover layer 46 therebetween, thus to form an exposed region 411. The exposed region 411 is not covered with the first conductive layer 1 or other elements, and the surface of the base substrate 41 is directly exposed.

Referring now to FIG. 158 to FIG. 170, a manufacturing method of the organic thin film solar cell module A16 will be described hereunder. The cited drawings are turned upside down from FIG. 149 and FIG. 150, to facilitate understanding. In addition, FIG. 158 to FIG. 168 illustrate the formation process of the structure corresponding to the cross-section taken along the line CXLIX-CXLIX in FIG. 148.

Referring first to FIG. 158, the base substrate 41 is prepared. On one of the surfaces of the base substrate 41, the first conductive film 10 formed of ITO is deposited by a known method such as sputtering.

Then the ITO is patterned to form the patterns of the openings 18, the display openings 181, the slits 193, and the slits 17. For the patterning of the ITO, for example, wet etching, or laser patterning with green laser is adopted as the case may be.

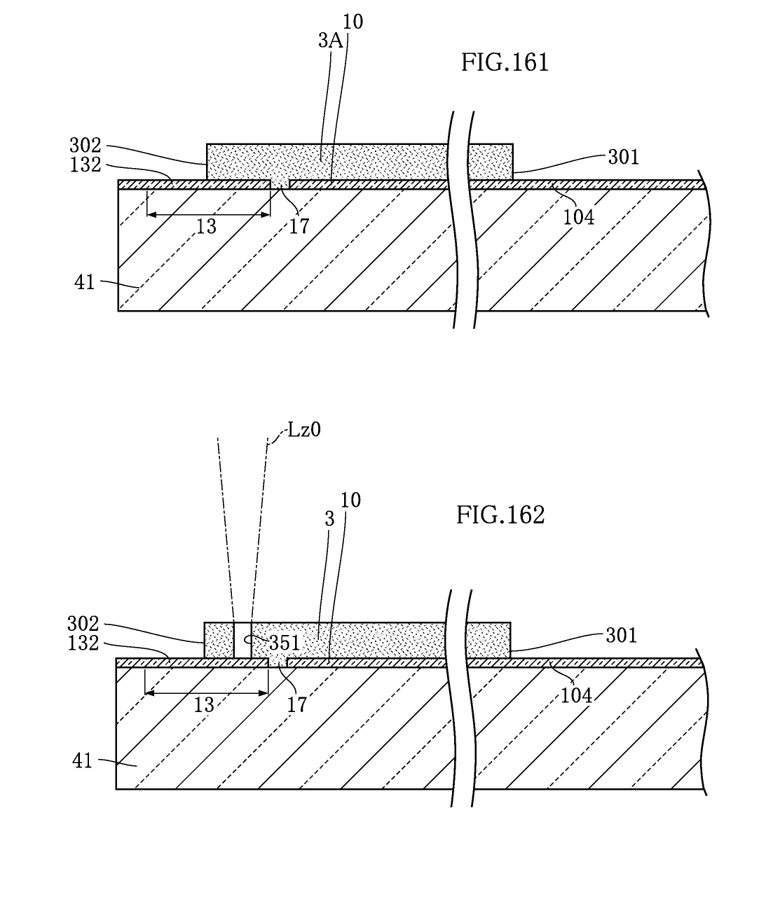

Proceeding to FIG. 161, an organic film 3A is formed. To form the organic film 3A, an organic film is deposited on the base substrate 41 and the first conductive film 10, for example by spin coating.

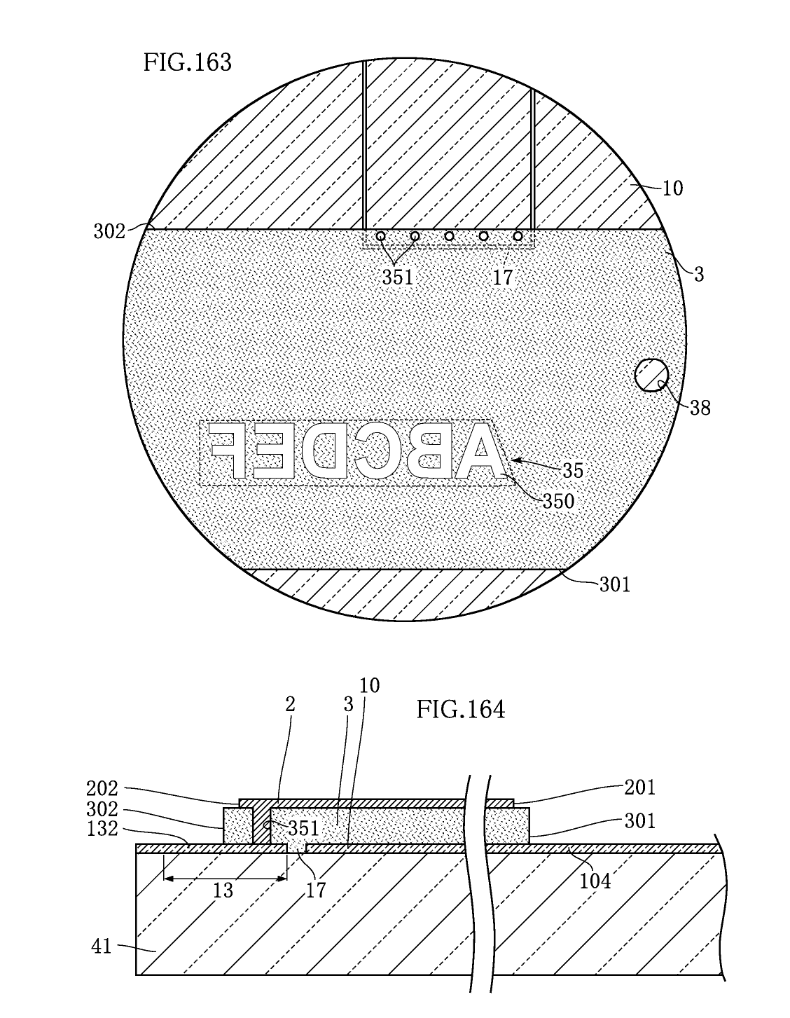

Proceeding to FIG. 162 and FIG. 163, the organic film 3A is patterned to form the photoelectric conversion layer 3. The patterning of the organic film 3A may be performed by, for example, oxygen plasma etching or laser patterning, to form the fifth inner recessed edge 301, the fifth outer recessed edge 302, the opening 38, the design display perforated portion 350 (design display section 35), and the conductive perforated portion 351. Without limitation to the above, the photoelectric conversion layer 3 may be formed by directly patterning the organic film on the base substrate 41 and the first conductive film 10, for example by slit coating, capillary coating, or gravure printing. Here, in the illustrated example, the conductive perforated portion 351 is a circular through-hole having a relatively small diameter. To form such conductive perforated portion 351, a laser beam Lz0 may be suitably utilized. It is preferable to select a wavelength of the laser beam Lz0 so as to remove the organic film 3A but leave the first conductive film 10, and from such a viewpoint a green laser beam may be selected.

Proceeding to FIG. 164, the second conductive layer 2 is formed. To form the second conductive layer 2, for example, one of the aforementioned metals is deposited by vacuum vapor deposition on the base substrate 41, the first conductive film 10, and the photoelectric conversion layer 3, to deposit a metal film thereon. Then the metal film is patterned, for example by etching with a mask layer. Through such patterning, the second conductive layer 2 including the fourth inner recessed edge 201 and the fourth outer recessed edge 202 is formed on the photoelectric conversion layer 3. In this process, further, the conductive perforated portion 351 of the photoelectric conversion layer 3 is filled with the second conductive layer 2. Therefore, electrical connection is established between the first conductive layer 1 and the second conductive layer 2, via the conductive perforated portion 351.

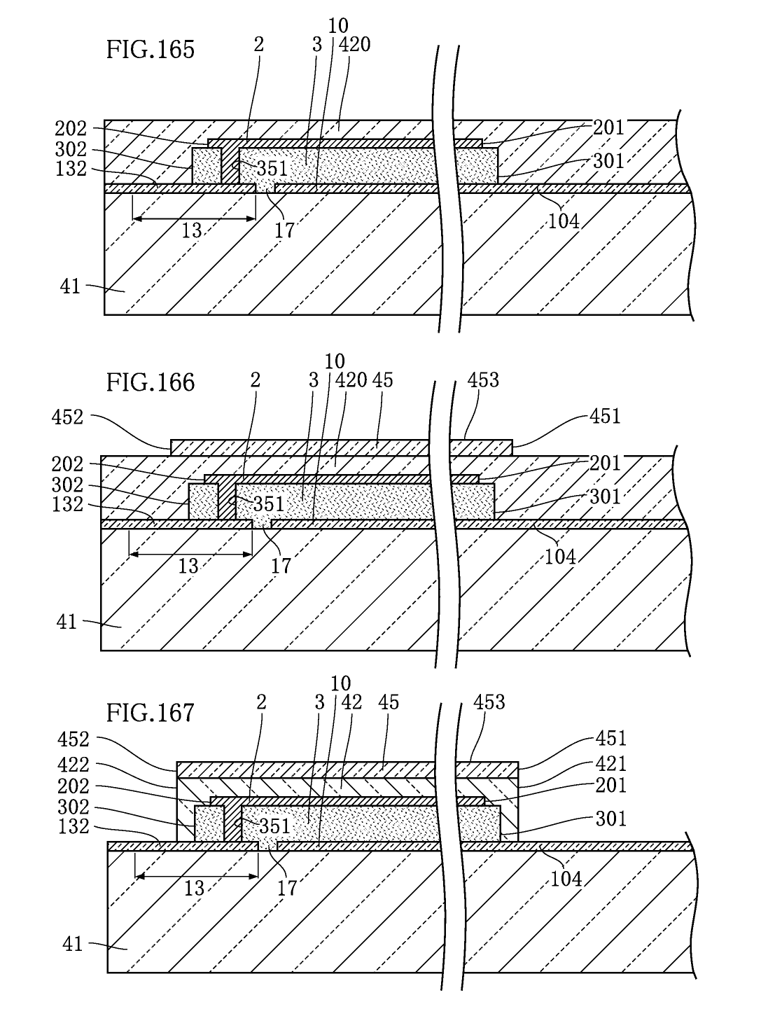

Proceeding to FIG. 165, the insulation film 420 is formed. To form the insulation film 420, SiN or SiON is deposited on the base substrate 41, the first conductive layer 1, the photoelectric conversion layer 3, and the second conductive layer 2, for example by plasma CVD.

Proceeding to FIG. 166, the first resin cover layer 45 is formed. To form the first resin cover layer 45, for example, a liquid resin material containing a UV-curable resin is applied to the insulation film 420 by screen printing, and the resin is irradiated with UV light thus to be cured. Thus, the first resin cover layer 45 including the second edge 451 and the second outer edge 452 is obtained.

Proceeding to FIG. 167, the insulation film 420 is patterned, using the first resin cover layer 45 as the mask. This patterning is performed through a wet etching process using hydrofluoric acid containing 0.55% to 4.5% of hydrogen fluoride. Such hydrofluoric acid barely dissolves the resin cover layer 45 formed of a UV-curable resin, but selectively dissolves the insulation film 420 formed of SiN or SiON. In addition, the hydrofluoric acid barely dissolves the first conductive film 10 formed of ITO. As result, the passivation layer 42 including the first edge 421 and the first outer edge 422 is formed. The first edge 421 coincides with the second edge 451 in plan view. The first edge 421 and the second edge 451 form a continuous surface. Likewise, the first outer edge 422 coincides with the second outer edge 452 in plan view. The first outer edge 422 and the second outer edge 452 form a continuous surface.

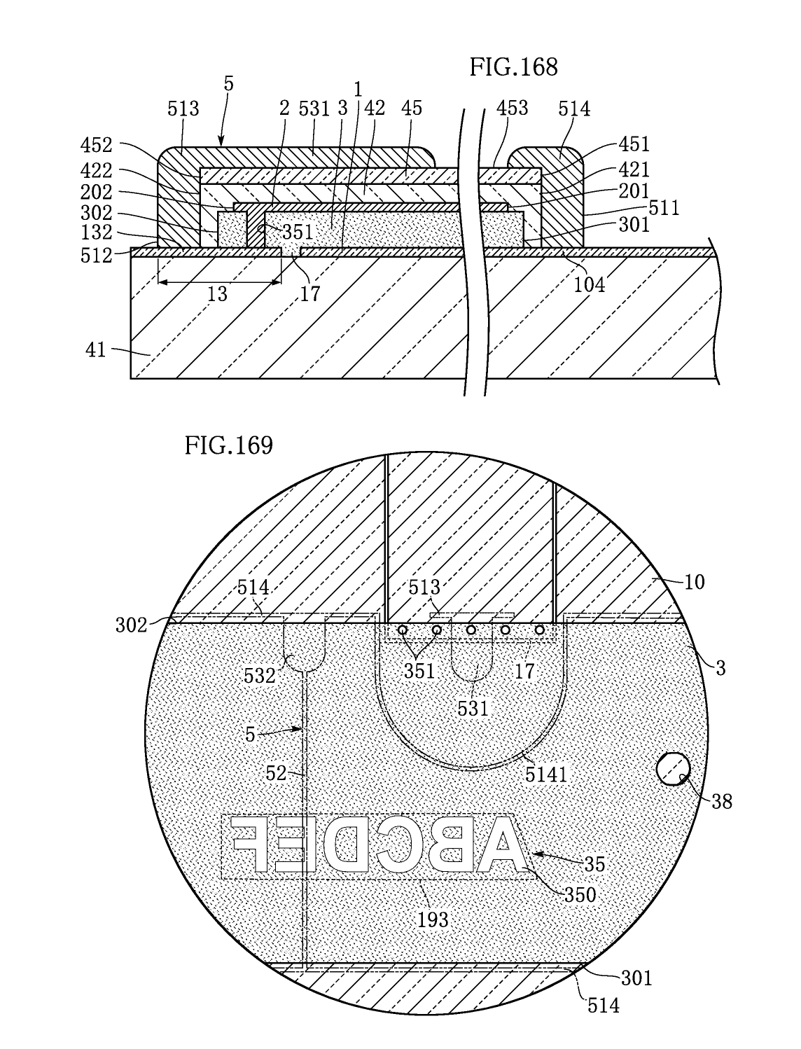

Proceeding to FIG. 168 and FIG. 169, the bypass conductive section 5 is formed. To form the bypass conductive section 5, for example, a paste containing Ag or carbon is applied, and then dried to harden the paste.

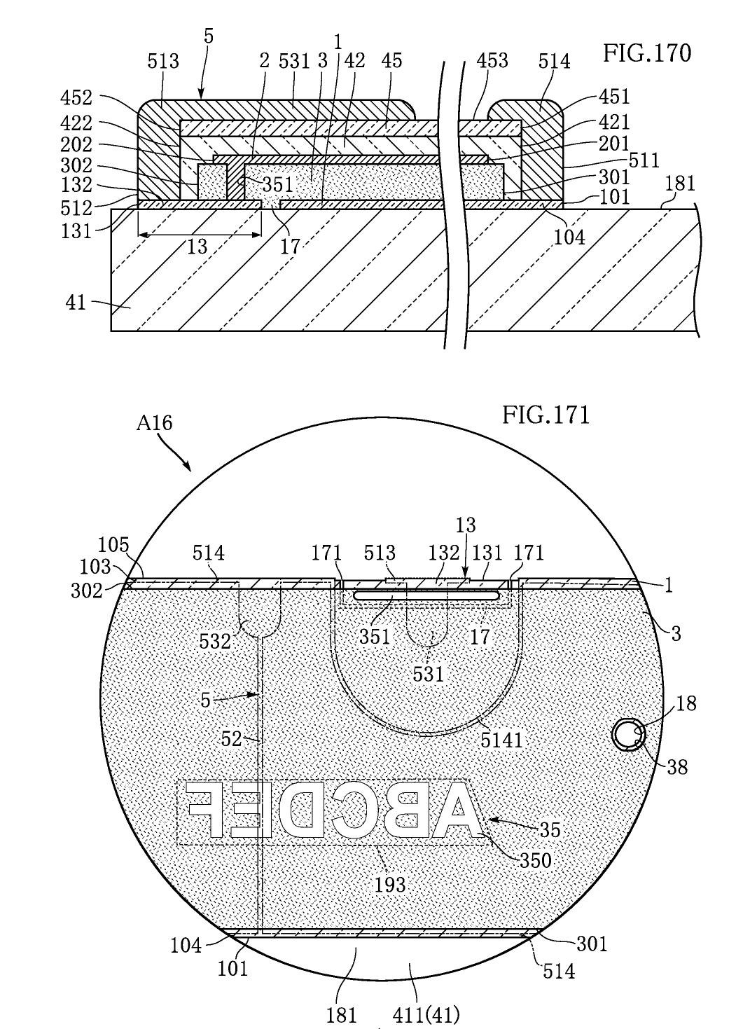

Proceeding to FIG. 170, the first conductive film 10 is patterned. The patterning is performed, for example, with aqua regia in which concentrated hydrochloric acid and concentrated nitric acid are mixed in a ratio of 3 to 1. By such patterning, portions of the first conductive film 10 exposed from the bypass conductive section 5 and the first resin cover layer 45 are selectively removed. As result, the first conductive layer 1 including the third edge 101 and so forth is formed. Then the second resin cover layer 46 is formed. To form the second resin cover layer 46, for example, a liquid resin material containing a UV-curable resin is applied to the insulation film 420 by screen printing, and the resin is irradiated with UV light thus to be cured. Thus, the second resin cover layer 46 including the sixth edge 461 and the sixth outer edge 462 is formed, and the resin cover layer 4 is obtained. Through the mentioned process, the organic thin film solar cell module A16 can be obtained.

The organic thin film solar cell module A16 and the electronic device B16 provide the following advantageous effects.

According to this embodiment, as shown in FIG. 148 and FIG. 149, the conductive perforated portions 351 are provided at the position close to the fifth outer recessed edge 302 of the photoelectric conversion layer 3, extending along the third outer edge 105. Accordingly, the non-generation region 30, including the conductive perforated portions 351 and overlapping with the connection portion 13, occupies a relatively small area in the vicinity of the third outer edge 105, which is, for example, smaller than the design display section 35. Therefore, the area ratio of the generation region 31, which contributes to the power generation, can be increased, in the photoelectric conversion layer 3.

In this embodiment, the conductive perforated portions 351 are through-holes of a circular shape in plan view, having a diameter of, for example, approximately 40 μm. Therefore, in the outer appearance of the organic thin film solar cell module A16 and the electronic device B16, the conductive perforated portions 351 and the generation region 31 including the same can be made barely visible. This is advantageous for attaining a more exquisite outer appearance of the organic thin film solar cell module A16 and the electronic device B16.

The first collector electrode 531 and the second collector electrode 532 are located so as to overlap with the second conductive layer 2 and the photoelectric conversion layer 3, in plan view. Therefore, the first collector electrode 531 and the second collector electrode 532 are not outwardly protruding from the third outer edge 105, in plan view. This is advantageous for reducing the footprint of the organic thin film solar cell module A16.

Since electrons are collected to the first collector electrode 531 through the conductive perforated portion 351, there is no need to utilize the design display perforated portion 350 constituting the design display section 35 to collect the electrons. Accordingly, there is no need to secure a conduction path for collecting the electrons from the design display section 35, for example in the first conductive layer 1. Therefore, the conduction path between the design display section 35 and the third outer edge 105 does not have to be provided. Such a configuration prevents appearance of a line extending from the design display section 35 to a terminal portion where the third outer edge 105 is located, in the outer appearance of the organic thin film solar cell module A16 and the electronic device B16. In particular, the design display section 35 is normally located at an eye-catching position on the outer appearance, away from the terminal portion of the third outer edge 105 or other elements. Therefore, omitting the line that is visible on the outer appearance is desirable for attaining a more exquisite outer appearance of the organic thin film solar cell module A16 and the electronic device B16.

With the bypass conductive section 5, the holes diffused to the first conductive layer 1 can be led to the second collector electrode 532, through the second bus-bar section 514. The bypass conductive section 5 is formed of a material lower in resistance than a material of the first conductive layer 1. Accordingly, the bypass conductive section 5 provides a conduction path that has lower resistance. Introducing the power generated by the photoelectric conversion layer 3 to such a conduction path suppresses a conduction loss. In addition, the bypass conductive section 5 is covered with the resin cover layer 4. Therefore, the resin cover layer 4 can be prevented from being degraded through reaction with, for example, ambient air. Consequently, both the degradation of the conduction path and the conduction loss can be prevented, in the organic thin film solar cell module A16 and the electronic device B16.

As shown in FIG. 149, the seventh edge 511 and the seventh outer edge 512 are located on the inner side of the sixth edge 461 and the sixth outer edge 462. In other words, the bypass conductive section 5 is completely covered with the resin cover layer 4. Therefore, the bypass conductive section 5 can be securely protected.

The base substrate 41 is exposed in the regions adjacent to the second edge 451 and the second outer edge 452. In such regions, the passivation layer 42 and the resin cover layer 45 are not formed. Therefore, the mentioned regions can be finished with higher transparency, so that the display unit 702 can be more clearly exhibited in the outer appearance.

The first conductive layer 1 is not formed on the base substrate 41, except for a small region covered with the bus-bar section 51, in the region adjacent to the second edge 451 and the first edge 421. Although the first conductive layer 1 is formed of ITO, the first conductive layer 1 may be visually recognized as a faintly colored portion, depending on the condition of ambient light. The configuration according to this embodiment enables the region for exhibiting the display unit 702 in the outer appearance to be finished with prominent transparency, thereby realizing a more exquisite outer appearance.

The fifth inner recessed edge 301 of the photoelectric conversion layer 3 and the fourth inner recessed edge 201 of the second conductive layer 2 are spaced apart from the first edge 421 and the second edge 451. Accordingly, the second conductive layer 2 and the photoelectric conversion layer 3 can be prevented from being electrically connected improperly, to the bypass conductive section 5. In addition, the passivation layer 42 is interposed between the fourth inner recessed edge 201 and the fifth inner recessed edge 301, and between the first edge 421 and the second edge 451. Therefore, a short circuit between the second conductive layer 2 or photoelectric conversion layer 3 and the bus-bar section 51 of the bypass conductive section 5.

By the patterning of the insulation film 420 using the first resin cover layer 45 as the mask, the passivation layer 42 can be formed in the same shape as the first resin cover layer 45. In other words, forming the first resin cover layer 45 from a material having high shape formability, such as the UV-curable resin, enables the passivation layer 42 to be formed in a desired shape, despite the material thereof having lower shape formability. The first resin cover layer 45 may be removed after the passivation layer 42 is formed. However, keeping the first resin cover layer 45 unremoved prevents intrusion of moisture and particles into the first conductive layer 1, the second conductive layer 2, and the photoelectric conversion layer 3, and contributes to improving the strength of the organic thin film solar cell module A16.

FIG. 171 to FIG. 183 illustrate a variation and other embodiments of the present invention. In these drawings, the elements same as or similar to those of the foregoing embodiments are given the same numeral as above, and the description will not be repeated.

FIG. 171 illustrates a variation of the organic thin film solar cell module A16. In this variation, the conductive perforated portion 351 is formed in an elongate shape in plan view. The longitudinal side of the conductive perforated portion 351 is generally parallel to the connection portion edge 131, extends along the longitudinal side of the connection portion 13. Suh a variation also increases the ratio of the area in the photoelectric conversion layer 3 that contributes to the power generation.

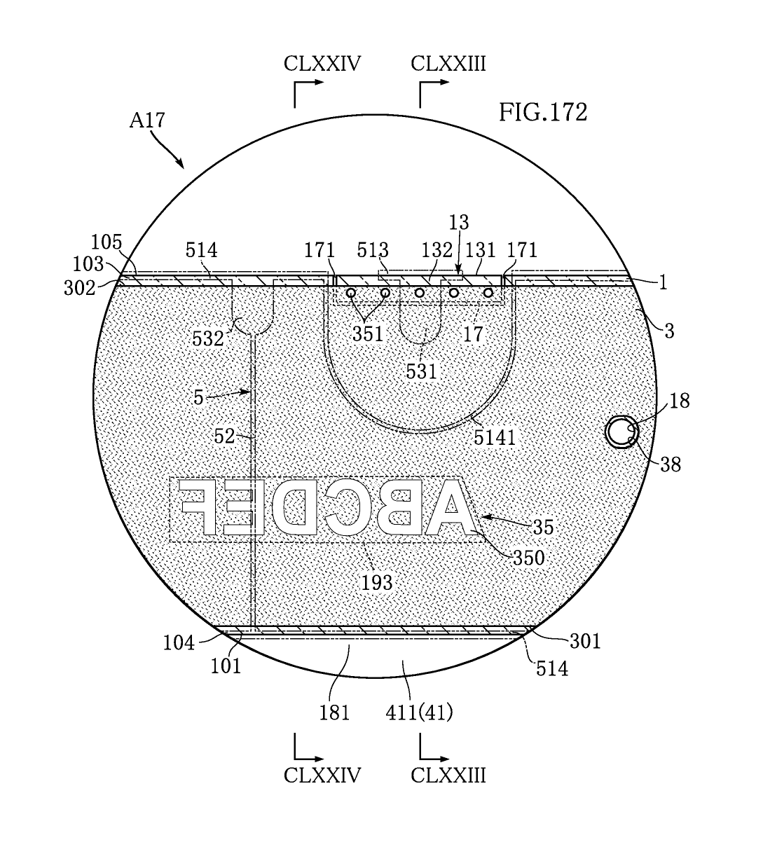

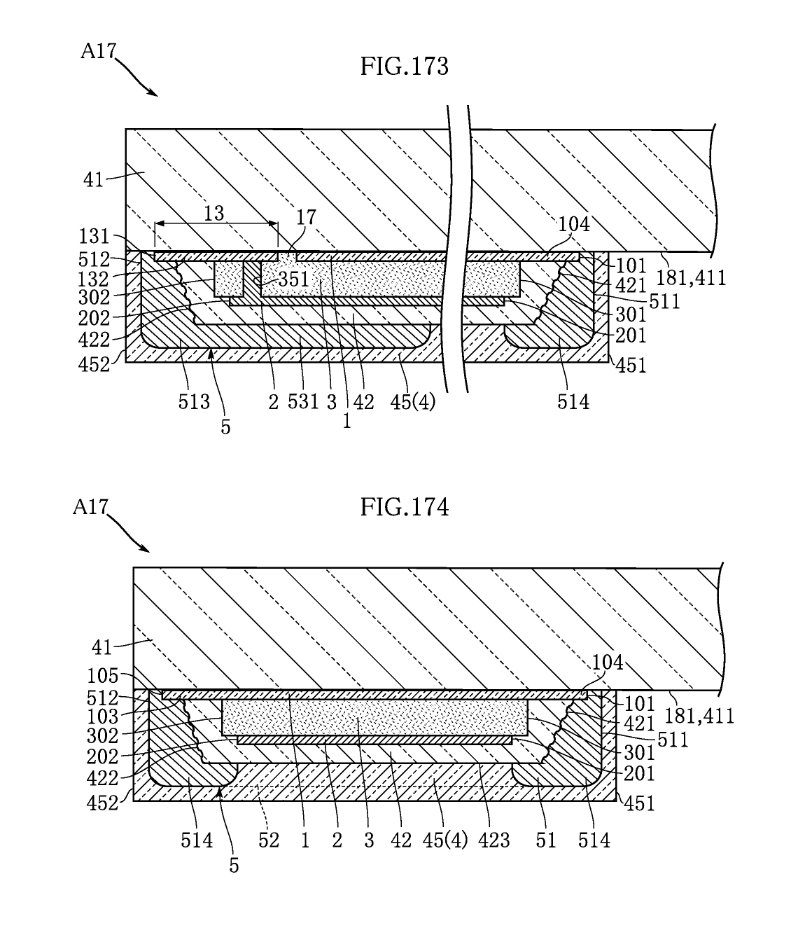

FIG. 172 to FIG. 175 illustrate an organic thin film solar cell module according to the eighteenth embodiment the present invention. The organic thin film solar cell module A17 according to this embodiment includes the first conductive layer 1, the second conductive layer 2, the photoelectric conversion layer 3, the base substrate 41, the passivation layer 42, the resin cover layer 4, and the bypass conductive section 5. The plan-view shape of the organic thin film solar cell module A17 is not specifically limited, and FIG. 172 to FIG. 175 represent the case where the organic thin film solar cell module A17 has the same plan-view shape as the organic thin film solar cell module A16, as an example. FIG. 172 is an enlarged partial bottom view showing the organic thin film solar cell module A17. FIG. 173 is an enlarged partial cross-sectional view taken along a line CLXXIII-CLXXIII in FIG. 172. FIG. 174 is an enlarged partial cross-sectional view taken along a line CLXXIV-CLXXIV in FIG. 172. FIG. 175 is an enlarged partial plan view without the first resin cover layer 45 and the bypass conductive section 5.

In this embodiment, the first edge 421 and the first outer edge 422 of the passivation layer 42 are, as shown in FIG. 174, formed in an uneven shape. In addition, the first edge 421 is, as a whole, inclined so as to be farther from the extended portion 103 of the first conductive layer 1 in plan view, at a position farther from the base substrate 41 in the thickness direction thereof. Likewise, the first outer edge 422 is inclined so as to be farther from the third edge 101 in plan view, at a position farther from the base substrate 41 in the thickness direction thereof. Further, the first edge 421 according to this embodiment has, as shown in FIG. 175, a non-linear shape spaced apart from the third edge 101, in plan view. The first edge 421 has a shape in which, for example, a plurality of bent lines and curved lines are connected. The first outer edge 422 also has a non-linear shape in plan view.

One of the second bus-bar sections 514 covers the first edge 421 of the passivation layer 42 generally over the entire length, except for a part thereof. The second bus-bar section 514 covers the first extended portion 104 of the first conductive layer 1 located between the third edge 101 and the first edge 421. The seventh edge 511 of the second bus-bar section 514 is located opposite to the first edge 421 across the third edge 101, in plan view. Accordingly, the second bus-bar section 514 is in direct contact with the base substrate 41. The other second bus-bar section 514 covers the first outer edge 422 of the passivation layer 42, over the entire length. This second bus-bar section 514 covers the second extended portion 103 of the first conductive layer 1. The seventh outer edge 512 of this second bus-bar section 514 is located opposite to the first outer edge 422 across the third outer edge 105, in plan view. Accordingly, this second bus-bar section 514 is in direct contact with the base substrate 41. Thus, each of the two second bus-bar sections 514 is electrically connected to the first conductive layer 1.

The first bus-bar section 513 covers the extended connection portion 132 of the connection portion 13 in the first conductive layer 1. The seventh edge 511 of the first bus-bar section 513 is located opposite to the first edge 421 with respect to the third edge 101, in plan view. Thus, the first bus-bar section 513 is in direct contact with the base substrate 41.

The resin cover layer 4 according to this embodiment only includes the first resin cover layer 45. As shown in FIG. 173 and FIG. 174, the first resin cover layer 45 covers the passivation layer 42 and the bypass conductive section 5, and is formed of, for example, a UV-curable resin. The first resin cover layer 45 may also serve as a transparent bonding layer for bonding the organic thin film solar cell module A17 and the display unit 702 together. In the illustrated example, the second edge 451 of the second edge 451 is located opposite to the first edge 421 with respect to the seventh edge 511, in plan view. The second outer edge 452 of the first resin cover layer 45 is located opposite to the first outer edge 422 with respect to the seventh outer edge 512, in plan view. Accordingly, the first resin cover layer 45 includes a portion in direct contact with the base substrate 41. In addition, the first resin cover layer 45 covers the portion of the surface 423 of the passivation layer 42 exposed from the bus-bar section 51.

Hereunder, a manufacturing method of the organic thin film solar cell module A17 will be described hereunder. The drawings referred to for the description are turned upside down from FIG. 173 and FIG. 174, to facilitate understanding.

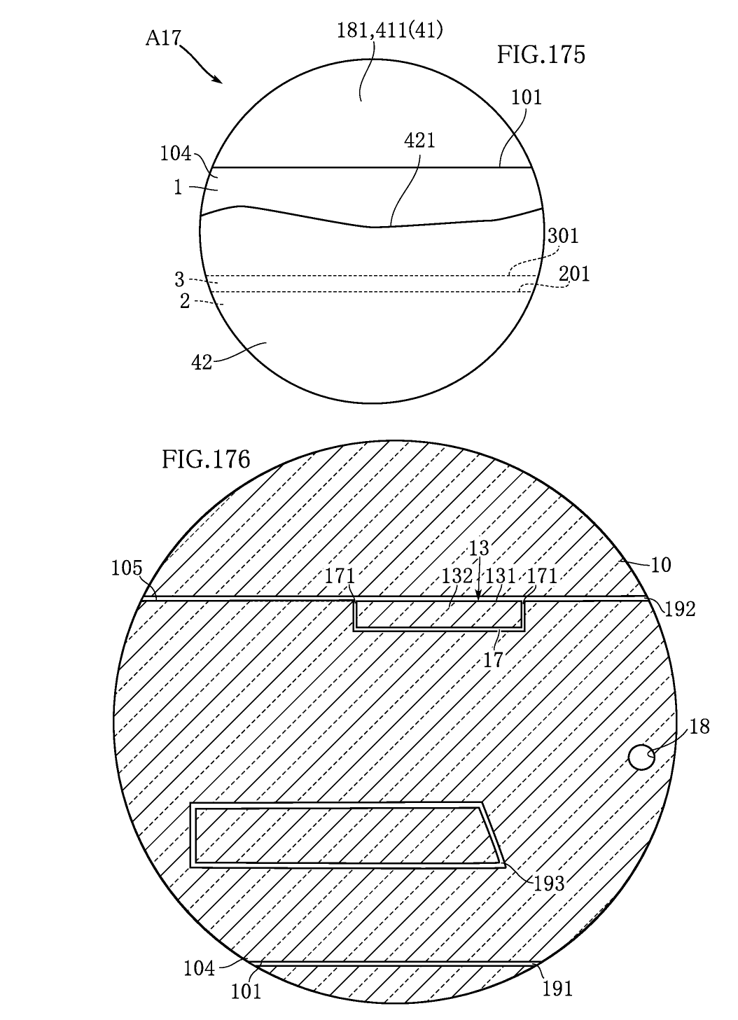

First, the base substrate 41 shown in FIG. 158 is prepared. On one of the surfaces of the base substrate 41, the first conductive film 10 formed of ITO is deposited by a known method such as sputtering, as shown in FIG. 59. Then the first conductive film 10 is patterned, as shown in FIG. 176. Thus, the slit 17, the slit 191, the slit 192, and the slit 193 are formed in the first conductive film 10. The first conductive film 10 is patterned, for example, by laser patterning. In this case, the type of the laser beam Lz1 is not specifically limited provided that the laser is capable of patterning the first conductive film 10 and, for example, the IR laser beam may be employed. One of the edges of the first conductive film 10 defining the slit 191, on the side of the second conductive layer 2 and the photoelectric conversion layer 3 shown in FIG. 174, corresponds to the third edge 101. The portion of the first conductive film 10 between the fifth inner recessed edge 301 and the slit 191 corresponds to the first extended portion 104. One of the edges of the first conductive film 10 defining the slit 192, on the side of the second conductive layer 2 and the photoelectric conversion layer 3 shown in FIG. 174, corresponds to the third outer edge 105. The portion of the first conductive film 10 between the slit 192 and the fifth outer recessed edge 302 of the photoelectric conversion layer 3 corresponds to the second extended portion 103. The portion defined by the slit 17 and the slit 192 corresponds to the connection portion 13.

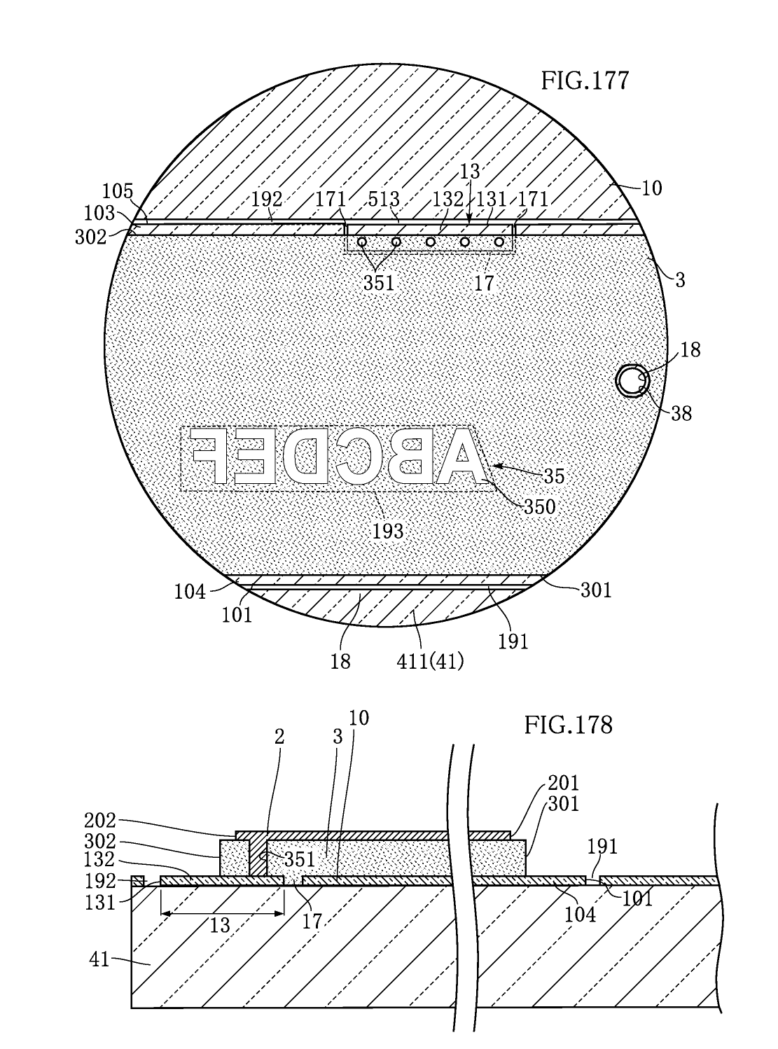

Then an organic film is deposited on the first conductive film 10, and the organic film is patterned, for example with the green laser beam, to form the photoelectric conversion layer 3 shown in FIG. 177.

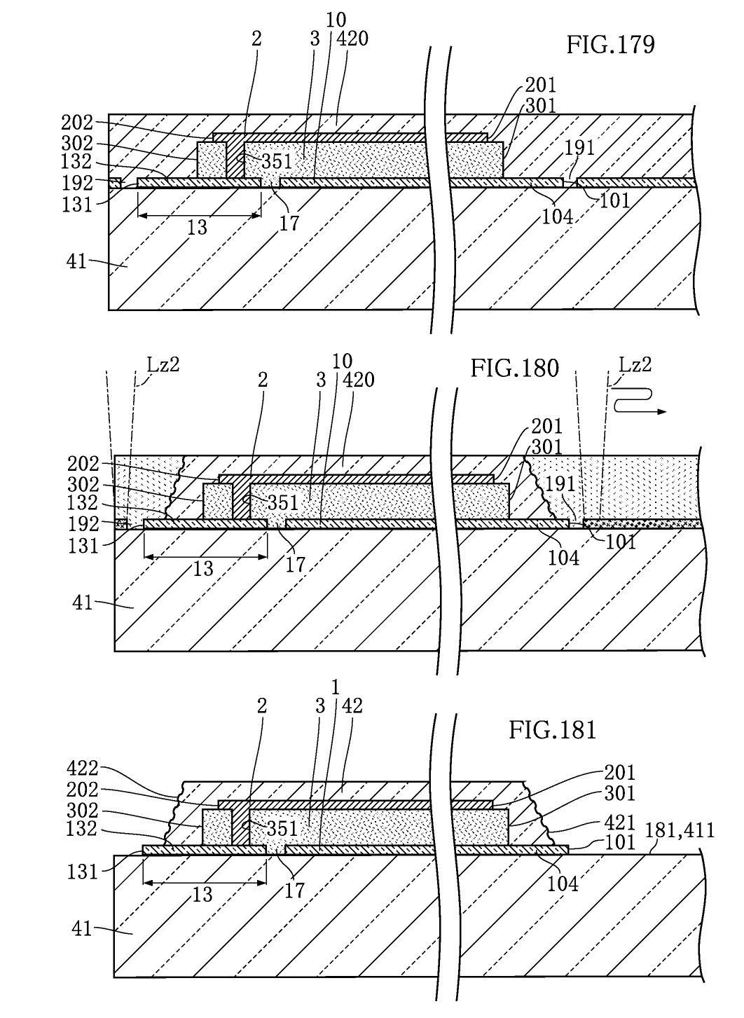

Then the second conductive layer 2 is formed as shown in FIG. 178, and the insulation film 420 is formed is formed as shown in FIG. 179. To form the insulation film 420, a film of SiN or SiON is deposited on the base substrate 41, the first conductive film 10, the photoelectric conversion layer 3, and the second conductive layer 2, for example by plasma CVD.

Proceeding to FIG. 179, the insulation film 420 is formed so as to cover the first conductive film 10, the second conductive layer 2, and the photoelectric conversion layer 3. Then the base substrate 41 is exposed in a region adjacent to the first edge 421, by partially removing the insulation film 420 thereby forming the passivation layer 42 having the first edge 421, and partially removing the first conductive film 10 thereby forming the first conductive layer 1. In this embodiment, the exposing of the includes, as shown in FIG. 180, irradiating the first conductive film 10 with the laser beam Lz2 through the insulation film 420, thereby partially removing the first conductive film 10 and the insulation film 420. In FIG. 180, a portion of the first conductive film 10 shaded with scattered dots that are relatively larger is the area irradiated with the laser beam Lz2. A portion of the insulation film 420 shaded with scattered dots that are relatively smaller is the portion removed owing to the irradiation of the laser beam Lz2. Here, for example an etching process may be adopted, without limitation of the irradiation of the laser beam Lz2.

More specifically, the portions of the first conductive film 10 opposite to the second conductive layer 2 and the photoelectric conversion layer 3 shown in FIG. 142, across the slit 191 and the slit 192 respectively, are irradiated with the laser beam Lz2 through the insulation film 420. For example, the IR laser beam having a wavelength of approximately 1,064 nm may be adopted as the laser beam Lz2. The portion of the first conductive film 10 irradiated with the laser beam Lz2 instantly volatilizes, upon being exposed to a significant amount of energy.

The laser beam Lz2 having the mentioned wavelength is barely absorbed by the insulation film 420, unlike the case of the first conductive film 10. Accordingly, the insulation film 420 is not directly destroyed by the laser beam Lz2. However, a portion of the insulation film 420 in contact with the first conductive film 10 is supported by the base substrate 41, via the first conductive film 10. When the first conductive film 10 volatilizes owing to the irradiation of the laser beam Lz2, the portion of the insulation film 420 is no longer supported by the base substrate 41. In addition, a portion of the insulation film 420, superposed on the portion of the first conductive film 10 irradiated with the laser beam Lz2 (portion shaded with the scattered dots that are relatively larger in FIG. 180), partially splashes owing to the volatilization pressure of the first conductive film 10.

Further, through investigations carried out by the present inventor, it has proved that a portion of the insulation film 420 adjacent to the portion of the first conductive film 10 irradiated with the laser beam Lz2 also splashes owing to the volatilization pressure of the first conductive film 10. In FIG. 180, the portion of the insulation film 420 that splashes as result of the irradiation of the laser beam Lz2 is shaded with scattered dots that are relatively smaller. In this embodiment, the portion of the insulation film 420 that splashes is located on the side of the second conductive layer 2 and the photoelectric conversion layer 3, beyond the slit 191 and the slit 192. However, the size and position of the slit 191 and the slit 192, as well as the irradiation range and output of the laser beam Lz2 are properly adjusted, so as to prevent the passivation layer 42 from being destroyed to such an extent that a part of the second conductive layer 2 and the photoelectric conversion layer 3 is exposed. Accordingly, the edge of the insulation film 420 on the side of the slit 191 constitutes the first edge 421, and the edge on the side of the slit 192 constitutes the first outer edge 422. The portion of the first conductive film 10 adjacent to the slit 191, shaded with the scattered dots, is removed by the irradiation of the laser beam Lz2. Therefore, the edge of the first conductive film 10 on the side of the photoelectric conversion layer 3 with respect to the slit 191 in plan view constitutes the third edge 101, and the edge of the first conductive film 10 on the side of the photoelectric conversion layer 3 with respect to the slit 192 in plan view constitutes the third outer edge 105. Likewise, the portion of the first conductive film 10 adjacent to the slit 192, shaded with the scattered dots, is also removed by the irradiation of the laser beam Lz2. In addition, a portion of the first conductive film 10 adjacent to the slit 191 and the slit 192 is exposed from the passivation layer 420, since the portion of the insulation film 420 adjacent to the slit 191 and the slit 192 partially splashes owing to the irradiation of the laser beam Lz2. The exposed portion constitutes the first extended portion 104 and the second extended portion 103.

Upon partially removing as above the first conductive film 10 and the insulation film 420 by the irradiation of the laser beam Lz2, the passivation layer 42 having the first edge 421 and the first outer edge 422 is formed, as shown in FIG. 181. In addition, the first conductive layer 1 including the portions extending from the first edge 421 and the first outer edge 422 is formed. In the first conductive layer 1, the third edge 101 and the extended portion 103 are also formed. Further, the connection portion 13 defined by the slit 17 is formed. Here, after the process shown in FIG. 180, the processed portion may be washed, for example with aqua regia, to remove the residue of the first conductive film 10 and other components remaining on the base substrate 41.

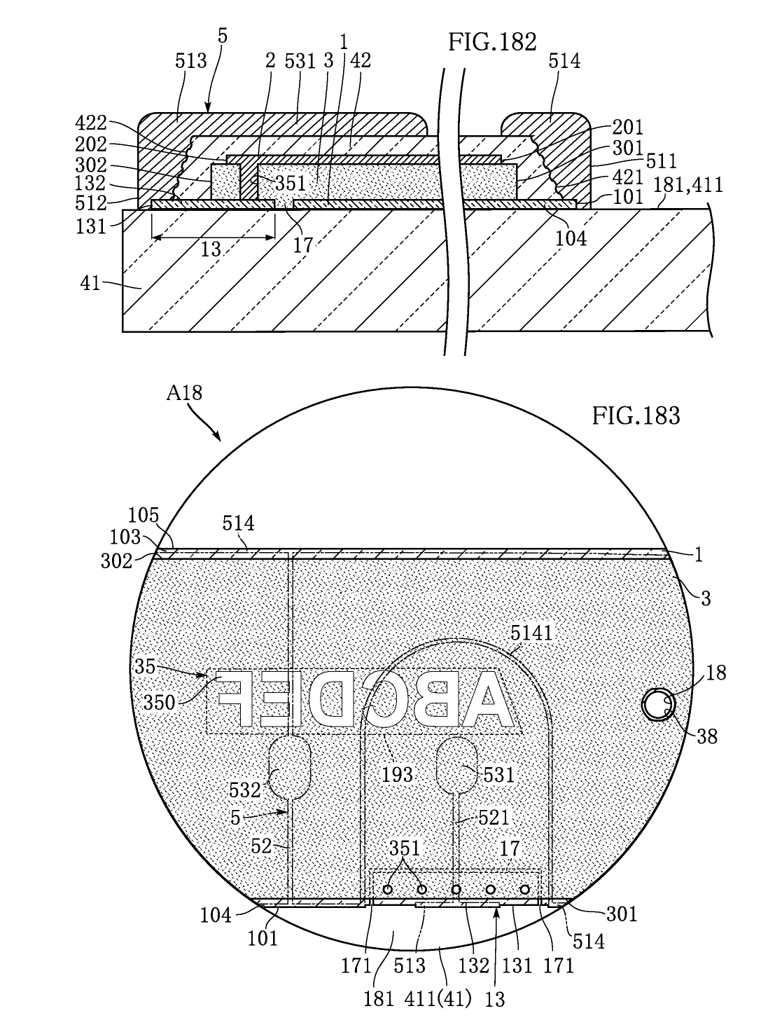

Proceeding to FIG. 182, the bypass conductive section 5 is formed. The bypass conductive section 5 is formed so as to cover the portion of the first conductive layer 1 extending from the passivation layer 42, and the first edge 421 and the first outer edge 422 of the passivation layer 42. In addition, it is preferable to form the bypass conductive section 5 so as to make the bypass conductive section 5 directly contact the base substrate 41. Thus, the bypass conductive section 5 including the bus-bar section 51 and the communication portion 52 is obtained.

Thereafter, the first resin cover layer 45 (resin cover layer 4) is formed so as to cover the bypass conductive section 5 and the passivation layer 42. To form the first resin cover layer 45, for example, a liquid resin material containing a UV-curable resin is applied to the passivation layer 42 by screen printing, and the resin is irradiated with UV light thus to be cured. Through the mentioned process, the organic thin film solar cell module A17 shown in FIG. 172 to FIG. 174 can be obtained.

The mentioned embodiment also increases the area ratio of the generation region 31 of the photoelectric conversion layer 3. In addition, as shown in FIG. 173 and FIG. 174, the second bus-bar section 514 of the bypass conductive section 5 covers the first extended portion 104 and the second extended portion 103 of the first conductive layer 1. The first bus-bar section 513 covers the extended connection portion 132 of the first conductive layer 1. Such a configuration allows the electric conduction area between the first conductive layer 1 and the bypass conductive section 5 to be increased, which is desirable for reducing the resistance. Forming the first edge 421 and the first outer edge 422 in an uneven shape leads to improved adhesion strength between the first edge 421 and the second bus-bar section 514 of the bypass conductive section 5, and between the first outer edge 422 and the first bus-bar section 513.

As shown in FIG. 180, the passivation layer 42 is removed utilizing the volatilization of the first conductive layer 1 caused by the irradiation of the laser beam Lz2 on the first conductive layer 1. Therefore, there is no need to employ a single-purpose laser beam or chemical for removing the passivation layer 42. This is advantageous for reduction in cost and time for the manufacturing. Employing the IR laser beam as the laser beam Lz2 allows the first conductive film 10 to be irradiated with higher efficiency, with the laser beam Lz2 through the insulation film 420. In addition, employing the IR laser beam as the laser beam Lz2 provides the advantage in that the first edge 421 and the first outer edge 422 of the passivation layer 42 can be finished in an uneven shape. Here, SiN, which is an example of the material of the insulation film 420, transmits light having a wavelength longer than 400 nm. Accordingly, in the case where the insulation film 420 is formed of SiN, the green laser beam, which has the wavelength of 532 nm, may be employed as the laser beam Lz2. On the other hand, in the case where UV laser beam having the wavelength of 355 nm is employed as the laser beam Lz2, the insulation film 420 and the first conductive film 10 both absorb the laser beam Lz2, and therefore these films can both be removed at a time.

The partial removal of the insulation film 420 and the first conductive film 10 is performed with the laser beam Lz2. The irradiation range of the laser beam Lz2 can be accurately controlled. Therefore, the laser beam Lz2 is suitable for removing a desired portion of the insulation film 420 and the first conductive film 10.

To remove the insulation film 420, the phenomenon that the insulation film 420 located adjacent to a region of the first conductive film 10 irradiated with the laser beam Lz2 is destroyed, is utilized. Accordingly, in the region of the first conductive layer 1 exposed from the passivation layer 42 shown in FIG. 181, the portion of the insulation film 420 that was covering this region is removed, despite that this region is not irradiated with the laser beam Lz2. Therefore, the region of the first conductive layer 1 exposed from the passivation layer 42 can be prevented from being accidentally destroyed, in the removal process of the insulation film 420.

Forming the slit 191 and the slit 192 in the first conductive film 10 prevents unintended expansion of the region of the insulation film 420 that may be affected by the volatilization of the first conductive film 10. In addition, forming the slit 191 and the slit 192 prevents, even when a part of the first conductive film 10 remains in the region to be removed, in the process of partially removing the first conductive film 10 shown in FIG. 180 and FIG. 181, accidental electrical connection between the residual part and the first conductive layer 1. However, the portion of the first conductive film 10 located opposite to the photoelectric conversion layer 3 across the slit 192 may remain as a part of the organic thin film solar cell module A17, without being removed. This portion is kept from being electrically connected to the first conductive layer 1, by the presence of the slit 192. Skipping the removal process of this portion contributes to reducing the manufacturing time. Here, the provision of the slit 191 and the slit 192 is merely an example, and these slits may be omitted.

FIG. 183 illustrates an organic thin film solar cell module according to an eighteenth embodiment of the present invention. In the organic thin film solar cell module A18 according to this embodiment, both ends 171 of the slit 17 reach the third edge 101 of the first conductive layer 1. Thus, the connection portion 13 is located so as to oppose the display opening 181. In other words, the connection portion 13 is located between the view display opening 181 and the design display section 35, in a plan. The second bus-bar section 514 opposed to the display opening 181 includes the circumvent portion 5141. Further, the bypass conductive section 5 according to this embodiment includes a communication portion 521. The communication portion 521 connects the first bus-bar section 513 and the first collector electrode 531. The first collector electrode 531 is spaced apart from the first bus-bar section 513. In the illustrated example, the second collector electrode 532 and the first collector electrode 531 are located at the same distance from the display opening 181.

The mentioned embodiment also increases the area ratio of the generation region 31 of the photoelectric conversion layer 3. In addition, although the connection portion 13 is located so as to oppose the display opening 181, the first collector electrode 531 is located so as to overlap with the second conductive layer and the photoelectric conversion layer 3, in plan view. Therefore, the first collector electrode 531 is not protruding into the display opening 181, and hence the display in the display unit 702 is prevented from being disturbed.

The organic thin film solar cell module and the electronic device according to the present invention are in no way limited to the foregoing embodiments. The specific configurations of the elements of the organic thin film solar cell module and the electronic device according to the present invention may be modified in various manners.

The foregoing configuration according to the present invention is broadly applicable, in addition to the mobile phone terminal, to various electronic devices that utilize the photovoltaic generation, such as a wrist watch and an electronic calculator.

The technical features of the present invention may be expressed as the following appendices.

### Appendix 1E

An organic thin film solar cell module including:

a transparent base substrate;

a transparent first conductive layer disposed on the base substrate;

a second conductive layer;

a photoelectric conversion layer formed of an organic thin film and interposed between the first conductive layer and the second conductive layer; and

a passivation layer covering the second conductive layer,

in which the first conductive layer includes an extended portion extending from the passivation layer in plan view, a slit formed such that both ends reach an edge of the extended portion, and a connection portion defined by the slit and having a connection portion edge connected to the both ends of the slit,

the photoelectric conversion layer includes a conductive perforated portion enclosed in the connection portion of the first conductive layer in plan view and formed so as to penetrate in the thickness direction,

the second conductive layer and the connection portion of the first conductive layer are electrically connected via the conductive perforated portion of the photoelectric conversion layer, and

the organic thin film solar cell module also includes a first bus-bar section covering at least a part of an extended connection portion in the connection portion, extending from the passivation layer, and a bypass conductive section including a first collector electrode electrically connected to the first bus-bar section.

### Appendix 2E

The organic thin film solar cell module according to appendix 1E, in which the conductive perforated portion has a circular shape in plan view.

### Appendix 3E

The organic thin film solar cell module according to appendix 1E, in which the conductive perforated portion has an elongate shape having a longitudinal side extending parallel to the edge of the connection portion, in plan view.

### Appendix 4E

The organic thin film solar cell module according to any one of appendices 1E to 3E, in which the first collector electrode overlaps with the second conductive layer and the photoelectric conversion layer in plan view, an

the passivation layer is interposed between the first collector electrode and the second conductive layer, in the thickness direction of the base substrate.

### Appendix 5E

The organic thin film solar cell module according to any one of appendices 1E to 4E, in which the bypass conductive section includes a second bus-bar section covering at least a part of the extended portion of the first conductive layer, and a second collector electrode electrically connected to the second bus-bar section.

### Appendix 6E

The organic thin film solar cell module according to appendix 5E, in which the second collector electrode overlaps with the second conductive layer and the photoelectric conversion layer in plan view, and

the passivation layer is interposed between the second collector electrode and the second conductive layer, in the thickness direction of the base substrate.

### Appendix 7E

The organic thin film solar cell module according to appendix 6E, in which the second bus-bar section includes a circumvent portion having both ends connected to a portion of the extended portion of the first conductive layer located on both sides of the connection portion, and arranged so as to circumvent the first collector electrode in plan view.

### Appendix 8E

The organic thin film solar cell module according to any one of appendices 1E to 7E, in which the photoelectric conversion layer includes a design display perforated portion formed so as to penetrate in the thickness direction, and constituting a design display section exposed in the outer appearance, and

the design display perforated portion is located opposite to the connection portion edge, across the conductive perforated portion.

### Appendix 9E

The organic thin film solar cell module according to any one of appendices 1E to 8E, in which the first conductive layer includes a display opening for forming the display region, a third edge that defines the display opening, and a first extended portion extending from the passivation layer toward the display opening, and

the connection portion is defined by the slit formed such that both ends reach the third edge.

### Appendix 10E

The organic thin film solar cell module according to any one of appendices 1E to 8E, in which the first conductive layer includes a display opening for forming the display region, a third edge that defines the display opening, a third outer edge located opposite to the third edge, a first extended portion extending from the passivation layer toward the display opening, and a second extended portion extending from the passivation layer in a direction opposite to the display opening, and

the connection portion is defined by the slit formed such that both ends reach the third outer edge.

### Appendix 11E

The organic thin film solar cell module according to appendix 9E or 10E, further including a resin cover layer covering the bypass conductive section.

### Appendix 12E

The organic thin film solar cell module according to appendix 11E, in which the passivation layer includes a first edge opposing the display opening in plan view,

the resin cover layer includes a first resin cover layer covering the passivation layer, a second resin cover layer disposed on the first resin cover layer and covering the bypass conductive section, and

the first resin cover layer includes a second edge coinciding with the first edge in plan view.

### Appendix 13E

The organic thin film solar cell module according to appendix 12E, in which the first edge and the second edge form a continuous surface.

### Appendix 14E

The organic thin film solar cell module according to appendix 13E, in which the bypass conductive section includes a seventh edge coinciding with the third edge in plan view.

### Appendix 15E

The organic thin film solar cell module according to appendix 14E, in which the second resin cover layer includes a sixth edge located opposite to the first edge across the third edge and the seventh edge in plan view, and is in contact with the base substrate.

### Appendix 16E

The organic thin film solar cell module according to appendix 15E, in which the second conductive layer includes a fourth inner recessed edge, inwardly recessed with respect to the first edge in plan view.

### Appendix 17E

The organic thin film solar cell module according to appendix 16E, in which the photoelectric conversion layer includes a fifth inner recessed edge, inwardly recessed with respect to the first edge in plan view.

### Appendix 18E

The organic thin film solar cell module according to appendix 17E, in which the fourth inner recessed edge is inwardly recessed with respect to the fifth inner recessed edge, in plan view.

### Appendix 19E

The organic thin film solar cell module according to appendix 11E, in which the passivation layer includes a first edge opposing the display opening in plan view, and

the bypass conductive section includes a seventh edge located opposite to the first edge across the third edge, in plan view.

### Appendix 20E

The organic thin film solar cell module according to appendix 19E, in which the resin cover layer includes a second edge located opposite to the first edge across the seventh edge in plan view, and is in contact with the base substrate.

### Appendix 21E

The organic thin film solar cell module according to appendix 20E, in which the second conductive layer includes a fourth inner recessed edge, inwardly recessed with respect to the first edge in plan view.

### Appendix 22E

The organic thin film solar cell module according to appendix 21E, in which the photoelectric conversion layer includes a fifth inner recessed edge, inwardly recessed with respect to the first edge in plan view.

### Appendix 23E

The organic thin film solar cell module according to appendix 22E, in which the fourth inner recessed edge is inwardly recessed with respect to the fifth inner recessed edge, in plan view.

### Appendix 24E

The organic thin film solar cell module according to appendix 18E or 23E, in which the first edge has an annular shape in plan view.

### Appendix 25E

The organic thin film solar cell module according to appendix 24E, in which the third edge has an annular shape in plan view.

### Appendix 26E

The organic thin film solar cell module according to appendix 25E, in which the fourth inner recessed edge has an annular shape in plan view.

### Appendix 27E

The organic thin film solar cell module according to appendix 26E, in which the fifth inner recessed edge has an annular shape in plan view.

### Appendix 28E

The organic thin film solar cell module according to appendix 27E, in which the seventh edge has an annular shape in plan view.

### Appendix 29E

The organic thin film solar cell module according to appendix 28E, in which the second edge has an annular shape in plan view.

### Appendix 30E

The organic thin film solar cell module according to appendix 18E, in which the sixth edge has an annular shape in plan view.

### Appendix 31E

The organic thin film solar cell module according to any one of appendices 11E to 30E, in which the first conductive layer is formed of ITO.

### Appendix 32E

The organic thin film solar cell module according to any one of appendices 11E to 31E, in which the second conductive layer is formed of a metal.

### Appendix 33E

The organic thin film solar cell module according to any one of appendices 11E to 32E, in which the second conductive layer is formed of A1.

### Appendix 34E

The organic thin film solar cell module according to any one of appendices 11E to 33E, in which the passivation film is formed of SiN.

### Appendix 35E

The organic thin film solar cell module according to any one of appendices 11E to 34E, in which the resin cover layer is formed of a UV-curable resin.

### Appendix 36E

An electronic device including:

the organic thin film solar cell module according to any one of appendices 1E to 35E; and

a drive unit to operate by power supplied from the organic thin film solar cell module.

### Nineteenth to Twenty-First Embodiments

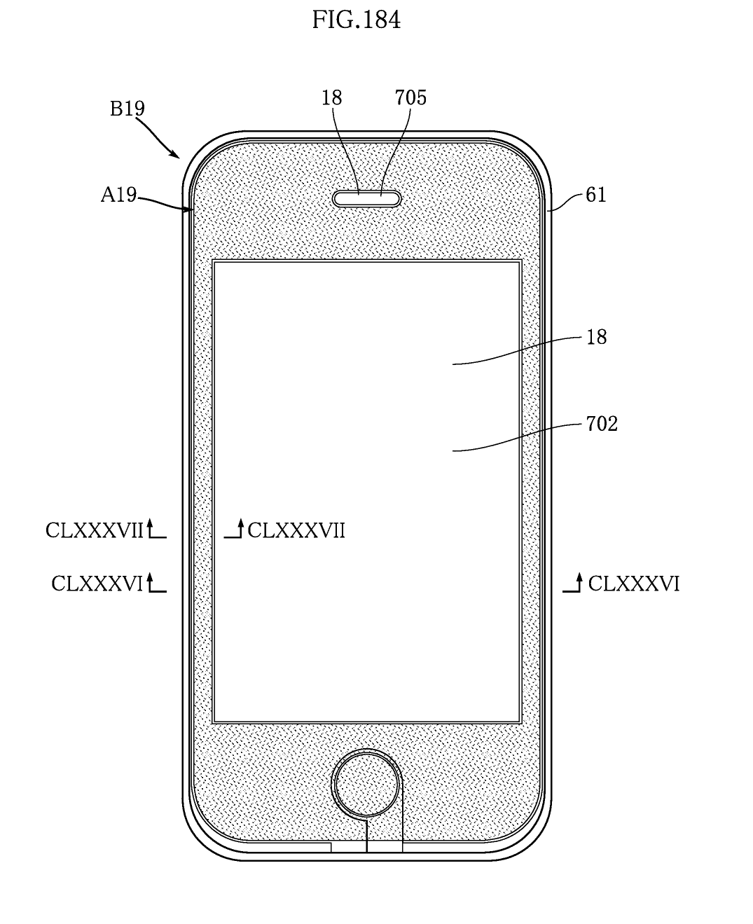

The reference numerals used for nineteenth to twenty-first embodiments and FIG. 184 to FIG. 219 are given for these particular embodiment and drawings, and independent of numerals used for other embodiments and drawings. It should be noted, however, that the arrangements of the nineteenth to twenty-first embodiments and those of any other embodiment may be combined or exchanged in an appropriate manner.

The term “transparent” used herein may be defined as having a transmittance of approximately 50% or higher. The term “transparent” may also be used for visible light when it is colorless and clear. The visible light corresponds to a wavelength range of approximately 360 nm to 830 nm and an energy range of approximately 3.45 eV to 1.49 eV. When a transmittance of a substance is 50% or higher in these ranges, that substance may be regarded as transparent.

FIG. 184 to FIG. 188 illustrate an electronic device according to the nineteenth embodiment of the present invention, and an organic thin film solar cell module according to the nineteenth and twentieth embodiments of the present invention. The electronic device B19 according to this embodiment includes an organic thin film solar cell module A19, an organic thin film solar cell module A20, the case 61, the control unit 701, the display unit 702, the input unit 703, the microphone 704, the speaker 705, the wireless communication unit 706, and the battery 707, and is configured as a mobile phone terminal.

The case 61, which accommodates therein other components of the electronic device B19, is formed of a metal, a resin, or glass.

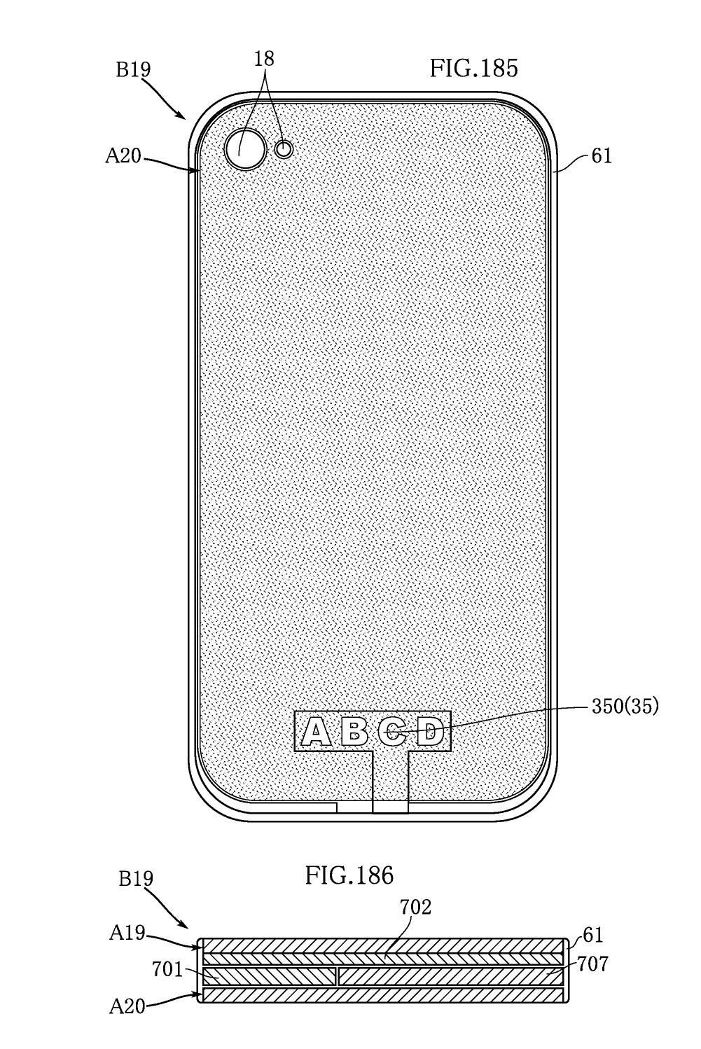

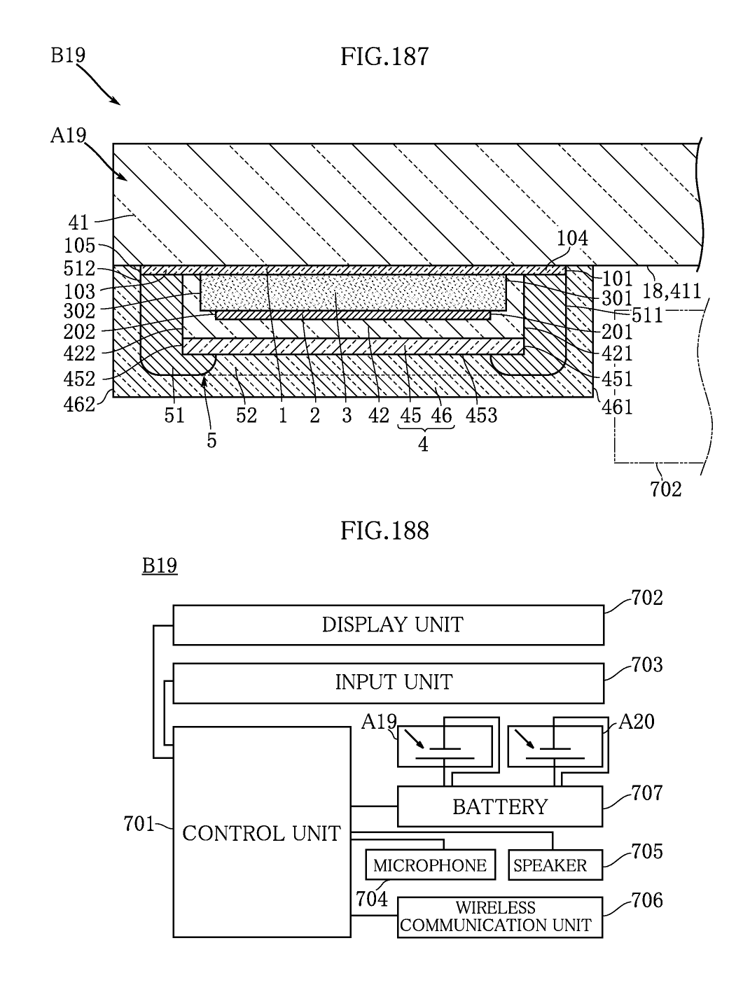

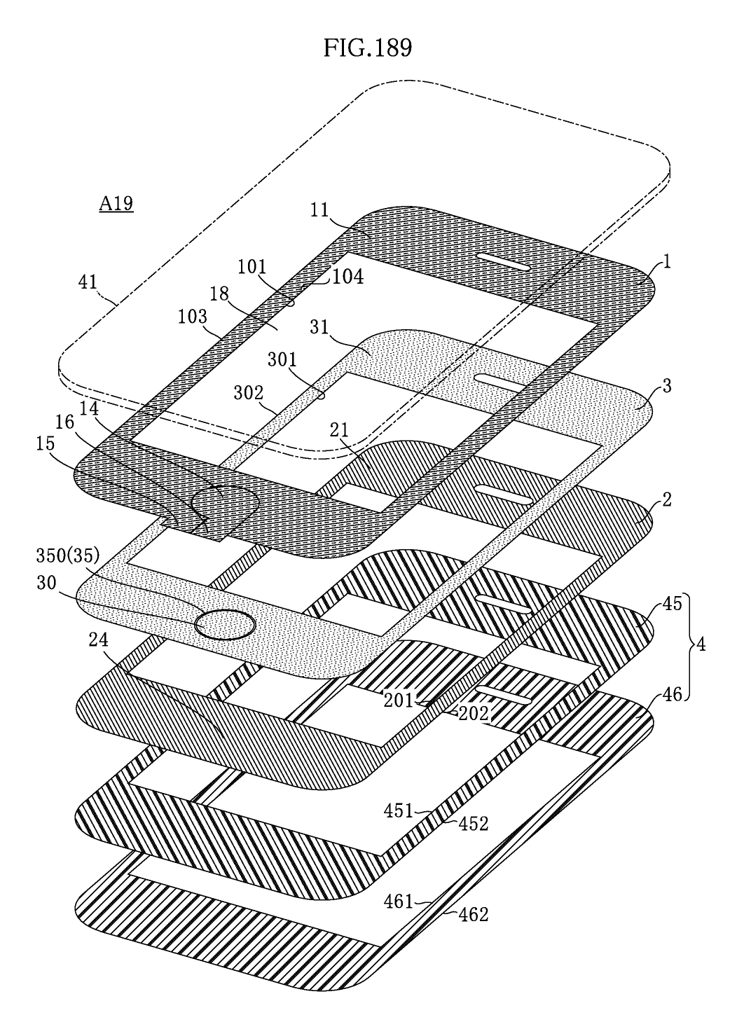

FIG. 184 is a plan view showing organic thin film solar cell modules A19 and A20, and the electronic device B19 incorporated with the organic thin film solar cell modules. FIG. 185 is a bottom view showing the organic thin film solar cell modules A19 and A20, and the electronic device B19. FIG. 186 is a schematic cross-sectional view taken along a line CLXXXVI-CLXXXVI in FIG. 184. FIG. 187 is an enlarged partial cross-sectional view taken along a line CLXXXVII-CLXXXVII in FIG. 184. FIG. 188 is a system diagram of the electronic device B19. In FIG. 186, the elements other than the case 61, the organic thin film solar cell module A19, the organic thin film solar cell module A20, the control unit 701, the display unit 702, and the battery 707 are omitted, to facilitate understanding.

The organic thin film solar cell module A19 and the organic thin film solar cell module A20, serving as the power source module for the electronic device B19, convert light, such as sunlight, into electric power. Further details will be described below.

The control unit 701 corresponds to the drive unit in the present invention, and operates by the power supplied from the organic thin film solar cell module A19 and the organic thin film solar cell module A20. The control unit 701 may receive power directly from the organic thin film solar cell module A19 and the organic thin film solar cell module A20, or from the battery 707, after the power from the organic thin film solar cell module A19 and the organic thin film solar cell module A20 is once charged in the battery 707. The control unit 701 includes, for example, a CPU, a memory, and an interface.

The display unit 702 serves to display various types of information in the outer appearance of the electronic device B19. The display unit 702 is constituted of, for example, an LCD panel or an organic EL display panel. In this embodiment, the display unit 702 displays the information in the outer appearance, through the organic thin film solar cell module A19.

The input unit 703 outputs an electric signal according to inputs made by the user, to the control unit 701. The input unit 703 is constituted of, for example, a touch panel disposed on the display unit 702. The display unit 702 and the input unit 703 may be integrally formed.

The microphone 704 is a device that converts the voice of the user into electric signals. The speaker 705 is a device that outputs the voice of a counterpart of the call and various message tones.

The wireless communication unit 706 is a device for bidirectional wireless communication, in compliance with a wireless communication standard.

The battery 707 is a device for storing power for driving the electronic device B19. The battery 707 is rechargeable. The battery 707 may be charged by the power from commercial power supply through a non-illustrated adapter, or from the organic thin film solar cell module A19 and the organic thin film solar cell module A20.

The organic thin film solar cell module A19 and the organic thin film solar cell module A20 each include the first conductive layer 1, the second conductive layer 2, the photoelectric conversion layer 3, the base substrate 41, the passivation layer 42, the resin cover layer 4, and the bypass conductive section 5. In this embodiment, the organic thin film solar cell module A19 and the organic thin film solar cell module A20 have a rectangular shape in plan view, however this is merely an example, and various shapes may be adopted. The organic thin film solar cell module A19 and the organic thin film solar cell module A20 have the same configuration, except for a minor difference. Hereunder, the organic thin film solar cell module A19 will first be described.

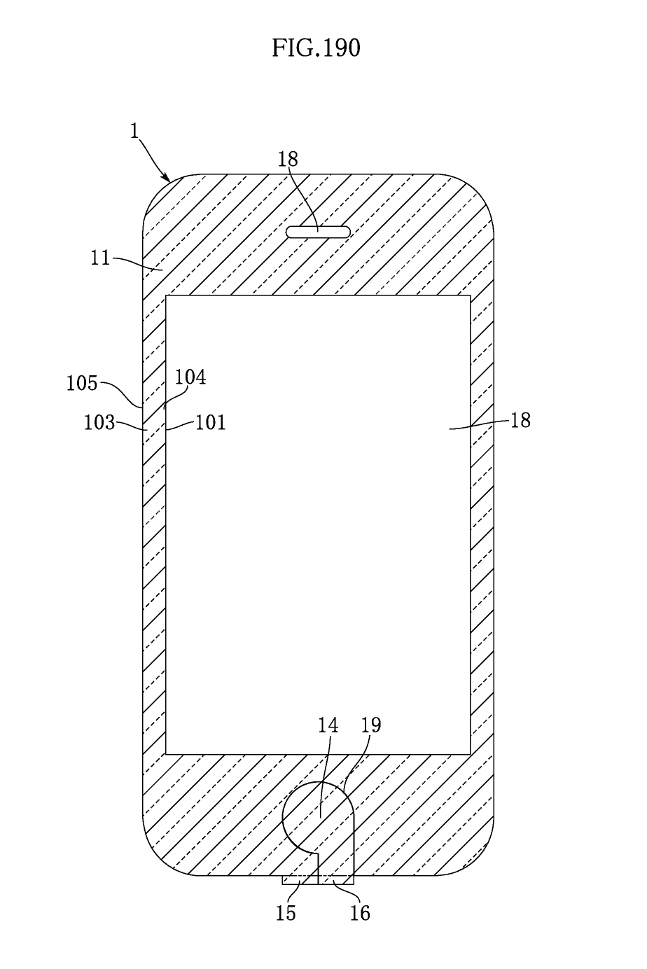

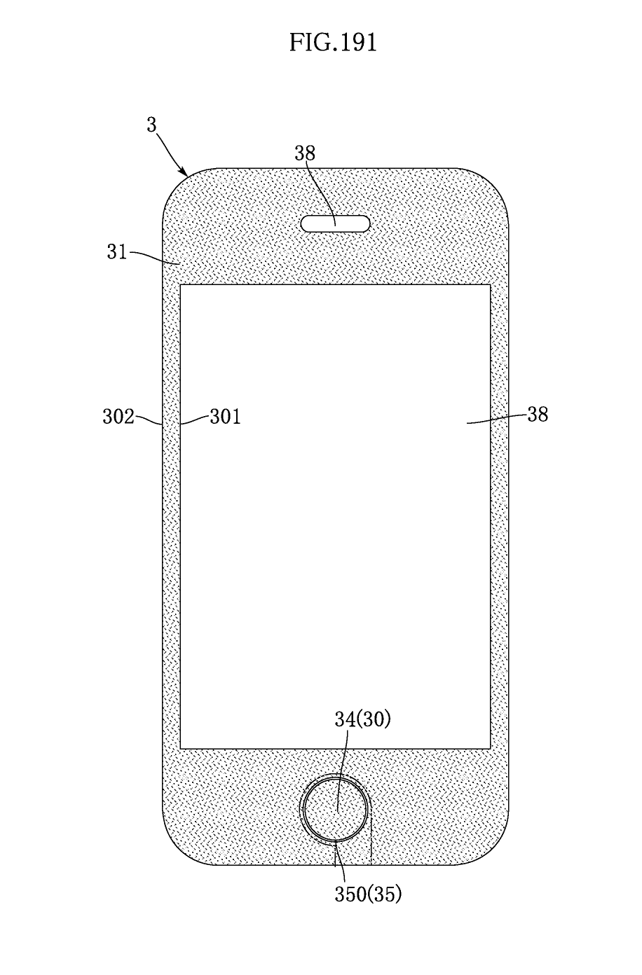

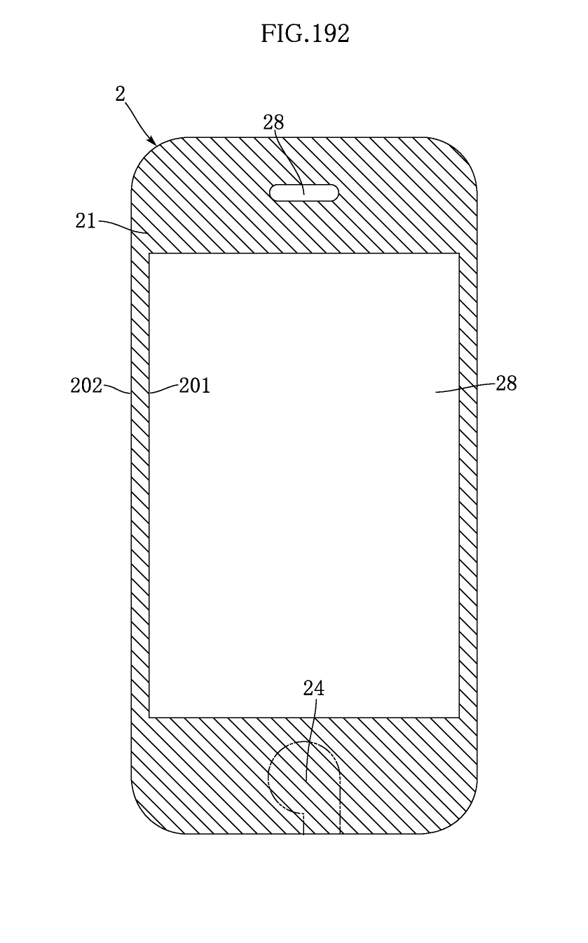

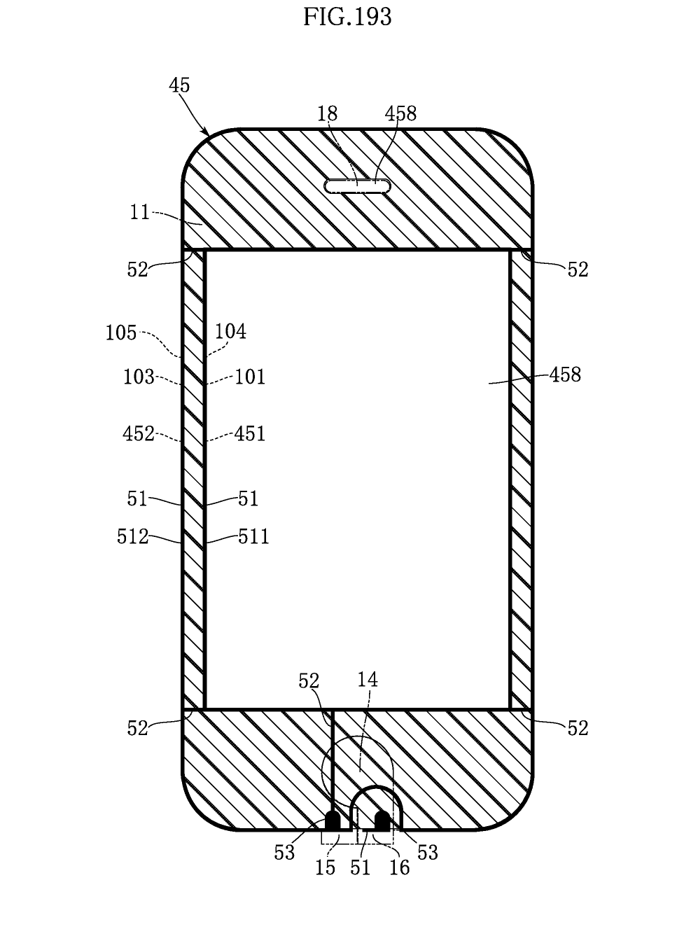

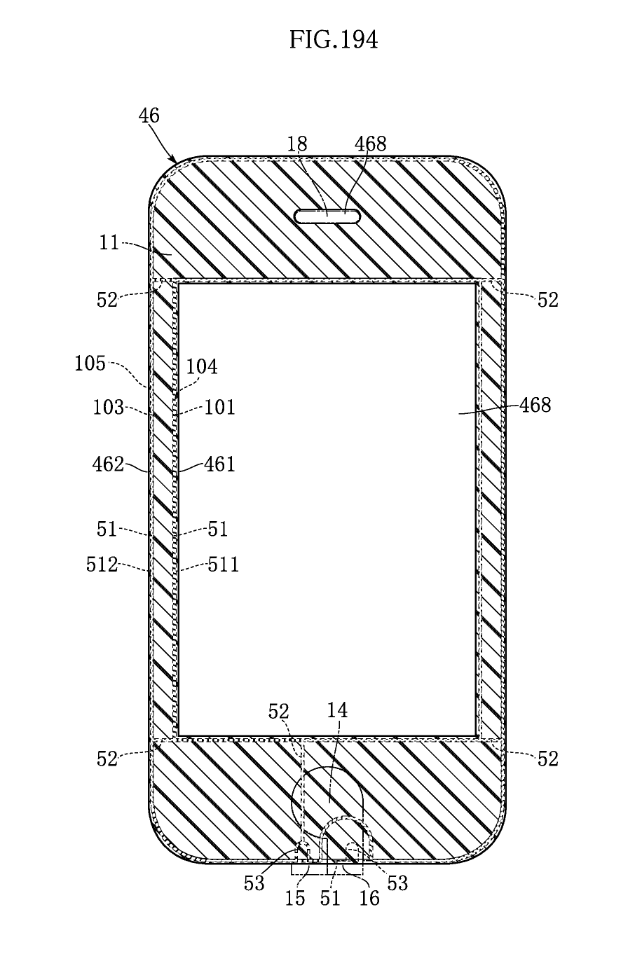

FIG. 189 is a partial exploded perspective view showing the first conductive layer 1, the second conductive layer 2, the photoelectric conversion layer 3, the base substrate 41, and the resin cover layer 4 of the organic thin film solar cell module A19. For the sake of clarity, the base substrate 41 is illustrated in imaginary lines (dash-dot-dot-lines). FIG. 190 is a plan view showing the first conductive layer 1 of the organic thin film solar cell module A19. FIG. 191 is a plan view showing the photoelectric conversion layer 3 of the organic thin film solar cell module A19. FIG. 192 is a plan view showing the second conductive layer 2 of the organic thin film solar cell module A19. FIG. 193 is a plan view showing the first resin cover layer 45 of the resin cover layer 4 to be described below, and the bypass conductive section 5 of the organic thin film solar cell module A19. FIG. 194 is a plan view showing the second resin cover layer 46 of the resin cover layer 4 of the organic thin film solar cell module A19, to be described below.

The base substrate 41 serves as the base of the organic thin film solar cell module A19. The base substrate 41 is formed of, for example, transparent glass or a resin. The base substrate 41 has a thickness of, for example, 0.05 mm to 2.0 mm.

The first conductive layer 1 is formed on the base substrate 41. The first conductive layer 1 is transparent, and formed of ITO in this embodiment. As shown in FIG. 189 and FIG. 190, the first conductive layer 1 includes a first electrode section 11, a first end portion 14, a third extended portion 15, a fourth extended portion 16, a plurality of openings 18 and the slits 19, a third edge 101, a third outer edge 105, a first extended portion 104, and a second extended portion 103. In this embodiment, the first conductive layer 1 has a generally circular shape in plan view, which is, however, merely an example of the shape of the first conductive layer 1. The first conductive layer 1 may be formed in various shapes. The first conductive layer 1 has a thickness of, for example, 100 nm to 300 nm. In FIG. 190, the first electrode section 11, the first end portion 14, the third extended portion 15, and the fourth extended portion 16 are hatched with oblique lines.

The first electrode section 11 is a layer in which holes created by the photoelectric conversion layer 3 are collected, and acts as what is known as an anode electrode. In this embodiment, a major part of the first conductive layer 1 acts as one first electrode section 11.

The third extended portion 15 extends from the first electrode section 11 outwardly of the photoelectric conversion layer 3 in plan view. In FIG. 190, the boundary between the first electrode section 11 and the third extended portion 15 is indicated by an imaginary line (dash-dot-dot line). Through the third extended portion 15, the holes originating from the power generation by the photoelectric conversion layer 3 can be led to outside of the organic thin film solar cell module A19.

The first end portion 14 is isolated from the first electrode section 11 via the slit 19. In this embodiment, the first end portion 14 has, for example, a circular shape in plan view. In this embodiment, the first end portion 14 is composed of a generally circular portion and a rectangular portion.

The fourth extended portion 16 extends from the first end portion 14 outwardly of the photoelectric conversion layer 3 in plan view. In FIG. 190, the boundary between the first end portion 14 and the fourth extended portion 16 is indicated by an imaginary line (dash-dot-dot line). In this embodiment, the third extended portion 15 and the fourth extended portion 16 are located adjacent to each other. Through the fourth extended portion 16, the holes originating from the power generation by the photoelectric conversion layer 3 can be led to outside of the organic thin film solar cell module A19.

The openings 18 are formed so as to penetrate through the first conductive layer 1 in the thickness direction. In this embodiment, two openings 18 are provided. The opening 18 at an upper position in FIG. 190 is formed, for example, to allow the speaker 705 to perform its function. The larger opening 18 at the central position in FIG. 190 is for exhibiting the information displayed by the display unit 702, in the outer appearance.

The third edge 101 defines the opening 18 at the central position in FIG. 119. In this embodiment, the third edge 101 surrounds the opening 18 from four directions, in a rectangular ring shape in plan view. However, it is not mandatory that the third edge 101 surrounds the opening 18 from four directions. For example, the third edge 101 may define the opening 18 from three directions, such that the opening 18 is open to outside through the first electrode section 11, in plan view. Alternatively, the third edge 101 may be formed so as to define the opening 18 from one or two directions. In the region adjacent to the third edge 101, in other words the opening 18 at the central position in FIG. 190, the base substrate 41 is exposed. In addition, the third edge 101 corresponds to the inner edge of a portion of the first conductive layer 1 extending from the second edge 451 of the resin cover layer 45 and the first edge 421 of the passivation layer 42, to be described below.

The first extended portion 104 inwardly (toward the opening 18) extends from the passivation layer 42. In this embodiment, the second extended portion 103 is formed generally along the entire inner peripheral edge of the first conductive layer 1.

The second extended portion 103 outwardly extends from the passivation layer 42. In this embodiment, the second extended portion 103 is formed generally along the entire outer peripheral edge of the first conductive layer 1.

A major part of the second conductive layer 2 is disposed on the first conductive layer 1 via the photoelectric conversion layer 3. A part of the second conductive layer 2 is in direct contact with the first conductive layer 1. The material of the second conductive layer 2 is not specifically limited, and may be transparent or non-transparent. In this embodiment, the second conductive layer 2 is formed of a metal, typically A1, W, Mo, Mn, or Mg. In the following example, the second conductive layer 2 is formed of A1. Accordingly, the second conductive layer 2 is non-transparent. In this case, a non-illustrated passive film formed of Al₂O₃ may be formed on the surface of the second conductive layer 2 opposite to the base substrate 41. The second conductive layer 2 has a thickness of, for example, 30 nm to 150 nm.

As shown in FIG. 192, the second conductive layer 2 includes the second electrode section 21, the second end portion 24, and a plurality of openings 28. Although the second conductive layer 2 has a generally rectangular shape in plan view in this embodiment, this is merely an example of the shape of the second conductive layer 2. The second conductive layer 2 may be formed in various shapes. In FIG. 192, the second electrode section 21 and the second end portion 24 are hatched with oblique lines.

The second electrode section 21 is a layer in which electrons created by the photoelectric conversion layer 3 are collected, and acts as what is known as a cathode electrode. The second electrode section 21 coincides with the first electrode section 11 in plan view. In this embodiment, a major portion of the second conductive layer 2 acts as the second electrode section 21.

The second end portion 24 coincides with the first end portion 14 of the first conductive layer 1 in plan view, and extends from the second electrode section 21. In FIG. 192, the shape of the second end portion 24 is indicated by an imaginary line (dash-dot-dot line), to facilitate understanding. The second end portion 24 is, like the first end portion 14, composed of a generally circular portion and a rectangular portion.

The openings 28 are formed so as to penetrate through the second conductive layer 2 in the thickness direction. In this embodiment, two openings 28 are provided. The opening 28 at an upper position in FIG. 192 is formed, for example, to allow the speaker 705 to perform its function. The larger opening 28 at the central position in FIG. 192 is for exhibiting the information displayed by the display unit 702, in the outer appearance.

The fourth inner recessed edge 201 defines the opening 28 at the central position in FIG. 192. In this embodiment, the fourth inner recessed edge 201 surrounds the opening 28 from four directions, in a rectangular ring shape in plan view. However, it is not mandatory that the fourth inner recessed edge 201 surrounds the opening 28 from four directions. For example, the fourth inner recessed edge 201 may define the opening 28 from three directions, such that the opening 28 is open to outside through the second electrode section 21, in plan view. Alternatively, the fourth inner recessed edge 201 may be formed so as to define the opening 28 from one or two directions. As shown in FIG. 187, the fourth inner recessed edge 201 is inwardly recessed (opposite to the direction toward the inner space of the opening 18) with respect to the third edge 101.

The fourth outer recessed edge 202 is, as shown in FIG. 187, inwardly recessed (to the right in FIG. 187), with respect to the first outer edge 422 of the passivation layer 42 and the second outer edge 452 of the resin cover layer 45 to be described below, in plan view. In this embodiment, the fourth outer recessed edge 202 has an annular shape in plan view.

The photoelectric conversion layer 3 is interposed between the first conductive layer 1 and the second conductive layer 2, and disposed on the base substrate 41. The photoelectric conversion layer 3 is formed of an organic thin film, and configured to perform a photoelectric conversion function, to convert received light into electric power. Although the configuration of the photoelectric conversion layer 3 is not specifically limited, the photoelectric conversion layer 3 may include, for example, a bulk heterojunction organic active layer and a hole transport layer disposed on the bulk heterojunction organic active layer on the side of the first conductive layer 1. In this embodiment, the photoelectric conversion layer 3 is formed in a rectangular shape in plan view, however this is merely an example and the photoelectric conversion layer 3 may be formed in various shapes. The photoelectric conversion layer 3 has a thickness of, for example, 50 nm to 300 nm.

In the bulk heterojunction organic active layer, p-type organic active layer regions and n-type organic active layer regions are intermixed, forming a complicated bulk hetero pn junction. The p-type organic active layer region is, for example, formed of poly(3-hexylthiophene-2,5diyl) (P3HT), and the n-type organic active layer region is formed of 6,6-phenyl-C61-butyric acid methyl ester (PCBM), for example. The hole transport layer is formed of, for example, PEDOT:PSS.

Examples of materials that may be utilized to form the photoelectric conversion layer 3 include phthalocyanine (Pc), zinc-phthalocyanine (ZnPc), N,N′-dimethyl perylene-3,4,9,10-dicarboximide (Me-Ptcdi), and Buckminster fullerene (C60). These materials are, for example, utilized for vacuum vapor deposition.

In addition, poly[2-methoxy-5-(3,7-dimethyl octyloxy)]-1,4-phenylene vinylene (MDMO-PPV), poly[N-9′-hepta-decanyl-2,7-carbazole-alt-5,5-(4′,7′-di-thienyl-2′1′,3′-b3nzothiadizaole)] (PCDTBT), 6,6-phenyl-C61-butyric acid methyl ester (PC60BM), or 6,6-phenyl-C71-butyric acid methyl ester (PC70BM) may be utilized to form the photoelectric conversion layer 3. These materials are, for example, utilized for a solution process.

As shown in FIG. 191, the photoelectric conversion layer 3 includes the non-generation region 30, the generation region 31, the design display section 35, a plurality of openings 38, the fifth inner recessed edge 301, and the fifth outer recessed edge 302. In FIG. 191, the non-generation region 30 and the generation region 31 are shaded with scattered dots.

The design display section 35 constitutes a design exhibited in the outer appearance through the first conductive layer 1. The design constituted by the design display section include those that the user can visually recognize as visually singular feature, such as characters, marks, and patterns. In this embodiment, the design display section 35 represents an annular shape.

In this embodiment, the design display section 35 is constituted of the perforated portion 350. The perforated portion 350 is formed so as to penetrate through the photoelectric conversion layer 3 in the thickness direction. The perforated portion 350 is visible in the outer appearance through the first conductive layer 1. In this embodiment, the perforated portion 350 exposes the second conductive layer 2 on the side of the first conductive layer 1. In other words, a part of the second conductive layer 2 is visible in the outer appearance, through the perforated portion 350.

The generation region 31 is interposed between the first electrode section 11 of the first conductive layer 1 and the second electrode section 21 of the second conductive layer 2, and performs the photoelectric conversion function to contribute to the power generation. The shape of the generation region 31 coincides with the first electrode section 11 and the second electrode section 21, in plan view.

The non-generation region 30 corresponds to a portion of the photoelectric conversion layer 3 deviated, in plan view, from the first electrode section 11 of the first conductive layer 1 and the second electrode section 21 of the second conductive layer 2, and overlapping with the first end portion 14 of the first conductive layer 1. The first end portion 14 is in contact with the second end portion 24 of the second conductive layer 2, and hence the collected holes and electrons are instantly coupled. Therefore, the non-generation region 30 is not involved in the power generation. Thus, the region of the photoelectric conversion layer 3 other than the generation regions 31 corresponds to the non-generation region 30.

In this embodiment, the non-generation region 30 is located in the terminal region 34. The terminal region 34 includes the perforated portion 350 (design display section 35). The terminal region 34 includes the perforated portion 350 (design display section 35) enclosed in the first end portion 14 of the first conductive layer 1 in plan view, and overlaps with the first end portion 14 of the first conductive layer 1 in plan view. In addition, the terminal region 34 overlaps with the second end portion 24 of the second conductive layer 2. The first end portion 14 of the first conductive layer 1 and the second end portion 24 of the second conductive layer 2 are in contact with each other, via the perforated portion 350 in the terminal region 34.

The openings 38 are formed so as to penetrate through the photoelectric conversion layer 3 in the thickness direction. In this embodiment, two openings 38 are provided. The opening 38 at an upper position in FIG. 191 is formed, for example, to allow the speaker 705 to perform its function. The larger opening 38 at the central position in FIG. 191 is for exhibiting the information displayed by the display unit 702, in the outer appearance.

The fifth inner recessed edge 301 defines the opening 38 at the central position in FIG. 191. In this embodiment, the fifth inner recessed edge 301 surrounds the opening 38 from four directions, in a rectangular ring shape in plan view. However, it is not mandatory that the fifth inner recessed edge 301 surrounds the opening 38 from four directions. For example, the fifth inner recessed edge 301 may define the opening 38 from three directions, such that the opening 38 is open to outside through the generation region 31, in plan view. Alternatively, the fifth inner recessed edge 301 may be formed so as to define the opening 38 from one or two directions. In addition, as shown in FIG. 187, the fifth inner recessed edge 301 is inwardly recessed (opposite to the direction toward the inner space of the opening 18) with respect to the third edge 101.

The fifth outer recessed edge 302 is, as shown in FIG. 187, inwardly recessed (to the right in FIG. 187), with respect to the first outer edge 422 of the passivation layer 42 and the second outer edge 452 of the resin cover layer 45 to be described below, in plan view. In this embodiment, the fifth outer recessed edge 302 has an annular shape in plan view.

With the configuration described above, in the organic thin film solar cell module A19 the third extended portion 15 extends from the first electrode section 11. The second electrode section 21 extends from the second end portion 24. The second end portion 24 is in contact with the first end portion 14 via the perforated portion 350 in the terminal region 34. The fourth extended portion 16 extends from the first end portion 14. As result, the third extended portion 15 and the fourth extended portion 16 each act as an output terminal of the organic thin film solar cell module A19.

The passivation layer 42 is disposed on the second conductive layer 2, so as to protect the second conductive layer 2 and the photoelectric conversion layer 3. The passivation layer 42 is, for example, formed of SiN or SiON. The passivation layer 42 has a thickness of, for example, 0.5 μm to 2.0 μm and, in this embodiment, approximately 1.5 μm.

The resin cover layer 4 covers the passivation layer 42. The resin cover layer 4 also covers the passivation layer 42. The resin cover layer 4 is formed of, for example, a UV-curable resin. The resin cover layer 4 has a thickness of, for example, 3 μm to 20 μm and, in this embodiment, approximately 10 μm.

In this embodiment, the resin cover layer 4 includes the first resin cover layer 45 and the second resin cover layer 46. The first resin cover layer 45 covers the passivation layer 42. The second resin cover layer 46 is disposed on the first resin cover layer 45, so as to cover the bypass conductive section 5.

As shown in FIG. 193, the first resin cover layer 45 includes a plurality of openings 458, the second edge 451, and the second outer edge 452. In FIG. 193, the first resin cover layer 45 is hatched with oblique lines.

The openings 458 are each formed by removing a part of the first resin cover layer 45, so as to penetrate therethrough. The three openings 458 at an upper position in FIG. 193 are formed, for example, to allow the speaker 705 to perform its function. The larger opening 458 at the central position in FIG. 193 is for exhibiting the information displayed by the display unit 702, in the outer appearance.

The second edge 451 defines the opening 458 at the central position in FIG. 193. In this embodiment, the second edge 451 surrounds the opening 458 from four directions, in a rectangular ring shape in plan view. However, it is not mandatory that the second edge 451 surrounds the opening 458 from four directions. For example, the second edge 451 may define the opening 458 from three directions, such that the opening 458 is open to outside through the first resin cover layer 45, in plan view. Alternatively, the second edge 451 may be formed so as to define the opening 458 from one or two directions.

The second outer edge 452 is located on the side opposite to the second edge 451, across at least a part of the photoelectric conversion layer 3 in plan view, and corresponds, in this embodiment, to the outer peripheral edge of the first resin cover layer 45.

As shown in FIG. 194, the second resin cover layer 46 includes a plurality of openings 468, the sixth edge 461, and the sixth outer edge 462.

The openings 468 are each formed by removing a part of the second resin cover layer 46, so as to penetrate therethrough. The three openings 468 at an upper position in FIG. 194 are formed, for example, to allow the speaker 705 to perform its function. The larger opening 468 at the central position in FIG. 194 is for exhibiting the information displayed by the display unit 702, in the outer appearance.

The sixth edge 461 defines the opening 458 at the central position in FIG. 194. In this embodiment, the sixth edge 461 surrounds the opening 468 from four directions, in a rectangular ring shape in plan view. However, it is not mandatory that the sixth edge 461 surrounds the opening 468 from four directions. For example, the sixth edge 461 may define the opening 468 from three directions, such that the opening 468 is open to outside through the second resin cover layer 46, in plan view. Alternatively, the sixth edge 461 may be formed so as to define the opening 468 from one or two directions. Further, the opening 468 may have a different plan-view shape, such as a circular shape.

The sixth outer edge 462 is located on the side opposite to the sixth edge 461, across at least a part of the photoelectric conversion layer 3 in plan view, and corresponds, in this embodiment, to the outer peripheral edge of the second resin cover layer 46.

The passivation layer 42 includes the first edge 421 and the first outer edge 422.

The first edge 421 coincides with the second edge 451 in plan view. In this embodiment, the first edge 421 forms a continuous surface with the second edge 451. The first outer edge 422 coincides with the second outer edge 452 in plan view. In this embodiment, the first outer edge 422 forms a continuous surface with the second outer edge 452.

The bypass conductive section 5 provides a route having a lower resistance than the first conductive layer 1, for collecting the holes that have reached the first conductive layer 1. In this embodiment, the bypass conductive section 5 includes two bus-bar sections 51, a plurality of communication portions 52, and two collector electrodes 53. The bypass conductive section 5 is formed of a material lower in resistance than the first conductive layer 1, and includes, for example, Ag or carbon.

As shown in FIG. 187 and FIG. 193, one of the bus-bar sections 51 covers the second edge 451 and the first edge 421 over the entire length. The bus-bar section 51 covers a portion of the first conductive layer 1 located between the third edge 101 and the first edge 421 (second edge 451). A seventh edge 511 of the bus-bar section 51 coincides with the third edge 101 in plan view. The other bus-bar section 51 covers the second outer edge 452 and the first outer edge 422 over the entire length. This bus-bar section 51 covers the second extended portion 103 of the first conductive layer 1. A seventh outer edge 512 of the bus-bar section 51 coincides with the third outer edge 105 in plan view. Thus, each of the two bus-bar sections 51 is electrically connected to the first conductive layer 1.

The communication portions 52 are formed on the first resin cover layer 45, and connects the bus-bar section 51 on the inner side in FIG. 193 and the communication portion 52 on the outer side in FIG. 193. One of the two collector electrodes 53 is electrically connected to the first conductive layer, and the other is electrically connected to the second conductive layer 2.

As shown in FIG. 187, a part of the base substrate 41 is exposed from a region adjacent to the second edge 451 and the first edge 421, via the bus-bar section 51 and the second resin cover layer 46 therebetween, thus to form the exposed region 411. The exposed region 411 is not covered with the first conductive layer 1 or other elements, and the surface of the base substrate 41 is directly exposed.

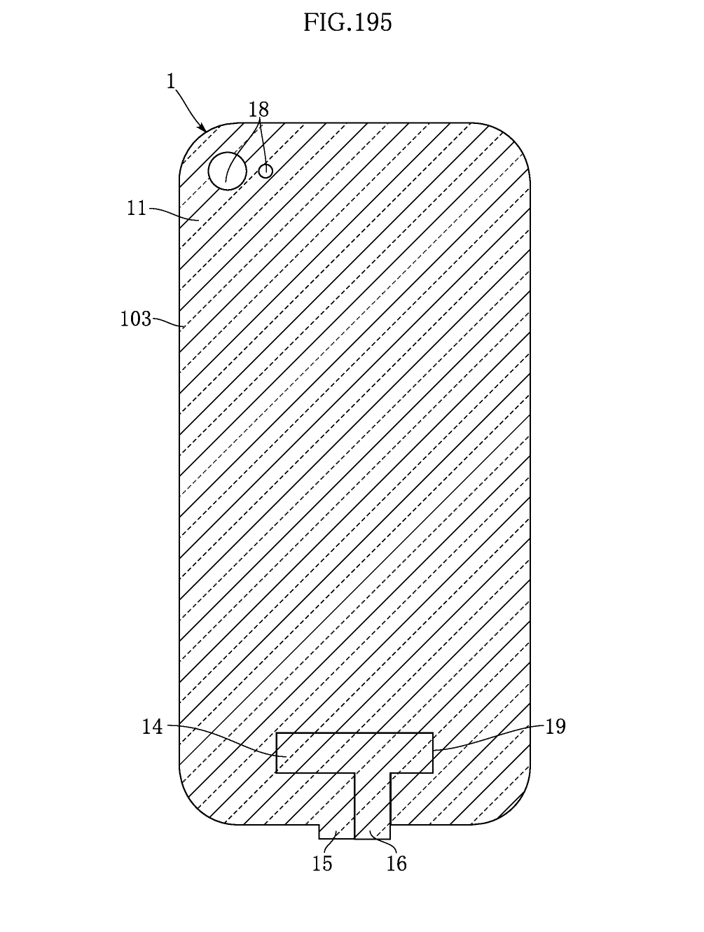

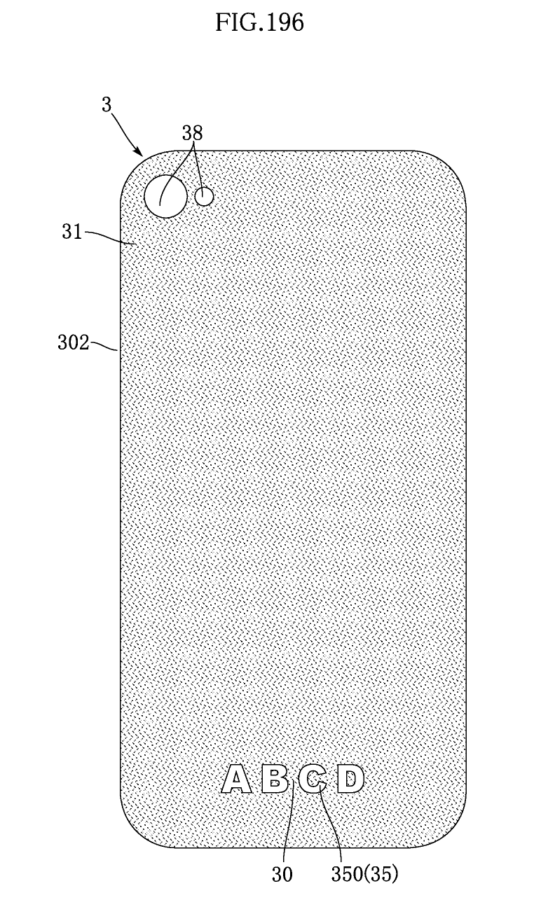

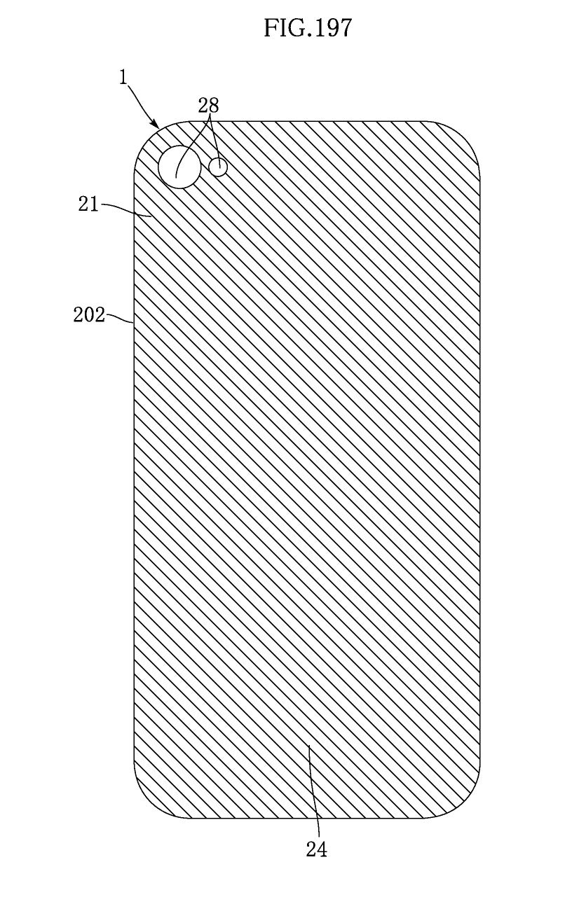

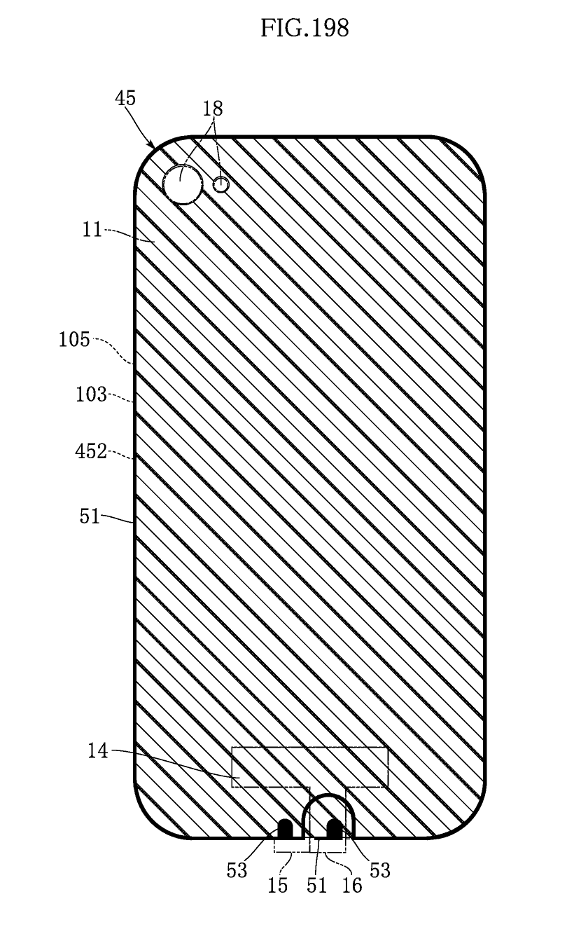

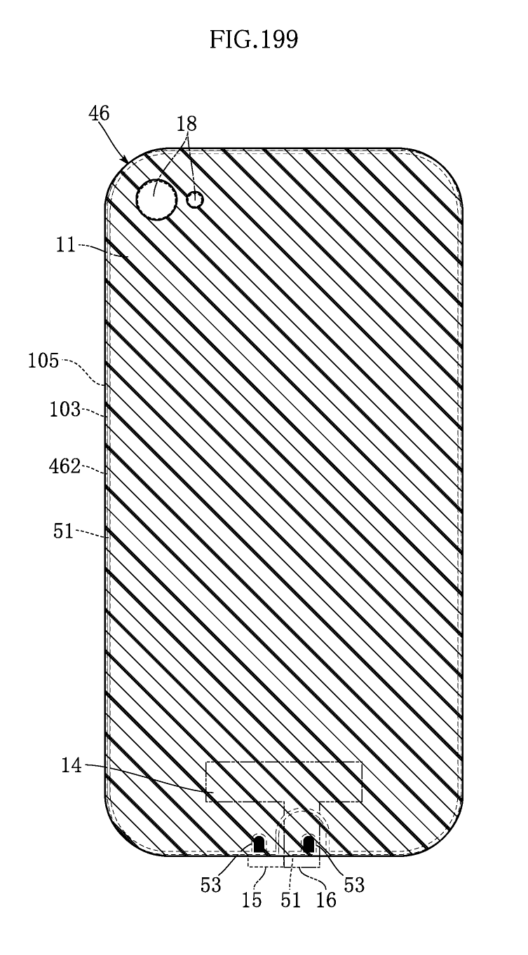

FIG. 195 is a plan view showing the first conductive layer 1 of the organic thin film solar cell module A20. FIG. 196 is a plan view showing the photoelectric conversion layer 3 of the organic thin film solar cell module A20. FIG. 197 is a plan view showing the second conductive layer 2 of the organic thin film solar cell module A20. FIG. 198 is a plan view showing the first resin cover layer 45 and the bypass conductive section 5 of the organic thin film solar cell module A20. FIG. 199 is a plan view showing the second resin cover layer 46 of the organic thin film solar cell module A20.

The organic thin film solar cell module A20 is without the opening 18, the opening 28, the opening 38, the opening 458, and the opening 468 for exhibiting the display unit 702 in the outer appearance. Accordingly, the third edge 101, the fourth inner recessed edge 201, the fifth inner recessed edge 301, the first edge 421, the second edge 451, and the sixth edge 461 are not provided. The bypass conductive section 5 includes the bus-bar sections 51 formed along the outer periphery, and is without the communication portion 52.

In this embodiment, as shown in FIG. 196, the photoelectric conversion layer 3 includes a plurality of perforated portions 350 (35). The perforated portions 350 each represent an alphabet. The first end portion 14 of the first conductive layer 1 and the second end portion 24 of the second conductive layer 2 are in contact with each other via the perforated portions 350, as in the organic thin film solar cell module A19.

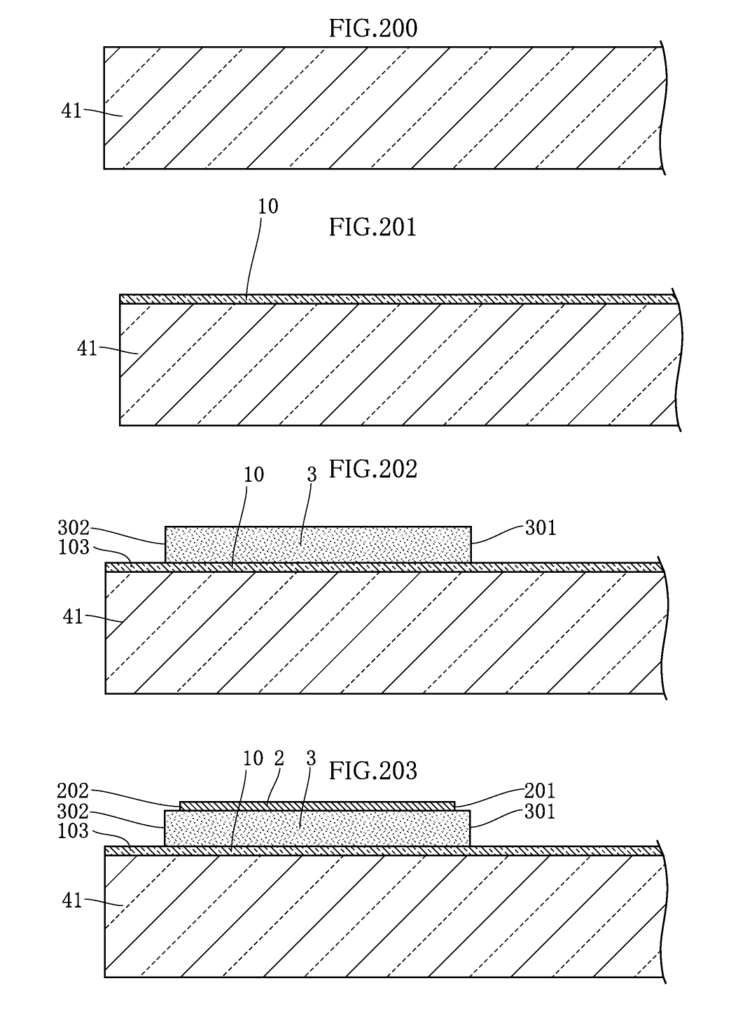

Referring now to FIG. 200 to FIG. 207, a manufacturing method of the organic thin film solar cell module A19 will be described hereunder. The cited drawings are turned upside down from FIG. 187, to facilitate understanding. In addition, FIG. 200 to FIG. 207 illustrate the formation process of the portion corresponding to the cross-section of the electronic device B19, taken along the line CLXXXVII-CLXXXVII in FIG. 184.

Referring first to FIG. 200, the base substrate 41 is prepared. On one of the surfaces of the base substrate 41, the first conductive layer 1 formed of ITO is deposited by a known method such as sputtering, as shown in FIG. 201. Then the ITO is patterned to form the patterns of the openings 18 and the slits 19. For the patterning of the ITO, for example, wet etching, or laser patterning using a green laser is adopted as the case may be.

Proceeding to FIG. 202, the photoelectric conversion layer 3 is formed. To form the photoelectric conversion layer 3, an organic film is deposited on the base substrate 41 and the first conductive layer 1 for example by spin coating, and the organic film is patterned to form the fifth inner recessed edge 301, the fifth outer recessed edge 302, the openings 38, and the perforated portion 350 (design display section 35), by oxygen plasma etching or laser patterning. Without limitation to the above, the photoelectric conversion layer 3 may be formed by directly patterning the organic film on the base substrate 41 and the first conductive film 10, for example by slit coating, capillary coating, or gravure printing.

Proceeding to FIG. 203, the second conductive layer 2 is formed. To form the second conductive layer 2, for example, one of the aforementioned metals is deposited by vacuum vapor deposition on the base substrate 41, the first conductive film 10, and the photoelectric conversion layer 3, to deposit a metal film thereon. Then the metal film is patterned, for example by etching with a mask layer. Through such patterning, the second conductive layer 2 including the fourth inner recessed edge 201 and the fourth outer recessed edge 202 is formed on the photoelectric conversion layer 3.

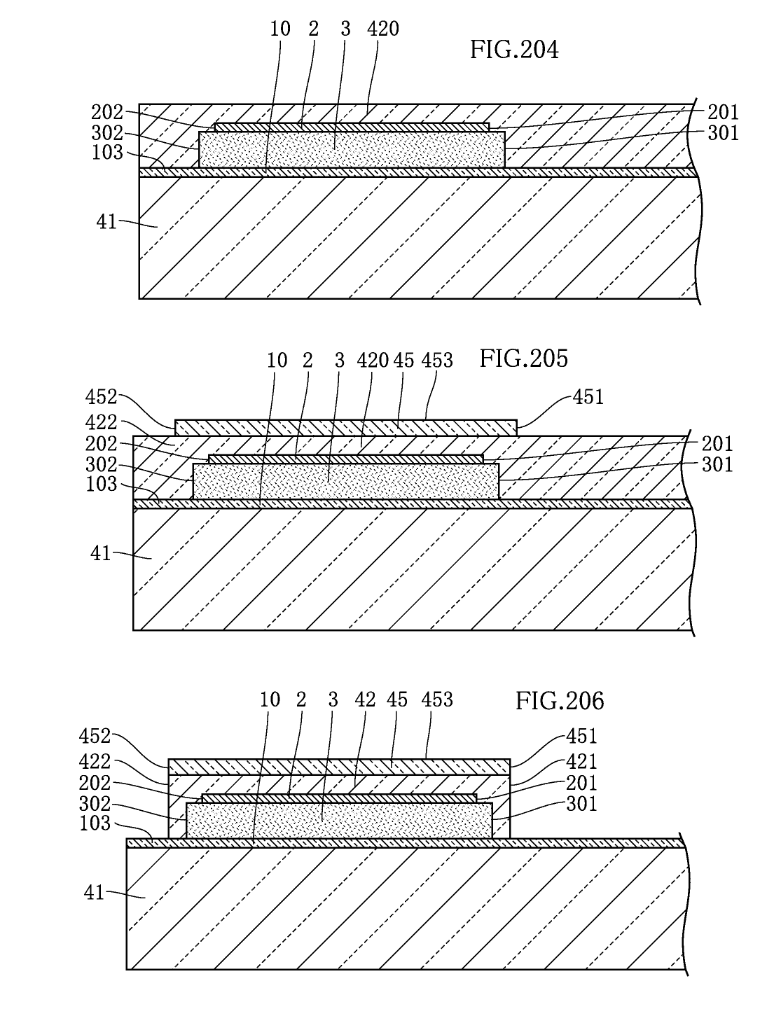

Proceeding to FIG. 204, the insulation film 420 is formed. To form the insulation film 420, SiN or SiON is deposited on the base substrate 41, the first conductive layer 1, the photoelectric conversion layer 3, and the second conductive layer 2, for example by plasma CVD.

Proceeding to FIG. 205, the first resin cover layer 45 is formed. To form the first resin cover layer 45, for example, a liquid resin material containing a UV-curable resin is applied to the insulation film 420 by screen printing, and the resin is irradiated with UV light thus to be cured. Thus, the first resin cover layer 45 including the second edge 451 and the second outer edge 452 is obtained.

Proceeding to FIG. 206, the insulation film 420 is patterned, using the first resin cover layer 45 as a mask. This patterning is performed through a wet etching process using hydrofluoric acid containing 0.55% to 4.5% of hydrogen fluoride. Such hydrofluoric acid barely dissolves the first resin cover layer 45 formed of a UV-curable resin, but selectively dissolves the insulation film 420 formed of SiN or SiON. In addition, the hydrofluoric acid barely dissolves the first conductive film 10 formed of ITO. As result, the passivation layer 42 including the first edge 421 and the first outer edge 422 is formed. The first edge 421 coincides with the second edge 451 in plan view. The first edge 421 and the second edge 451 form a continuous surface. Likewise, the first outer edge 422 coincides with the second outer edge 452 in plan view. The first outer edge 422 and the second outer edge 452 form a continuous surface.

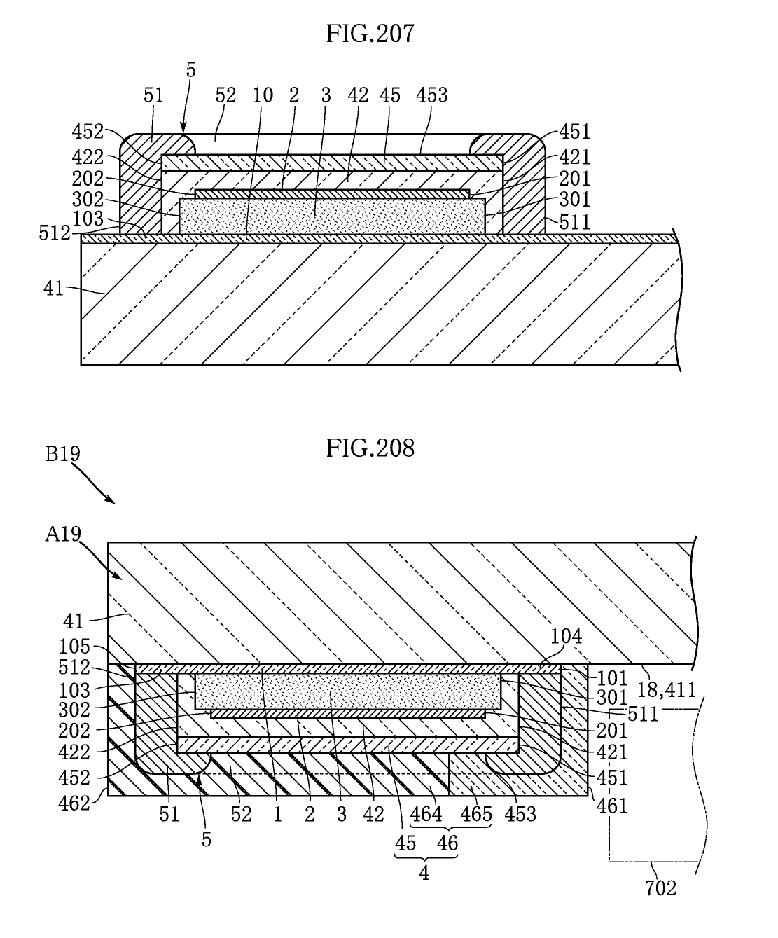

Proceeding to FIG. 207, the bypass conductive section 5 is formed. To form the bypass conductive section 5, for example, a paste containing Ag or carbon is applied, and then dried to harden the paste.

Then the first conductive film 10 is patterned. The patterning is performed, for example, with aqua regia in which concentrated hydrochloric acid and concentrated nitric acid are mixed in a ratio of 3 to 1. By such patterning, portions of the first conductive film 10 exposed from the bypass conductive section 5 and the resin cover layer 45 are selectively removed. As result, the first conductive layer 1 including the third edge 101 and so forth is formed. Then the second resin cover layer 46 is formed. To form the second resin cover layer 46, for example, a liquid resin material containing a UV-curable resin is applied to the insulation film 420 by screen printing, and the resin is irradiated with UV light thus to be cured. Thus, the second resin cover layer 46 including the sixth edge 461 and the sixth outer edge 462 is formed, and the resin cover layer 4 is obtained. Through the mentioned process, the organic thin film solar cell module A19 can be obtained. The organic thin film solar cell module A20 can also be obtained through the same process.

The organic thin film solar cell module A19 and the electronic device B19 provide the following advantageous effects.

According to this embodiment, providing the bypass conductive section 5 allows the holes diffused to the first conductive layer 1 to be led to the collector electrode 53, through the bus-bar section 51. The bypass conductive section 5 is formed of a material lower in resistance than a material of the first conductive layer 1. Accordingly, the bypass conductive section 5 provides a conduction path that has lower resistance. Introducing the power generated by the photoelectric conversion layer 3 to such a conduction path suppresses a conduction loss. In addition, the bypass conductive section 5 is covered with the resin cover layer 4. Therefore, the resin cover layer 4 can be prevented from being degraded through reaction with, for example, ambient air. Consequently, both the degradation of the conduction path and the conduction loss can be prevented, in the organic thin film solar cell modules A19 and A20, and the electronic device B19.

As shown in FIG. 187, the seventh edge 511 and the seventh outer edge 512 are located on the inner side of the sixth edge 461 and the sixth outer edge 462. In other words, the bypass conductive section 5 is completely covered with the resin cover layer 4. Therefore, the bypass conductive section 5 can be securely protected.

The base substrate 41 is exposed in the regions adjacent to the second edge 451 and the second outer edge 452. In such regions, the passivation layer 42 and the first resin cover layer 45 are not formed. Therefore, the mentioned regions can be finished with higher transparency, so that the display unit 702 can be more clearly exhibited in the outer appearance.

The first conductive layer 1 is not formed on the base substrate 41, except for a small region covered with the bus-bar section 51, in the region adjacent to the second edge 451 and the first edge 421. Although the first conductive layer 1 is formed of ITO, the first conductive layer 1 may be visually recognized as a faintly colored portion, depending on the condition of ambient light. The configuration according to this embodiment enables the region for exhibiting the display unit 702 in the outer appearance to be finished with prominent transparency, thereby realizing a more exquisite outer appearance.

The fifth inner recessed edge 301 of the photoelectric conversion layer 3 and the fourth inner recessed edge 201 of the second conductive layer 2 are spaced apart from the first edge 421 and the second edge 451. Accordingly, the second conductive layer 2 and the photoelectric conversion layer 3 can be prevented from being electrically connected improperly, to the bypass conductive section 5. In addition, the passivation layer 42 is interposed between the fourth inner recessed edge 201 and the fifth inner recessed edge 301, and between the first edge 421 and the second edge 451. Therefore, a short circuit between the second conductive layer 2 or photoelectric conversion layer 3 and the bus-bar section 51 of the bypass conductive section 5.

By the patterning of the insulation film 420 using the first resin cover layer 45 as the mask, the passivation layer 42 can be formed in the same shape as the resin cover layer 45. In other words, forming the first resin cover layer 45 from a material having high shape formability, such as the UV-curable resin, enables the passivation layer 42 to be formed in a desired shape, despite the material thereof having lower shape formability. The first resin cover layer 45 may be removed after the passivation layer 42 is formed. However, keeping the first resin cover layer 45 unremoved prevents intrusion of moisture and particles into the first conductive layer 1, the second conductive layer 2, and the photoelectric conversion layer 3, and contributes to improving the strength of the organic thin film solar cell module A19.

Since the first conductive layer 1 is patterned after the bypass conductive section 5 is formed, the communication portion 52 of the bypass conductive section 5 enters into contact with a portion of the first conductive layer 1 having a significant area in plan view (for example, second extended portion 103), instead of the end face of the first conductive layer 1. Such a configuration reduces contact resistance between the first conductive layer 1 and bypass conductive section 5, thereby assuring the electrical conduction therebetween.

FIG. 208 to FIG. 219 illustrate a variation and other embodiments of the present invention. In these drawings, the elements same as or similar to those of the foregoing embodiments are given the same numeral as above, and the description will not be repeated.

FIG. 208 illustrates a variation of the electronic device B19 and organic thin film solar cell module A19. In this variation, the second resin cover layer 46 includes a non-translucent portion 464 and a translucent portion 465. The non-translucent portion 464 overlaps with the bypass conductive section 5 in plan view, and is located on the outer side with respect to the first edge 421. The non-translucent portion 464 is formed of a non-translucent material, for example a white resin. The translucent portion 465 is located in a region including a region located opposite to the first outer edge 422 with respect to the non-translucent portion 464. In the example shown in FIG. 145, the translucent portion 465 is formed so as to span over the bus-bar section 51 on the right in the drawing. In addition, a part of the translucent portion 465 is in contact with the base substrate 41. The configuration according to this variation can also protect the bypass conductive section 5. Further, the presence of the non-translucent portion 464 prevents degradation of the bypass conductive section 5 due to exposure to light, such as UV light.

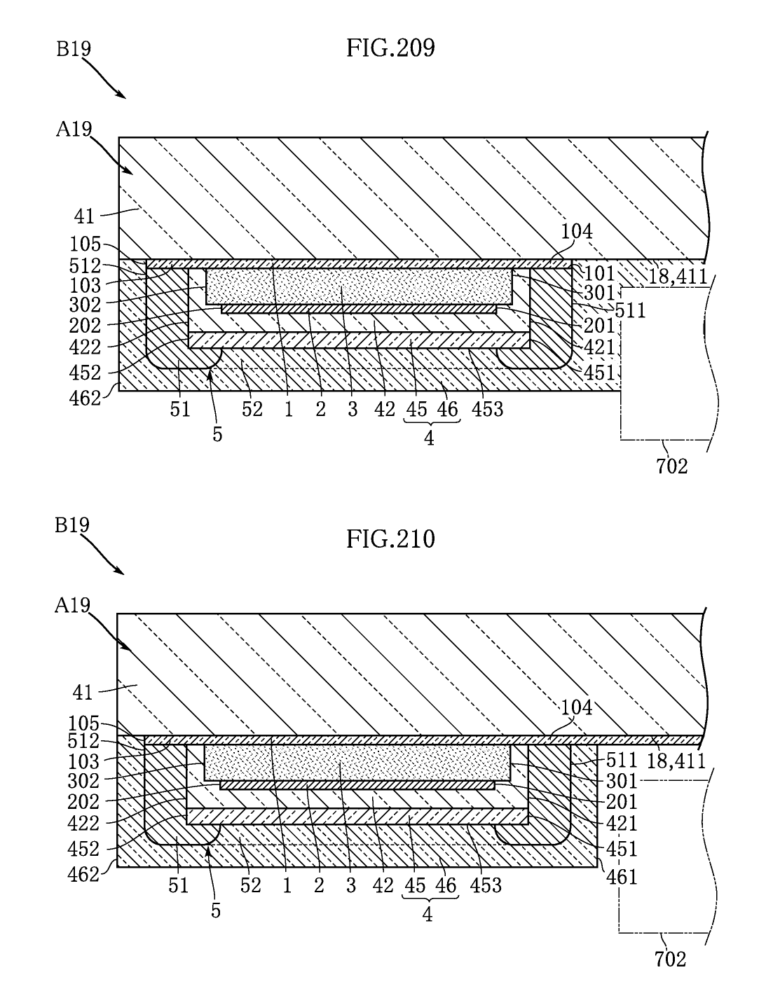

FIG. 209 illustrates another variation of the electronic device B19 and the organic thin film solar cell module A19. In this variation, the second resin cover layer 46 of the resin cover layer 4 also serves as a bonding layer for bonding the organic thin film solar cell module A19 and the display unit 702 together. In this case, the second resin cover layer 46 is formed of a transparent material.

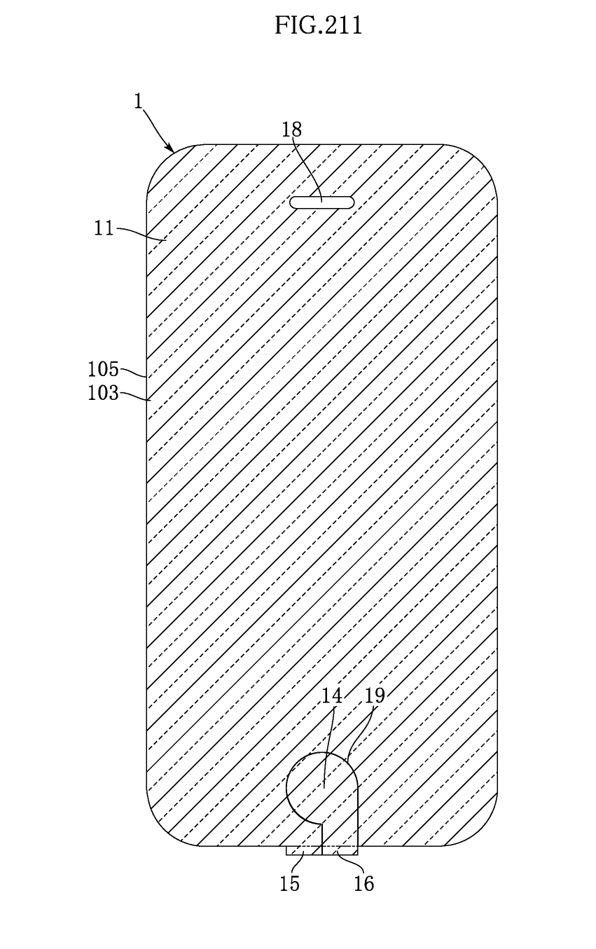

FIG. 210 illustrates still another variation of the electronic device B19 and the organic thin film solar cell module A19. FIG. 211 is a plan view showing the first conductive layer 1 according to this variation. In this variation, the first conductive layer 1 is without the opening 18 defined by the third edge 101 and the third edge 101. In other words, in this variation the first conductive layer 1 overlaps with the display unit 702, in plan view.

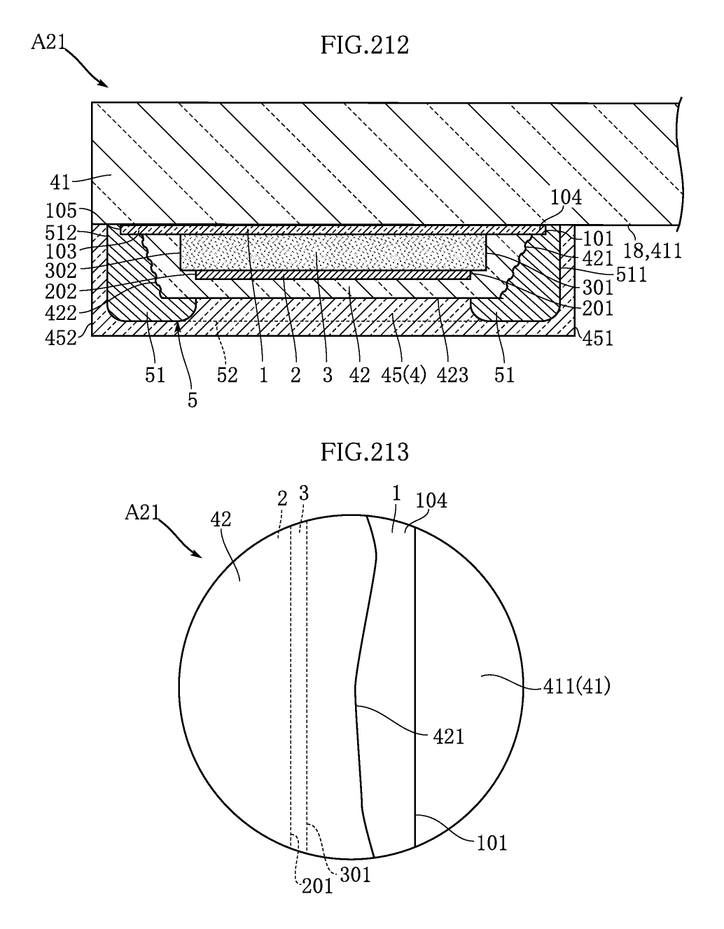

FIG. 212 and FIG. 213 illustrate an organic thin film solar cell module according to the twenty-first embodiment the present invention. The organic thin film solar cell module A21 according to this embodiment includes the first conductive layer 1, the second conductive layer 2, the photoelectric conversion layer 3, the base substrate 41, the passivation layer 42, the resin cover layer 4, and the bypass conductive section 5. The plan-view shape of the organic thin film solar cell module A21 is not specifically limited, and FIG. 212 and FIG. 213 represent the case where the organic thin film solar cell module A21 has the same plan-view shape as the organic thin film solar cell module A19, as an example. FIG. 212 is an enlarged partial cross-sectional view of the organic thin film solar cell module A21, corresponding to the view of FIG. 187. FIG. 213 is an enlarged partial plan view in which the first resin cover layer 45 and the bypass conductive section 5 are omitted.

In this embodiment, the first edge 421 and the first outer edge 422 of the passivation layer 42 are, as shown in FIG. 212, formed in an uneven shape. In addition, the first edge 421 is, as a whole, inclined so as to be farther from the extended portion 103 of the first conductive layer 1 in plan view, at a position farther from the base substrate 41 in the thickness direction thereof. Likewise, the first outer edge 422 is inclined so as to be farther from the third edge 101 in plan view, at a position farther from the base substrate 41 in the thickness direction thereof. Further, the first edge 421 according to this embodiment has, as shown in FIG. 213, a non-linear shape spaced apart from the third edge 101, in plan view. The first edge 421 has a shape in which, for example, a plurality of bent lines and curved lines are connected. The first outer edge 422 also has a non-linear shape in plan view.

One of the bus-bar sections 51 covers the first edge 421 of the passivation layer 42, over the entire length. The bus-bar section 51 covers the first extended portion 104 of the first conductive layer 1 located between the third edge 101 and the first edge 421. The seventh edge 511 of the bus-bar section 51 is located opposite to the first edge 421 across the third edge 101, in plan view. Accordingly, the bus-bar section 51 is in direct contact with the base substrate 41. The other bus-bar section 51 covers the first outer edge 422 of the passivation layer 42, over the entire length. This bus-bar section 51 covers the second extended portion 103 of the first conductive layer 1. The seventh outer edge 512 of this bus-bar section 51 is located opposite to the first outer edge 422 across the third outer edge 105, in plan view. Accordingly, this bus-bar section 51 is in direct contact with the base substrate 41. Thus, each of the two bus-bar sections 51 is electrically connected to the first conductive layer 1.

The communication portion 52 is formed on the surface 423 of the passivation layer 42. The communication portion 52 connects, for example, the two bus-bar sections 51 to each other, or a portion of the bypass conductive section 5 other than the bus-bar section 51 and the communication portion 52, to the bus-bar section 51.

The resin cover layer 4 according to this embodiment only includes the first resin cover layer 45. As shown in FIG. 212, the first resin cover layer 45 covers the passivation layer 42 and the bypass conductive section 5, and is formed of, for example, a UV-curable resin. The first resin cover layer 45 may also serve as a transparent bonding layer for bonding the organic thin film solar cell module A21 and the display unit 702 together. In the illustrated example, the second the edge 451 of the second edge 451 is located opposite to the first edge 421 with respect to the seventh edge 511, in plan view. The second outer edge 452 of the first resin cover layer 45 is located opposite to the first outer edge 422 with respect to the seventh outer edge 512, in plan view. Accordingly, the first resin cover layer 45 includes a portion in direct contact with the base substrate 41. In addition, the first resin cover layer 45 covers the portion of the surface 423 of the passivation layer 42 exposed from the bus-bar section 51.

Hereunder, a manufacturing method of the organic thin film solar cell module A21 will be described. The drawings referred to for the description are turned upside down from FIG. 212, to facilitate understanding.

First, the base substrate 41 shown in FIG. 200 is prepared. On one of the surfaces of the base substrate 41, the first conductive film 10 formed of ITO is deposited by a known method such as sputtering. Then the photoelectric conversion layer 3 is formed as shown in FIG. 202, and the second conductive layer 2 is formed as shown in FIG. 203.

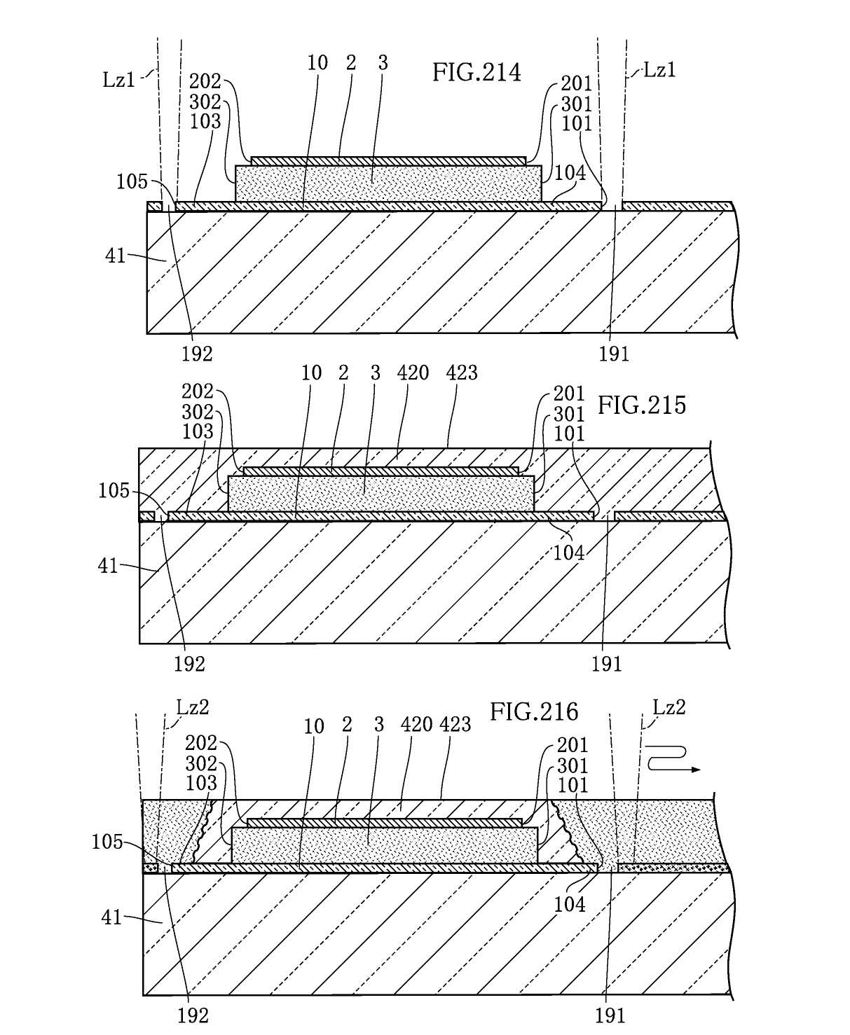

Proceeding to FIG. 214, the first conductive film 10 is patterned by laser patterning utilizing the laser beam Lz1, to form the slit 191 and the slit 192. In this case, the type of the laser beam Lz1 is not specifically limited provided that the laser is capable of patterning the first conductive film 10 and, for example, the IR laser beam may be employed. One of the edges of the first conductive film 10 defining the slit 191, on the side of the second conductive layer 2 and the photoelectric conversion layer 3 shown in FIG. 214, corresponds to the third edge 101. The portion of the first conductive film 10 between the fifth inner recessed edge 301 and the slit 191 corresponds to the first extended portion 104. One of the edges of the first conductive film 10 defining the slit 192, on the side of the second conductive layer 2 and the photoelectric conversion layer 3 shown in FIG. 214 corresponds to the third outer edge 105. The portion of the first conductive film 10 between the slit 192 and the fifth outer recessed edge 302 of the photoelectric conversion layer 3 corresponds to the second extended portion 103.

The patterning for forming the slit 191 and the slit 192 in the first conductive film 10 may be performed before the formation of the photoelectric conversion layer 3. For this patterning, for example, wet etching or oxygen plasma etching may be adopted, as the case may be. Without limitation to the above, the first conductive film 10 may be formed by directly patterning the ITO on the base substrate 41, for example through a nanoimprint lithography process.

Proceeding to FIG. 215, the insulation film 420 is formed. To form the insulation film 420, a film of SiN or SiON is deposited on the base substrate 41, the first conductive film 10, the photoelectric conversion layer 3, and the second conductive layer 2, for example by plasma CVD.

Then the base substrate 41 is exposed in a region adjacent to the first edge 421, by partially removing the insulation film 420 thereby forming the passivation layer 42 having the first edge 421, and partially removing the first conductive film 10 thereby forming the first conductive layer 1. In this embodiment, the exposing of the includes, as shown in FIG. 216, irradiating the first conductive film 10 with the laser beam Lz2 through the insulation film 420, thereby partially removing the first conductive film 10 and the insulation film 420. In FIG. 216, a portion of the first conductive film 10 shaded with scattered dots that are relatively larger is the area irradiated with the laser beam Lz2. A portion of the insulation film 420 shaded with scattered dots that are relatively smaller is the portion removed owing to the irradiation of the laser beam Lz2. Here, for example an etching process may be adopted, without limitation of the irradiation of the laser beam Lz2.

More specifically, the portions of the first conductive film 10 opposite to the second conductive layer 2 and the photoelectric conversion layer 3 shown in FIG. 216, across the slit 191 and the slit 192 respectively, are irradiated with the laser beam Lz2 through the insulation film 420. For example, the IR laser beam having a wavelength of approximately 1,064 nm may be adopted as the laser beam Lz2. The portion of the first conductive film 10 irradiated with the laser beam Lz2 instantly volatilizes, upon being exposed to a significant amount of energy.

The laser beam Lz2 having the mentioned wavelength is barely absorbed by the insulation film 420, unlike the case of the first conductive film 10. Accordingly, the insulation film 420 is not directly destroyed by the laser beam Lz2. However, a portion of the insulation film 420 in contact with the first conductive film 10 is supported by the base substrate 41, via the first conductive film 10. When the first conductive film 10 volatilizes owing to the irradiation of the laser beam Lz2, the portion of the insulation film 420 is no longer supported by the base substrate 41. In addition, a portion of the insulation film 420, superposed on the portion of the first conductive film 10 irradiated with the laser beam Lz2 (portion shaded with the scattered dots that are relatively larger in FIG. 216), partially splashes owing to the volatilization pressure of the first conductive film 10.

Further, through investigations carried out by the present inventor, it has proved that a portion of the insulation film 420 adjacent to the portion of the first conductive film 10 irradiated with the laser beam Lz2 also splashes owing to the volatilization pressure of the first conductive film 10. In FIG. 216, the portion of the insulation film 420 that splashes as result of the irradiation of the laser beam Lz2 is shaded with scattered dots that are relatively smaller. In this embodiment, the portion of the insulation film 420 that splashes is located on the side of the second conductive layer 2 and the photoelectric conversion layer 3, beyond the slit 191 and the slit 192. However, the size and position of the slit 191 and the slit 192, as well as the irradiation range and output of the laser beam Lz2 are properly adjusted, so as to prevent the passivation layer 42 from being destroyed to such an extent that a part of the second conductive layer 2 and the photoelectric conversion layer 3 is exposed. Accordingly, the edge of the insulation film 420 on the side of the slit 191 constitutes the first edge 421, and the edge on the side of the slit 192 constitutes the first outer edge 422. The portion of the first conductive film 10 adjacent to the slit 191, shaded with the scattered dots, is removed by the irradiation of the laser beam Lz2. Therefore, the edge of the first conductive film 10 on the side of the photoelectric conversion layer 3 with respect to the slit 191 in plan view constitutes the third edge 101, and the edge of the first conductive film 10 on the side of the photoelectric conversion layer 3 with respect to the slit 192 in plan view constitutes the third outer edge 105. Likewise, the portion of the first conductive film 10 adjacent to the slit 192, shaded with the scattered dots, is also removed by the irradiation of the laser beam Lz2. In addition, a portion of the first conductive film 10 adjacent to the slit 191 and the slit 192 is exposed from the passivation layer 420, since the portion of the insulation film 420 adjacent to the slit 191 and the slit 192 partially splashes owing to the irradiation of the laser beam Lz2. The exposed portion constitutes the first extended portion 104 and the second extended portion 103.

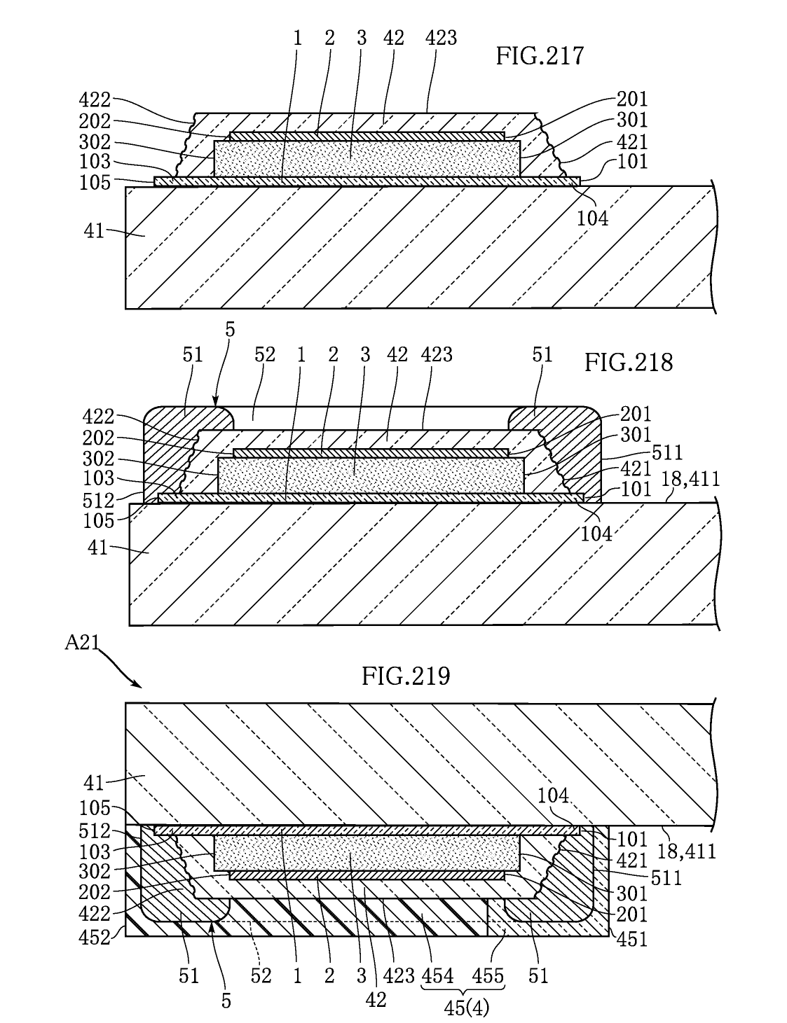

Upon partially removing as above the first conductive film 10 and the insulation film 420 by the irradiation of the laser beam Lz2, the passivation layer 42 having the first edge 421 and the first outer edge 422 is formed, as shown in FIG. 217. In addition, the first conductive layer 1 including the portions extending from the first edge 421 and the first outer edge 422 is formed. In the first conductive layer 1, the third edge 101 and the extended portion 103 are also formed. Here, after the process shown in FIG. 216, the processed portion may be washed, for example with aqua regia, to remove the residue of the first conductive film 10 and other components remaining on the base substrate 41.

Proceeding to FIG. 218, the bypass conductive section 5 is formed. To form the bypass conductive section 5, for example, a paste containing Ag or carbon is applied, and then dried to harden the paste. The bypass conductive section 5 is formed so as to cover the portion of the first conductive layer 1 extending from the passivation layer 42. In addition, it is preferable to form the bypass conductive section 5 so as to make the bypass conductive section 5 directly contact the base substrate 41. Thus, the bypass conductive section 5 including the bus-bar section 51 and the communication portion 52 is obtained.

Thereafter, the first resin cover layer 45 (resin cover layer 4) is formed so as to cover the bypass conductive section 5 and the passivation layer 42. To form the first resin cover layer 45, for example, a liquid resin material containing a UV-curable resin is applied to the passivation layer 42 by screen printing, and the resin is irradiated with UV light thus to be cured. Through the mentioned process, the organic thin film solar cell module A21 shown in FIG. 212 can be obtained.

With the mentioned embodiment also, both the degradation of the conduction path and the conduction loss can be prevented, in the organic thin film solar cell modules A19 and the electronic device B19. In addition, as shown in FIG. 212, the bus-bar section 51 of the bypass conductive section 5 covers the first extended portion 104 and the second extended portion 103 of the first conductive layer 1. Such a configuration allows the electric conduction area between the first conductive layer 1 and the bypass conductive section 5 to be increased, which is desirable for reducing the resistance. Forming the first edge 421 and the first outer edge 422 in an uneven shape leads to improved adhesion strength between the first edge 421 and the bus-bar section 51 of the bypass conductive section 5, and between the first outer edge 422 and the bus-bar section 51.

As shown in FIG. 216, the passivation layer 42 is removed utilizing the volatilization of the first conductive layer 1 caused by the irradiation of the laser beam Lz2 on the first conductive layer 1. Therefore, there is no need to employ a single-purpose laser beam or chemical for removing the passivation layer 42. This is advantageous for reduction in cost and time for the manufacturing. Employing the IR laser beam as the laser beam Lz2 allows the first conductive film 10 to be irradiated with higher efficiency, with the laser beam Lz2 through the insulation film 420. In addition, employing the IR laser beam as the laser beam Lz2 provides the advantage in that the first edge 421 and the first outer edge 422 of the passivation layer 42 can be finished in an uneven shape. Here, SiN, which is an example of the material of the insulation film 420, transmits light having a wavelength longer than 400 nm. Accordingly, in the case where the insulation film 420 is formed of SiN, the green laser beam, which has the wavelength of 532 nm, may be employed as the laser beam Lz2. On the other hand, in the case where UV laser beam having the wavelength of 355 nm is employed as the laser beam Lz2, the insulation film 420 and the first conductive film 10 both absorb the laser beam Lz2, and therefore these films can both be removed at a time.

The partial removal of the insulation film 420 and the first conductive film 10 is performed with the laser beam Lz2. The irradiation range of the laser beam Lz2 can be accurately controlled. Therefore, the laser beam Lz2 is suitable for removing a desired portion of the insulation film 420 and the first conductive film 10.

To remove the insulation film 420, the phenomenon that the insulation film 420 located adjacent to a region of the first conductive film 10 irradiated with the laser beam Lz2 is destroyed, is utilized. Accordingly, in the region of the first conductive layer 1 exposed from the passivation layer 42 shown in FIG. 219, the portion of the insulation film 420 that was covering this region is removed, despite that this region is not irradiated with the laser beam Lz2. Therefore, the region of the first conductive layer 1 exposed from the passivation layer 42 can be prevented from being accidentally destroyed, in the removal process of the insulation film 420.

Forming the slit 191 and the slit 192 in the first conductive film 10 prevents unintended expansion of the region of the insulation film 420 that may be affected by the volatilization of the first conductive film 10. In addition, forming the slit 191 and the slit 192 prevents, even when a part of the first conductive film 10 remains in the region to be removed, in the process of partially removing the first conductive film 10 shown in FIG. 218 and FIG. 219, accidental electrical connection between the residual part and the first conductive layer 1. However, the portion of the first conductive film 10 located opposite to the photoelectric conversion layer 3 across the slit 192 may remain as a part of the organic thin film solar cell module A20, without being removed. This portion is kept from being electrically connected to the first conductive layer 1, by the presence of the slit 192. Skipping the removal process of this portion contributes to reducing the manufacturing time. Here, the provision of the slit 191 and the slit 192 is merely an example, and these slits may be omitted.

FIG. 219 illustrates a variation of the organic thin film solar cell module A21. In this variation, the first resin cover layer 45 includes a non-translucent portion 454 and a translucent portion 455. The non-translucent portion 454 overlaps with the bypass conductive section 5 in plan view, and is located on the outer side with respect to the first edge 421. The non-translucent portion 454 is formed of a non-translucent material, for example a white resin. The translucent portion 455 is located in a region including a region located opposite to the first outer edge 422 with respect to the non-translucent portion 454. In the example shown in FIG. 145, the translucent portion 455 is formed so as to span over the bus-bar section 51 on the right in the drawing. In addition, a part of the translucent portion 455 is in contact with the base substrate 41. The configuration according to this variation can also protect the bypass conductive section 5. Further, the presence of the non-translucent portion 454 prevents degradation of the bypass conductive section 5 due to exposure to light, such as UV light.

The organic thin film solar cell module and the electronic device according to the present invention are in no way limited to the foregoing embodiments. The specific configurations of the elements of the organic thin film solar cell module and the electronic device according to the present invention may be modified in various manners.

The foregoing configuration according to the present invention is broadly applicable, in addition to the mobile phone terminal, to various electronic devices that utilize the photovoltaic generation, such as a wrist watch and an electronic calculator.

The technical features of the present invention may be expressed as the following appendices.

### Appendix 1F

An organic thin film solar cell module including:

a transparent base substrate;

a transparent first conductive layer disposed on the base substrate;

a second conductive layer;

a photoelectric conversion layer formed of an organic thin film and interposed between the first conductive layer and the second conductive layer; and

a passivation layer covering the second conductive layer,

in which the first conductive layer includes an extended portion extending from the passivation layer in plan view, and

the organic thin film solar cell module also includes:

a bypass conductive section covering at least a part of the extended portion, and formed of a material having lower resistance than a material of the first conductive layer; and

a resin cover layer covering the bypass conductive section.

### Appendix 2F

The organic thin film solar cell module according to appendix 1F, in which the passivation layer includes a first edge, and the base substrate is exposed in a region adjacent to the first edge.

### Appendix 3F

The organic thin film solar cell module according to appendix 2F, in which the extended portion of the first conductive layer includes a first extended portion exposed from the first edge, and

the first extended portion includes a third edge spaced apart from the first edge in plan view.

### Appendix 4F

The organic thin film solar cell module according to appendix 3F, in which the resin cover layer includes a first resin cover layer covering the passivation layer, and a second resin cover layer disposed on the first resin cover layer and covering the bypass conductive section, and

the first resin cover layer includes a second edge coinciding with the first edge in plan view.

### Appendix 5F

The organic thin film solar cell module according to appendix 4F, in which the first edge and the second edge form a continuous surface.

### Appendix 6F

The organic thin film solar cell module according to appendix 5F, in which the bypass conductive section includes a seventh edge coinciding with the third edge in plan view.

### Appendix 7F

The organic thin film solar cell module according to appendix 6F, in which the second resin cover layer includes a sixth edge located opposite to the first edge across the third edge and the seventh edge in plan view, and is in contact with the base substrate.

### Appendix 8F

The organic thin film solar cell module according to appendix 7F, in which the second conductive layer includes a fourth inner recessed edge, inwardly recessed with respect to the first edge in plan view.

### Appendix 9F

The organic thin film solar cell module according to appendix 8F, in which the photoelectric conversion layer includes a fifth inner recessed edge, inwardly recessed with respect to the first edge in plan view.

### Appendix 10F

The organic thin film solar cell module according to appendix 9F, in which the fourth inner recessed edge is inwardly recessed with respect to the fifth inner recessed edge, in plan view.

### Appendix 11F

The organic thin film solar cell module according to appendix 10F, in which the passivation layer includes a first outer edge located opposite to the first edge across at least a part of the photoelectric conversion layer in plan view,

the extended portion includes a second extended portion extending from the first outer edge, and

the second extended portion includes a third outer edge spaced apart from the first outer edge in plan view.

### Appendix 12F

The organic thin film solar cell module according to appendix 11F, in which the first resin cover layer includes a second outer edge coinciding with the first outer edge in plan view.

### Appendix 13F

The organic thin film solar cell module according to appendix 12F, in which the first outer edge and the second outer edge form a continuous surface.

### Appendix 14F

The organic thin film solar cell module according to appendix 13F, in which the bypass conductive section includes a seventh outer edge coinciding with the third outer edge in plan view.

### Appendix 15F

The organic thin film solar cell module according to appendix 14F, in which the second resin cover layer includes a sixth outer edge located opposite to the first outer edge across the third outer edge and the seventh outer edge in plan view, and is in contact with the base substrate.

### Appendix 16F

The organic thin film solar cell module according to appendix 15F, in which the second resin cover layer includes a non-translucent portion overlapping with the bypass conductive section in plan view, and located in a region on the side of the first outer edge, with respect to the first edge.

### Appendix 17F

The organic thin film solar cell module according to appendix 16F, in which the non-translucent portion is white.

### Appendix 18F

The organic thin film solar cell module according to appendix 3F, in which the bypass conductive section includes a seventh edge located opposite to the first edge across the third edge in plan view.

### Appendix 19F

The organic thin film solar cell module according to appendix 18F, in which the resin cover layer includes a second edge located opposite to the first edge across the seventh edge in plan view, and is in contact with the base substrate.

### Appendix 20F

The organic thin film solar cell module according to appendix 19F, in which the second conductive layer includes a fourth inner recessed edge, inwardly recessed with respect to the first edge in plan view.

### Appendix 21F

The organic thin film solar cell module according to appendix 20F, in which the photoelectric conversion layer includes a fifth inner recessed edge, inwardly recessed with respect to the first edge in plan view.

### Appendix 22F

The organic thin film solar cell module according to appendix 21F, in which the fourth inner recessed edge is inwardly recessed with respect to the fifth inner recessed edge, in plan view.

### Appendix 23F

The organic thin film solar cell module according to appendix 22F, in which the passivation layer includes a first outer edge located opposite to the first edge across at least a part of the photoelectric conversion layer in plan view,

### Appendix 24F

The organic thin film solar cell module according to appendix 23F, in which the bypass conductive section includes a seventh outer edge located opposite to the first outer edge across the third outer edge in plan view.

### Appendix 25F

The organic thin film solar cell module according to appendix 24F, in which the resin cover layer includes a second outer edge located opposite to the first outer edge across the seventh outer edge in plan view, and is in contact with the base substrate.

### Appendix 26F

The organic thin film solar cell module according to appendix 25F, in which the resin cover layer includes a non-translucent portion overlapping with the bypass conductive section in plan view, and formed in a region on the side of the first outer edge, with respect to the first edge.

### Appendix 27F

The organic thin film solar cell module according to appendix 26F, in which the non-translucent portion is white.

### Appendix 28F

The organic thin film solar cell module according to appendix 15F or 25F, in which the first edge has an annular shape in plan view.

### Appendix 29F

The organic thin film solar cell module according to appendix 28F, in which the third edge has an annular shape in plan view.

### Appendix 30F

The organic thin film solar cell module according to appendix 29F, in which the fourth inner recessed edge has an annular shape in plan view.

### Appendix 31F

The organic thin film solar cell module according to appendix 30F, in which the fifth inner recessed edge has an annular shape in plan view.

### Appendix 32F

The organic thin film solar cell module according to appendix 31F, in which the sixth edge has an annular shape in plan view.

### Appendix 33F

The organic thin film solar cell module according to appendix 32F, in which the seventh edge has an annular shape in plan view.

### Appendix 34F

The organic thin film solar cell module according to appendix 15F, in which the second edge has an annular shape in plan view.

### Appendix 35F

The organic thin film solar cell module according to any one of appendices 1F to 34F, in which the first conductive layer is formed of ITO.

### Appendix 36F

The organic thin film solar cell module according to any one of appendices 1F to 35F, in which the second conductive layer is formed of a metal.

### Appendix 37F

The organic thin film solar cell module according to any one of appendices 1F to 36F, in which the second conductive layer is formed of A1.

### Appendix 38F

The organic thin film solar cell module according to any one of appendices 1F to 37F, in which the passivation film is formed of SiN.

### Appendix 39F

The organic thin film solar cell module according to any one of appendices 1F to 38F, in which the resin cover layer is formed of a UV-curable resin.

### Appendix 40F

An electronic device including:

the organic thin film solar cell module according to any one of appendices 1F to 39F; and

a drive unit to operate by power supplied from the organic thin film solar cell module.

### Twenty-Second to Twenty-Seventh Embodiments

The term “transparent” used herein will be defined as having a transmittance of approximately 50% or higher. The term “transparent” will also be used when visible light is colorless and transparent. The visible light corresponds to a wavelength range of approximately 360 nm to 830 nm and an energy range of approximately 3.45 eV to 1.49 eV, and when a transmittance of a substance is 50% or higher in the mentioned range, that substance will be regarded as transparent.

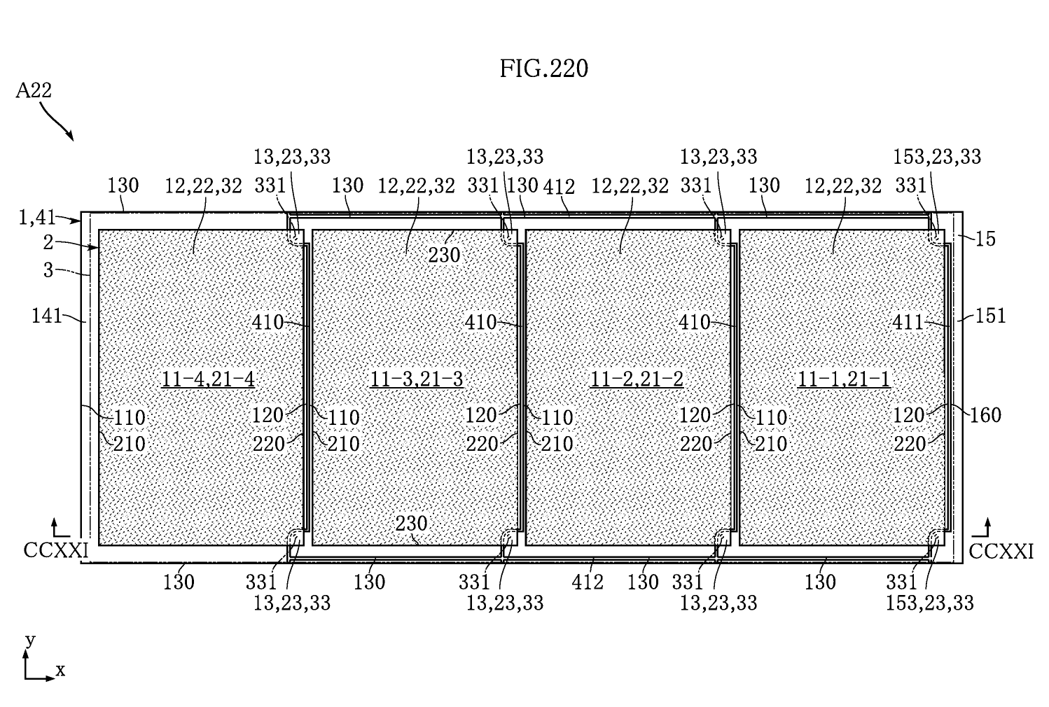

FIG. 220 to FIG. 226 illustrate an organic thin film solar cell module according to a twenty-second embodiment of the present invention. FIG. 227 illustrates an electronic device according to the twenty-second embodiment of the present invention.

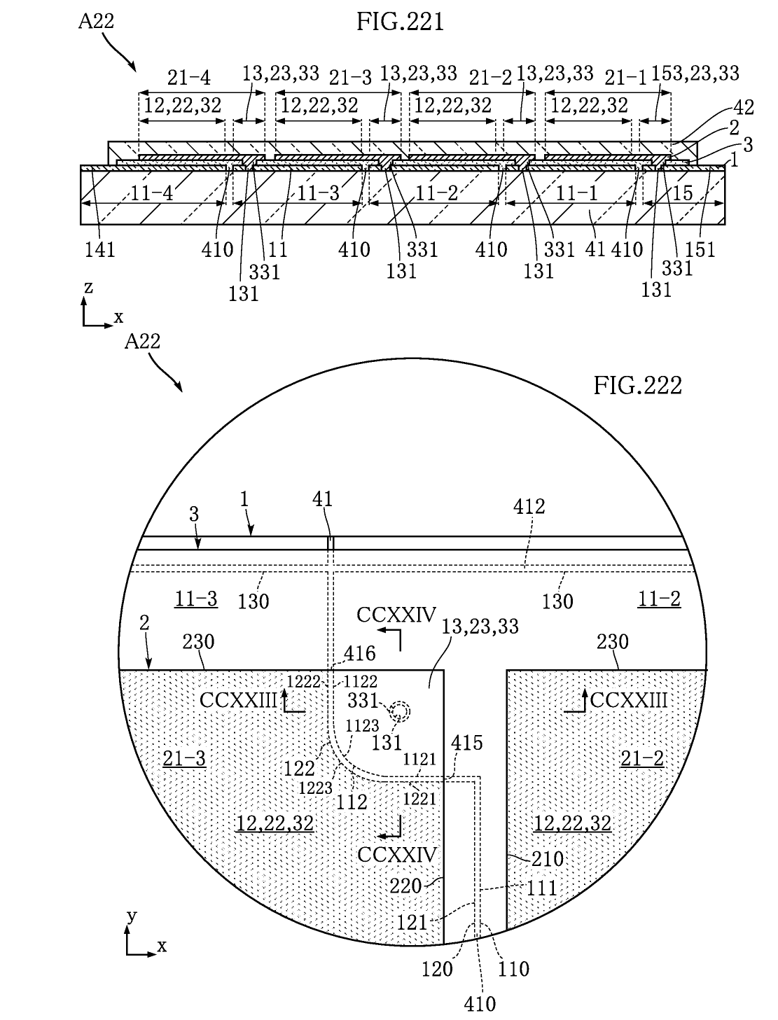

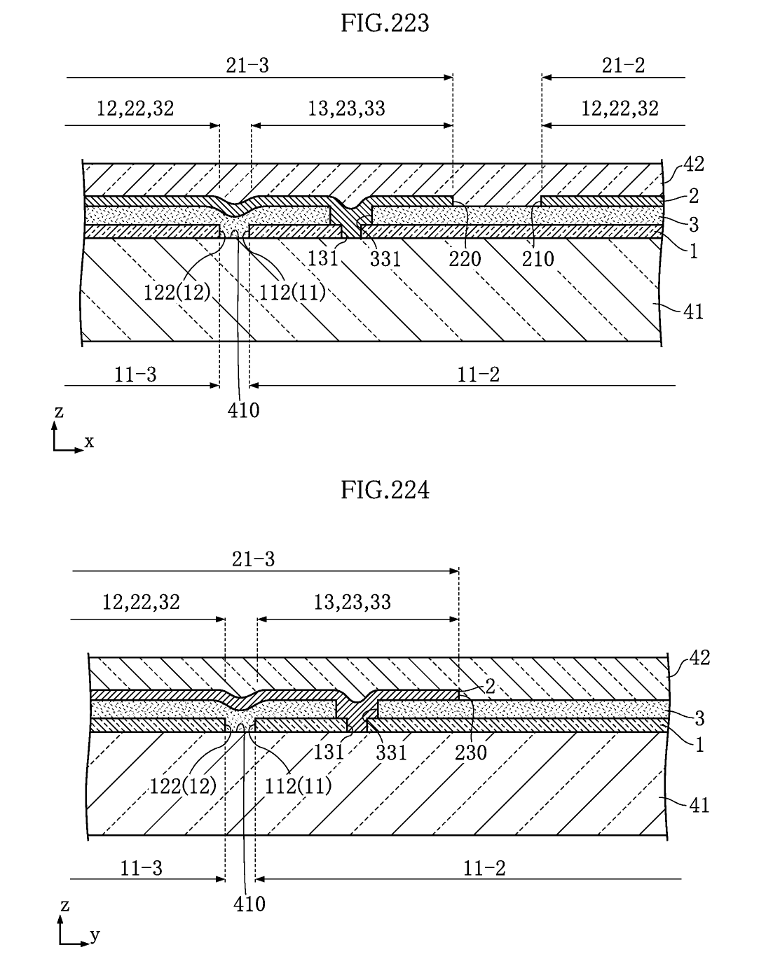

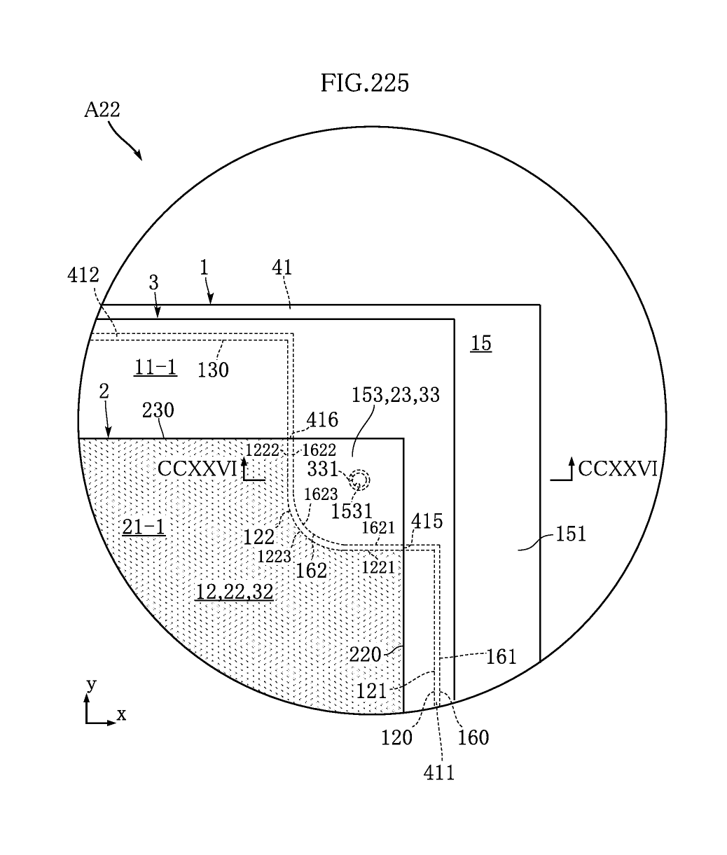

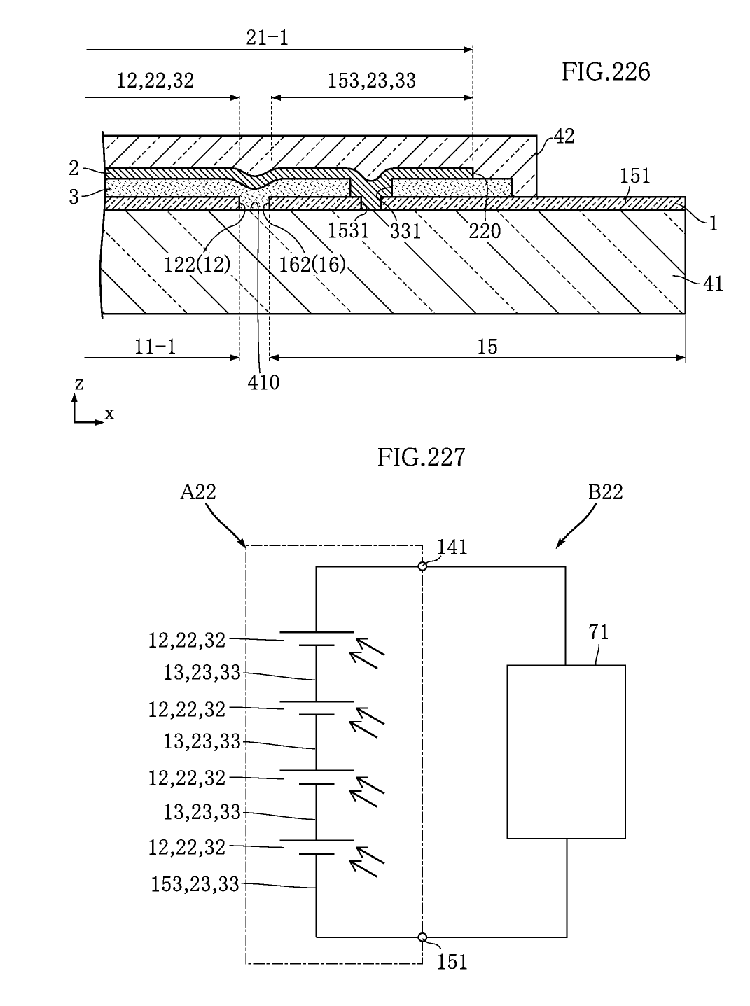

FIG. 220 is a partial plan view showing the organic thin film solar cell module A22. FIG. 221 is a cross-sectional view taken along a line CCXXI-CCXXI in FIG. 220. FIG. 222 is an enlarged partial plan view showing the organic thin film solar cell module A22. FIG. 223 is an enlarged partial cross-sectional view taken along a line CCXXIII-CCXXIII in FIG. 222. FIG. 224 is an enlarged partial cross-sectional view taken along a line CCXXIV-CCXXIV in FIG. 222. FIG. 225 is an enlarged partial plan view showing the organic thin film solar cell module A22. FIG. 226 is an enlarged partial cross-sectional view taken along a line CCXXVI-CCXXVI in FIG. 225. FIG. 227 is a system diagram of the organic thin film solar cell module A22 and the electronic device B22. In the description below, a “z-direction view” refers to a plan view, and a “z-direction” refers to a thickness direction of, for example, a base substrate 41.

As shown in FIG. 227, the electronic device B22 includes the organic thin film solar cell module A22 and a drive unit 71. The organic thin film solar cell module A22 serves as the power source module for the electronic device B22, and is configured to convert light, such as sunlight, into electric power.

The drive unit 71 operates by power supplied from the organic thin film solar cell module A22. The configuration and function of the drive unit 71 are not specifically limited, and various configurations may be adopted, provided that the function of the electronic device B22 can be realized. The drive unit 71 may be set up as, for example, an electronic arithmetic processing unit for realizing the electronic device B22 acting as electronic calculator, a wireless communication unit for realizing the electronic device B22 acting as wireless communication module, a timing processor for realizing the electronic device B22 acting as wrist watch, and an input/output operation processor for realizing the electronic device B22 acting as mobile electronic terminal device.

The organic thin film solar cell module A22 includes a base substrate 41, a first conductive layer 1, a second conductive layer 2, a photoelectric conversion layer 3, and a passivation layer 42. Although the organic thin film solar cell module A22 has a rectangular shape in z-direction view in this embodiment, this is merely an example and the organic thin film solar cell module A22 may be formed in various shapes. In FIG. 220, FIG. 222, and FIG. 225, the passivation layer 42 is omitted for sake of simplicity.

The base substrate 41 serves as the base of the organic thin film solar cell module A22. The base substrate 41 may have a single-layer or multilayer structure, formed of a material selected from, for example, transparent glass and resins. The base substrate 41 has a thickness of 0.05 mm to 2.0 mm. The shape and size of the base substrate 41 are not specifically limited, and in this embodiment the base substrate 41 has a rectangular shape in z-direction view.

As shown in FIG. 220 and FIG. 222, the organic thin film solar cell module A22 includes a plurality of substrate exposure regions 410 and substrate exposure regions 412, and also substrate exposure regions 411 as shown in FIG. 220. The substrate exposure regions 410, substrate exposure regions 411, and substrate exposure regions 412 are regions of the base substrate 41 exposed from the first conductive layer 1.

The first conductive layer 1 is formed on the base substrate 41. The first conductive layer 1 is transparent, and formed of ITO in this embodiment. The first conductive layer 1 includes a plurality of first blocks 11, and a third block 15. The first conductive layer 1 may be formed in various shapes. The first conductive layer 1 has a thickness of, for example, 100 nm to 300 nm.

The first blocks 11 are located adjacent to each other via the substrate exposure region 410. In this embodiment, four first blocks 11 are located side by side, with three substrate exposure regions 410 each interposed between the first blocks 11. The four first blocks 11 are aligned along a straight line in the x-direction. In the description below, the four first blocks 11 may be distinguished as first block 11-1, first block 11-2, first block 11-3, and first block 11-4 when necessary to facilitate understanding.

The first block 11 includes a first block first edge 110, a first block second edge 120, and two first block third edges 130.

The first block first edge 110 defines a part of the substrate exposure region 410. The first block second edge 120 defines another part of the substrate exposure region 410. In other words, the substrate exposure region 410 is defined by the first block first edge 110 of one of the first blocks 11 (first block 11-2 on the right in the x-direction in FIG. 222), and the first block second edge 120 of the other first block 11 (first block 11-3 on the left in the x-direction in FIG. 222).

In this embodiment, the first block first edge 110 of the first blocks 11-1 to 3 includes a first side 111, and the first block second edge 120 of the first blocks 11-2 to 4 includes a second side 121. The first side 111 (first side 111 of the first block 11-2 in FIG. 222) and the second side 121 (second side 121 of the first block 11-3 in FIG. 222), defining the same substrate exposure region 410, are parallel to each other. In this embodiment, the first side 111 and the second side 121 both linearly extend in the y-direction. Accordingly, the portion of the substrate exposure region 410 defined by the first side 111 and the second side 121 also linearly extend in the y-direction, in this embodiment.

The two first block third edges 130 each connect an end of the first block first edge 110 and a corresponding end of the first block second edge 120. In this embodiment, the first block third edges 130 linearly extend in the x-direction. The first block third edges 130 define a part of the substrate exposure region 412. The first block 11 according to this embodiment has a generally rectangular shape in x-direction view, defined by the first side 111 of the first block first edge 110, the second side 121 of the first block second edge 120, and the two first block third edges 130.

As shown in FIG. 220 and FIG. 225, the first block 11-1 on the right extremity in the x-direction and the third block 15 are located adjacent to each other via the substrate exposure region 411. The third block 15 includes a third block edge 160. The third block edge 160 of the third block 15 and the first block second edge 120 of the first block 11-1 adjacent to the third block 15 define the substrate exposure region 411. The third block edge 160 includes a third block parallel portion 161. The third block parallel portion 161 is parallel to the second side 121 of the first block 11-1. In this embodiment, the third block parallel portion 161 linearly extend in the y-direction.

The photoelectric conversion layer 3 is disposed on the base substrate 41 and the first conductive layer 1, and interposed between the first conductive layer 1 and the second conductive layer 2. The photoelectric conversion layer 3 is formed of an organic thin film, and configured to perform a photoelectric conversion function, to convert received light into electric power. Although the configuration of the photoelectric conversion layer 3 is not specifically limited, the photoelectric conversion layer 3 may include, for example, a bulk heterojunction organic active layer and a hole transport layer disposed on the bulk heterojunction organic active layer on the side of the first conductive layer 1. In this embodiment, the photoelectric conversion layer 3 is formed in a circular shape in plan view, however this is merely an example and the photoelectric conversion layer 3 may be formed in various shapes. The photoelectric conversion layer 3 has a thickness of, for example, 50 nm to 300 nm.

In the bulk heterojunction organic active layer, p-type organic active layer regions and n-type organic active layer regions are intermixed, forming a complicated bulk hetero pn junction. The p-type organic active layer region is, for example, formed of poly(3-hexylthiophene-2,5diyl) (P3HT), and the n-type organic active layer region is formed of 6,6-phenyl-C61-butyric acid methyl ester (PCBM), for example. The hole transport layer is formed of, for example, PEDOT:PSS.

Examples of materials that may be utilized to form the photoelectric conversion layer 3 include phthalocyanine (Pc), zinc-phthalocyanine (ZnPc), N,N′-dimethyl perylene-3,4,9,10-dicarboximide (Me-Ptcdi), and Buckminster fullerene (C60). These materials are, for example, utilized for vacuum vapor deposition.

In addition, poly[2-methoxy-5-(3,7-dimethyl octyloxy)]-1,4-phenylene vinylene (MDMO-PPV), poly[N-9′-hepta-decanyl-2,7-carbazole-alt-5,5-(4′,7′-di-thienyl-2′1′,3′-b3nzothiadizaole)] (PCDTBT), 6,6-phenyl-C61-butyric acid methyl ester (PC60BM), or 6,6-phenyl-C71-butyric acid methyl ester (PC70BM) may be utilized to form the photoelectric conversion layer 3. These materials are, for example, utilized for a solution process.

A major part of the second conductive layer 2 is disposed on the first conductive layer 1 via the photoelectric conversion layer 3. A part of the second conductive layer 2 is in direct contact with the first conductive layer 1. The material of the second conductive layer 2 is not specifically limited, and may be transparent or non-transparent. In this embodiment, the second conductive layer 2 is formed of a metal, typically A1, W, Mo, Mn, or Mg. In the following example, the second conductive layer 2 is formed of A1. Accordingly, the second conductive layer 2 is non-transparent. In this case, a non-illustrated passive film of Al₂O₃ may be formed on the surface of the second conductive layer 2 opposite to the base substrate 41. The second conductive layer 2 has a thickness of, for example, 30 nm to 150 nm.

As shown in FIG. 220, the second conductive layer 2 includes a plurality of second blocks 21. The second blocks 21 are located adjacent to each other, via a part of the substrate exposure region 410. In this embodiment, specifically, the second blocks 21 adjacent to each other are aligned with the first side 111 of the first block first edge 110 and the second side 121 of the first block second edge 120 therebetween. In this embodiment, the four second blocks 21 are aligned, with a part of each of the three substrate exposure regions 410 therebetween. Further, the four second blocks 21 are aligned along a straight line in the x-direction. In the description below, the four second blocks 21 may be distinguished as second block 21-1, second block 21-2, second block 21-3, and second block 21-4 when necessary to facilitate understanding.

As shown in FIG. 220 and FIG. 222, the second block 21 overlaps with the first block 11 in z-direction view. The second block 21 includes a second block first edge 210, a second block second edge 220, and two second block third edges 230.

The second block first edge 210 of the second blocks 21-1 to 3 (second block 21-2 in FIG. 222) is located opposite to the first block second edge 120 of the first block 11-2 to 4 (first block 11-3 in FIG. 222) defining the substrate exposure region 410, across the first block first edge 110 of the first blocks 11-1 to 3 (first block 11-2 in FIG. 222), also defining the substrate exposure region 410. The second block second edge 220 is opposed to the second block first edge 210 of the second block 21 adjacent thereto, across a part of the substrate exposure region 410, in z-direction view.

In this embodiment, the second block first edge 210 (of the second block 21-2 in FIG. 222) and the second block second edge 220 (of the second block 21-3 in FIG. 222) are parallel to each other. The second block first edge 210 and the second block second edge 220 linearly extend in the y-direction. Thus, in this embodiment the first side 111, the second side 121, the second block first edge 210, and the second block second edge 220 are parallel to each other and linearly extend in the y-direction.

The two second block third edges 230 each connect an end of the second block first edge 210 and a corresponding end of the second block second edge 220. The two second block third edges 230 are parallel to each other and linearly extend in the x-direction. The second block 21, having the second block first edge 210, the second block second edge 22, and the two second block third edges 230, has a rectangular shape in z-direction view.

As shown in FIG. 221, FIG. 223, FIG. 224, and FIG. 226, the passivation layer 42 is disposed on the second conductive layer 2, so as to cover the second conductive layer 2 and the photoelectric conversion layer 3. The passivation layer 42 is, for example, formed of SiN or SiON. The passivation layer 42 has a thickness of, for example, 0.5 μm to 2.0 μm and, in this embodiment, approximately 1.5 μm. Since the passivation layer 42 covers the photoelectric conversion layer 3, intrusion of moisture or particles from outside into the photoelectric conversion layer 3 can be prevented. In addition, the passivation layer 42 is thicker than the photoelectric conversion layer 3, and hence the strength of the organic thin film solar cell module A22 can be improved. The passivation layer 42 having a flat surface as above can be formed, for example, by making the passivation layer 42 thicker than the photoelectric conversion layer 3, and through a CVD process to be described below. Another layer may additionally formed on the passivation layer 42. For example, a bonding layer for bonding another element of the electronic device B22 and the organic thin film solar cell module A22 together may be provided. Alternatively, a cover layer for protecting the passivation layer 42 may be provided.

As shown in FIG. 222 to FIG. 224, the first block first edge 110 of the first blocks 11-1 to 3 (first block 11-2 in FIG. 222) includes two first shielded portions 112, in addition to the first side 111. The first shielded portions 112 each correspond to a portion of the first block first edge 110 overlapping with the second block 21 in z-direction view, and are shielded with the second block 21 in z-direction view. In this embodiment, the two first shielded portions 112 are connected to the respective end portions of the first side 111 in the y-direction. The shape of the first shielded portion 112 is not specifically limited, and in this embodiment the first shielded portion 112 is formed so as to protrude from the first side 111 in the x-direction, and includes a first side 1121, a second side 1122, and a third side 1123. The first side 1121 extends in the x-direction, parallel to the first block third edge 130. The second side 1122 extends in the y-direction, so as to intersect the first side 1121. The third side 1123, connecting the first side 1121 and the second side 1122, is formed in a curved shape in the example shown in FIG. 222. An end of the first shielded portion 112 shown in FIG. 222 reaches the second block second edge 220, and the other end intersects the second block third edge 230 in z-direction view.

As shown in FIG. 222 to FIG. 224, the first block second edge 120 of the first blocks 11-2 to 4 (first block 11-3 in FIG. 222) includes two second shielded portions 122, in addition to the second side 121. The second shielded portion 122 each correspond to a portion of the first block second edge 120 overlapping with the second block 21 in z-direction view. In this embodiment, the two second shielded portions 122 are connected to the respective end portions of the second side 121 in the y-direction. The shape of the second shielded portion 122 is not specifically limited, and in this embodiment the second shielded portion 122 is retracted from the second side 121 in the x-direction, and includes a first side 1221, a second side 1222, and a third side 1223. The first side 1221 extends in the x-direction, parallel to the first block third edge 130. The second side 1222 extends in the y-direction, so as to intersect the first side 1221. The third side 1223, connecting the first side 1221 and the second side 1222, is formed in a curved shape in the example shown in FIG. 222. An end of the second shielded portion 122 shown in FIG. 222 reaches the second block second edge 220, and the other end reaches the second block third edge 230 in z-direction view.

Because of the first shielded portion 112 and the second shielded portion 122 configured as above, the substrate exposure region 410 according to this embodiment overlaps with the second block 21 in z-direction view, and includes an intersection 415 and an intersection 416. The intersection 415 is the intersection between the substrate exposure region 410 and the second block second edge 220. The intersection 416 is the intersection between the substrate exposure region 410 and the second block third edge 230.

As shown in FIG. 220 to FIG. 224, the photoelectric conversion layer 3 includes a plurality of photoelectric conversion layer connection portions 33. As shown in FIG. 222 to FIG. 224, the photoelectric conversion layer connection portion 33 overlaps with both of the first block 11 (in FIG. 222, first block 11-2) of the first conductive layer 1 and the second block 21 (in FIG. 222, second block 21-3) of the second conductive layer 2 in z-direction view, which are adjacent to each other via a part of the substrate exposure region 410 (in FIG. 222, region defined by the first side 111 of the first block 11-2 and the second side 121 of the first block 11-3), and is defined by the first shielded portion 112 of the first block 11 and the second block second edge 220 of the second block 21. In this embodiment, further, the photoelectric conversion layer connection portion 33 is defined by the second block third edge 230 (in FIG. 222, second block third edge 230 of the second block 21-3). Thus, the photoelectric conversion layer connection portion 33 according to this embodiment is located at a position overlapping with a corner portion of the second block 21 (in FIG. 222, second block 21-3) of a rectangular shape, in z-direction view. In addition, in this embodiment the two photoelectric conversion layer connection portions 33 are respectively located at two corner portions spaced apart from each other in the y-direction, in each of the second blocks 21, as shown in FIG. 220.

The photoelectric conversion layer connection portion 33 includes a photoelectric conversion layer perforated portion 331. The photoelectric conversion layer perforated portion 331 is a through-hole formed so as to penetrate through the photoelectric conversion layer 3 in the z-direction. The shape and size of the photoelectric conversion layer perforated portion 331 are not specifically limited, and in this embodiment the photoelectric conversion layer perforated portion 331 has a circular shape in z-direction view. The photoelectric conversion layer perforated portion 331 has a diameter of, for example, approximately 40 μm.

The first blocks 11-1 to 3 each include a first connection portion 13. The first connection portion 13 is located at a position coinciding with the photoelectric conversion layer connection portion 33 in z-direction view. The second block 21 includes a second connection portion 23. The second connection portion 23 is located at a position coinciding with the photoelectric conversion layer connection portion 33 in z-direction view. The first connection portion 13 of the first blocks 11-1 to 3 and the second connection portion 23 of the second blocks 21-2 to 4 are in contact with each other via the photoelectric conversion layer perforated portion 331, the electrically connected to each other. Accordingly, the first connection portion 13, the second connection portion 23, and the photoelectric conversion layer connection portion 33 are regions not involved in power generation.

In this embodiment, the first connection portion 13 of the first block 11 includes a first perforated portion 131. In this embodiment, the first perforated portion 131 refers to a through-hole penetrating through the first conductive layer 1 in the z-direction. The first perforated portion 131 is enclosed in the photoelectric conversion layer perforated portion 331, in z-direction view. In addition, the inner edge of the first perforated portion 131 is spaced apart from the inner edge of the photoelectric conversion layer perforated portion 331, in z-direction view. Accordingly, a part of the first connection portion 13 of the first block 11 is exposed from the photoelectric conversion layer perforated portion 331, in z-direction view. The second connection portion 23 of the second blocks 21-2 to 4 of the second conductive layer 2 is in contact with the exposed portion. In addition, the second connection portion 23 of the second blocks 21-2 to 4 is in contact with the base substrate 41 via the first perforated portion 131.

The photoelectric conversion layer 3 includes a plurality of photoelectric conversion layer generation sections 32. The first block 11 of the first conductive layer 1 includes a first electrode section 12, and the second block 21 of the second conductive layer 2 includes a second electrode section 22. In FIG. 220, FIG. 222, and FIG. 225, the first electrode section 12, the second electrode section 22, and the photoelectric conversion layer generation section 32 are shaded with scattered dots. The first electrode section 12 is spaced apart from the photoelectric conversion layer connection portion 33 and overlapping with the second block 21 of the second conductive layer 2, in z-direction view. In other words, the second block 21 coincides with the first electrode section 12, in z-direction view. The photoelectric conversion layer generation section 32 coincides with the first electrode section 12 and the second electrode section 22, in z-direction view. In this embodiment, the first electrode section 12, the second electrode section 22, and the photoelectric conversion layer generation section 32 are defined by the second block first edge 210, the second block second edge 220, the two second block third edges 230, and the two second shielded portions 122, in z-direction view. The first electrode section 12 and the second electrode section 22 are stacked with the photoelectric conversion layer generation section 32 therebetween, and are hence not in contact with each other. Accordingly, the first electrode section 12, the second electrode section 22, and the photoelectric conversion layer generation section 32 are regions involved in power generation.

In this embodiment, the photoelectric conversion layer connection portion 33 and a part of the photoelectric conversion layer generation section 32 are located adjacent to each other in the y-direction with a gap therebetween, in z-direction view. More specifically, the photoelectric conversion layer connection portion 33 is located at the same position as a part of the photoelectric conversion layer generation section 32, in the x-direction. The first connection portion 13 is adjacent, in the y-direction, to a part of the first electrode section 12 of the first block 11 adjacent via the substrate exposure region 410. Thus, the position of the first connection portion 13 in the x-direction overlaps with the position of the part of the first electrode section 12 in the x-direction.

As shown in FIG. 220, FIG. 221, FIG. 225, and FIG. 226, the third block 15 includes an external electrode section 151 and an external connection portion 153. The external connection portion 153 is located at a position coinciding with the second connection portion 23 of the second block 21-1 and the photoelectric conversion layer connection portion 33, in z-direction view. The external connection portion 153 is in contact with the second connection portion 23 of the second block 21-1, via the photoelectric conversion layer perforated portion 331. In this embodiment, the external connection portion 153 includes an external connection portion perforated portion 1531. In this embodiment, the external connection portion perforated portion 1531 refers to a through-hole penetrating through the external connection portion 153 of the first conductive layer 1, in the z-direction. The external connection portion perforated portion 1531 is enclosed in the photoelectric conversion layer perforated portion 331, in z-direction view. Further, the inner edge of the external connection portion perforated portion 1531 is spaced apart from the inner edge of the photoelectric conversion layer perforated portion 331, in z-direction view. Accordingly, a part of the external connection portion 153 of the third block 15 is exposed from the photoelectric conversion layer perforated portion 331, in z-direction view. The second connection portion 23 of the second block 21-1 of the second conductive layer 2 is in contact with the exposed portion. In addition, the second connection portion 23 is in contact with the base substrate 41, via the external connection portion perforated portion 1531. The external electrode section 151 is exposed from the second conductive layer 2, the photoelectric conversion layer 3, and the passivation layer 42. The external electrode section 151 is a portion from which the power generated in the organic thin film solar cell module A22 is outputted, and is electrically connected, for example, to a terminal of the electronic device B22.

In this embodiment, as shown in FIG. 220 and FIG. 221, the first block 11-4, located on the side opposite to the third block 15 in the x-direction, includes an external electrode section 141. The external electrode section 141 is a portion of the first block 11-4 exposed from the second conductive layer 2, the photoelectric conversion layer 3, and the passivation layer 42. The external electrode section 141 is a portion from which the power generated in the organic thin film solar cell module A22 is outputted, and is electrically connected, for example, to a terminal of the electronic device B22.

In this embodiment, as seen from FIG. 220, FIG. 221, and FIG. 227, in the organic thin film solar cell module A22, four sets of the first electrode section 12, the second electrode section 22, and the photoelectric conversion layer generation section 32, are connected to each other directly, i.e. merely via six sets of the first connection portion 13, the second connection portion 23, and the photoelectric conversion layer connection portion 33. The power generated in the four sets of the first electrode section 12, the second electrode section 22 and the photoelectric conversion layer generation section 32 connected in series to each other, is outputted from the external electrode section 141 and the external electrode section 151. Such power is utilized to activate the drive unit 71 of the electronic device B22.

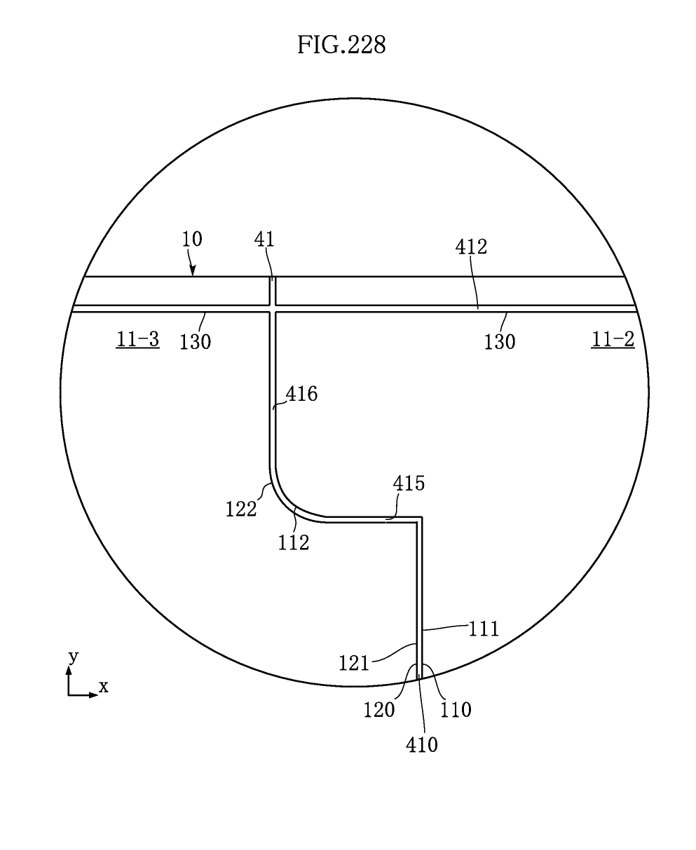

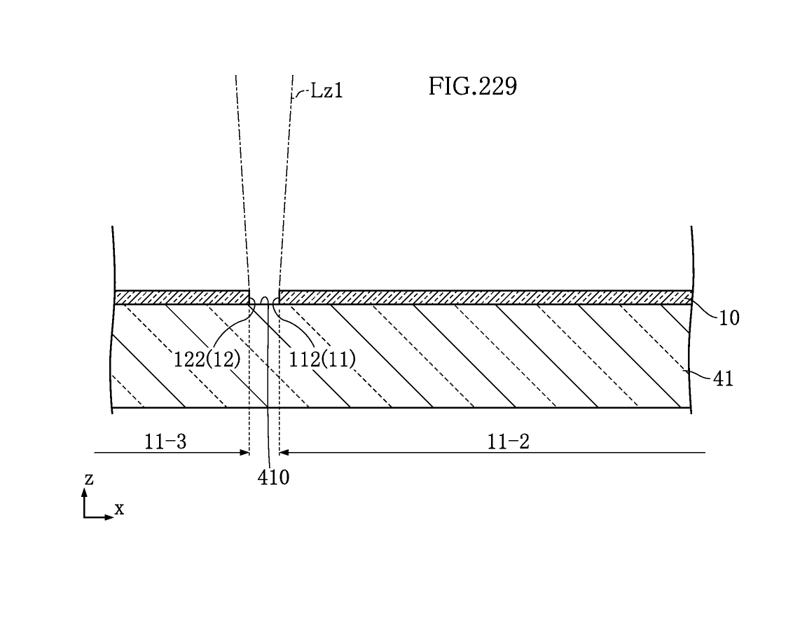

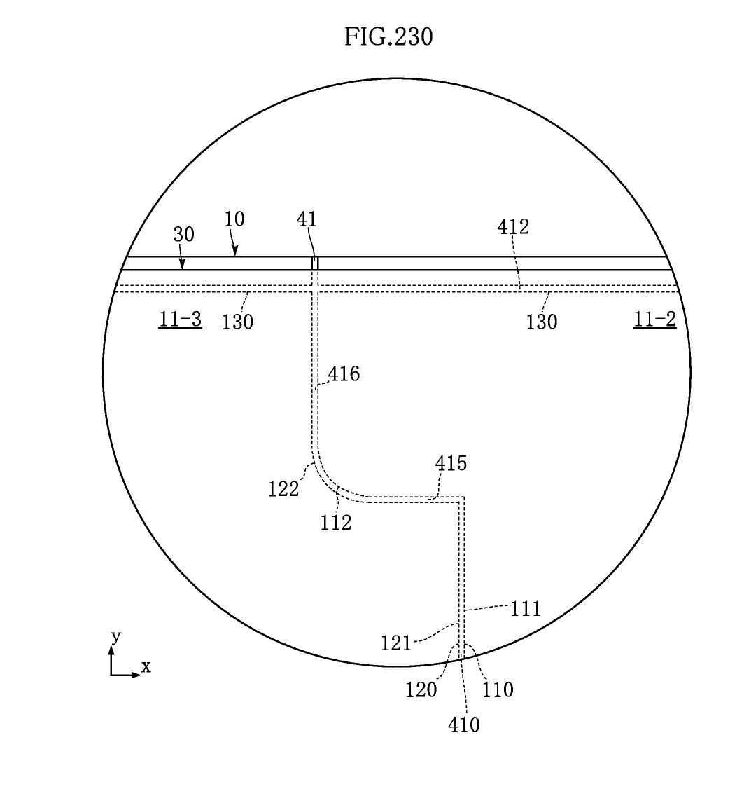

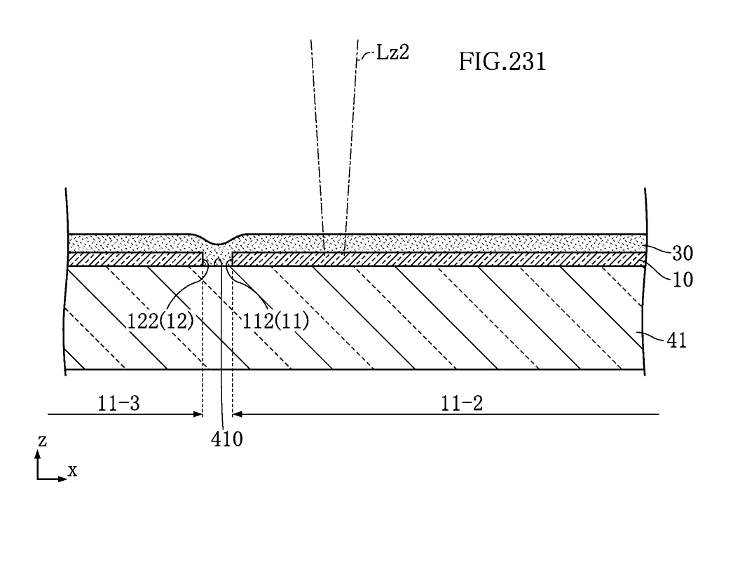

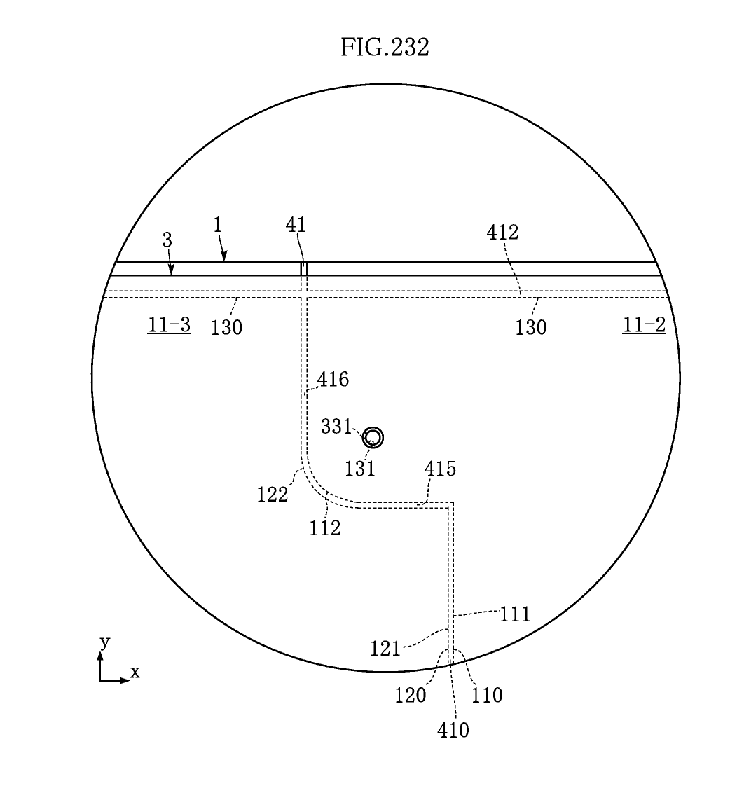

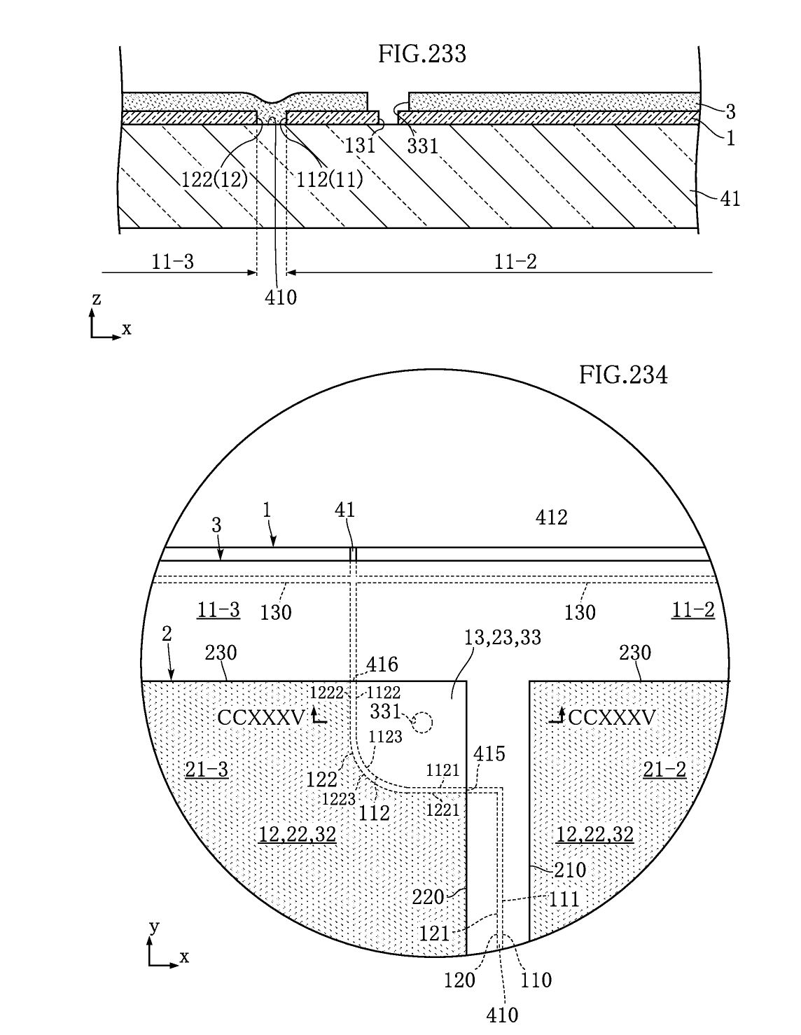

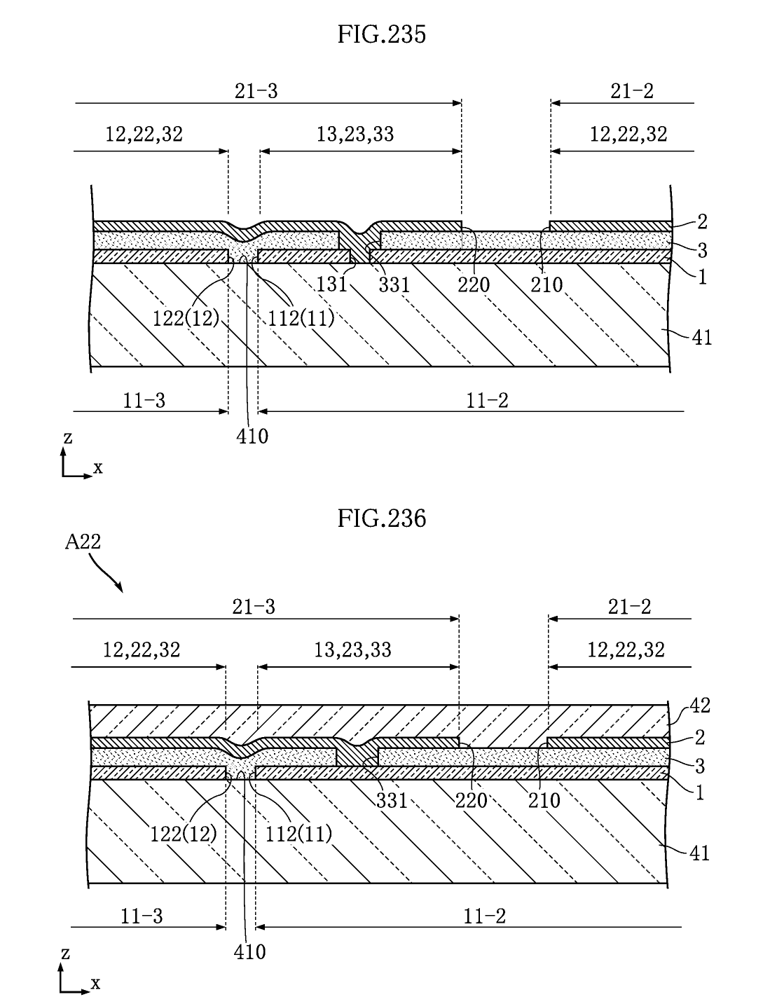

Hereunder, a manufacturing method of the organic thin film solar cell module A22 will be described with reference to FIG. 228 to FIG. 235. FIG. 228, FIG. 230, FIG. 232, and FIG. 234 are enlarged partial plan views showing the same portion as that of FIG. 222, and FIG. 229, FIG. 231, FIG. 233, and FIG. 235 are enlarged partial cross-sectional view showing the same portion as that of FIG. 223.

Referring first to FIG. 228 and FIG. 229, the first conductive film 10 is formed on one of the surfaces of the base substrate 41, by depositing ITO by a known method such as sputtering. Then the first conductive film 10 is patterned to form the substrate exposure region 410, the substrate exposure region 411, and the substrate exposure region 412. Thus, a plurality of first blocks 11 and the third block 15 can be obtained. For the patterning of the first conductive film 10, for example, a wet etching process, or a laser patterning that utilizes green laser beam or IR laser beam, may be employed. In this embodiment, the IR laser beam is employed as a laser beam Lz1. In FIG. 228, the portions to be subsequently formed into the first shielded portion 112 and the second shielded portion 122 are indicated by these numerals, to facilitate understanding.

Proceeding to FIG. 230 and FIG. 231, an organic film 30 is formed. The organic film 30 may be formed by applying an organic film for example by spin coating, onto the base substrate 41 and the first conductive film 10. Then the photoelectric conversion layer perforated portion 331 is formed in the organic film 30. The photoelectric conversion layer perforated portion 33 may be formed, for example, by laser patterning. For the laser patterning, a laser beam Lz2 is selected from laser beams that are capable of partially removing the photoelectric conversion layer perforated portion 331. In this embodiment, the IR laser beam is employed as the laser beam Lz2, to perform the laser patterning. In this case, the laser beam Lz2 removes a part of each of the organic film 30 and the first conductive film 10. Accordingly, the photoelectric conversion layer perforated portion 331 is formed in the organic film 30, and the first perforated portion 131 is formed in the first conductive film 10 at a time. Through such laser patterning, the first conductive layer 1 and the photoelectric conversion layer 3 can be obtained, as shown in FIG. 232 and FIG. 233.

Proceeding to FIG. 234 and FIG. 235, the second conductive layer 2 is formed. To form the second conductive layer 2, for example, one of the aforementioned metals is deposited by vacuum vapor deposition on the base substrate 41, the first conductive layer 1, and the photoelectric conversion layer 3, to form a metal film thereon. Then the metal film is patterned, for example by etching with a mask layer. Through such patterning, the second conductive layer 2 including a plurality of second blocks 21 is formed on the first conductive layer 1 and the photoelectric conversion layer 3. Thereafter, SiN or SiON is deposited on the base substrate 41, the first conductive layer 1, the photoelectric conversion layer 3, and the second conductive layer 2, for example by plasma CVD, to form the passivation layer 42. Through the mentioned process, the organic thin film solar cell module A22 can be obtained.

The organic thin film solar cell module A22 and the electronic device B22 provide the following advantageous effects.

In this embodiment, as shown in FIG. 222, the substrate exposure region 410, a part of which is defined by the first shielded portion 112 of the first block 11-2 defining the photoelectric conversion layer connection portion 33, includes the intersection 415 intersecting the second block second edge 220 of the second block 21-3. Accordingly, the photoelectric conversion layer connection portion 33 is formed along a part of the second block second edge 220 of the second block 21-3, instead of along the entire length thereof. Such a configuration allows reduction of the area ratio of the photoelectric conversion layer connection portion 33, which is the non-generating portion, to the photoelectric conversion layer 3, thereby preventing reduction of the area of the photoelectric conversion layer generation section 32, which is the section actually contributing to the power generation.

In the example shown in FIG. 222, the substrate exposure region 410 includes the intersection 415 and the intersection 416. In other words, the substrate exposure region 410 defining the photoelectric conversion layer connection portion 33 extends from the second block second edge 220 of the second block 21-3 and intersects the second block third edge 230 of the second block 21-3. In the case where, for example, the substrate exposure region 410 intersects the second block second edge 220 of the second block 21-3 at two points unlike in this embodiment, the portion of the substrate exposure region 410 overlapping with the second block 21-3 in z-direction view is extended, compared with the configuration of this embodiment. Since the substrate exposure region 410 is a region not involved in the power generation, the mentioned configuration of this embodiment contributes to reducing the area ratio of the non-generating region.

The photoelectric conversion layer perforated portion 331 is a through-hole having a diameter of, for example, approximately 40 μm. Accordingly, the area of the photoelectric conversion layer connection portion 33 including the photoelectric conversion layer perforated portion 331 can be further reduced.

The first perforated portion 131 is collectively formed with the photoelectric conversion layer perforated portion 331, by employing the IR laser beam as the laser beam Lz2 shown in FIG. 231. The IR laser beam is capable of partially removing the first conductive layer 1 which is formed of ITO, and can therefore be utilized as the laser beam Lz1 shown in FIG. 229, used for the laser patterning of the first conductive film 10. Therefore, it suffices to employ one type of laser beam, namely the IR laser beam, as the laser beam Lz1 and the laser beam Lz2 employed in the manufacturing method of the organic thin film solar cell module A22, shown in FIG. 228 to FIG. 235. This is advantageous for simplifying the manufacturing method and equipment, and contributes to reducing the manufacturing time.

Two sets of the first connection portion 13, the second connection portion 23, and the photoelectric conversion layer connection portion 33 are respectively provided so as to overlap with the two corner portions of the second block 21, and therefore the resistance between two sets of the first electrode section 12, the second electrode section 22, and the photoelectric conversion layer generation section 32, located adjacent to each other, can be reduced. Further, even when the electric conduction fails in one of the sets of the first connection portion 13, the second connection portion 23, and the photoelectric conversion layer connection portion 33, the other set of the first connection portion 13, the second connection portion 23, and the photoelectric conversion layer connection portion 33 can properly connect the two sets of the first electrode section 12, the second electrode section 22, and the photoelectric conversion layer generation section 32 adjacent to each other.

FIG. 236 to FIG. 244 illustrate a variation and other embodiments of the present invention. In the mentioned drawings, the elements same as or similar to those of the foregoing embodiments are given the same numeral.

FIG. 236 illustrates a variation of the organic thin film solar cell module A22. In this variation, the first perforated portion 131 is not formed in the first connection portion 13 of the first block 11 (first block 11-2 in FIG. 236). In other words, the base substrate 41 is covered with the first connection portion 13 (in the first block 11-2 in FIG. 236) of the first conductive layer 1, in the region enclosed in the photoelectric conversion layer perforated portion 331 in z-direction view. Such a configuration can be obtained by employing green laser beam as the laser beam Lz2 in the laser patterning process to form the photoelectric conversion layer perforated portion 331 in the organic film 30, and appropriately adjusting the output and irradiation time. In addition, the projection 332 is not formed in the photoelectric conversion layer 3, in this variation.

The configuration according to the mentioned variation also suppresses a decrease in area of the photoelectric conversion layer generation section 32, which actually contributes to the power generation. In subsequent embodiments, the first perforated portion 131 may, or not may, be formed in the region where the photoelectric conversion layer perforated portion 331 is provided.

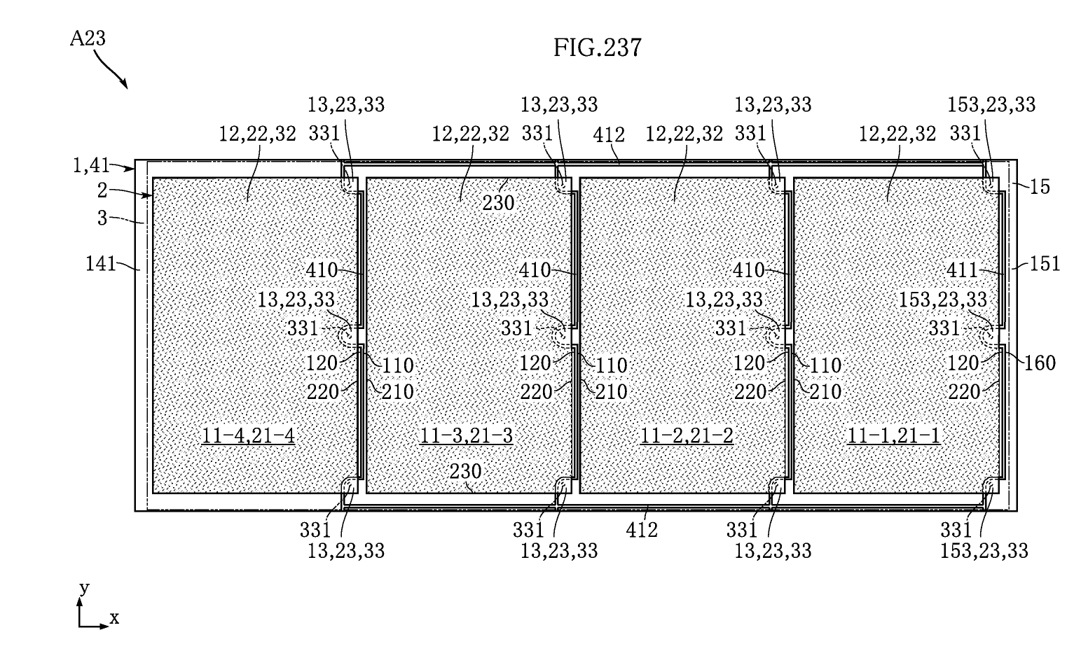

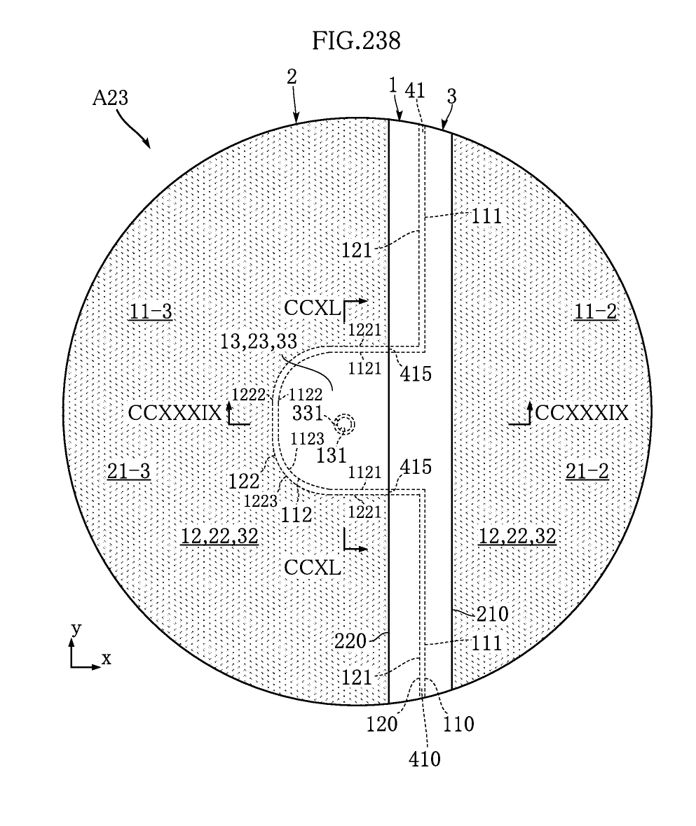

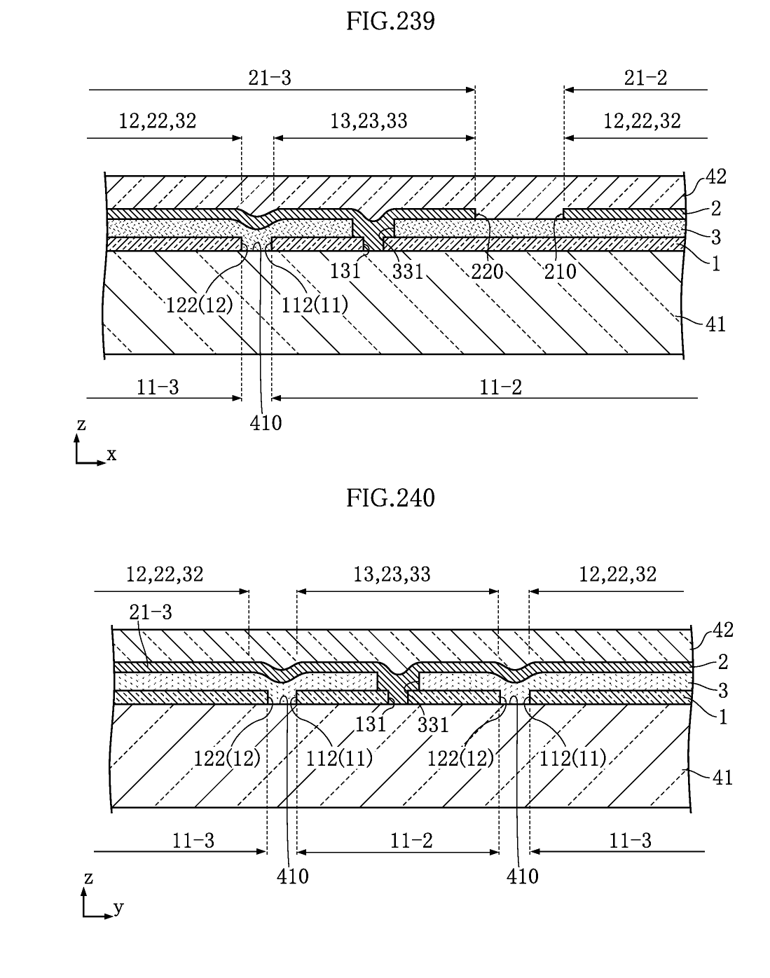

FIG. 238 to FIG. 240 illustrate an organic thin film solar cell module according to the twenty-third embodiment of the present invention. In the organic thin film solar cell module A23 according to this embodiment, the configurations of the first connection portion 13, the second connection portion 23, and the photoelectric conversion layer connection portion 33 are different from those of the foregoing embodiment. FIG. 237 is a partial plan view showing the organic thin film solar cell module A23. FIG. 238 is an enlarged partial plan view showing the organic thin film solar cell module A23. FIG. 239 is an enlarged partial cross-sectional view taken along a line CCXXXIX-CCXXXIX in FIG. 238. FIG. 240 is an enlarged partial cross-sectional view taken along a line CCXL-CCXL in FIG. 238.

In this embodiment, as shown in FIG. 237, one set of the first connection portion 13, the second connection portion 23, and the photoelectric conversion layer connection portion 33 is provided between two sets of the first connection portion 13, the second connection portion 23, and the photoelectric conversion layer connection portion 33, respectively located at positions corresponding to the two corner portions of the second block 21 spaced apart from each other in the y-direction. As shown in FIG. 238 to FIG. 240, the substrate exposure region 410 defining the first connection portion 13, the second connection portion 23, and the photoelectric conversion layer connection portion 33 in the z-direction view includes two intersections 415 intersecting the second block second edge 220 of the second block 21-3. The two intersections 415 are spaced apart from each other in the y-direction. In addition, the first electrode section 12 of the first block 11-3, the second electrode section 22 of the second block 21-3, and the photoelectric conversion layer generation section 32 are located on both sides of the first connection portion 13 of the first block 11-2, the second connection portion 23 of the second block 21-3, and the photoelectric conversion layer connection portion 33 in the y-direction. In other words, the first connection portion 13 of the first block 11-2, the second connection portion 23 of the second block 21-3, and the photoelectric conversion layer connection portion 33 are interposed between the first electrode section 12 of the first block 11-3, the second electrode section 22 of the second block 21-3, and the photoelectric conversion layer generation section 32, in the y-direction. In this embodiment, the first shielded portion 112 includes the two first sides 1121, the second side 1122, and the two third sides 1123. Likewise, the second shielded portion 122 includes the two first sides 1221, the second side 1222, and the two third sides 1223.

The configuration according to the above embodiment also suppresses a decrease in area of the photoelectric conversion layer generation section 32, which actually contributes to the power generation. Although the photoelectric conversion layer connection portion 33 shown in FIG. 238 is not involved in the power generation, the substrate exposure region 410 defining this connection portion includes the two intersections 415 intersecting the second block second edge 220 of the second block 21-3. In other words, the photoelectric conversion layer generation section 32 is located on both sides of the photoelectric conversion layer connection portion 33 in the y-direction. Such a configuration suppresses a decrease in area of the photoelectric conversion layer generation section 32, compared with the case where the photoelectric conversion layer connection portion 33 is provided over the entire length of the second block second edge 220. Further, providing the first connection portion 13, the second connection portion 23, and the photoelectric conversion layer connection portion 33 as shown in FIG. 238 leads to reduced resistance between the two sets of the first electrode section 12, second electrode section 22, and the photoelectric conversion layer generation section 32 adjacent to each other, thereby further assuring the electrical connection therebetween.

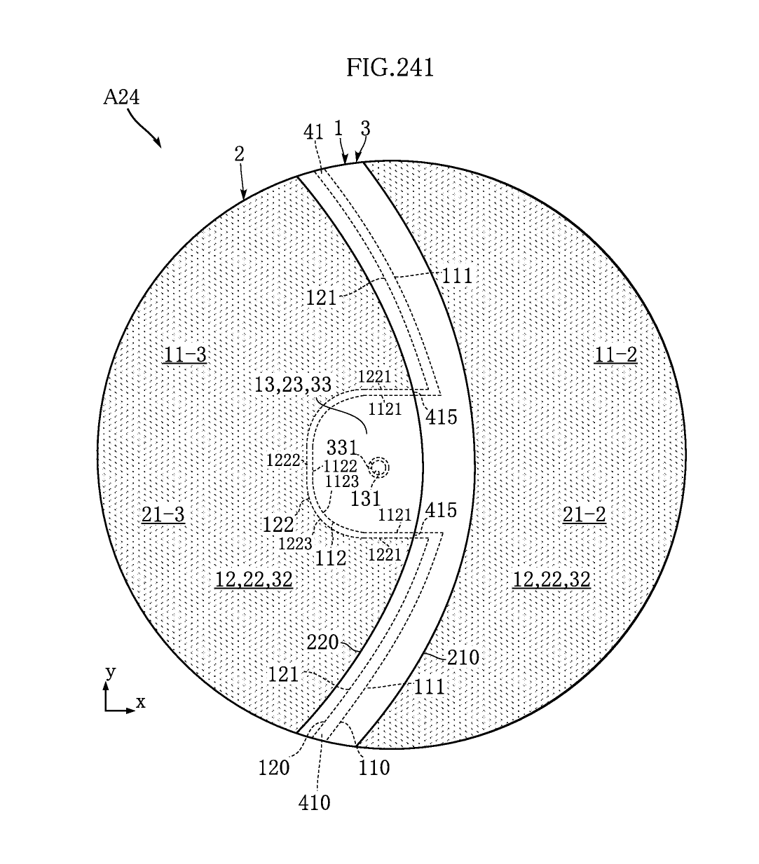

FIG. 241 is an enlarged partial plan view showing an organic thin film solar cell module A24 according to the twenty-fourth embodiment of the present invention. In this embodiment, although the first connection portion 13, the second connection portion 23, and the photoelectric conversion layer connection portion 33 are configured in the same way as the organic thin film solar cell module A23, the shapes of the first block first edge 110, the first block second edge 120, the second block first edge 210, the second block second edge 220, and the substrate exposure region 410 are different from the foregoing embodiments.

In this embodiment, the first side 111 of the first block 11-2 and the second side 121 of the first block 11-3 shown in FIG. 222 are both formed in a curved shape. However, the first side 111 and the second side 121 are parallel to each other. Likewise, the second block first edge 210 of the second block 21-2 and the second block second edge 220 of the second block 21-3 are both formed in a curved shape. However, the second block first edge 210 and the second block second edge 220 are parallel to each other. In addition, the first side 111, the second side 121, the second block first edge 210, and the second block second edge 220 are parallel to each other.

The configuration according to the above embodiment also suppresses a decrease in area of the photoelectric conversion layer generation section 32, which actually contributes to the power generation. Further, as seen from this embodiment, the first side 111 and the second side 121 may be formed in various shapes, such as a curved shape and a bent shape, without limitation to the linear shape. Likewise, the second block first edge 210 and the second block second edge 220 may also be formed in various shapes, such as a curved shape and a bent shape, without limitation to the linear shape.

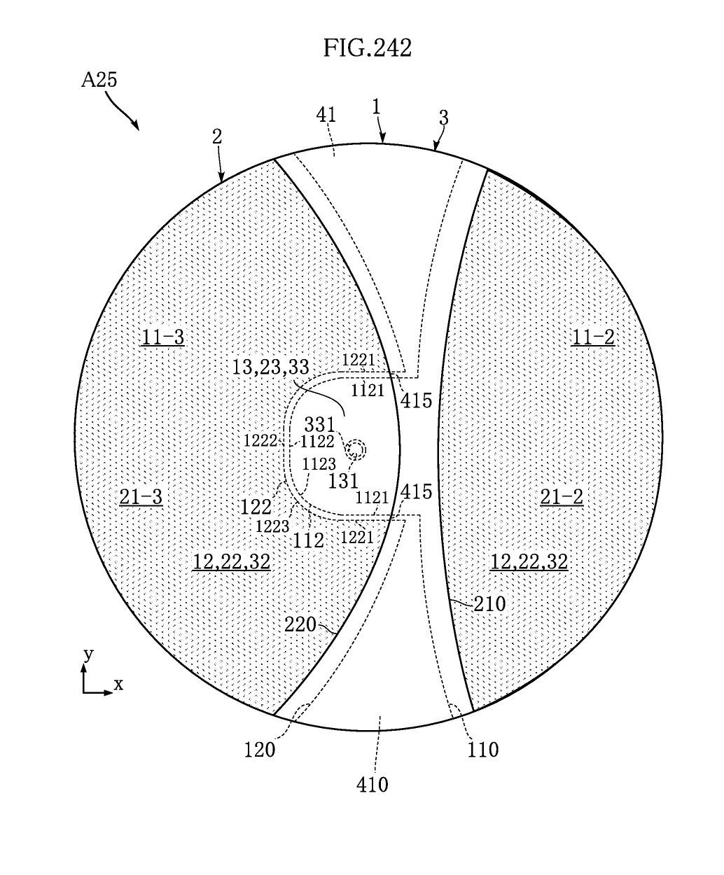

FIG. 242 is an enlarged partial plan view showing an organic thin film solar cell module A25 according to the twenty-fifth embodiment of the present invention. In this embodiment, although the first connection portion 13, the second connection portion 23, and the photoelectric conversion layer connection portion 33 are configured in the same way as the organic thin film solar cell module A23 and the organic thin film solar cell module A24, the shapes of the first block first edge 110 of the first block 11-2, the first block second edge 120 of the first block 11-3, the second block first edge 210 of the second block 21-2, the second block second edge 220 of the second block 21-3, and the substrate exposure region 410 are different from the foregoing embodiments.

In this embodiment, the first block first edge 110 of the first block 11-2 and the first block second edge 120 of the first block 11-3 are formed in a curved shape, except for the first shielded portion 112 and the second shielded portion 122. The curved portions are formed so as to protrude in opposite directions in the x-direction, in the z-direction view, and not parallel to each other. Likewise, the second block first edge 210 of the second block 21-2 and the second block second edge 220 of the second block 21-3 are formed so as to protrude in opposite directions in the x-direction, in the z-direction view, and not parallel to each other. However, the curved portion of the first block first edge 110 of the first block 11-2 and the second block first edge 210 of the second block 21-2 are parallel to each other. Likewise, the curved portion of the first block second edge 120 of the first block 11-3 and the second block second edge 220 of the second block 21-3 are parallel to each other.

The configuration according to the above embodiment also suppresses a decrease in area of the photoelectric conversion layer generation section 32, which actually contributes to the power generation. Here, it is not mandatory to make the first block first edge 110 and the first block second edge 120 parallel to each other, in a portion spaced apart from the second block 21 in the z-direction view. In addition, it is not mandatory to make the second block first edge 210 and the second block second edge 220 parallel to each other.

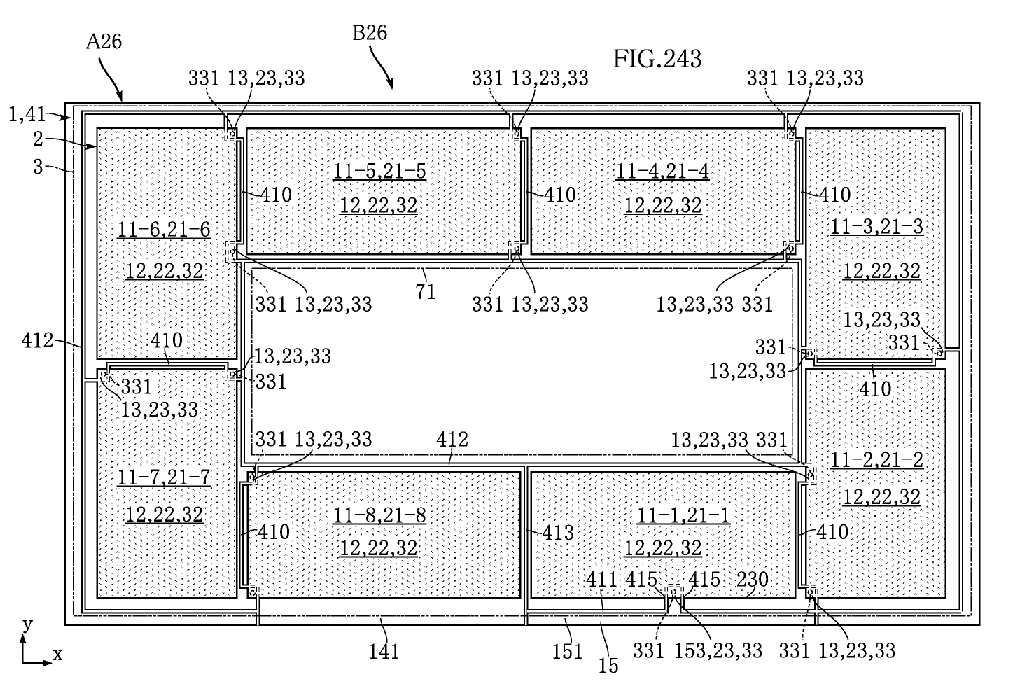

FIG. 243 illustrates an organic thin film solar cell module A26 and an electronic device B26 according to the twenty-sixth embodiment of the present invention. In this embodiment, the first conductive layer 1 includes eight first blocks 11-1 to 8, and the second conductive layer 2 includes eight second blocks 21-1 to 8. In addition, eight sets of the first electrode section 12, the second electrode section 22, and the photoelectric conversion layer generation section 32 are connected in series, via fourteen sets of the first connection portion 13, the second connection portion 23, and the photoelectric conversion layer connection portion 33, and power is outputted from the external electrode section 141 and the external electrode section 151. In this embodiment, further, eight sets of the first electrode section 12, the second electrode section 22, and the photoelectric conversion layer generation section 32 are aligned in an annular shape, in the z-direction view.

The base substrate 41 is located, and a part of the first conductive layer 1 may be located, in the region surrounded by the eight sets of the first electrode section 12, the second electrode section 22, and the photoelectric conversion layer generation section 32 in the z-direction view. In this region, however, it is preferable that only the base substrate 41 is located. This region is utilized for exposing the display unit, for example constituted of an LCD panel, in the drive unit 71, in the outer appearance of the electronic device B26. The electronic device B26 thus configured can be exemplified by an LCD wrist watch and a mobile electronic terminal.

In this embodiment, the substrate exposure region 411 defining the intersection 415 includes two intersections 415 intersecting the second block third edge 230 of the second block 21. The intersections 415 are located at a central position of the second block third edge 230 linearly extending in the x-direction.

The configuration according to the above embodiment also suppresses a decrease in area of the photoelectric conversion layer generation section 32, which actually contributes to the power generation.

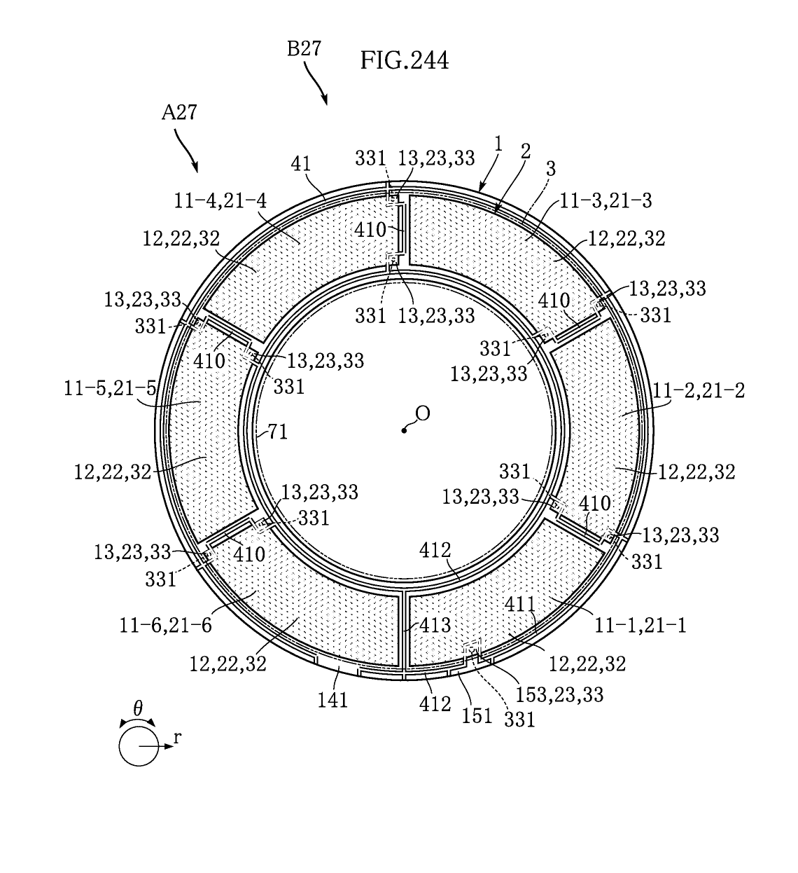

FIG. 244 illustrates an organic thin film solar cell module A27 and an electronic device B27 according to the twenty-seventh embodiment of the present invention. For the description with reference to FIG. 244, a cylindrical coordinate system, formed about a central axis passing a point O, is employed. An r-direction represents the radial direction, and a θ-direction represents the circumferential direction. In this embodiment, the first conductive layer 1 includes six first blocks 11-1 to 6, and the second conductive layer includes six second blocks 21-1 to 6. In addition, six sets of the first electrode section 12, the second electrode section 22, and the photoelectric conversion layer generation section 32 are connected in series, via ten sets of the first connection portion 13, the second connection portion 23, and the photoelectric conversion layer connection portion 33, and power is outputted from the external electrode section 141 and the external electrode section 151. In this embodiment, further, six sets of the first electrode section 12, the second electrode section 22, and the photoelectric conversion layer generation section 32 are aligned in an annular shape along the θ-direction, in the z-direction view.

As in the organic thin film solar cell module A26 and the electronic device B26, the base substrate 41 is located, and a part of the first conductive layer 1 may be located, in the region surrounded by the six sets of the first electrode section 12, the second electrode section 22, and the photoelectric conversion layer generation section 32 in the z-direction view. In this region, however, it is preferable that only the base substrate 41 is located. The electronic device B27 thus configured can be exemplified by an LCD wrist watch.

The configuration according to the above embodiment also suppresses a decrease in area of the photoelectric conversion layer generation section 32, which actually contributes to the power generation.

The organic thin film solar cell module and the electronic device according to the present invention are in no way limited to the foregoing embodiments. The specific configurations of the elements of the organic thin film solar cell module and the electronic device according to the present invention may be modified in various manners.

The technical features of the present invention may be expressed as the following appendices.

### Appendix 1G

An organic thin film solar cell module including:

a transparent base substrate;

a transparent first conductive layer disposed on the base substrate;

a second conductive layer; and

a photoelectric conversion layer formed of an organic thin film and interposed between the first conductive layer and the second conductive layer,

in which the first conductive layer includes two first blocks adjacent to each other via a substrate exposure region where a part of the base substrate is exposed from the first conductive layer,

the second conductive layer includes two second blocks adjacent to each other via a part of the substrate exposure region,

one of the two first blocks adjacent to each other includes a first block first edge that defines the substrate exposure region,

the other of the two first blocks adjacent to each other includes a first block second edge that defines the substrate exposure region,

one of the two second blocks adjacent to each other includes a second block first edge overlapping with the one of the two first blocks in plan view, and located opposite to the first block second edge of the other of the two first blocks adjacent to each other, across the first block first edge of the one of the two first blocks adjacent to each other,

the other of the two second blocks adjacent to each other includes a second block second edge opposing the first edge of the one of the two second blocks adjacent to each other, in plan view,

the photoelectric conversion layer includes a photoelectric conversion layer perforated portion formed so as to penetrate through a photoelectric conversion layer connection portion in the thickness direction, the photoelectric conversion layer connection portion being formed in a region overlapping with both of the one of the two first blocks adjacent to each other and the other of the two second blocks adjacent to each other in plan view, and defined by (i) a first shielded portion corresponding to a portion of the first block first edge of the one of the two first blocks adjacent to each other overlapping with the other of the two second blocks adjacent to each other, and (ii) the second block second edge of the other of the two second blocks adjacent to each other, and

the substrate exposure region includes one or more intersections intersecting the second block second edge of the other of the two second blocks adjacent to each other.

### Appendix 2G

The organic thin film solar cell module according to appendix 1G, in which the one of the two first blocks adjacent to each other includes a first electrode section spaced apart from the photoelectric conversion layer connection portion and overlapping with the second conductive layer in plan view,

the one of the two second blocks adjacent to each other includes a second electrode section coinciding with the first electrode section in plan view, and

the photoelectric conversion layer includes a photoelectric conversion layer generation section coinciding with the first electrode section and the second electrode section in plan view.

### Appendix 3G

The organic thin film solar cell module according to appendix 2G, in which the one of the two first blocks adjacent to each other includes a first connection portion coinciding with the photoelectric conversion layer connection portion in plan view, and

the other of the two second blocks adjacent to each other includes a second connection portion coinciding with the photoelectric conversion layer connection portion in plan view.

### Appendix 4G

The organic thin film solar cell module according to appendix 3G, in which the photoelectric conversion layer connection portion and a part of the photoelectric conversion layer generation section are located adjacent to each other, in a direction intersecting the direction in which the two first blocks are aligned, in plan view.

### Appendix 5G

The organic thin film solar cell module according to appendix 3G, in which the photoelectric conversion layer generation section is located on both sides of the photoelectric conversion layer connection portion, in a direction intersecting the direction in which the two first blocks are aligned, in plan view.

### Appendix 6G

The organic thin film solar cell module according to any one of appendices 3G to 5G, in which the photoelectric conversion layer perforated portion has a circular shape in plan view.

### Appendix 7G

The organic thin film solar cell module according to any one of appendices 3G to 6G, in which the first connection portion of the one of the two first blocks adjacent to each other includes a first perforated portion enclosed in the photoelectric conversion layer perforated portion in plan view, and formed so as to penetrate in the thickness direction.

### Appendix 8G

The organic thin film solar cell module according to appendix 7G, in which an inner edge of the first perforated portion is spaced apart from an inner edge of the photoelectric conversion layer perforated portion in plan view.

### Appendix 9G

The organic thin film solar cell module according to any one of appendices 3G to 6G, in which the first connection portion of the one of the two first blocks adjacent to each other covers the base substrate, in a region enclosed in the photoelectric conversion layer perforated portion, in plan view.

### Appendix 10G

The organic thin film solar cell module according to any one of appendices 3G to 9G, in which the other of the two second blocks adjacent to each other includes second block third edge connected to the second block second edge and extending in a direction away from the one of the two second blocks adjacent to each other, and

the substrate exposure region includes two of the intersections, one formed on the second block second edge, and the other formed on the second block third edge, of the other of the two second blocks adjacent to each other.

### Appendix 11G

The organic thin film solar cell module according to any one of appendices 3G to 9G, in which the substrate exposure region includes two of the intersections, each formed on the second block second edge of the other of the two second blocks adjacent to each other.

### Appendix 12G

The organic thin film solar cell module according to any one of appendices 3G to 11G, in which the first block first edge of the one of the two first blocks adjacent to each other has a first side in a region spaced apart from the two second block in plan view, and the first block second edge of the other of the two first blocks adjacent to each other has a second edge parallel to the first side.

### Appendix 13G

The organic thin film solar cell module according to appendix 12G, in which the first side and the second side are linear.

### Appendix 14G

The organic thin film solar cell module according to appendix 12G or 13G, in which the second block first edge of the one of the two second blocks adjacent to each other, and the second block second edge of the other of the two second blocks adjacent to each other are parallel to each other.

### Appendix 15G

The organic thin film solar cell module according to appendix 14G, in which the second block first edge of the one of the two second blocks adjacent to each other, and the second block second edge of the other of the two second blocks adjacent to each other are linear.

### Appendix 16G

The organic thin film solar cell module according to appendix 12G, in which the first side of the one of the two first blocks adjacent to each other, the second side of the other of the two first blocks adjacent to each other, the second block first edge of the one of the two second blocks adjacent to each other, and the second block second edge of the other of the two second blocks adjacent to each other are parallel to each other.

### Appendix 17G

The organic thin film solar cell module according to appendix 16G, in which the first side, the second side, the second block first edge, and the second block second edge are linear.

### Appendix 18G

The organic thin film solar cell module according to any one of appendices 3G to 17G, in which three or more of the first blocks adjacent to each other, and three or more of the second blocks adjacent to each other are aligned.

### Appendix 19G

The organic thin film solar cell module according to appendix 18G, in which three or more of the first blocks adjacent to each other, and three or more of the second blocks adjacent to each other are aligned along a straight line.

### Appendix 20G

The organic thin film solar cell module according to appendix 19G, in which three or more of the first blocks adjacent to each other, and three or more of the second blocks adjacent to each other are aligned in an annular shape.

### Appendix 21G

The organic thin film solar cell module according to any one of appendices 18G to 20G, in which the second block located between two of the second blocks, out of the three or more second blocks adjacent to each other, includes a second block first edge and a second block second edge, and two second block third edges each connecting both ends of the second block first edge and both ends of the second block second edge.

### Appendix 22G

The organic thin film solar cell module according to appendix 21G, in which the second block first edge and the second block second edge of the second block located between two of the second blocks, out of the three or more second blocks adjacent to each other, are parallel to each other.

### Appendix 23G

The organic thin film solar cell module according to appendix 22G, in which the two second block third edges of the second block located between two of the second blocks, out of the three or more second blocks adjacent to each other, are parallel to each other.

### Appendix 24G

The organic thin film solar cell module according to appendix 23G, in which the second block first edge and the second block second edge are perpendicular to the two second block third edges, in the second block located between two of the second blocks, out of the three or more second blocks adjacent to each other.

### Appendix 25G

The organic thin film solar cell module according to any one of appendices 3G to 24G, in which the first conductive layer includes a third block having an external connection portion coinciding with the photoelectric conversion layer connection portion in plan view, and an external electrode section connected to the external connection portion and exposed from the second conductive layer and the photoelectric conversion layer.

### Appendix 26G

The organic thin film solar cell module according to any one of appendices 1G to 25G, in which the first conductive layer is formed of ITO.

### Appendix 27G

The organic thin film solar cell module according to any one of appendices 1G to 26G, in which the second conductive layer is formed of a metal.

### Appendix 28G

The organic thin film solar cell module according to any one of appendices 1G to 27G, in which the second conductive layer is formed of A1.

### Appendix 29G

The organic thin film solar cell module according to any one of appendices 1G to 28G, further including a passivation layer covering the second conductive layer.

### Appendix 30G

The organic thin film solar cell module according to appendix 29G, in which the passivation layer is formed of SiN or SiON.

### Appendix 31G

An electronic device including:
the organic thin film solar cell module according to any one of appendices 1G to 30G; and

a drive unit to operate by power supplied from the organic thin film solar cell module.

1. An organic thin film solar cell module comprising:
a transparent base substrate;
a transparent first conductive layer disposed on the base substrate;
a second conductive layer; and
a photoelectric conversion layer forming of an organic thin film and interposed between the first conductive layer and the second conductive layer,
wherein the second conductive layer is thicker than the photoelectric conversion layer.

2. The organic thin film solar cell module according to claim 1, wherein the first conductive layer includes two first blocks adjacent to each other via a substrate exposure region where a part of the base substrate is exposed from the first conductive layer,
the second conductive layer includes two second blocks adjacent to each other via a part of the substrate exposure region, and
the photoelectric conversion layer includes a photoelectric conversion layer perforated portion penetrating through a photoelectric conversion layer connection portion in a thickness direction, the photoelectric conversion layer connection portion overlapping with one of the two first blocks and another of the two second blocks in plan view.

3. The organic thin film solar cell module according to claim 2, wherein the photoelectric conversion layer includes a projection surrounding the photoelectric conversion layer perforated portion in plan view, the projection being covered with the second conductive layer.

4. The organic thin film solar cell module according to claim 2, wherein the one of the two first blocks includes a first electrode section spaced apart from the photoelectric conversion layer connection portion and overlapping with the second conductive layer in plan view,
another of the two second blocks includes a second electrode section coinciding with the first electrode section in plan view, and
the photoelectric conversion layer includes a photoelectric conversion layer generation section coinciding with the first electrode section and the second electrode section in plan view.

5. The organic thin film solar cell module according to claim 4, wherein the one of the two first blocks includes a first connection portion coinciding with the photoelectric conversion layer connection portion in plan view, and
said another of the two the second blocks includes a second connection portion coinciding with the photoelectric conversion layer connection portion in plan view.

6. The organic thin film solar cell module according to claim 5, wherein the photoelectric conversion layer perforated portion has a circular shape in plan view.

7. The organic thin film solar cell module according to claim 6, wherein the first connection portion of the one of the two first blocks includes a first perforated portion enclosed in the photoelectric conversion layer perforated portion in plan view and penetrating in the thickness direction.

8. The organic thin film solar cell module according to claim 7, wherein an inner edge of the first perforated portion is spaced apart from an inner edge of the photoelectric conversion layer perforated portion in plan view.

9. The organic thin film solar cell module according to claim 5, wherein the first connection portion of the one of the two first blocks covers the base substrate in a region enclosed in the photoelectric conversion layer perforated portion in plan view.

10. The organic thin film solar cell module according to claim 1, wherein the first conductive layer is formed of ITO.

11. The organic thin film solar cell module according to claim 1, wherein the second conductive layer is formed of a metal.

12. The organic thin film solar cell module according to claim 11, wherein the second conductive layer is formed of A1.

13. The organic thin film solar cell module according to claim 1, further comprising a passivation layer covering the second conductive layer.

14. The organic thin film solar cell module according to claim 13, wherein the passivation layer is formed of SiN or SiON.

15. An electronic device comprising:
an organic thin film solar cell module according to claim 1; and
a drive unit to operate by power supplied from the organic thin film solar cell module.

16. A method of manufacturing an organic thin film solar cell module, the method comprising:
disposing a transparent first conductive layer on a transparent base substrate;
disposing a photoelectric conversion layer formed of an organic thin film on the first conductive layer; and
disposing a second conductive layer on the photoelectric conversion layer,
wherein the disposing of the second conductive layer includes forming the second conductive layer so as to be thicker than the photoelectric conversion layer.

17. The method according to claim 16, wherein the disposing of the second conductive layer includes depositing a metal through a vapor deposition process.

18. The method according to claim 16, wherein the disposing of the photoelectric conversion layer includes forming a photoelectric conversion layer perforated portion so as to penetrate through the photoelectric conversion layer, and
the disposing of the second conductive layer includes covering the photoelectric conversion layer perforated portion with the second conductive layer.

19. The method according to claim 18, wherein the disposing of the photoelectric conversion layer includes forming, in the first conductive layer, the photoelectric conversion layer perforated portion and a first perforated portion enclosed in the photoelectric conversion layer perforated portion in plan view and penetrating in the thickness direction.

20. The method according to claim 19, wherein the forming of the photoelectric conversion layer perforated portion includes using an IR laser beam.

21. The method according to claim 16, wherein the first conductive layer is formed of ITO.

22. The method according to claim 16, wherein the second conductive layer is formed of a metal.

23. The method according to claim 22, wherein the second conductive layer is formed of A1.
